(19) United States
(12) Patent Application Publication
(10) Pub. No.: US 2026/0131332 A1
(43) Pub. Date: May 14, 2026

(54) THERMAL MODULE WITH OPTICAL FIBERS EXTENDING THERETHROUGH

(71) Applicant: GEN-PROBE INCORPORATED, San Diego, CA (US)

(72) Inventors: David OPALSKY, San Diego, CA (US); David Howard COMBS, San Diego, CA (US); Norbert D. HAGEN, Carlsbad, CA (US); David BUSE, San Diego, CA (US)

(73) Assignee: GEN-PROBE INCORPORATED, San Diego, CA (US)

(21) Appl. No.: 19/438,743

(22) Filed: Jan. 2, 2026

Related U.S. Application Data
(63) Continuation of application No. PCT/US2025/026844, filed on Apr. 29, 2025.
(60) Provisional application No. 63/640,761, filed on Apr. 30, 2024.

(51) Int. Cl. B01L 7/00

(52) U.S. Cl. CPC B01L 7/00; B01L 2300/023; B01L 2300/0654

(57) ABSTRACT

An assembly includes first and second thermal modules. Each thermal module includes at least one thermal assembly comprising a thermal element in thermal contact with an associated thermal block. Each thermal block has an exposed contact surface, and each contact surface of the second thermal module is situated in aligned opposition with respect to an associated contact surface of the first thermal module. A thermal module actuator is configured to effect automated relative movement between the first thermal module and the second thermal module to vary a distance between the contact surface of each thermal assembly of the second thermal module and the associated contact surface of each thermal assembly of the first thermal module. An optical fiber is associated with a through hole extending through the thermal block of each thermal assembly of the first thermal module to transmit an optical signal through each thermal block of the first thermal module.

### CROSS REFERENCE TO RELATED APPLICATION

This application is a continuation application of International Application No. PCT/US2025/026844 designating the United States and having an international filing date of Apr. 29, 2025, and which claims the benefit of the filing date of U.S. Provisional Application No. 63/640,761, filed Apr. 30, 2024.

### FIELD OF THE DISCLOSURE

This disclosure relates to systems and methods for performing sample preparation and sample analysis operations within a fluidic cartridge, including effecting fluid movement through channels between chambers within the fluidic cartridge, sample purification, sample/reagent mixing to form sample reaction mixtures, heating and/or cooling sample reaction mixtures, and detecting signals indicative of test results from sample reaction mixtures.

### BACKGROUND

Assay procedures performed in test platforms, such as fluidic cartridges, require precise movement of fluid throughout the fluidic cartridge. Such precision, both in terms of volume and timing of fluid movement, requires precision devices and robust process controls.

In addition, assay procedures often require the application of thermal energy (isothermal or thermocyclic energy) to a reaction chamber to induce a desired reaction within a reaction mixture contained within the reaction chamber. Such assay procedures may also involve the detection of an optical emission signal emitted from the contents of the reaction chamber during the thermally-induced reaction and/or the application of an excitation optical signal to the contents of the reaction chamber.

Application of thermal energy to the reaction chamber requires that a thermal device, or heater, such as a thermoelectric module, be placed in thermal contact with an outer surface of a wall of the reaction chamber, which typically requires physical or near contact between the thermal device and the outer surface of the wall. Similarly, detecting an optical emission signal from the contents of the reaction chamber and applying an optical excitation signal to the reaction chamber requires that an optical detector or an optical emitter (light source) be placed in physical contact or near contact with an outer surface of a wall of the reaction chamber or that an optical transmitter (e.g., a waveguide, such as a light pipe or an optical fiber) extending from the detector and/or emitter be placed in physical contact or near contact with the outer surface of the reaction chamber so that optical signals may be transmitted from the emitter to the reaction chamber and/or so that optical signals may be transmitted from the reaction chamber to the detector.

A thermal device placed in contact with an outer surface of the reaction chamber would interfere with an optical device (e.g., detector/emitter/transmitter) placed in contact with the same outer surface of the reaction chamber, if not prevent placement of an optical device in contact with the same outer surface of the reaction chamber, and vice versa. Consequently, the thermal device is typically placed in contact with an outer surface of one wall of the reaction chamber, and the optical device is placed in contact with an outer surface of another wall of the reaction chamber (typically an opposed wall). Having a thermal device in contact with only one wall of the reaction chamber, however, can lead to a temperature gradient within the reaction chamber between the wall of the chamber that is in contact with the thermal device and the opposite wall that is not in contact with the thermal device (i.e., the wall that is in contact with the optical device). Such a thermal gradient could lead to inaccurate and/or inconsistent test results. Of course, placing the thermal device on both opposed walls of the reaction chamber to minimize or eliminate such a temperature gradient could interfere with the ability of the detector and/or emitter to detect optical emission signals from or apply optical excitation signals to the contents of the reaction chamber.

### SUMMARY

The following presents a simplified summary in order to provide a basic understanding of some aspects described herein. This summary is not an extensive overview of the claimed subject matter. It is intended to neither identify key or critical elements of the claimed subject matter nor delineate the scope thereof. Its sole purpose is to present some concepts in a simplified form as a prelude to the more detailed description that is presented later.

Implementations of the disclosure can be described in view of the following embodiments, the features of which can be combined in any reasonable manner.

Embodiment A1. An assembly comprising: a first thermal module comprising one or more thermal assemblies, wherein each thermal assembly of the first thermal module comprises: a thermal element; and a thermal block associated with the thermal element, wherein the thermal block has an exposed contact surface and at least one through hole extending through the thermal block, and wherein the thermal element and the associated thermal block of each thermal assembly are in thermal contact; a second thermal module comprising one or more thermal assemblies, wherein each thermal assembly of the second thermal module comprises: a thermal element; and a thermal block associated with the thermal element, wherein the thermal block has an exposed contact surface, wherein the thermal element and the associated thermal block of each thermal assembly are in thermal contact, and wherein each contact surface of the second thermal module is situated in aligned opposition with respect to an associated contact surface of the first thermal module; a thermal module actuator configured to effect automated relative movement between the first thermal module and the second thermal module to vary a distance between the contact surface of each thermal assembly of the second thermal module and the associated contact surface of each thermal assembly of the first thermal module; and an optical fiber associated with each through hole extending through the thermal block of each thermal assembly of the first thermal module to transmit an optical signal through each thermal block of the first thermal module.

Embodiment A2. The assembly of embodiment A1, wherein each thermal block comprises at least one of a thermally conductive ceramic and a metal.

Embodiment A3. The assembly of embodiment A1 or A2, wherein each thermal block comprises aluminum.

Embodiment A4. The assembly of any one of embodiments A1 to A3, further comprising at least one of an optical emitter and an optical detector optically coupled to a proximal end of each optical fiber associated with the through hole extending through the thermal block of each thermal assembly of the first thermal module.

Embodiment A5. The assembly of any one of embodiments A1 to A4, wherein the first thermal module comprises two thermal assemblies, and wherein the second thermal module comprises two thermal assemblies.

Embodiment A6. The assembly of any one of embodiments A1 to A5, wherein the thermal block of each thermal assembly of the first thermal module includes at least two through holes extending through the thermal block.

Embodiment A7. The assembly any one of embodiments A1 to A6, wherein the thermal element of each thermal assembly of the first thermal module includes a through hole that is associated with each through hole extending through the associated thermal block of the first thermal module, and wherein each optical fiber extends through one of the through holes extending through the thermal element of the first thermal module.

Embodiment A8. The assembly of any one of embodiments A1 to A7, wherein the through hole extends through the thermal block of each thermal assembly of the first thermal module to the contact surface, and wherein the optical fiber associated with each through hole extends at least partially through the associated through hole or is aligned with the associated through hole.

Embodiment A9. The assembly of embodiment A8, wherein each optical fiber extends fully through the associated hole so that an end of the optical fiber is flush with the contact surface.

Embodiment A10. The assembly of embodiment A8, wherein each optical fiber extends fully through the associated hole so that an end of the optical fiber extends above the contact surface of the associated thermal block.

Embodiment A11. The assembly of embodiment A10, wherein the end of each optical fiber extends above the contact surface by 0.05 mm to 0.35 mm.

Embodiment A12. The assembly of any one of embodiments A1 to A11, wherein the thermal block of each thermal assembly of the second thermal module has at least one through hole extending through the thermal block, and wherein the assembly comprises an optical fiber associated with each through hole extending through the thermal block of each thermal assembly of the second thermal module to transmit an optical signal through each thermal block of the second thermal module.

Embodiment A13. The assembly of embodiment A12, further comprising at least one of an optical emitter and an optical detector optically coupled to a proximal end of each optical fiber associated with the through hole extending through the thermal block of each thermal assembly of the second thermal module.

Embodiment A14. The assembly of embodiment A12 or A13, wherein the thermal block of each thermal assembly of the second thermal module includes at least two through holes extending through the thermal block.

Embodiment A15. The assembly any one of embodiments A12 to A14, wherein the thermal element of each thermal assembly of the second thermal module includes a through hole that is associated with each through hole extending through the associated thermal block of the second thermal module, and wherein each optical fiber extends through one of the through holes extending through the thermal element of the second thermal module.

Embodiment A16. The assembly of any one of embodiments A1 to A15, wherein each thermal assembly of the first thermal module comprises a cover positioned over the thermal element and the associated thermal block of the thermal assembly, wherein the cover has an opening formed therein through which the contact surface of the thermal block is exposed, and wherein each thermal assembly of the second thermal module comprises a cover positioned over the thermal element and the associated thermal block of the thermal assembly, wherein the cover has an opening formed therein through which the contact surface of the thermal block is exposed.

Embodiment A17. The assembly of embodiment A16, wherein the cover comprises a plastic.

Embodiment A18. The assembly of embodiment A16 or A17, wherein each cover comprises at least one of Ultem® (polyetherimide) and Delrin® (polyoxymethylene (POM)).

Embodiment A19. The assembly of any one of embodiments A1 to A18, wherein the thermal element of each thermal assembly of the first thermal module comprises a thermoelectric module, and wherein the thermal element of each thermal assembly of the second thermal module comprises a thermoelectric module.

Embodiment A20. The assembly of any one of embodiments A1 to A19, wherein each thermal assembly of the second thermal module comprises a heat sink including a plurality of heat dissipation fins, and wherein the thermal element of each thermal assembly of the second thermal module is in thermal contact with the heat sink.

Embodiment A21. The assembly of embodiment A20, wherein each heat sink comprises at least one of a thermally conductive ceramic and a metal.

Embodiment A22. The assembly of embodiment A20 or A21, wherein each heat sink comprises aluminum.

Embodiment A23. The assembly of any one of embodiments A20 to A22, further comprising a separate heat sink associated with each thermal assembly of the second thermal module.

Embodiment A24. The assembly of any one of embodiments A20 to A23, further comprising a heat sink heater operatively associated with each heat sink.

Embodiment A25. The assembly of any one of embodiments A1 to A24, further comprising a mounting block, wherein the thermal element of each thermal assembly of the first thermal module is in thermal contact with the mounting block.

Embodiment A26. The assembly of embodiment A25, wherein the mounting block comprises at least one of a thermally conductive ceramic and a metal.

Embodiment A27. The assembly of embodiment A25 or A26, wherein the mounting block comprises aluminum.

Embodiment A28. The assembly of any one of embodiments A25 to A27, further comprising a mounting block heater operatively associated with the mounting block.

Embodiment A29. The assembly of any one of embodiments A25 to A28, further comprising a fan positioned adjacent the mounting block.

Embodiment A30. The assembly of embodiment A1, further comprising: a heat sink associated with the second thermal module, wherein the heat sink comprises a plurality of heat dissipation fins, and wherein the thermal element of each thermal assembly of the second thermal module is in thermal contact with the heat sink; a cover positioned over the thermal element and associated thermal block of each thermal assembly of the second thermal module, wherein the cover has an opening extending therein through which the contact surface of the associated thermal block is exposed, at least two fasteners securing the cover to the heat sink of each thermal assembly of the second thermal module, each fastener extending through a hole through a portion of the heat sink and into the cover of each thermal assembly of the second thermal module; and a spring disposed over each of the at least two fasteners between a head of the fastener and a surface of the heat sink of the second thermal module.

Embodiment A31. The assembly of embodiment A30, wherein the heat sink comprises a separate heat sink for each thermal assembly of the second thermal module.

Embodiment A32. The assembly of embodiment A30 or embodiment A31, further comprising: at least two fasteners securing the heat sink of the second thermal module to an attaching structure, each fastener extending through an opening formed in the heat sink and into the attaching structure; and a spring disposed over each of the at least two fasteners securing the heat sink of the second thermal module to an attaching structure between a head of the fastener and a surface of the heat sink of the second thermal module.

Embodiment A33. The assembly of any one of embodiments A1 and A30 to A32, further comprising: a mounting block associated with the first thermal module, wherein the thermal element of each thermal assembly of the first thermal module is in thermal contact with the mounting block; a cover positioned over each thermal element and associated thermal block of each thermal assembly of the first thermal module, wherein the cover has an opening formed therein through which the contact surface of the thermal block is exposed, at least two fasteners securing the cover of each thermal assembly of the first thermal module to the mounting block, each fastener extending through a hole through a portion of the mounting block and into the cover; and a spring disposed over each of the at least two fasteners securing the cover of each thermal assembly of the first thermal module to the mounting block between a head of the fastener and a surface of the mounting block.

Embodiment A34. The assembly of any one of embodiments A1 to A33, wherein the second thermal module is fixed and the first thermal module is movable, and wherein the thermal module actuator is coupled to the first thermal module and is configured to move the first thermal module between a first position and a second position with respect to the second thermal module, wherein the contact surface of each thermal assembly of the first thermal module is closer to the associated contact surface of each thermal assembly of the second thermal module when the first thermal module is in the second position than when the first thermal module is in the first position.

Embodiment A35. The assembly of embodiment A34, further comprising a contact detector coupled to the first thermal module and configured generate a detectable signal when the contact detector contacts a test platform disposed between the first thermal module and the second thermal module when the first thermal module is moved from the first position to the second position.

Embodiment A36. The assembly of embodiment A35, further comprising an upper block to which the first thermal module is attached and with which the thermal module actuator is coupled for moving the first thermal module between the first and second positions, and wherein the contact detector comprises: an optical sensor attached to the upper block and comprising an optical transmitter and an optical receiver spaced apart from the optical transmitter; and a plunger including a plunger rod movably disposed within a hole formed through the upper block and configured so that when the contact detector contacts the test platform disposed between the first and second thermal modules, one portion of the plunger contacts the test platform and another portion of the plunger is moved to a position between the optical transmitter and the optical receiver of the optical sensor to alter an optical beam from the optical transmitter to the optical receiver.

Embodiment A37. The assembly of any one of embodiments A34 to A36, wherein the thermal module actuator comprises: a motor secured to a motor mount; and a lead screw coupled to the motor and to the first thermal module so that rotation of the lead screw by the motor effects movement of the first thermal module with respect to the second thermal module from the first position to the second position or from the second position to the first position.

Embodiment A38. The assembly of embodiment A37, wherein the motor is mounted to a motor mounting plate that is supported by the motor mount, and wherein, when the first thermal assembly is moved to the second position by the thermal module actuator, continued operation of the motor causes the motor mounting plate to separate from the motor mount.

Embodiment A39. The assembly of embodiment A38, further comprising at least one spring disposed between the motor mounting plate and a portion of the motor mount, such that a spring force of each spring increases as the motor mounting plate separates from the motor mount.

Embodiment A40. The assembly of embodiment A39, wherein the motor mount comprises: side supports; a top crossbar extending between the side supports; and an intermediate crossbar extending between the side supports at a spaced-apart position from the top crossbar, wherein the motor and motor mounting plate are supported on the intermediate cross bar such that when the first thermal assembly is moved to the second position by the thermal module actuator, continued operation of the motor causes the motor mounting plate to separate from the intermediate crossbar and move toward the top crossbar, and wherein the at least one spring comprises two springs disposed between the motor mounting plate and the top crossbar.

Embodiment A41. The assembly of embodiment A40, further comprising: an upper block to which the first thermal module is attached, wherein the lead screw is coupled to the upper block; and linear bearings positioned between the intermediate crossbar and the upper block.

Embodiment A42. The assembly according to any one of embodiments A1 to A41, further comprising a movable tray for supporting a test platform and configured for selective, motorized movement between an extended position not located between the first and second thermal modules and a retracted position located between the first and second thermal modules.

Embodiment B1. A method comprising: (A) placing a test platform comprising a reaction chamber between a first heater and a second heater; (B) effecting automated movement of the first heater toward the second heater to sandwich the reaction chamber between the first and second heaters; (C) with the first and second heaters, applying thermal energy to or absorbing thermal energy from a reaction mixture contained within the reaction chamber sandwiched between the first and second heaters; and (D) during C, transmitting at least one optical signal through a portion of the first heater via an optical fiber embedded within or extending fully or partially through the first heater.

Embodiment B2. The method of embodiment B1, wherein each of the first and second heaters comprises a thermal element configured to emit thermal energy to heat a body in thermal contact with the thermal element and/or absorb thermal energy to cool a body in thermal contact with the thermal element, and wherein the optical fiber extends at least partially through a hole formed through the thermal element.

Embodiment B3. The method of embodiment B2, wherein the thermal element comprises a thermoelectric device.

Embodiment B4. The method of embodiment B2 or B3, wherein each of the first and second heaters comprises a thermal block associated with the thermal element, wherein the thermal block has an exposed contact surface that contacts the reaction chamber sandwiched between the first and second heaters.

Embodiment B5. The method of embodiment B4, wherein each thermal block comprises at least one of a thermally conductive ceramic and a metal.

Embodiment B6. The method of embodiment B4 or B5, wherein each thermal block comprises aluminum.

Embodiment B7. The method any one of embodiments B4 to B6, wherein a hole extends through the thermal block to the contact surface, and wherein the optical fiber extends at least partially through the hole extending through the thermal block, or is aligned with the hole extending through the thermal block.

Embodiment B8. The method of embodiment B7, wherein the optical fiber extends fully through the hole extending through the thermal block so that an end of the optical fiber is flush with the contact surface.

Embodiment B9. The method of embodiment B7, wherein the optical fiber extends fully through the hole extending through the thermal block so that an end of the optical fiber extends above the contact surface.

Embodiment B10. The method of any one of embodiments B4 to B9, wherein each of the first and second heaters comprises a cover positioned over the thermal element and the associated thermal block, wherein the cover has an opening formed therein through which the contact surface of the thermal block is exposed.

Embodiment B11. The method of embodiment B10, wherein the cover comprises a plastic.

Embodiment B12. The method of embodiment B10 or B11, wherein each cover comprises at least one of Ultem® (polyetherimide) and Delrin® (polyoxymethylene (POM)).

Embodiment B13. The method of any one of embodiments B2 to B12, wherein each of the first and second heaters comprises a heat sink, and wherein the thermal element of each of the first and second heaters is in thermal contact with the heat sink.

Embodiment B14. The method of embodiment B13, wherein the heat sink of at least one of the first and second heaters includes heat dissipation fins.

Embodiment B15. The method of embodiment B13 or B14, wherein each heat sink comprises at least one of a thermally conductive ceramic and a metal.

Embodiment B16. The method of any one of embodiments B13 to B15, wherein each heat sink comprises aluminum.

Embodiment B17. The method of any one of embodiments B1 to B16, wherein D comprises at least one of transmitting the at least one optical signal from an optical emitter to the reaction chamber via the optical fiber and transmitting the at least one optical signal from the reaction chamber to an optical detector via the optical fiber.

Embodiment B18. The method of embodiment B1, wherein each of the first and second heaters comprises at least two thermal elements configured to emit thermal energy to heat a body in thermal contact with the thermal element and/or absorb thermal energy to cool a body in thermal contact with the thermal element, wherein the first and second heaters comprise the same number of thermal elements, and wherein the optical fiber comprises an optical fiber extending at least partially through a hole formed through each thermal element of the first heater, each optical fiber being configured to transmit an optical signal to and/or from a different reaction chamber.

Embodiment B19. The method of embodiment B18, wherein each thermal element comprises a thermoelectric device.

Embodiment B20. The method of embodiment B18 or B19, wherein each of the first and second heaters comprises a thermal block associated with each thermal element, wherein each thermal block has an exposed contact surface that contacts a different reaction chamber or set of reaction chambers sandwiched between the first and second heaters.

Embodiment B21. The method of embodiment B20, wherein each optical fiber extends at least partially through or is aligned with a hole formed through the associated thermal block.

Embodiment B22. The method of embodiment B21, wherein each optical fiber extends fully through the associated hole so that an end of the optical fiber is flush with the contact surface or extends above the contact surface of the associated thermal block.

Embodiment B23. The method of any one of embodiments B20 to B22, wherein each of the first and second heaters comprises a cover positioned over each thermal element and the associated thermal block, wherein each cover has an opening formed therein through which the contact surface of the associated thermal block is exposed.

Embodiment B24. The method of embodiment B1, wherein the optical fiber comprises at least two optical fibers, each optical fiber extending at least partially through an associated hole formed through the first heater and configured to transmit an optical signal through the first heater to and/or from a different reaction chamber of the test platform.

Embodiment B25. The method of any one of embodiments B1 to B24, further comprising, before effecting automated movement of the first heater toward the second heater to sandwich the reaction chamber between the first and second heaters, effecting automated movement of the test platform from a first position not disposed between the first and second heaters to a second position between the first and second heaters.

Embodiment B26. The method of embodiment B25, wherein effecting automated movement of the test platform from the first position not disposed between the first and second heaters to the second position between the first and second heaters comprises supporting the test platform on a movable tray and effecting automated movement of the tray and the test platform supported by the tray from the first position not disposed between the first and second heaters to the second position between the first and second heaters.

Embodiment B27. The method of any one of embodiments B1 to B26, further comprising detecting the presence of a test platform between the first heater and the second heater with a test platform detector comprising an optical detector and a plunger shaft mounted in a fixed position with respect to the first heater, wherein the plunger shaft is movable with respect to the optical detector between a first position at which the plunger shaft is not detected by the optical detector and a second position at which the plunger shaft is detected by the optical detector, and wherein, while effecting automated movement of the first heater toward the second heater, if a test platform is situated between the first and second heaters, the plunger shaft will contact the test platform and move from the first position to the second position.

Embodiment B28. The method of any one of embodiments B1 to B27, further comprising: before (A), adding sample to a sample chamber of the test platform; and after (B) and before (C), combining the sample with one or more other substances contained within on or more chambers of the test platform to form the reaction mixture; and wherein (D) comprises transmitting an optical signal from the reaction mixture within the reaction chamber to an optical detector via the optical fiber.

Embodiment C1. A system for conducting an assay, the system comprising: a test platform including at least one reaction chamber for containing a reaction mixture; and an instrument for applying thermal energy to the reaction chamber of the test platform and for transmitting optical signals to and/or from the reaction chamber, the instrument comprising: first and second heaters disposed in an opposed, spaced-apart configuration to receive the reaction chamber between the first and second heaters; an actuator for moving the first heater with respect to the second heater to sandwich the reaction chamber between the first and second heaters by moving the first heater toward the second heater and/or by moving the second heater toward the first heater when the reaction chamber is disposed between the first and second heaters, wherein first and second heaters apply thermal energy to or absorb thermal energy from the reaction chamber sandwiched between the first and second heaters; and an optical fiber extending at least partially through an opening extending through the first heater and configured to transmit an optical signal through the first heater to and/or from the reaction chamber.

Embodiment C2. The system of embodiment C1, wherein each of the first and second heaters comprises a thermal element configured to emit thermal energy to heat a body in thermal contact with the thermal element and/or absorb thermal energy to cool a body in thermal contact with the thermal element, and wherein the optical fiber extends at least partially through a hole formed through the thermal element.

Embodiment C3. The system of embodiment C2, wherein the thermal element comprises a thermoelectric device.

Embodiment C4. The system of embodiment C2 or C3, wherein each of the first and second heaters comprises a thermal block associated with the thermal element, wherein the thermal block has an exposed contact surface that that is in thermal contact with the reaction chamber sandwiched between the first and second heaters.

Embodiment C5. The system of embodiment C4, wherein the contact surface is in physical contact with the reaction chamber sandwiched between the first and second heaters.

Embodiment C6. The system of embodiment C4 or C5, wherein each thermal block comprises at least one of a thermally conductive ceramic and a metal.

Embodiment C7. The assembly of any one of embodiments C4 to C6, wherein each thermal block comprises aluminum.

Embodiment C8. The system of any one of embodiments C4 to C7, wherein the optical fiber extends at least partially through or is aligned with a hole formed through the thermal block to the contact surface.

Embodiment C9. The system of any one of embodiments C4 to C8, wherein each of the first and second heaters comprises a cover positioned over the thermal element and the associated thermal block, wherein the cover has an opening formed therein through which the contact surface of the thermal block is exposed.

Embodiment C10. The system of embodiment C9, wherein the contact surface of the thermal block extends above the cover.

Embodiment C11. The system of embodiment C10, wherein the cover comprises a plastic.

Embodiment C12. The system of any one of embodiments C9 to C11, wherein each cover comprises at least one of Ultem® (polyetherimide) and Delrin® (polyoxymethylene (POM)).

Embodiment C13. The system of any one of embodiments C2 to C12, wherein each of the first and second heaters comprises a heat sink, and wherein the thermal element of each of the first and second heaters is in thermal contact with the heat sink.

Embodiment C14. The system of embodiment C13, wherein the heat sink of at least one of the first and second heaters includes heat dissipation fins.

Embodiment C15. The system of embodiment C13 or C14, wherein each heat sink comprises at least one of a thermally conductive ceramic and a metal.

Embodiment C16. The system of any one of embodiments C13 to C15, wherein each heat sink comprises aluminum.

Embodiment C17. The system of any one of embodiments C1 to C16, wherein the instrument comprises at least one of an optical emitter and an optical detector optically coupled to a proximal end of the optical fiber.

Embodiment C18. The system of embodiment C1, wherein each of the first and second heaters comprises at least two thermal elements configured to emit thermal energy to heat a body in thermal contact with the thermal element and/or absorb thermal energy to cool a body in thermal contact with the thermal element, wherein the first and second heaters comprise the same number of thermal elements, and wherein the optical fiber comprises an optical fiber extending at least partially through a hole formed through each thermal element of the first heater, each optical fiber being configured to transmit an optical signal to and/or from a different reaction chamber.

Embodiment C19. The system of embodiment C18, wherein the instrument comprises a plurality of optical fibers extending at least partially through each thermal element of the first heater.

Embodiment C20. The system of embodiment C18 or C19, wherein each thermal element comprises a thermoelectric device.

Embodiment C21. The system of embodiment C19 or C20, wherein each of the first and second heaters comprises a thermal block associated with each thermal element, wherein each thermal block has an exposed contact surface that contacts a different reaction chamber sandwiched between the first and second heaters.

Embodiment C22. The system of embodiment C21, wherein each optical fiber extends at least partially through or is aligned with an associated hole extending through the associated thermal block to the contact surface.

Embodiment C23. The system of embodiment C22, wherein each optical fiber extends fully through the associated hole extending through the thermal block so that an end of the optical fiber is flush with the contact surface or so that an end of the optical fiber extends above the contact surface.

Embodiment C24. The system of embodiment C23, wherein the end of each optical fiber extends above the contact surface by 0.05 mm to 0.35 mm.

Embodiment C25. The system of any one of embodiments C21 to C24, wherein each of the first and second heaters comprises a cover positioned over each thermal element and the associated thermal block, wherein each cover has an opening formed therein through which the contact surface of the associated thermal block is exposed.

Embodiment C26. The system of embodiment C25, wherein the contact surface of each thermal block extends above the associated cover.

Embodiment C27. The system of embodiment C25 or C26, wherein each cover comprises at least one of Ultem® (polyetherimide) and Delrin® (polyoxymethylene (POM)).

Embodiment C28. The system of embodiment C1, wherein the optical fiber of the instrument comprises at least two optical fibers, each optical fiber extending at least partially through an associated hole formed through the first heater and configured to transmit an optical signal through the first heater to and/or from a different reaction chambers of the test platform.

Embodiment C29. The system of any one of embodiments C1 to C28, wherein the instrument further comprises a test platform detector comprising an optical detector and a plunger shaft mounted in a fixed position with respect to the first heater, wherein the plunger shaft is movable with respect to the optical detector between a first position at which the plunger shaft is not detected by the optical detector and a second position at which the plunger shaft is detected by the optical detector, and wherein, as the first heater is moved with respect to the second heater by the actuator, if a test platform is situated between the first and second heaters, the plunger shaft will contact the test platform and move from the first position to the second position.

Embodiment C30. The system of any one of embodiments C1 to C29, wherein the test platform comprises a fluidic cartridge comprising: a sample chamber for receiving a fluid sample; one or more functional chambers containing a material used in performing the assay; a syringe barrel; a syringe stopper disposed within the syringe barrel and engageable by a syringe plunger of the instrument; and a network of channels directly or indirectly connecting the sample chamber and each functional chamber to the syringe barrel and directly or indirectly connecting the syringe barrel to the at least one reaction chamber.

Embodiment C31. The system of embodiment C30, wherein the instrument comprises: a movable tray for supporting the fluidic cartridge and configured for moving the fluidic cartridge supported by the tray between a first position at which the least one reaction chamber is not disposed between the first and second heaters and a second position at which the at least one reaction chamber is disposed between the first and second heaters; and a syringe plunger configured to be engageable with the syringe stopper to removably connect the syringe stopper to an end of the syringe plunger, and wherein the syringe plunger is situated within the instrument so that the syringe plunger is aligned with the syringe barrel when the cartridge is in the second position.

Embodiment C32. The system of embodiment C31, wherein the fluidic cartridge comprises a process valve associated with the sample chamber and each of the one or more functional chambers containing a material used in performing the assay, and at least two reaction valves associated with each reaction chamber, and wherein the instrument comprises: a support cradle on which the fluidic cartridge is operatively supported when the fluidic cartridge is in the second position; and a plurality of actuator heads disposed within the support cradle, each actuator head being selectively movable with respect to the support cradle to engage an associated one of the process valves or reaction valves of the fluidic cartridge to open or close the associated valve.

Embodiment C33. The system of embodiment C31 or C32, wherein the instrument comprises a syringe driver including a motor coupled to the syringe plunger and configured to actuate the syringe plunger.

Embodiment C34. The system of embodiment C33, wherein the instrument comprises an encoder coupled to the motor of the syringe driver and a controller programmed to control operation of the syringe driver by: (A) operating the motor in a first direction to move the syringe plunger and the stopper coupled to the syringe plunger within the syringe barrel toward a bottom wall of the syringe barrel; (B) monitoring a motor demand signal of the motor while operating the motor in the first direction, wherein motor demand comprises a motor operational parameter that is directly or indirectly proportional to motor output; (C) detecting an inflection in the motor demand signal, wherein the inflection in the motor demand signal indicates that the stopper has contacted the bottom wall of the syringe barrel; (D) after detecting the inflection, continuing to operate the motor in the first direction until the motor stalls; (E) after detecting the inflection and until the motor stalls, counting encoder steps of the encoder coupled to the motor; (F) operating the motor in a second direction for a number of encoder steps counted in E; and (G) after (F), continuing to operate the motor in the second direction for a predetermined number of steps of the encoder to move the stopper to a predefined distance away from the bottom wall of the syringe to draw a predefined volume of fluid into the syringe barrel.

Embodiment C35. The system of any one of embodiments C30 to C34, wherein the fluidic cartridge comprises a syringe blocker removably coupled to the syringe barrel and configured to hold the syringe stopper against a bottom wall of the syringe barrel.

Embodiment C36. The system of embodiment C30, wherein the instrument comprises: a syringe plunger configured to be engageable with the syringe stopper to removably connect the syringe stopper to an end of the syringe plunger; and a syringe driver including a motor coupled to the syringe plunger and configured to actuate the syringe plunger to move the syringe plunger into the syringe barrel to engage the stopper; and wherein the fluidic cartridge comprises: a syringe blocker removably coupled to the syringe barrel and configured to hold the syringe stopper against a bottom wall of the syringe barrel, and wherein the syringe plunger and the syringe blocker are cooperatively configured so that the syringe plunger operatively engages the syringe blocker when the syringe plunger is moved into the syringe barrel to uncouple the syringe blocker from the syringe barrel and permit the syringe stopper to be moved away from the bottom wall of the syringe plunger.

Embodiment C37. The system of embodiment C36, wherein the syringe plunger engages the stopper in an interference fit.

Embodiment C38. The system of embodiment C36 or C37, wherein the syringe plunger includes plunger ribs, and the syringe blocker includes cam walls, each cam wall having a cam edge that is engaged by the plunger ribs as the syringe plunger is moved into the syringe barrel to rotate the syringe blocker from a first position coupled to the syringe barrel to a second position uncoupled from the syringe barrel.

Embodiment C39. The system of embodiment C38, wherein the syringe blocker includes flanges and the fluidic cartridge includes a blocker ring attached to the syringe barrel, the blocker ring including radial flanges, and wherein when the syringe blocker is in the first position coupled to the syringe barrel the flanges of the syringe blocker overlap the radial flanges of the blocker ring, and when the syringe blocker is in the second position uncoupled from the syringe barrel the flanges of the syringe blocker do not overlap the radial flanges of the blocker ring.

Embodiment C40. The system of any one of embodiments C30 to C39, wherein the fluidic cartridge includes a sample chamber cap for closing the sample chamber, wherein the sample chamber cap comprises an upper portion and a lower portion with a radial wall dividing the upper portion from the lower portion, wherein the upper portion includes a peripheral wall defined by an axially-extending ring projecting above the radial wall, and the lower portion comprises a peripheral wall defined by an axially extending tapered wall projecting below the radial wall; wherein a vent hole is formed in the radial wall and at least one side vent hole is formed in the peripheral wall of the upper portion, and wherein the lower portion includes a least one radial rib projecting from an outer surface of the tapered wall.

Embodiment C41. The system of any one of embodiments C30 to C40, wherein the fluidic cartridge includes a protective venting cover disposed over at least the one or more functional chambers containing a material used in performing the assay, the protective venting cover comprising: a venting membrane configured to contain liquids in the one or more functional chambers and having through pores formed therein to permit vapor passage through the venting membrane; and a protective cover secured to the venting membrane to block the through pores and reduce or prevent vapor passage, wherein the protective cover is peelable from the venting membrane by a user prior to use of the cartridge.

Embodiment C42. The system of embodiment C41, wherein the venting membrane of the venting cover includes blind pores extending partially through a thickness of the venting membrane.

Embodiment C43. The system of any one of embodiments C30 to C42, wherein the fluidic cartridge includes a functional chamber comprising a purification column configured to bind target nucleic acid from the fluid sample material.

Embodiment C44. The system of embodiment C43, wherein the purification column comprises silica.

Embodiment C45. The system of any one of embodiments C30 to C44, wherein the fluidic cartridge comprises: a cartridge body having a first face, a second face, at least one opening in the cartridge body extending from the first face to the second face, and one or more grooves formed in the second face; a first film affixed to the first face of the cartridge body and covering a first end of the at least one opening, wherein the first film comprises a transparent or translucent material to permit an optical signal to pass through the first film into or out of the at least one opening; a second film affixed to the second face of the cartridge body and covering the one or more grooves to form one or more channels traversing a portion of the second face, and wherein the second film covers a portion of the second face that is spatially separated from the at least one opening; and a thermally-conductive laminate seal affixed to the second face of the cartridge body and covering a second end of the at least one opening, wherein the at least one opening covered by the first film and the thermally-conductive laminate seal defines a reaction chamber for receiving the reaction mixture, wherein the thermally-conductive laminate seal comprises: a plastic layer affixed to the second face of the cartridge body and covering the second end of the at least one opening; and a conductive foil layer affixed a surface of the plastic layer opposite a surface of the plastic affixed to the second face of the cartridge body.

Embodiment C46. The system of embodiment C45, wherein the cartridge body includes one or more grooves formed in the first face, and wherein the first film affixed to the first face of the cartridge body covers the one or more grooves formed in the first face to form one or more channels traversing a portion of the first face.

Embodiment C47. The system of embodiment C45 or C46, wherein the second film includes a cutout exposing the at least one opening, and wherein the thermally-conductive laminate seal is affixed to the second face of the cartridge body within the cutout of the second film.

Embodiment C48. The system of any one of embodiments C45 to C47, wherein the plastic layer comprises polypropylene.

Embodiment C49. The system of any one of embodiments C45 to C48, wherein the conductive layer comprises a metallic foil.

Embodiment C50. The system of embodiment C49, wherein the metallic foil comprises aluminum.

Embodiment C51. The system of any one of embodiments C45 to C50, wherein the conductive layer is reflective and the plastic layer is transparent or translucent.

Embodiment C52. The system of any one of embodiments C45 to C51, wherein the cartridge body is opaque.

Embodiment C53. The system of any one of embodiments C45 to C52, wherein a thickness of the plastic layer of the thermally-conductive laminate seal is less than a thickness of the second film.

Embodiment C54. The system of any one of embodiments C45 to C53, wherein the thickness of the plastic layer is about 10 μm to about 20 μm.

Embodiment C55. The system of any one of embodiments C45 to C54, wherein the thickness of the conductive layer is about 60 μm to about 80 μm.

Embodiment C56. The system of any one of embodiments C45 to C55, wherein the thickness of the second film is about 100 μm to about 200 μm.

Embodiment C57. The system of any one of embodiments C45 to C56, wherein the second film comprises polypropylene.

Embodiment C58. The system of any one of embodiments C45 to C57, wherein the first face is a top face of the cartridge and the second face is a bottom face of the cartridge.

Embodiment C59. The system of any one of embodiments C45 to C58, wherein the cartridge body is a plastic and the thermally-conductive laminate seal is affixed to the second face of the cartridge body by heat sealing or ultrasonic welding between the plastic layer and the cartridge body.

Embodiment C60. The system of any one of embodiments C45 to C58, wherein the thermally-conductive laminate seal is affixed to the second face of the cartridge body by an adhesive.

Embodiment C61. The system of any one of embodiments C45 to C60, wherein the cartridge body includes at least two openings adjacent to one another extending from the first face to the second face, the first film covers the first end of each of the at least two openings, and the thermally-conductive laminate seal covers the end of each of the at least two openings, and wherein the thermally-conductive laminate seal is constructed and arranged to minimize or prevent optical transmissions between the at least two openings through the plastic layer of the thermally-conductive laminate seal.

Embodiment C62. The system of any one of embodiments C32 to C34, further comprising a first actuating mechanism configured to selectively move each actuator head of the plurality of actuator heads with respect to the support cradle to engage the associated one of the process valves of the fluidic cartridge to open or close the associated process valve, where the plurality of process valves are arranged in a circular configuration. The first actuating mechanism comprises a valve actuator piston operably engageable with each actuator head of the plurality actuator heads associated with a one of the process valves, where each valve actuator piston extends into or through the support cradle and is movable between a first position corresponding to one of the closed configuration of the process valve associated with the engaged actuator head and the open position of the process valve associated with the engaged actuator head and a second position corresponding to the other of the open position of the process valve associated with the engaged actuator head and the closed position of the process valve associated with the engaged actuator head. A spring is coupled to each valve actuator piston for biasing the valve actuator piston into the first position. A cam follower surface is associated with each valve actuator piston. A rotary cam is rotatable about an axis of rotation corresponding to a center of the circular configuration of the plurality of process valves, and the rotary cam comprises a cam rod extending radially with respect to the axis of rotation and rotatable about the axis of rotation, and a cam disposed on a radial outer end of the cam rod. Rotation of the cam rod about the axis of rotation causes the cam to engage the cam follower surface associated with each valve actuator piston, one at a time, to cause movement of the valve actuator piston associated with the cam follower surface engaged by the cam from the first position to the second position.

Embodiment C63. The system of any one of embodiments C32 to C34 and C62, further comprising a second actuating mechanism configured to selectively move each actuator head of the plurality of actuator heads with respect to the support cradle to engage the associated one of the reaction valves of the fluidic cartridge to open or close the associated reaction valve. The second actuating mechanism comprises a valve actuator piston operably engageable with each actuator head of the plurality actuator heads associated with a one of the reaction valves, where each valve actuator piston is movable between a first position corresponding to one of the closed configuration of the engaged reaction valve and the open position of the engaged reaction valve and a second position corresponding to the other of the open position of the engaged reaction valve and the closed position of the engaged reaction valve. A spring is coupled to each valve actuator piston for biasing the valve actuator piston into the first position. At least one camshaft is supported for rotation about a camshaft axis of rotation and includes at least one cam lobe. An actuator lever is associated with each cam lobe and with each valve actuator piston and is oriented transversely to the longitudinal axis of the camshaft. The actuator lever comprises a pivot connection at which the actuator lever is mounted for pivoting movement about a pivot axis of rotation, a piston engagement spatially separated from the pivot connection and at which the actuator lever is operatively engaged with the associated valve actuator piston so that pivoting movement of the actuator lever in a first direction about the pivot axis of rotation causes movement of the associated valve actuator piston from its first position to its second position, and a cam follower surface disposed between the pivot connection and the piston engagement. The cam follower surface is constructed and arranged to be engaged by the associated cam lobe as the camshaft rotates about the camshaft axis of rotation to cause pivoting movement of the actuator lever in the first direction.

Embodiment C64. The system of any one of embodiments C45 to C61, further comprising a dried reagent adhered to an outer surface of the plastic layer of the thermally-conductive laminate seal.

Embodiment C65. The system of embodiment C64, wherein the dried reagent is adhered only to a portion of the outer surface of the plastic layer corresponding to a location of the reaction chamber.

Embodiment C66. The system of embodiment C65, wherein the portion of the outer surface of the plastic layer to which the dried reagent is adhered is treated so as to increase the hydrophilicity of the portion of the outer surface.

Embodiment C67. The system of embodiment C66, wherein the portion of the outer surface of the plastic layer to which the dried reagent is adhered is treated with a corona discharge or a plasma treatment to increase the hydrophilicity of the portion of the outer surface

Embodiment C68. The system of embodiment C59, wherein the cartridge body includes one or more energy directors formed on the second face and at least partially surrounding each of the at least one opening, wherein the energy directors are configured to melt during heat sealing or ultrasonic welding process and fuse with the plastic layer.

Embodiment C69. The system of embodiment C68, wherein the cartridge body includes one or more inspection holes formed through the cartridge body at a region of the cartridge body to which the thermally-conductive laminate seal is affixed and energy directors at least partially surrounding each inspection hole.

Embodiment C70. The system of any one of embodiments C30 to C44, wherein the fluidic cartridge comprises: a cartridge body having a first face, a second face, at one or more openings in the cartridge body extending from the first face to the second face, and one or more grooves formed in the second face; a first film affixed to the first face of the cartridge body and covering a first end of the one or more openings, wherein the first film comprises a transparent or translucent material to permit an optical signal to pass through the first film into or out of the one or more openings; a second film affixed to the second face of the cartridge body and covering the one or more grooves to form one or more channels traversing a portion of the second face and a second end of each of the one or more openings, wherein the one or more openings covered by the first film and the second film define one or more reaction chambers for receiving the reaction mixture; and one or more dried reagents adhered to a surface of the second film, wherein a location of each of the one or more dried reagents corresponds to a location of each of the one or more reaction chambers.

Embodiment C71. The system of embodiment C70, wherein the dried reagent is adhered only to a portion of the second film corresponding to the location of the one or more reaction chambers.

Embodiment C72. The system of embodiment C71, wherein the portion of the surface of the second film to which the one or more dried reagents are adhered is more hydrophilic than the remainder of the surface of the second film.

Embodiment D1. An instrument for receiving a fluidic cartridge, wherein the fluidic cartridge comprises a sample chamber and a cap closing the sample chamber, the instrument comprising: a first chassis; a second chassis, including a cartridge support cradle configured to hold a cartridge situated between the first chassis and the second chassis; an actuator coupled to one or both of the first chassis and the second chassis and configured to effect automated relative movement between the first chassis and the second chassis to vary a distance between the first chassis and the second chassis; and a cartridge detector mounted within the upper chassis, wherein the cartridge detector comprises a plunger rod configured for movement between a first position and a second position and a sensor for detecting when the plunger rod is in the second position, and wherein, as the first chassis and the second chassis are moved relatively toward each other by the actuator, if a cartridge is situated on the cartridge support cradle, the plunger rod will contact the cartridge and move from the first position to the second position.

Embodiment D2. The instrument of embodiment D1, wherein the sensor of the cartridge detector comprises an optical detector, wherein, when the plunger rod is in the first position, the plunger rod is not detected by the optical detector, and when the plunger rod is in the second position, the plunger rod is detected by the optical detector.

Embodiment D3. The instrument of embodiment D1 or D2, wherein the cartridge detector comprises a spring coupled to the plunger rod to bias the plunger rod into the first position.

Embodiment D4. The instrument of any one of embodiments D1 to D3, wherein the cartridge detector comprises a plunger pad attached to an end of the plunger rod for contacting the cartridge situated on the cartridge support cradle as the first chassis and the second chassis are moved relatively toward each other.

Embodiment D5. The instrument of embodiment D4, wherein, if a cartridge is situated on the cartridge support cradle, the plunger pad will contact the cap as the first chassis and the second chassis are moved relatively toward each other.

Embodiment D6. The instrument of embodiment D2, wherein the first chassis comprises an upper block with a through hole through which the plunger rod extends, and wherein the optical detector comprises an optical transmitter disposed on one side of the through hole and an optical receiver disposed on an opposite side of the through hole so that when the plunger rod is moved to the second position, a portion of the plunger rod is positioned between the optical transmitter and the optical receiver to disrupt an optical beam between the optical transmitter and the optical receiver.

Embodiment D7. The instrument of any one of embodiments D1 to D6, wherein the fluidic cartridge comprises one or more reaction chambers, and wherein the first chassis comprises a first thermal module configured to apply thermal energy to a first side of each of the one or more reaction chambers; the second chassis comprises a second thermal module configured to apply thermal energy to a second side of each of the one or more reaction chambers; and the actuator is controlled to effect automated relative movement between the first chassis and the second chassis to selective position a portion of each of the first and second thermal modules in thermal contact with the one or more reaction chambers.

Embodiment D8. The instrument of embodiment D7, further comprising an optical fiber associated with each of the one or more reaction chambers, wherein each optical fiber extends through a portion of the first thermal module to transmit optical signals through the first thermal module to and/or from the associated reaction chamber.

Embodiment D9. The instrument of embodiment D8, further comprising at least one of an optical emitter and an optical detector optically coupled to a proximal end of each optical fiber extending through the first thermal module.

Embodiment E1. An instrument for applying thermal energy to a reaction chamber of a test platform, the instrument comprising: first and second heaters disposed in a spaced-apart configuration to receive the reaction chamber in a position with respect to the first and second heaters so that the first and second heaters contact different parts of the reaction chamber, and wherein each heater is configured to apply thermal energy to the reaction chamber by conductive heat transfer through a part of the reaction chamber contacted by the respective heater; a first controller configured to control thermal energy generated by the first heater; and a second controller configured to control thermal energy generated by the second heater, wherein control by the first controller of thermal energy generated by the first heater is independent of control by the second controller of thermal energy generated by the second heater, and control by the second controller of thermal energy generated by the second heater is independent of control by the first controller of thermal energy generated by the first heater, and wherein the first controller controls thermal energy generated by the first heater and the second controller controls thermal energy generated by the second heater to achieve a common temperature profile for the first heater and the second heater.

Embodiment E2. The instrument of embodiment E1, further comprising an actuator for moving the first heater with respect to the second heater to sandwich the reaction chamber between the first and second heaters by moving the first heater toward the second heater when the reaction chamber is disposed between the first and second heaters, wherein first and second heaters apply thermal energy to the reaction chamber sandwiched between the first and second heaters.

Embodiment E3. The instrument of embodiment E1 or E2, further comprising an optical fiber extending at least partially through a hole formed through the first heater and configured to transmit an optical signal through the first heater to and/or from the reaction chamber.

Embodiment E4. The instrument of any one of embodiments E1 to E3, wherein each of the first and second heaters comprises a thermal element configured to emit thermal energy to heat a body in thermal contact with the thermal element and/or absorb thermal energy to cool a body in thermal contact with the thermal element.

Embodiment E5. The instrument of embodiment E3, wherein each of the first and second heaters comprises a thermal element configured to emit thermal energy to heat a body in thermal contact with the thermal element and/or absorb thermal energy to cool a body in thermal contact with the thermal element, and wherein the optical fiber extends at least partially through a hole formed through the thermal element of the first heater.

Embodiment E6. The instrument of embodiment E4 or E5, wherein the thermal element comprises a thermoelectric device.

Embodiment E7. The instrument of any one of embodiments E4 to E6, wherein each of the first and second heaters comprises a thermal block associated with the thermal element, wherein the thermal block has an exposed contact surface that contacts the reaction chamber disposed between the first and second heaters.

Embodiment E8. The instrument of embodiment E7, wherein each thermal block comprises at least one of a thermally conductive ceramic and a metal.

Embodiment E9. The instrument of embodiment E7 or E8, wherein each thermal block comprises aluminum.

Embodiment E10. The instrument of embodiment E5, wherein each of the first and second heaters comprises a thermal block associated with the thermal element, wherein the thermal block has an exposed contact surface that contacts the reaction chamber sandwiched between the first and second heaters, and wherein the optical fiber extends at least partially through or is aligned with a hole formed through the thermal block of the first heater to the contact surface.

Embodiment E11. The instrument of embodiment E10, wherein the optical fiber extends fully through the associated hole so that an end of the optical fiber is flush with the contact surface, or the end of the optical fiber extends above the contact surface of the associated thermal block.

Embodiment E12. The instrument of any one of embodiments E7 to E11, wherein each of the first and second heaters comprises a cover positioned over the thermal element and the associated thermal block, wherein the cover has an opening formed therein through which the contact surface of the thermal block is exposed.

Embodiment E13. The instrument of embodiment E12, wherein the cover comprises a plastic.

Embodiment E14. The instrument of embodiment E12 or E13, wherein each cover comprises at least one of Ultem® (polyetherimide) and Delrin® (polyoxymethylene (POM)).

Embodiment E15. The instrument of any one of embodiments E4 to E14, wherein each of the first and second heaters comprises a heat sink, and wherein the thermal element of each of the first and second heaters is in thermal contact with the heat sink.

Embodiment E16. The instrument of embodiment E15, wherein the heat sink of at least one of the first and second heaters includes heat dissipation fins.

Embodiment E17. The instrument of embodiment E16, wherein each heat sink comprises at least one of a thermally conductive ceramic and a metal.

Embodiment E18. The instrument of any one of embodiments E15 to E17, wherein each heat sink comprises aluminum.

Embodiment E19. The instrument of any one of embodiments E1 to E18, further comprising a movable holder for supporting a test platform and configured for moving a test platform supported by the movable holder between a first position at which the reaction chamber is not disposed between the first and second heaters, and a second position at which the reaction chamber is disposed between the first and second heaters.

Embodiment E20. The instrument of embodiment E3 or E5, further comprising at least one of an optical emitter and an optical detector optically coupled to a proximal end of the optical fiber.

Embodiment E21. The instrument of anyone of embodiments E1 to E20, comprising: a first temperature sensor for monitoring a temperature of the first heater; and a second temperature sensor for monitoring a temperature of the second heater, wherein the first temperature sensor and second temperature sensor are independent of one another, wherein the first controller is configured to control thermal energy generated by the first heater by comparing a temperature measurement of the first heater from the first temperature sensor with the common temperature profile, and applying power to the first heater in response to the comparison of the temperature measurement from the first temperature sensor with the common temperature profile, and wherein the second controller is configured to control thermal energy generated by the second heater by comparing a temperature measurement of the second heater from the second temperature sensor with the common temperature profile, and applying power to the second heater in response to the comparison of the temperature measurement from the second temperature sensor with the common temperature profile.

Embodiment F1. A method for applying thermal energy to a reaction chamber of a test platform, the method comprising: applying thermal energy to first and second sides of the reaction chamber with first and second heaters, respectively; controlling thermal energy generated by the first heater independently of thermal energy generated by the second heater; controlling the thermal energy generated by the second heater independently of the thermal energy generated by the first heater; and controlling the thermal energy generated by the first heater and the thermal energy generated by the second heater to achieve a common temperature profile for the first heater and the second heater.

Embodiment F2. The method of embodiment F1, further comprising moving the first heater with respect to the second heater with an actuator to sandwich the reaction chamber between the first and second heaters by moving the first heater toward the second heater when the reaction chamber is disposed between the first and second heaters, and applying thermal energy with the first and second heaters to the reaction chamber sandwiched between the first and second heaters.

Embodiment F3. The method of embodiment F1 or F2, further comprising transmitting an optical signal through the first heater to and/or from the reaction chamber with an optical fiber extending through at least a portion of the first heater.

Embodiment F4. The method of any one of embodiments F1 to F3, wherein each of the first and second heaters comprises a thermal element configured to emit thermal energy to heat a body in thermal contact with the thermal element and/or absorb thermal energy to cool a body in thermal contact with the thermal element.

Embodiment F5. The method of embodiment F3, wherein each of the first and second heaters comprises a thermal element configured to emit thermal energy to heat a body in thermal contact with the thermal element and/or absorb thermal energy to cool a body in thermal contact with the thermal element, and wherein the optical fiber extends at least partially through a hole formed through the thermal element of the first heater.

Embodiment F6. The method of embodiment F4 or F5, wherein the thermal element comprises a thermoelectric device.

Embodiment F7. The method of any one of embodiments F4 to F6, wherein applying thermal energy to the first and second sides of the reaction chamber with first and second heaters comprises: contacting the first side of the reaction chamber with a contact surface of a thermal block associated with the thermal element of the first heater; and contacting the second side of the reaction chamber with a contact surface of a thermal block associated with the thermal element of the second heater.

Embodiment F8. The method of embodiment F5, wherein each of the first and second heaters comprises a thermal block associated with the thermal element, wherein the thermal block has an exposed contact surface that contacts the reaction chamber sandwiched between the first and second heaters, and wherein the optical fiber extends at least partially through or is aligned with a hole formed through the thermal block of the first heater to the contact surface.

Embodiment F9. The method of any one of embodiments F1 to F8, further comprising moving the test platform between a first position at which the reaction chamber is not disposed between the first and second heaters, and a second position at which the reaction chamber is disposed between the first and second heaters, wherein moving the test platform between the first and second positions is effected by powered movement of a tray supporting the test platform.

Embodiment F10. The method of anyone of embodiments F1 to F9, wherein controlling the thermal energy generated by the first heater to achieve the common temperature profile comprises: monitoring a temperature of the first heater with a first temperature sensor; comparing a temperature measurement of the first heater from the first temperature sensor with the common temperature profile; applying power to the first heater in response to the comparison of the temperature measurement from the first temperature sensor with the common temperature profile; monitoring a temperature of the second heater with a second temperature sensor; comparing a temperature measurement of the second heater from the second temperature sensor with the common temperature profile; and applying power to the second heater in response to the comparison of the temperature measurement from the second temperature sensor with the common temperature profile, wherein the first temperature sensor and second temperature sensor are independent of one another.

Embodiment G1. A method for controlling a syringe pump comprising an elastomeric stopper disposed within a syringe barrel and a syringe plunger connected to the stopper, the method comprising: (A) operating a motor coupled to the syringe plunger in a first direction to move the syringe plunger and the stopper within the syringe barrel toward a bottom wall of the syringe barrel; (B) monitoring a motor demand signal of the motor while operating the motor in the first direction, wherein motor demand comprises a motor operational parameter that is directly or indirectly proportional to motor output; (C) detecting an inflection in the motor demand signal, wherein the inflection in the motor demand signal indicates that the stopper has contacted the bottom wall of the syringe barrel; (D) after detecting the inflection, continuing to operate the motor in the first direction until the motor stalls; (E) after detecting the inflection and until the motor stalls, counting encoder steps of an encoder coupled to the motor; (F) operating the motor in a second direction for a number of encoder steps counted in (E); and (G) after (F), continuing to operate the motor in the second direction to move the stopper to a predefined distance away from the bottom wall of the syringe to draw a predefined volume of fluid into the syringe barrel.

Embodiment G2. The method of embodiment G1, wherein motor demand comprises at least one of current demand by the motor, voltage demand by the motor, and power demand by the motor.

Embodiment G3. The method of embodiment G1 or G2, wherein G comprises operating the motor in the second direction for a predetermined number of steps of the encoder.

Embodiment G4. The method of any one of embodiments G1 to G3, wherein the motor comprises a servo motor.

Embodiment G5. The method of any one of embodiments G1 to G4, wherein the encoder comprises a rotary encoder.

Embodiment G6. The method of any one of embodiments G1 to G5, wherein D comprises detecting motor stall by detecting from the encoder that the motor has stopped rotating and/or by detecting that the motor demand has reached a pre-defined maximum level.

Embodiment G7. The method of any one of embodiments G1 to G6, wherein the syringe plunger is component of an instrument, and the stopper is a component of a fluidic cartridge acted upon by the instrument, and wherein the syringe barrel is defined by a side wall of a chamber of the fluidic cartridge that is in fluid communication with other chambers of the cartridge.

Embodiment G8. The method of embodiment G7, wherein the stopper is retained within the syringe barrel by a blocker releasably interlocked with the side wall of the chamber defining the syringe barrel, wherein the blocker is released by the syringe plunger when the syringe plunger is inserted through the blocker and into engagement with the stopper to permit vertical movement of the stopper during use.

Embodiment G9. The method of any one of embodiments G1 to G8, wherein the syringe plunger engages the stopper in an interference fit.

Embodiment H1. A cartridge for detecting an analyte of interest from a reaction mixture by exposing the reaction mixture to an excitation optical signal and detecting the presence or absence of an emission optical signal from the reaction mixture, the cartridge comprising: a cartridge body having a first face, a second face, at least one opening in the cartridge body extending from the first face to the second face, and one or more grooves formed in the second face; a first film affixed to the first face of the cartridge body and covering a first end of the at least one opening, wherein the first film comprises a transparent or translucent material to permit an optical signal to pass through the first film into or out of the at least one opening; a second film affixed to the second face of the cartridge body and covering the one or more grooves to form one or more channels traversing a portion of the second face, and wherein the second film covers a portion of the second face that is spatially separated from the at least one opening; and a thermally-conductive laminate seal affixed to the second face of the cartridge body and covering a second end of the at least one opening, wherein the at least one opening covered by the first film and the thermally-conductive laminate seal defines a reaction chamber for receiving the reaction mixture, wherein the thermally-conductive laminate seal comprises: a plastic layer affixed to the second face of the cartridge body and covering the second end of the at least one opening; and a conductive layer affixed to a surface of the plastic layer opposite a surface of the plastic affixed to the second face of the cartridge body.

Embodiment H2. The cartridge of embodiment H1, wherein the cartridge body includes one or more grooves formed in the first face, and wherein the first film affixed to the first face of the cartridge body covers the one or more grooves formed in the first face to form one or more channels traversing a portion of the first face.

Embodiment H3. The cartridge of embodiment H1 or H2, wherein the second film includes a cutout exposing the at least one opening, and wherein the thermally-conductive laminate seal is affixed to the second face of the cartridge body within the cutout of the second film.

Embodiment H4. The cartridge of any one of embodiments H1 to H3, wherein the plastic layer comprises polypropylene.

Embodiment H5. The cartridge of any one of embodiments H1 to H4, wherein the conductive layer comprises a metallic foil.

Embodiment H6. The cartridge of embodiment H5, wherein the metallic foil comprises aluminum.

Embodiment H7. The cartridge of any one of embodiments H1 to H6, wherein the conductive layer is reflective and the plastic layer is transparent or translucent.

Embodiment H8. The cartridge of any one of embodiments H1 to H7, wherein the cartridge body is opaque.

Embodiment H9. The cartridge of any one of embodiments H1 to H8, wherein a thickness of the plastic layer of the thermally-conductive laminate seal is less than a thickness of the second film.

Embodiment H10. The cartridge of any one of embodiments H1 to H9, wherein the thickness of the plastic layer is about 10 μm to about 20 μm.

Embodiment H11. The cartridge of any one of embodiments H1 to H10, wherein the thickness of the conductive layer is about 60 μm to about 80 μm.

Embodiment H12. The cartridge of any one of embodiments H1 to H11, wherein the thickness of the second film is about 100 μm to about 200 μm.

Embodiment H13. The cartridge of any one of embodiments H1 to H12, wherein the second film comprises polypropylene.

Embodiment H14. The cartridge of any one of embodiments H1 to H13, wherein the first face is a top face of the cartridge and the second face is a bottom face of the cartridge.

Embodiment H15. The cartridge of any one of embodiments H1 to H14, wherein the cartridge body is a plastic and the thermally-conductive laminate seal is affixed to the second face of the cartridge body by heat sealing or ultrasonic welding between the plastic layer and the cartridge body.

Embodiment H16. The cartridge of any one of embodiments H1 to H14, wherein the thermally-conductive laminate seal is affixed to the second face of the cartridge body by an adhesive.

Embodiment H17. The cartridge of any one of embodiments H1 to H16, wherein the cartridge body includes at least two openings adjacent to one another extending from the first face to the second face, the first film covers the first end of each of the at least two openings, and the thermally-conductive laminate seal covers the end of each of the at least two openings, and wherein the thermally-conductive laminate seal is constructed and arranged to minimize or prevent optical transmissions between the at least two openings through the plastic layer of the thermally-conductive laminate seal.

Embodiment H18. A cartridge within which the presence or absence of an analyte of interest contained in a reaction mixture can be detected by exposing the reaction mixture to an excitation optical signal and detecting the presence or absence of an emission optical signal from the reaction mixture, the cartridge comprising: a cartridge body having one or more reaction chambers, each reaction chamber being configured to receive a reaction mixture, wherein one wall of each reaction chamber is transparent or translucent to permit an optical signal to pass through the wall into or out of the reaction chamber, and wherein each reaction chamber is open to a surface of the cartridge body; a film affixed to the surface of the cartridge body and covering a first portion of the surface of the cartridge body, and wherein the first portion of the surface is spatially separated from the reaction chamber open to the surface; and a thermally-conductive laminate seal affixed to a second portion of the surface of the cartridge body, wherein the second portion of the surface encompasses the reaction chamber open to the surface and the thermally-conductive laminate seal closes the reaction chamber, and wherein the thermally-conductive laminate seal comprises: a plastic layer affixed to the second portion of the surface of the cartridge body and closing the reaction chamber; and a conductive layer affixed to a surface of the plastic layer opposite a surface of the plastic affixed to the second portion of the surface of the cartridge body.

Embodiment H19. The cartridge of embodiment H18, wherein the cartridge body includes a first face and a second face, and wherein the second face encompasses the surface of the cartridge body to which the reaction chamber is open, and wherein the one wall of the reaction chamber that is transparent or translucent comprises a transparent or translucent film affixed to the first face of the cartridge body and covering a first end of the reaction chamber.

Embodiment H20. The cartridge of embodiment H19, wherein the cartridge body includes one or more grooves formed in the first face, and wherein the film affixed to the first face of the cartridge body covers the one or more grooves formed in the first face to form one or more channels traversing a portion of the first face.

Embodiment H21. The cartridge of any one of embodiments H18 to H20, wherein the film affixed to the surface of the cartridge body to which the reaction chamber is open includes a cutout, and wherein the thermally-conductive laminate seal is affixed to the cartridge body within the cutout.

Embodiment H22. The cartridge of any one of embodiments H18 to H21, wherein the plastic layer comprises polypropylene.

Embodiment H23. The cartridge of any one of embodiments H18 to H22, wherein the conductive layer comprises a metallic foil.

Embodiment H24. The cartridge of embodiment H23, wherein the metallic foil comprises aluminum.

Embodiment H25. The cartridge of any one of embodiments H18 to H24, wherein the conductive layer is reflective and the plastic layer is transparent or translucent.

Embodiment H26. The cartridge of any one of embodiments H18 to H25, wherein a thickness of the plastic layer of the thermally-conductive laminate seal is less than a thickness of the film affixed to the surface of the cartridge body to which the reaction chamber is open.

Embodiment H27. The cartridge of any one of embodiments H18 to H26, wherein the thickness of the plastic layer is about 10 μm to about 20 μm.

Embodiment H28. The cartridge of any one of embodiments H18 to H27, wherein the thickness of the conductive layer is about 60 μm to about 80 μm.

Embodiment H29. The cartridge of embodiment H19 or H20, wherein the thickness of the film affixed to the surface of the cartridge body to which the reaction chamber is open is about 100 μm to about 200 μm.

Embodiment H30. The cartridge of any one of embodiments H18, H20, or H29, wherein the film affixed to the surface of the cartridge body to which the reaction chamber is open comprises polypropylene.

Embodiment H31. The cartridge of embodiment H19 to H20, wherein the first face is a top face of the cartridge and the second face is a bottom face of the cartridge.

Embodiment H32. The cartridge of any one of embodiments H18 to H31, wherein the cartridge body is a plastic and the thermally-conductive laminate seal is affixed to the cartridge body by heat sealing or ultrasonic welding between the plastic layer and the cartridge body.

Embodiment H33. The cartridge of any one of embodiments H18 to H31, wherein the thermally-conductive laminate seal is affixed to the cartridge by an adhesive.

Embodiment H34. The cartridge of any one of embodiments H18 to H33, wherein the cartridge body includes at least two reaction chambers, and the thermally-conductive laminate seal closes the at least two reaction chambers, and wherein the thermally-conductive laminate seal is constructed and arranged to minimize or prevent optical transmissions between the at least two reaction chambers through the plastic layer of the thermally-conductive laminate seal.

Embodiment H35. The cartridge of any one of embodiment H1 to H34, further comprising a dried reagent adhered to an outer surface of the plastic layer of the thermally-conductive laminate seal.

Embodiment H36. The cartridge of embodiment H35, wherein the dried reagent is adhered only to a portion of the outer surface of the plastic layer corresponding to a location of the reaction chamber.

Embodiment H37. The cartridge of embodiment H36, wherein at least part of the surface of the plastic layer is treated so that the portion of the surface to which the dried reagent is adhered has greater hydrophilicity as compared to the rest of the surface of the plastic layer.

Embodiment H38. The cartridge of embodiment H36, wherein the portion of the outer surface of the plastic layer to which the dried reagent is adhered is treated so as to increase the hydrophilicity of the treated portion of the outer surface of the plastic layer as compared to an untreated portion of the outer surface of the plastic layer.

Embodiment H39. The cartridge of embodiment H38, wherein the portion of the outer surface of the plastic layer to which the dried reagent is adhered is treated with a corona discharge or a plasma treatment to increase the hydrophilicity of the treated portion of the outer surface of the plastic layer as compared to the untreated portion of the outer surface of the plastic layer.

Embodiment H40. The cartridge of embodiment H15 or H32, wherein the cartridge body includes one or more energy directors formed on the second face and at least partially surrounding each of the at least one opening, wherein the energy directors are configured to melt during heat sealing or ultrasonic welding process and fuse with the plastic layer.

Embodiment H41. The cartridge of embodiment H40, wherein the cartridge body includes one or more inspection holes formed through the cartridge body at a region of the cartridge body to which the thermally-conductive laminate seal is affixed and energy directors at least partially surrounding each inspection hole.

Embodiment I1. A system for applying thermal energy to a reaction mixture and for transmitting optical signals to and/or from the reaction mixture, the system comprising: a reaction chamber for receiving the reaction mixture, wherein a first wall of the reaction chamber is transparent or translucent, and a second wall of the reaction chamber comprises a thermally-conductive laminate seal, wherein the thermally-conductive laminate seal comprises a plastic layer facing an interior space of the reaction chamber and a conductive layer disposed over the plastic layer; a first heater that is in contact with the first wall of the reaction chamber or is configured to be placed in contact with the first wall of the reaction chamber to heat the reaction mixture within the reaction chamber by conductive thermal energy transfer to the first wall of the reaction chamber contacted by the first heater; a second heater that is in contact with the second wall of the reaction chamber to heat the reaction mixture within the reaction chamber by conductive thermal energy transfer to the second wall of the reaction chamber contacted by the second heater; and an optical waveguide extending at least partially through the first heater and configured to transmit an optical signal through the first heater and the first wall to the reaction mixture contained within the reaction chamber and/or to transmit an optical signal from the reaction mixture contained within the reaction chamber through the first wall and the first heater.

Embodiment I2. The system of embodiment I1, wherein neither the first heater nor the second heater comprises a light source.

Embodiment I3. The system of embodiment I1 or I2, wherein each of the first heater and the second heater comprises a thermoelectric module.

Embodiment I4. The system of any one of embodiments I1 to I3, wherein the first heater is movable with respect to the second heater between a first position in which the first heater is not in contact with the first wall of the reaction chamber and a second position in which the first heater is in contact with the first wall of the reaction chamber.

Embodiment I5. The system of any one of embodiments I1 to I4, wherein the reaction chamber is part of a cartridge comprising a cartridge body having a first face, a second face, at least one opening in the cartridge body extending from the first face to the second face, and wherein the first wall comprises a first film affixed to the first face of the cartridge body and covering a first end of the at least one opening, and wherein the thermally-conductive laminate seal is affixed to the second face of the cartridge body and covering a second end of the at least one opening, wherein the at least one opening covered by the first film and the thermally-conductive laminate define the reaction chamber.

Embodiment I6. The system of embodiment I5, wherein the cartridge body is opaque.

Embodiment I7. The system of embodiment I5 or I6, wherein the first face is a top face of the cartridge and the second face is a bottom face of the cartridge.

Embodiment I8. The system of any one of embodiments I1 to I7, wherein the plastic layer comprises polypropylene.

Embodiment I9. The system of any one of embodiments I1 to I8, wherein the conductive layer comprises a metallic foil.

Embodiment I10. The system of embodiment I9, wherein the metallic foil comprises aluminum.

Embodiment I11. The system of any one of embodiments I1 to I10, wherein the conductive layer is reflective and the plastic layer is transparent or translucent.

Embodiment I12. The system of any one of embodiments I1 to I11, further comprising two or more reaction chambers arranged in sets of at least two reaction chambers.

Embodiment I13. The system of any one of embodiments I1 to I12, further comprising at least one of an optical emitter and an optical detector optically coupled to the optical waveguide.

Embodiment I14. The system of any one of embodiments I1 to I13, wherein the optical waveguide comprises an optical fiber.

Embodiment I15. The system of any one of embodiment s I1 to I14, further comprising a dried reagent adhered to a surface of the plastic layer of the thermally-conductive laminate seal facing the interior space of the reaction chamber.

Embodiment I16. The system of embodiment I15, wherein the dried reagent is adhered only to a portion of the outer surface of the plastic layer corresponding to a location of the reaction chamber.

Embodiment I17. The system of embodiment I16, wherein at least part of the surface of the plastic layer is treated so that the portion of the surface to which the dried reagent is adhered has greater hydrophilicity as compared to the rest of the surface of the plastic layer.

Embodiment I18. The system of embodiment I16, wherein the portion of the outer surface of the plastic layer to which the dried reagent is adhered is treated so as to increase the hydrophilicity of the portion of the outer surface.

Embodiment I19. The system of embodiment I18, wherein the portion of the outer surface of the plastic layer to which the dried reagent is adhered is treated with a corona discharge or a plasma treatment to increase the hydrophilicity of the portion of the outer surface.

Embodiment I20. The system of any one of embodiments I5 to I7, wherein the cartridge body is a plastic and the thermally-conductive laminate seal is affixed to the second face of the cartridge body by heat sealing or ultrasonic welding between the plastic layer and the cartridge body.

Embodiment I21. The system of embodiment I20, wherein the cartridge body includes one or more energy directors formed on the second face and at least partially surrounding each of the at least one opening, wherein the energy directors are configured to melt during heat sealing or ultrasonic welding process and fuse with the plastic layer.

Embodiment I22. The system of embodiment I21, wherein the cartridge body includes one or more inspection holes formed through the cartridge body at a region of the cartridge body to which the thermally-conductive laminate seal is affixed and energy directors at least partially surrounding each inspection hole.

Embodiment I23. The system of any one of embodiment I5 to I7, wherein the thermally-conductive laminate seal is affixed to the second face of the cartridge body by an adhesive.

Embodiment J1. A method for applying thermal energy to a reaction mixture and for transmitting optical signals to and/or from the reaction mixture, wherein the reaction mixture is contained within a reaction chamber having a first wall that is transparent or translucent and a second wall comprising a thermally-conductive laminate seal, wherein the thermally-conductive laminate seal comprises a plastic layer facing an interior space of the reaction chamber and a conductive layer disposed over the plastic layer, the method comprising: contacting the first wall of the reaction chamber with a first heater and heating the reaction mixture within the reaction chamber by conductive thermal energy transfer to the first wall of the reaction chamber contacted by the first heater; contacting the second wall of the reaction chamber with a second heater and heating the reaction mixture within the reaction chamber by conductive thermal energy transfer to the second wall of the reaction chamber contacted by the second heater; and transmitting an optical signal through the first heater and the first wall to the reaction mixture contained within the reaction chamber by an optical waveguide extending at least partially through the first heater and/or transmitting an optical signal from the reaction mixture contained within the reaction chamber through the first wall and the first heater by the optical waveguide.

Embodiment J2. The method of embodiment J1, wherein neither the first heater nor the second heater comprises a light source.

Embodiment J3. The method of embodiment J1 or J2, wherein each of the first heater and the second heater comprises a thermoelectric module.

Embodiment J4. The method of any one of embodiments J1 to J3, further comprising moving the first heater with respect to the second heater between a first position in which the first heater is not in contact with the first wall of the reaction chamber and a second position in which the first heater is in contact with the first wall of the reaction chamber.

Embodiment J5. The method of any one of embodiments J1 to J4, wherein the reaction chamber is part of a cartridge comprising a cartridge body having a first face, a second face, and at least one opening in the cartridge body extending from the first face to the second face, and wherein the first wall comprises a first film affixed to the first face of the cartridge body and covering a first end of the at least one opening, and wherein the thermally-conductive laminate seal is affixed to the second face of the cartridge body and covering a second end of the at least one opening, wherein the at least one opening covered by the first film and the thermally-conductive laminate seal define the reaction chamber.

Embodiment J6. The method of embodiment J5, wherein the cartridge body is opaque.

Embodiment J7. The method of embodiment J5 or J6, wherein the first face is a top face of the cartridge and the second face is a bottom face of the cartridge.

Embodiment J8. The method of any one of embodiments J1 to J7, wherein the plastic layer comprises polypropylene.

Embodiment J9. The method of any one of embodiments J1 to J8, wherein the conductive layer comprises a metallic foil.

Embodiment J10. The method of embodiment J9, wherein the metallic foil comprises aluminum.

Embodiment J11. The method of any one of embodiments J1 to J10, wherein the conductive layer is reflective and the plastic layer is transparent or translucent.

Embodiment J12. The method of any one of embodiments J1 to J11, further comprising two or more reaction chambers arranged in sets of at least two reaction chambers.

Embodiment J13. The method of any one of embodiments J1 to J12, further comprising at least one of an optical emitter and an optical detector optically coupled to the optical waveguide.

Embodiment J14. The method of any one of embodiments J1 to J13, wherein the optical waveguide comprises an optical fiber.

Embodiment K1. A valve actuator cooperatively arranged with respect to one or more fluid flow control valves within a fluidic device to selectively actuate each valve into a closed configuration preventing fluid flow or into an open configuration permitting fluid flow, the valve actuator comprising: a valve actuator piston operably engageable with each valve, wherein each valve actuator piston is movable between a first position corresponding to one of the closed configuration of the engaged valve and the open position of the engaged valve and a second position corresponding to the other of the open position of the engaged valve and the closed position of the engaged valve; a spring coupled to each valve actuator piston for biasing the valve actuator piston into the first position; at least one camshaft supported for rotation about a camshaft axis of rotation and including at least one cam lobe; and an actuator lever associated with each cam lobe and with each valve actuator piston, wherein the actuator lever comprises: a pivot connection at which the actuator lever is mounted for pivoting movement about a pivot axis of rotation; a piston engagement spatially separated from the pivot connection and at which the actuator lever is operatively engaged with the associated valve actuator piston so that pivoting movement of the actuator lever in a first direction about the pivot axis of rotation causes movement of the associated valve actuator piston from its first position to its second position; and a cam follower surface disposed between the pivot connection and the piston engagement, wherein the cam follower surface is constructed and arranged to be engaged by an associated cam lobe of the at least one camshaft as the camshaft rotates about the camshaft axis of rotation to cause pivoting movement of the actuator lever in the first direction.

Embodiment K2. The valve actuator of embodiment K1, wherein the valve actuator is cooperatively arranged with respect to six fluid flow control valves, and wherein the at least one camshaft comprises three camshafts and the at least one cam lobe of each camshaft comprises two cam lobes.

Embodiment K3. The valve actuator of embodiment K1, wherein the valve actuator is cooperatively arranged with respect to eight fluid flow control valves, and wherein the at least one camshaft comprises two camshafts and the at least one cam lobe of each camshaft comprises four cam lobes.

Embodiment K4. The valve actuator of any one of embodiments K1 to K3, further comprising a motor coupled to each camshaft for effecting powered rotation of the camshaft about the camshaft axis of rotation.

Embodiment K5. The valve actuator of embodiment K4, wherein each motor comprises a stepper motor.

Embodiment K6. The valve actuator of any one of embodiments K1 to K5, wherein each valve actuator piston comprises a contact end configured to directly or indirectly contact the associated valve, an extension extending from the contact end and having a width that is greater than a width of the contact end, and a lever collar having a width that is less than the width of the extension.

Embodiment K7. The valve actuator of embodiment K6, wherein each valve actuator piston further includes a peripheral rib surrounding the contact end.

Embodiment K8. The valve actuator of embodiment K6 or K7, wherein the valve actuator piston further includes a spring housing disposed below the lever collar and defining a hollow cylindrical space within which the spring is seated.

Embodiment K9. The valve actuator of embodiment K8, wherein a width of the spring housing is greater than the width of the lever collar, and wherein a top surface of the spring housing defines an annular lever seat, and wherein the piston engagement of each actuator lever comprises a yoke that receives the lever collar and is seated on the lever seat.

Embodiment K10. The valve actuator of embodiment K6 or K7, wherein the valve actuator piston further includes a spring rod below the lever collar, and wherein the spring coaxially surrounds the spring rod.

Embodiment K11. The valve actuator of embodiment K10, wherein the valve actuator piston further includes an enlargement between the lever collar and the spring rod, the enlargement having a width that is greater than the width of the lever collar, wherein a top surface of the enlargement defines an annular lever seat, and wherein the piston engagement of each actuator lever comprises a yoke that receives the lever collar and is seated on the lever seat.

Embodiment K12. The valve actuator of any one of embodiments K1 to K11, wherein at least one actuator lever has an “L” shape including first leg extending from the pivot connection and a second leg extending laterally from the first leg, wherein the engagement is formed on a side of the second leg between the first leg and an end of the second leg, and wherein the cam follower surface is formed on the first leg between the pivot connection and the second leg.

Embodiment K13. The valve actuator of any one of embodiments K1 to K12, wherein the pivot connection of each actuator lever comprises a pivot anchor comprising a partial cylinder and a pivot socket having a shape conforming to the pivot anchor and configured to rotatably retain the pivot anchor so that the pivot axis of rotation corresponds to a longitudinal axis of the partial cylinder.

Embodiment K14. The valve actuator of any one of embodiments K1 to K12, wherein the pivot connection of each actuator lever comprises a pivot rod extending through a pivot hole formed through the actuator lever so that the pivot axis of rotation corresponds to a longitudinal axis of the pivot rod.

Embodiment K15. The valve actuator of any one of embodiments K1 to K14, wherein each actuator lever includes a cam ring and the cam follower surface is formed within the cam ring.

Embodiment K16. The valve actuator of embodiment K13, further comprising a frame having an end wall, a bottom wall, a first side wall, and a second side wall, wherein the pivot socket is situated on the first side wall or the second side wall.

Embodiment K17. The valve actuator of embodiment K14, further comprising a frame having an end wall, a bottom wall, a first side wall, a second side wall, and a front wall, wherein the pivot rod extends between the front wall and the end wall.

Embodiment K18. The valve actuator of embodiment K16 or K17, further comprising a bearing mount associated with each camshaft and comprising: a mounting block secured to the bottom wall; an upright stanchion extending from the mounting block; and a bearing disposed within the stanchion at a position spaced from the mounting block and configured to rotatably receive a journal end of the associated camshaft.

Embodiment L1. An actuating mechanism cooperatively arranged with respect to a plurality of fluid flow control valves within a fluidic device, wherein the plurality of flow control valves are arranged in a circular configuration and the actuating mechanism is configured to selectively actuate each of the plurality of valves into a closed configuration preventing fluid flow or into an open configuration permitting fluid flow, and wherein the actuating mechanism comprises: a valve actuator piston operably engageable with each of the plurality of valves, wherein each valve actuator piston is axially movable between a first position corresponding to one of the closed configuration of the engaged valve and the open position of the engaged valve and a second position corresponding to the other of the open position of the engaged valve and the closed position of the engaged valve; a spring coupled to each valve actuator piston for biasing the valve actuator piston into the first position; a cam follower surface associated with each valve actuator piston; and a rotary cam that is rotatable about an axis of rotation corresponding to a center of the circular configuration of the plurality of flow control valves, wherein the rotary cam comprises: a cam rod extending radially with respect to the axis of rotation and rotatable about the axis of rotation, and a cam disposed on a radial outer end of the cam rod, wherein rotation of the cam rod about the axis of rotation to a rotational position of a selected one of the valve actuator pistons causes the cam to engage the cam follower surface associated with the selected valve actuator piston and move the selected valve actuator piston associated with the cam follower surface engaged by the cam from the first position to the second position.

Embodiment L2. The actuating mechanism of embodiment L1, wherein the first position of the valve actuator piston corresponds to the closed configuration of the associated valve and the second position of the valve actuator corresponds to the open configuration of the associated valve.

Embodiment L3. The actuating mechanism of embodiment L1 or L2, wherein the cam comprises a roller bearing attached to the radial outer end of the cam rod, and wherein the roller bearing is rotatable about an axis of rotation corresponding to a longitudinal axis of the cam rod.

Embodiment L4. The actuating mechanism of any one of embodiments L1 to L3, further comprising a rotary position sensor configured to detect a rotary position of the rotary cam.

Embodiment L5. The actuating mechanism of any one of embodiments L1 to L4, further comprising a cam rotor having a longitudinal axis corresponding to the axis of rotation, wherein the cam rod extends radially from the cam rotor.

Embodiment L6. The actuating mechanism of embodiment L5, wherein the cam rotor comprises: a center shaft supported for rotation about the axis of rotation; a cam rod mounting head including a radial extension flange and an axial wall extending from a radial periphery of the radial extension flange, wherein the axial wall is radially spaced from the center shaft, and wherein the cam rod is mounted within the cam rod mounting head.

Embodiment L7. The actuating mechanism of embodiment L6, wherein the axial wall of the cam rod mounting head includes a plurality of spaced-apart sensor flags formed about a circumference of the axial wall, and wherein the actuating mechanism further comprises an optical sensor comprising an optical emitter on one side of the axial wall and optical receiver on an opposite side of the axial wall.

Embodiment L8. The actuating mechanism of any one of embodiments L5 to L7, further comprising a cam drive comprising a motor and one or more gears coupling the motor with the cam rotor.

Embodiment L9. The actuating mechanism of any one of embodiments L1 to L8, wherein each valve actuator piston comprises: a contact rod configured to directly or indirectly contact the engaged valve; a cam block on which the cam follower surface is disposed; a lower rod projecting below the cam block; and a spring rod projecting below the lower rod and wherein the spring is coaxially disposed over the spring rod.

Embodiment L10. The actuating mechanism of embodiment L9, further including a stop flange at a base of the contact rod to prevent over insertion of the contact rod.

Embodiment L11. The actuating mechanism of embodiment L9 or L10, wherein a radially inner side of the cam block is narrower in a circumferential direction than a radially outer side of the cam block.

Embodiment L12. The actuating mechanism of any one of embodiments L1 to L11, wherein the cam follower surface has an inverted V shape.

Embodiment L13. The actuating mechanism of embodiment L12, wherein the cam follower surface has a flattened surface at a peak of the inverted V shape.

Embodiment M1. A system for performing one or more processes within a fluidic cartridge, wherein the fluidic cartridge comprises a plurality of fluid chambers, fluid channels connecting each of the fluid chambers with at least one other of the fluid chambers, and a plurality of valves selectively configurable in either an open state permitting fluid flow past or through the valve and a closed state preventing fluid flow past or through the valve, and wherein the system comprises: a pump mechanism operably engageable with the fluidic cartridge for moving fluids between the chambers and through the plurality of channels; a plurality of valve actuator pistons, wherein each valve actuator piston is movable between a first position and a second position and is operatively associated with one valve of the plurality of valves of the fluidic cartridge, and wherein, when the valve actuator piston is in its first position, the valve actuator piston exerts a force on the operatively associated valve to cause the valve to be in one of the closed state and the open state, and, when the valve actuator piston is in its second position, the force exerted by the valve actuator piston is removed from the operatively associated valve to cause the valve to be in the other of the closed state and the open state; a biasing element associated with each valve actuator piston for exerting a biasing force on the associated valve actuator piston to urge the associated valve actuator piston into its first position; and one or more piston actuator mechanisms coupled to or otherwise selectively engageable with each valve actuator piston and constructed and arranged to selectively apply a force to at least one valve actuator piston coupled to or engaged by the piston actuator mechanism to move the valve actuator piston against the biasing force from its first position to its second position and to selectively remove the force applied to the valve actuator piston to allow the valve actuator piston to move under the biasing force from its second position back to its first position.

Embodiment M2. The system of embodiment M1, wherein the first position of each valve actuator piston corresponds to the closed state of the associated valve and the second position of each valve actuator corresponds to the open state of the associated valve.

Embodiment M3. The system of embodiment M1 or M2, wherein the fluidic cartridge includes a syringe barrel and a syringe stopper disposed within the syringe barrel, wherein the fluid channels comprise a network of fluid channels directly or indirectly connecting one or more of the plurality of fluid chambers to the syringe barrel, and wherein the pump mechanism comprises: a movable syringe plunger configured to be engageable with the syringe stopper to removably connect the syringe stopper to the syringe plunger; and a syringe driver including a motor coupled to the syringe plunger and configured to actuate the syringe plunger to move the syringe stopper within the syringe barrel to move the engaged syringe stopper within the syringe barrel to either draw fluid into the syringe barrel or to expel fluid from the syringe barrel.

Embodiment M4. The system of any one of embodiments M1 to M3, wherein the system comprises: a support cradle on which the fluidic cartridge is operatively supported; and a plurality of actuator heads disposed within the support cradle, each actuator head being associated with one of the valves of the fluidic cartridge and with one of the valve actuator pistons, wherein each actuator head is configured to be movable with respect to the support cradle in response to movement of the associated valve actuator piston between its first and second positions to engage the associated valve to open or close the associated valve.

Embodiment M5. The system of any one of embodiments M1 to M4, wherein at least a portion of the plurality of valves are arranged in a circular configuration so that the valve actuator pistons associated with the portion of the plurality of valve are also arranged in a circular configuration, wherein each of the circularly-arranged valve actuator pistons includes a cam follower surface, and wherein the one or more piston actuator mechanisms comprises a rotary piston actuator comprising: a rotary cam that is rotatable about an axis of rotation corresponding to a center of the circular configuration of the valves, wherein the rotary cam comprises: a cam rod extending radially with respect to the axis of rotation and rotatable about the axis of rotation, and a cam disposed on a radial outer end of the cam rod, wherein the rotary piston actuator is configured to position the cam rod at a rotational position with respect to the axis of rotation to engage the cam follower surface associated with a selected one of the circularly-arranged valve actuator pistons to cause movement of the valve actuator piston associated with the cam follower surface engaged by the cam from the first position to the second position and then move the cam rod away from the rotational position of the selected valve actuator piston to disengage the cam follower surface associated with the selected valve actuator piston and permit movement of the selected valve actuator piston from the second position to the first position.

Embodiment M6. The system of embodiment M5, wherein the cam of the rotary piston actuator comprises a roller bearing attached to the radial outer end of the cam rod, and wherein the roller bearing is rotatable about an axis of rotation corresponding to a longitudinal axis of the cam rod.

Embodiment M7. The system of embodiment M5 or M6, wherein the rotary piston actuator further comprises a rotary position sensor configured to detect a rotary position of the rotary cam.

Embodiment M8. The system of any one of embodiments M5 to M7, wherein the rotary piston actuator further comprises a cam rotor having a longitudinal axis corresponding to the axis of rotation, wherein the cam rod extends radially from the cam rotor.

Embodiment M9. The system of embodiment M8, wherein the cam rotor of the rotary piston actuator comprises: a center shaft supported for rotation about the axis of rotation; and a cam rod mounting head including a radial extension flange and an axial wall extending from the radial extension flange, wherein the axial wall is radially spaced from the center shaft, and wherein the cam rod is mounted within the cam rod mounting head.

Embodiment M10. The system of embodiment M9, wherein the axial wall of the cam rod mounting head includes a plurality of spaced-apart sensor flags formed about a circumference of the axial wall, and the wherein the rotary piston actuator further comprises an optical sensor comprising an optical emitter on one side of the axial wall and an optical receiver on an opposite side of the axial wall.

Embodiment M11. The system of any one of embodiments M8 to M10, wherein the rotary piston actuator further comprises a cam drive comprising a motor and one or more gears coupling the motor with the cam rotor.

Embodiment M12. The system of any one of embodiments M5 to M11, wherein each of the valve actuator pistons arranged in the circular configuration comprises: a contact rod configured to directly or indirectly contact the engaged valve; a cam block on which the cam follower surface is disposed; a lower rod projecting below the cam block; and a spring rod projecting below the lower rod, and wherein the biasing element comprises a spring coaxially disposed over the spring rod.

Embodiment M13. The system of embodiment M12, wherein a radially inner side of the cam block is narrower in a circumferential direction with respect to the axis of rotation than a radially outer side of the cam block.

Embodiment M14. The system of any one of embodiments M1 to M13, wherein the one or more piston actuator mechanisms comprises a cam-driven piston actuator comprising: at least one camshaft supported for rotation about a camshaft axis of rotation and including at least one cam lobe; and an actuator lever associated with each cam lobe and with each of at least a portion of the plurality of valve actuator pistons, wherein each actuator lever comprises: a pivot connection at which the actuator lever is mounted for pivoting movement about a pivot axis of rotation; a piston engagement spatially separated from the pivot connection and at which the actuator lever is operatively engaged with the associated valve actuator piston so that pivoting movement of the actuator lever in a first direction about the pivot axis of rotation causes movement of the associated valve actuator piston from its first position to its second position; and a cam follower surface disposed between the pivot connection and the piston engagement, wherein the cam follower surface is constructed and arranged to be engaged by an associated cam lobe of the at least one camshaft as the camshaft rotates about the camshaft axis of rotation to cause pivoting movement of the actuator lever in the first direction.

Embodiment M15. The system of embodiment M14, further comprising six valve actuator pistons cooperatively arranged with respect to six valves, and wherein the at least one camshaft of the cam-driven piston actuator comprises three camshafts and the at least one cam lobe of each camshaft comprises two cam lobes.

Embodiment M16. The system of embodiment M14, further comprising eight valve actuator pistons cooperatively arranged with respect to eight valves, and wherein the at least one camshaft of the cam-driven piston actuator comprises two camshafts and the at least one cam lobe of each camshaft comprises four cam lobes.

Embodiment M17. The system of any one of embodiments M14 to M16, wherein the cam-driven piston actuator further comprises a motor coupled to each camshaft for effecting powered rotation of the camshaft about the camshaft axis of rotation.

Embodiment M18. The system of any one of embodiments M14 to M17, wherein each valve actuator piston associated with an actuator lever comprises a contact end configured to directly or indirectly contact the associated valve, an extension extending from the contact end and having a width that is greater than a width of the contact end, and a lever collar having a width that is less than the width of the extension.

Embodiment M19. The system of embodiment M18, wherein each valve actuator piston associated with an actuator lever further includes a spring housing disposed below the lever collar and defining a hollow cylindrical space, and wherein the biasing element comprises spring seated within the space.

Embodiment M20. The system of embodiment M19, wherein a width of the spring housing is greater than the width of the lever collar, wherein a top surface of the spring housing defines an annular lever seat, and wherein the piston engagement of each actuator lever comprises a yoke that receives the lever collar and is seated on the lever seat.

Embodiment M21. The system of embodiment M18, wherein each valve actuator piston associated with an actuator lever further comprises: a spring rod extending below the lever collar, wherein the biasing element comprises a spring coaxially surrounding the spring rod; and an enlargement between the lever collar and the spring rod and having a width that is greater than the width of the lever collar and wherein a top surface of the enlargement defines an annular lever seat, and wherein the piston engagement of each actuator lever comprises a yoke that receives the lever collar and is seated on the lever seat.

Embodiment M22. The system of any one of embodiments M14 to M21, wherein the pivot connection of each actuator lever of the cam-driven piston actuator comprises a pivot anchor comprising a partial cylinder and a pivot socket having a shape conforming to the pivot anchor and configured to rotatably retain the pivot anchor so that the pivot axis of rotation corresponds to a longitudinal axis of the partial cylinder.

Embodiment M23. The system of any one of embodiments M14 to M21, wherein the pivot connection of each actuator lever of the cam-driven piston actuator comprises a pivot rod extending through a pivot hole formed through the actuator lever so that the pivot axis of rotation corresponds to a longitudinal axis of the pivot rod.

Embodiment M24. The system of any one of embodiments M14 to M23, wherein each actuator lever of the cam-driven piston actuator includes a cam ring and the cam follower surface is formed within the cam ring.

Embodiment M25. The system of embodiment M22, wherein the cam-driven piston actuator comprises a frame having an end wall, a bottom wall, a first side wall, and a second side wall, and wherein the pivot socket is situated on the first side wall or the second side wall.

Embodiment M26. The system of embodiment M23, wherein cam-driven piston actuator comprises a frame having an end wall, a bottom wall, a first side wall, a second side wall, and a front wall, and wherein the pivot rod extends between the front wall and the end wall.

Embodiment M27. The system of any one of embodiments M1 to M26, wherein the plurality of chambers of the fluidic cartridge comprises at least one reaction chamber, and wherein the system further comprises: first and second heaters disposed in an opposed, spaced-apart configuration to receive the at least one reaction chamber between the first and second heaters; an actuator for moving the first heater with respect to the second heater to sandwich the at least one reaction chamber between the first and second heaters by moving the first heater toward the second heater and/or by moving the second heater toward the first heater when the at least one reaction chamber is disposed between the first and second heaters, wherein first and second heaters are configured to apply thermal energy to or absorb thermal energy from the at least one reaction chamber sandwiched between the first and second heaters; and an optical fiber aligned with or extending at least partially through an opening extending through the first heater and configured to transmit an optical signal through the first heater to and/or from the at least one reaction chamber.

Embodiment M28. The system of embodiment M27, wherein each of the first and second heaters comprises at least one thermal element configured to emit thermal energy to heat a body in thermal contact with the thermal element and/or absorb thermal energy to cool a body in thermal contact with the thermal element, and wherein the optical fiber extends at least partially through a hole formed through each thermal element of the first heater, each optical fiber being configured to transmit an optical signal to and/or from a different one of the at least one reaction chamber.

Embodiment M29. The system of embodiment M28, wherein each of the first and second heaters comprises a thermal block associated with each thermal element, wherein each thermal block has an exposed contact surface that contacts one of the at least one reaction chamber.

Embodiment M30. The system of embodiment M28 or M29, wherein each of the first and second heaters comprises a heat sink, wherein the thermal element of each of the first and second heaters is in thermal contact with the heat sink, and wherein the heat sink of at least one of the first and second heaters includes heat dissipation fins.

Embodiment M31. The system of any one of embodiments M27 to M30, further comprising at least one of an optical emitter and an optical detector optically coupled to the optical fiber.

Embodiment M32. The system of any one of embodiments M27 to M31, further comprising a movable tray for supporting the fluidic cartridge and configured to move the fluidic cartridge supported by the tray between a first position at which at the least one reaction chamber is not disposed between the first and second heaters and a second position at which the at least one reaction chamber is disposed between the first and second heaters.

Embodiment N1. A method of manufacturing a fluidic cartridge comprising: affixing a first film to a cartridge body, wherein the cartridge body has a first face, a second face, and at least one opening in the cartridge body extending from the first face to the second face, wherein the first film is secured to at least a portion of the first face to cover a first end of the at least one opening; and affixing a thermally-conductive laminate seal to a portion of the second face of the cartridge body to cover a second end of the at least one opening, wherein the thermally-conductive laminate seal comprises a plastic layer facing the at least one opening and a conductive layer disposed over the plastic layer.

Embodiment N2. The method of embodiment N1, wherein the cartridge body is opaque.

Embodiment N3. The method of embodiment N1 or N2, wherein at least a portion of the first film covering the at least one opening is transparent or translucent.

Embodiment N4. The method of any one of embodiments N1 to N3, wherein the plastic layer of the thermally-conductive laminate seal comprises polypropylene.

Embodiment N5. The method of any one of embodiments N1 to N4, wherein the conductive layer of the thermally-conductive laminate seal comprises a metallic foil.

Embodiment N6. The method of embodiment N5, wherein the metallic foil comprises aluminum.

Embodiment N7. The method of any one of embodiments N1 to N6, wherein the conductive layer of the thermally-conductive laminate seal is reflective and the plastic layer of the thermally-conductive laminate seal is transparent or translucent.

Embodiment N8. The method of any one of embodiments N1 to N7, wherein the at least one opening in the cartridge body comprises two or more openings arranged in sets of at least two openings.

Embodiment N9. The method of any one of embodiments N1 to N8, further comprising, before or after affixing the thermally-conductive laminate seal to a portion of the second face of the cartridge body, adhering a dried reagent to at least a portion of the surface of the plastic layer of the thermally-conductive laminate seal facing the at least one opening.

Embodiment N10. The method of embodiment N9, wherein the reagent comprises components for performing a polymerase chain reaction (PCR).

Embodiment N11. The method of embodiment N9 or N10, further comprising adhering the dried reagent to only a portion of the surface of the plastic layer corresponding to a location of the at least one opening.

Embodiment N12. The method of embodiment N11, wherein an edge of the dried reagent is spaced apart from an edge of the at least one opening.

Embodiment N13. The method of embodiment N11 or N12, wherein adhering the dried reagent to only the portion of the surface of the plastic layer corresponding to the location of the at least one opening comprises treating at least part of the surface of the plastic layer so that the portion of the surface to which the dried reagent is adhered has greater hydrophilicity as compared to the rest of the surface of the plastic layer.

Embodiment N14. The method of embodiment N13, further comprising treating the portion of the surface of the plastic layer to which the dried reagent is adhered so as to increase the hydrophilicity of the treated portion of the surface of the plastic layer as compared to the untreated portion of the surface of the plastic layer.

Embodiment N15. The method of embodiment N14, wherein the untreated portion of the surface of the plastic layer is hydrophobic.

Embodiment N16. The method of embodiment N14 or N15, further comprising treating the portion of the surface of the plastic layer to which the dried reagent is adhered with corona discharge or plasma to increase the hydrophilicity of the treated portion of the surface of the plastic layer as compared to the untreated portion of the surface of the plastic layer.

Embodiment N17. The method of embodiment N16, wherein treating the portion of the surface of the plastic layer to which the dried reagent is adhered with corona discharge or plasma comprises: affixing a mask to the surface of the plastic layer, wherein the mask has one or more openings exposing a portion of the surface of the plastic layer; and applying the corona discharge or plasma to the masked surface of the plastic layer, wherein only the portion of the surface of the plastic layer exposed through the one or more openings in the mask will be treated by the corona discharge or plasma.

Embodiment N18. The method of any one of embodiments N1 to N4, wherein the cartridge body and the first film each comprise a plastic, and wherein the first film is secured to the first face of the cartridge body by thermal welding, an adhesive, or chemical linking.

Embodiment N19. The method of embodiment N18, wherein the cartridge body and the first film each comprise polypropylene, and wherein the first film has a thickness of about 0.1 mm.

Embodiment N20. The method of any one of embodiments N1 to N17, wherein the cartridge body comprises a plastic, and wherein the thermally-conductive laminate seal is affixed to the second face of the cartridge body by heat sealing or ultrasonic welding the plastic layer of the thermally-conductive laminate seal to the cartridge body.

Embodiment N21. The method of embodiment N20, wherein the cartridge body includes one or more energy directors formed on the second face and at least partially surrounding each of the at least one opening, and wherein heat sealing or ultrasonic welding the plastic layer of the thermally-conductive laminate seal to the cartridge body comprises melting the energy directors and fusing the melted energy directors with the plastic layer.

Embodiment N22. The method of embodiment N21, wherein the cartridge body includes one or more inspection holes formed through the cartridge body at a region of the cartridge body to which the thermally-conductive laminate seal is affixed and energy directors at least partially surrounding each inspection hole, and wherein the method includes the step of inspecting each of the one or more inspection holes after heat sealing or ultrasonic welding the plastic layer of the thermally-conductive laminate seal to the cartridge body to determine if the energy directors at least partially surrounding the inspection hole have melted and at least partially blocked the inspection hole.

Embodiment N23. The method of embodiment N22, wherein the energy directors at least partially surrounding each of the at least one opening and the energy directors at least partially surrounding each inspection hole are the same size.

Embodiment N24. The method of embodiment N22, wherein the energy directors at least partially surrounding each of the at least one opening and the energy directors at least partially surrounding each inspection hole are the different sizes.

Embodiment N25. The method of any one of embodiments N21 to N24, wherein each energy director comprises a raised rib, and wherein the rib has a triangular cross-sectional shape forming a pointed top edge of the rib.

Embodiment N26. The method of any one of embodiments N22 to N25, wherein the energy directors at least partially surrounding each inspection hole are configured to completely block the inspection hole after the step of affixing the thermally-conductive laminate seal to the portion of the second face of the cartridge body.

Embodiment N27. The method of any one of embodiments N20 to N26, wherein the first film comprises a plastic, and wherein the first film is secured to the first face of the cartridge body by thermal welding, an adhesive, or chemical linking.

Embodiment N28. The method of embodiment N27, wherein the cartridge body and the first film each comprise polypropylene, and wherein the first film has a thickness of about 0.1 mm.

Embodiment N29. The method of any one of embodiments N1 to N19, wherein the thermally-conductive laminate seal is affixed to the second face of the cartridge body by an adhesive.

Embodiment N30. The method of any one of embodiments N1 to N29, further comprising affixing a second film to at least a portion of the second face of the cartridge body not covered by the thermally-conductive laminate seal and covering one or more grooves formed in the second face of the cartridge body to form one or more channels traversing a portion of the second face.

Embodiment N31. The method of any one of embodiments N1 to N30, wherein the first film affixed to the first face of the cartridge body covers one or more grooves formed in the first face to form one or more channels traversing a portion of the first face.

Embodiment N32. The method of embodiment N31, wherein the second film includes a cutout exposing the at least one opening, and wherein the thermally-conductive laminate seal is affixed to the second face of the cartridge body within the cutout of the second film.

Embodiment N33. The method of any one of embodiments N1 to N32, wherein the cartridge body includes one or more wells directly or indirectly connected to the at least one opening, wherein the method further comprises affixing a cover to the cartridge body over one or more of the wells to form an at least partially enclosed chamber with each covered well.

Embodiment N34. The method of embodiments N33, wherein the cover affixed to the cartridge body over the one or more wells comprises a protective venting cover, the protective venting cover comprising: a venting membrane configured to contain liquids in the one or more wells and having through pores formed therein to permit vapor passage through the venting membrane; and a protective cover secured to the venting membrane to block the through pores and reduce or prevent vapor passage, wherein the protective cover is peelable from the venting membrane by a user prior to use of the cartridge.

Embodiment N35. The method of embodiment N34, wherein the venting membrane of the venting cover includes blind pores extending partially through a thickness of the venting membrane.

Embodiment O1. A method of manufacturing a fluidic cartridge comprising: affixing a first film to a cartridge body, wherein the cartridge body has a first face, a second face, and at least one opening in the cartridge body extending from the first face to the second face, wherein the first film is secured to at least a portion of the first face to cover a first end of the at least one opening; affixing a seal to at least a portion of the second face of the cartridge body to cover a second end of the at least one opening, wherein the seal comprises a plastic layer facing the at least one opening; and before or after affixing the seal to a portion of the second face of the cartridge body, adhering a dried reagent to at least a portion of the surface of the plastic layer of the seal facing the at least one opening.

Embodiment O2. The method of embodiment O1, wherein the cartridge body is opaque.

Embodiment O3. The method of embodiment O1 or O2, wherein at least a portion of the first film covering the at least one opening is transparent or translucent.

Embodiment O4. The method of any one of embodiments O1 to O3, wherein the plastic layer of the seal comprises polypropylene.

Embodiment O5. The method of any one of embodiments O1 to O4, wherein the at least one opening in the cartridge body comprises two or more openings arranged in sets of at least two openings.

Embodiment O6. The method of any one of embodiments O1 to O5, wherein the reagent comprises components for performing a polymerase chain reaction (PCR).

Embodiment O7. The method of any one of embodiments O1 to O6, further comprising adhering the dried reagent to only a portion of the surface of the plastic layer corresponding to a location of the at least one opening.

Embodiment O8. The method of embodiment O7, wherein an edge of the dried reagent is spaced apart from an edge of the at least one opening.

Embodiment O9. The method of embodiment O7 or O8, wherein adhering the dried reagent to only the portion of the surface of the plastic layer corresponding to the location of the at least one opening comprises treating at least part of the surface of the plastic layer so that the portion of the surface to which the dried reagent is adhered has greater hydrophilicity as compared to the rest of the surface of the plastic layer.

Embodiment O10. The method of embodiment O9, further comprising treating the portion of the surface of the plastic layer to which the dried reagent is adhered so as to increase the hydrophilicity of the treated portion of the surface of the plastic layer as compared to the untreated portion of the surface of the plastic layer.

Embodiment O11. The method of embodiment O10, wherein the untreated portion of the surface of the plastic layer is hydrophobic.

Embodiment O12. The method of embodiment O10 or O11, further comprising treating the portion of the surface of the plastic layer to which the dried reagent is adhered with corona discharge or plasma to increase the hydrophilicity of the treated portion of the surface of the plastic layer as compared to the untreated portion of the surface of the plastic layer.

Embodiment O13. The method of embodiment O12, wherein treating the portion of the surface of the plastic layer to which the dried reagent is adhered with corona discharge or plasma comprises: affixing a mask to the surface of the plastic layer, wherein the mask has one or more openings exposing a portion of the surface of the plastic layer; and applying the corona discharge or plasma to the masked surface of the plastic layer, wherein only the portion of the surface of the plastic layer exposed through the one or more openings in the mask will be treated by the corona discharge or plasma.

Embodiment O14. The method of any one of embodiments O1 to O4, wherein the cartridge body and the first film each comprise a plastic, and wherein the first film is secured to the first face of the cartridge body by thermal welding, an adhesive, or chemical linking.

Embodiment O15. The method of embodiment O14, wherein the cartridge body and the first film each comprise polypropylene, and wherein the first film has a thickness of about 0.1 mm.

Embodiment O16. The method of any one of embodiments O1 to O13, wherein the cartridge body comprises a plastic, and wherein the seal is affixed to the second face of the cartridge body by heat sealing or ultrasonic welding the plastic layer of the seal to the cartridge body.

Embodiment O17. The method of embodiment O16, wherein the cartridge body includes one or more energy directors formed on the second face and at least partially surrounding each of the at least one opening, and wherein heat sealing or ultrasonic welding the plastic layer of the seal to the cartridge body comprises melting the energy directors and fusing the melted energy directors with the plastic layer.

Embodiment O18. The method of embodiment O17, wherein the cartridge body includes one or more inspection holes formed through the cartridge body at a region of the cartridge body to which the seal is affixed and energy directors at least partially surrounding each inspection hole, and wherein the method includes the step of inspecting each of the one or more inspection holes after heat sealing or ultrasonic welding the plastic layer of the seal to the cartridge body to determine if the energy directors at least partially surrounding the inspection hole have melted and at least partially blocked the inspection hole.

Embodiment O19. The method of embodiment O18, wherein the energy directors at least partially surrounding each of the at least one opening and the energy directors at least partially surrounding each inspection hole are the same size.

Embodiment O20. The method of embodiment O18, wherein the energy directors at least partially surrounding each of the at least one opening and the energy directors at least partially surrounding each inspection hole are the different sizes.

Embodiment O21. The method of any one of embodiments O17 to O20, wherein each energy director comprises a raised rib, and wherein the rib has a triangular cross-sectional shape forming a pointed top edge of the rib.

Embodiment O22. The method of any one of embodiments O18 to O21, wherein the energy directors at least partially surrounding each inspection hole are configured to completely block the inspection hole after the step of affixing the seal to the portion of the second face of the cartridge body.

Embodiment O23. The method of any one of embodiments O16 to O22, wherein the first film comprises a plastic, and wherein the first film is secured to the first face of the cartridge body by thermal welding, an adhesive, or chemical linking.

Embodiment O24. The method of embodiment O23, wherein the cartridge body and the first film each comprise polypropylene, and wherein the first film has a thickness of about 0.1 mm.

Embodiment O25. The method of any one of embodiments O1 to O15, wherein the seal is affixed to the second face of the cartridge body by an adhesive.

Embodiment O26. The method of any one of embodiments O1 to O25, further comprising affixing a second film to at least a portion of the second face of the cartridge body not covered by the seal and covering one or more grooves formed in the second face of the cartridge body to form one or more channels traversing a portion of the second face.

Embodiment O27. The method of embodiment O26, wherein the second film includes a cutout exposing the at least one opening, and wherein the seal is affixed to the second face of the cartridge body within the cutout of the second film.

Embodiment O28. The method of any one of embodiments O1 to O25, wherein the seal comprises a second film which, in addition to covering the second end of the at least one opening, covers one or more grooves formed in the second face of the cartridge body to form one or more channels traversing a portion of the second face.

Embodiment O29. The method of any one of embodiments O1 to O28, wherein the first film affixed to the first face of the cartridge body covers one or more grooves formed in the first face to form one or more channels traversing a portion of the first face.

Embodiment O30. The method of any one of embodiments O1 to O29, wherein the cartridge body includes one or more wells directly or indirectly connected to the at least one opening, wherein the method further comprises affixing a cover to the cartridge body over one or more of the wells to form an at least partially enclosed chamber with each covered well.

Embodiment O31. The method of embodiment O30, wherein the cover affixed to the cartridge body over the one or more wells comprises a protective venting cover, the protective venting cover comprising: a venting membrane configured to contain liquids in the one or more wells and having through pores formed therein to permit vapor passage through the venting membrane; and a protective cover secured to the venting membrane to block the through pores and reduce or prevent vapor passage, wherein the protective cover is peelable from the venting membrane by a user prior to use of the cartridge.

Embodiment O32. The method of embodiment O31, wherein the venting membrane of the venting cover includes blind pores extending partially through a thickness of the venting membrane.

Embodiment P1. A method of manufacturing a fluidic cartridge comprising: affixing a first film to a cartridge body, wherein the cartridge body comprises a plastic and has a first face, a second face, and at least one opening in the cartridge body extending from the first face to the second face, wherein the first film is secured to at least a portion of the first face to cover a first end of the at least one opening; and affixing a seal to at least a portion of the second face of the cartridge body to cover a second end of the at least one opening, wherein the cartridge body includes one or more energy directors formed on the second face and at least partially surrounding each of the at least one opening, wherein the seal comprises a plastic layer facing the at least one opening, and wherein affixing the seal to the second face of the cartridge body comprises heat sealing or ultrasonic welding the plastic layer of the seal to the cartridge body by melting the energy directors and fusing the melted energy directors with the plastic layer.

Embodiment P2. The method of embodiment P1, wherein the cartridge body is opaque.

Embodiment P3. The method of embodiment P1 or P2, wherein at least a portion of the first film covering the at least one opening is transparent or translucent.

Embodiment P4. The method of any one of embodiments P1 to P3, wherein the plastic layer of the seal comprises polypropylene.

Embodiment P5. The method of any one of embodiments P1 to P4, wherein the plastic layer of the seal is transparent or translucent.

Embodiment P6. The method of any one of embodiments P1 to P5, wherein the at least one opening in the cartridge body comprises two or more openings arranged in sets of at least two openings.

Embodiment P7. The method of any one of embodiments P1 to P6, further comprising, before or after affixing the seal to a portion of the second face of the cartridge body, adhering a dried reagent to at least a portion of the surface of the plastic layer of the seal facing the at least one opening.

Embodiment P8. The method of embodiment P7, wherein the reagent comprises components for performing a polymerase chain reaction (PCR).

Embodiment P9. The method of embodiment P7 or P8, further comprising adhering the dried reagent to only a portion of the surface of the plastic layer corresponding to a location of the at least one opening.

Embodiment P10. The method of embodiment P9, wherein an edge of the dried reagent is spaced apart from an edge of the at least one opening.

Embodiment P11. The method of embodiment P9 or P10, wherein adhering the dried reagent to only the portion of the surface of the plastic layer corresponding to the location of the at least one opening comprises treating at least part of the surface of the plastic layer so that the portion of the surface to which the dried reagent is adhered has greater hydrophilicity as compared to the rest of the surface of the plastic layer.

Embodiment P12. The method of embodiment P11, further comprising treating the portion of the surface of the plastic layer to which the dried reagent is adhered so as to increase the hydrophilicity of the treated portion of the surface of the plastic layer as compared to the untreated portion of the surface of the plastic layer.

Embodiment P13. The method of embodiment P12, wherein the untreated portion of the surface of the plastic layer is hydrophobic.

Embodiment P14. The method of embodiment P12 or P13, further comprising treating the portion of the surface of the plastic layer to which the dried reagent is adhered with corona discharge or plasma to increase the hydrophilicity of the treated portion of the surface of the plastic layer as compared to the untreated portion of the surface of the plastic layer.

Embodiment P15. The method of embodiment P14, wherein treating the portion of the surface of the plastic layer to which the dried reagent is adhered with corona discharge or plasma comprises: affixing a mask to the surface of the plastic layer, wherein the mask has one or more openings exposing a portion of the surface of the plastic layer; and applying the corona discharge or plasma to the masked surface of the plastic layer, wherein only the portion of the surface of the plastic layer exposed through the one or more openings in the mask will be treated by the corona discharge or plasma.

Embodiment P16. The method of any one of embodiments P1 to P4, wherein the first film comprises a plastic, and wherein the first film is secured to the first face of the cartridge body by thermal welding, an adhesive, or chemical linking.

Embodiment P17. The method of embodiment P16, wherein the cartridge body and the first film each comprise polypropylene, and wherein the first film has a thickness of about 0.1 mm.

Embodiment P18. The method of any one of embodiments P1 to P17, wherein the cartridge body includes one or more inspection holes formed through the cartridge body at a region of the cartridge body to which the seal is affixed and energy directors at least partially surrounding each inspection hole, and wherein the method includes the step of inspecting each of the one or more inspection holes after heat sealing or ultrasonic welding the plastic layer of the seal to the cartridge body to determine if the energy directors at least partially surrounding the inspection hole have melted and at least partially blocked the inspection hole.

Embodiment P19. The method of embodiment P18, wherein the energy directors at least partially surrounding each of the at least one opening and the energy directors at least partially surrounding each inspection hole are the same size.

Embodiment P20. The method of embodiment P18, wherein the energy directors at least partially surrounding each of the at least one opening and the energy directors at least partially surrounding each inspection hole are the different sizes.

Embodiment P21. The method of any one of embodiments P17 to P20, wherein each energy director comprises a raised rib, and wherein the rib has a triangular cross-sectional shape forming a pointed top edge of the rib.

Embodiment P22. The method of any one of embodiments P18 to P21, wherein the energy directors at least partially surrounding each inspection hole are configured to completely block the inspection hole after the step of affixing the seal to the portion of the second face of the cartridge body.

Embodiment P23. The method of any one of embodiments P18 to P22, wherein the first film comprises a plastic, and wherein the first film is secured to the first face of the cartridge body by thermal welding, an adhesive, or chemical linking.

Embodiment P24. The method of embodiment P23, wherein the cartridge body and the first film each comprise polypropylene, and wherein the first film has a thickness of about 0.1 mm.

Embodiment P25. The method of any one of embodiments P1 to P24, further comprising affixing a second film to at least a portion of the second face of the cartridge body not covered by the seal and covering one or more grooves formed in the second face of the cartridge body to form one or more channels traversing a portion of the second face.

Embodiment P26. The method of embodiment P25, wherein the second film includes a cutout exposing the at least one opening, and wherein the seal is affixed to the second face of the cartridge body within the cutout of the second film.

Embodiment P27. The method of any one of embodiments P1 to P24, wherein the seal comprises a second film which, in addition to covering the second end of the at least one opening, covers one or more grooves formed in the second face of the cartridge body to form one or more channels traversing a portion of the second face.

Embodiment P28. The method of any one of embodiments P1 to P27, wherein the first film affixed to the first face of the cartridge body covers one or more grooves formed in the first face to form one or more channels traversing a portion of the first face.

Embodiment P29. The method of any one of embodiments P1 to P28, wherein the cartridge body includes one or more wells directly or indirectly connected to the at least one opening, wherein the method further comprises affixing a cover to the cartridge body over one or more of the wells to form an at least partially enclosed chamber with each covered well.

Embodiment P30. The method of embodiments P29, wherein the cover affixed to the cartridge body over the one or more wells comprises a protective venting cover, the protective venting cover comprising: a venting membrane configured to contain liquids in the one or more wells and having through pores formed therein to permit vapor passage through the venting membrane; and a protective cover secured to the venting membrane to block the through pores and reduce or prevent vapor passage, wherein the protective cover is peelable from the venting membrane by a user prior to use of the cartridge.

Embodiment P31. The method of embodiment P30, wherein the venting membrane of the venting cover includes blind pores extending partially through a thickness of the venting membrane.

Other features and characteristics of the subject matter of this disclosure, as well as the methods of operation, functions of related elements of structure and the combination of parts, and economies of manufacture, will become more apparent upon consideration of the following description and the appended claims with reference to the accompanying drawings, all of which form a part of this specification, where like reference numerals designate corresponding parts in the various figures.

### BRIEF DESCRIPTION OF THE DRAWINGS

The accompanying drawings, which are incorporated herein and form part of the specification, illustrate various embodiments of the subject matter of this disclosure. In the drawings, like reference numbers indicate identical or functionally similar elements.

FIG. 1 is a rear perspective view of an instrument as described herein.

FIG. 2 is a front perspective view of the instrument.

FIG. 3 is an exploded top perspective view of an example of a fluidic cartridge that is processed in the instrument described herein.

FIG. 4 is a top plan view of a cartridge body of the fluidic cartridge.

FIG. 5 is a bottom plan view of the cartridge body.

FIG. 6 is a top perspective view of the cartridge body.

FIG. 7 is a bottom perspective view of the cartridge body.

FIG. 8 is a schematic transverse cross-section of the fluidic cartridge through reaction/detection chambers of the fluidic cartridge.

FIG. 9 is a bottom perspective view of a protective venting cover of the fluidic cartridge.

FIG. 10 and FIG. 10 “Detail A” show a cross-section of the protective venting cover along the line A-A in FIG. 9.

FIG. 11 is an exploded, top perspective view of a blocker, a blocker ring, and a syringe stopper of the fluidic cartridge.

FIG. 12 is a top perspective view of the blocker.

FIG. 13 is a top view of the blocker.

FIG. 14 is a bottom view of the blocker.

FIG. 15 is a top perspective view of a sample chamber cap of the fluidic cartridge.

FIG. 16 is a side view of the sample chamber cap.

FIG. 17 is a transverse cross-section of the sample chamber cap along the line A-A in FIG. 15.

FIG. 18 is a cross-section of the fluidic cartridge along the line B-B in FIG. 4 showing the cartridge body.

FIG. 19 is a cross-section of the fluidic cartridge along the line A-A in FIG. 4 showing the cartridge body.

FIG. 20 is a perspective view of a syringe driver of the instrument.

FIG. 21 is a plot of motor current demand versus stopper travel for four different fluidic cartridges.

FIG. 22 is a flow diagram illustrating a method for using the demand of a motor of the syringe drive module and the output of an encoder coupled to the motor to control the position of the syringe stopper and thus the volume of fluid drawn into the syringe barrel SB of the fluidic cartridge.

FIG. 23 is a partial, top perspective view showing a cartridge support frame of the instrument.

FIG. 23A is a perspective view of a cartridge support cradle of the cartridge support frame in isolation.

FIG. 24 is a partial, top perspective view showing the cartridge support frame supporting the fluidic cartridge.

FIG. 25 is a schematic cross-section through first and second thermal modules of the instrument and through reaction/detection chambers of the cartridge and with the first thermal module in a raised position with respect to the second thermal module and the cartridge.

FIG. 26 is a schematic cross-section through the first and second thermal modules of the instrument and through the reaction/detection chambers of the cartridge and with the first thermal module in a lower position with respect to the second thermal module and the cartridge.

FIG. 27 is a top perspective view of an upper chassis of the instrument.

FIG. 28 is a side view of the upper chassis.

FIG. 29 is a bottom perspective view of the upper chassis.

FIG. 30 is a top, partial perspective view of the instrument showing the first (top) and second (bottom) thermal modules.

FIG. 31 is a top, partial perspective view of a first (top) thermal module and second (bottom) thermal module.

FIG. 32 is a bottom, partial perspective view of the first thermal module and the second thermal module.

FIG. 33 is a top perspective view of the first thermal module.

FIG. 34 is a bottom perspective view of the first thermal module.

FIG. 35 is a cross-sectional view of the first thermal module through the line A-A in FIG. 33.

FIG. 36 is a perspective view of the first thermal module with a first thermal assembly of the first thermal module shown in an exploded view.

FIG. 37 is an exploded, perspective view of a second thermal assembly of the second thermal module.

FIG. 38 is a front view of the first and second thermal assemblies of the second thermal module.

FIG. 39 is a left-side view of the second thermal assembly of the second thermal module.

FIG. 40 is a right-side view of the first thermal assembly of the second thermal module.

FIG. 41 is a top perspective view of the second thermal assembly of the second thermal module.

FIG. 42 is a partial, top, left-side perspective view of a contact detector of the instrument when the first thermal module is in the raised position with respect to the cartridge.

FIG. 43 is a partial, top, left-side perspective view of the contact detector of the instrument when the first thermal module is in the lowered position with respect to the cartridge and the contact detector is in contact with the cartridge.

FIG. 44 is a partial, top, front perspective view of the contact detector of the instrument.

FIG. 45 shows a flow diagram illustrating an embodiment of a method for performing an assay using the instrument and fluidic cartridge described herein.

FIG. 46 is a plot of a temperature profile of a thermal cycler as described herein.

FIG. 47 is a perspective partial view illustrating a portion of the upper chassis of the instrument supporting a cartridge with a rotary valve actuator attached to the upper chassis.

FIG. 48 is a partial longitudinal cross-section of the structure shown in FIG. 47.

FIG. 49 is a top perspective view of the rotary valve actuator.

FIG. 50 is a transverse cross-section of the rotary valve actuator.

FIG. 51 is a backside view of the cross-section shown in FIG. 50.

FIG. 52 is a perspective view of a valve actuator piston of the rotary valve actuator.

FIG. 53 is a perspective view of an embodiment of a cam operated valve actuator.

FIG. 54 is a top perspective view of the cam-operated valve actuator of FIG. 53.

FIG. 55 is a cross-section along the line A-A in FIG. 54.

FIG. 56 is a cross-section along the line B-B in FIG. 54.

FIG. 57 is a cross-section along the line C-C in FIG. 54.

FIG. 58 is a cross-section along the line D-D in FIG. 54.

FIG. 59 is a front view of a valve actuator piston of the cam-operated valve actuator of FIGS. 53-58.

FIG. 60 is a perspective view of the valve actuator piston of FIG. 59.

FIG. 61 is a perspective view of an alternate embodiment of a cam operated valve actuator.

FIG. 62 is a top view of the cam-operated valve actuator of FIG. 61.

FIG. 63 is a cross-section along the line A-A in FIG. 62.

FIG. 64 is a cross-section along the line B-B in FIG. 62.

FIG. 65 is a cross-section along the line C-C in FIG. 62.

FIG. 66 is a cross-section along the line D-D in FIG. 62.

FIG. 67 is a front view of a valve actuator piston of the cam-operated valve actuator of FIGS. 61-66.

FIG. 68 is a perspective view of the valve actuator piston of FIG. 67.

FIG. 69 is a partial transverse cross-section across the cartridge body through the reaction chambers and thermally-conductive laminate seal with the top film and bottom film omitted from the figure.

FIG. 70 is a top plan view of a laminate seal with a mask having openings, where the mask is shown as cross-hatched.

### DETAILED DESCRIPTION

While aspects of the subject matter of the present disclosure may be embodied in a variety of forms, the following description and accompanying drawings are merely intended to disclose some of these forms as specific examples of the subject matter. Accordingly, the subject matter of this disclosure is not intended to be limited to the forms or embodiments so described and illustrated.

### Definitions

Unless defined otherwise, all terms of art, notations and other technical terms or terminology used herein have the same meaning as is commonly understood by one of ordinary skill in the art to which this disclosure belongs. All patents, applications, published applications and other publications referred to herein are incorporated by reference in their entirety. If a definition set forth in this section is contrary to or otherwise inconsistent with a definition set forth in the patents, applications, published applications, and other publications that are herein incorporated by reference, the definition set forth in this section prevails over the definition that is incorporated herein by reference.

Unless otherwise indicated or the context suggests otherwise, as used herein, “a” or “an” means “at least one” or “one or more.”

References in the specification to “one embodiment,” “an embodiment,” a “further embodiment,” “an example,” “some aspects,” “a further aspect,” “aspects,” etc., indicate that the embodiment, example, or aspect described may include a particular feature, structure, or characteristic, but every embodiment encompassed by this disclosure may not necessarily include the particular feature, structure, or characteristic. Moreover, such phrases are not necessarily referring to the same embodiment, example, or aspect. Further, when a particular feature, structure, or characteristic is described in connection with an embodiment, such feature, structure, or characteristic is also a description in connection with other embodiments, examples, or aspects, whether or not explicitly described.

This description may use various terms describing relative spatial arrangements and/or orientations or directions in describing the position and/or orientation of a component, apparatus, location, feature, or a portion thereof or direction of movement, force, or other dynamic action. Unless specifically stated, or otherwise dictated by the context of the description, such terms, including, without limitation, top, bottom, above, below, under, on top of, upper, lower, left, right, in front of, behind, beneath, next to, adjacent, between, horizontal, vertical, diagonal, longitudinal, transverse, radial, axial, clockwise, counter-clockwise, etc., are used for convenience in referring to such component, apparatus, location, feature, or a portion thereof or movement, force, or other dynamic action represented in the drawings and are not intended to be limiting.

Unless otherwise indicated, or the context suggests otherwise, terms used herein to describe a physical and/or spatial relationship between a first component, structure, or portion thereof and a second component, structure, or portion thereof, such as, attached, connected, fixed, joined, linked, coupled, or similar terms or variations of such terms, shall encompass both a direct relationship in which the first component, structure, or portion thereof is in direct contact with the second component, structure, or portion thereof or there are one or more intervening components, structures, or portions thereof between the first component, structure, or portion thereof and the second component, structure, or portion thereof.

Unless otherwise stated, any specific dimensions mentioned in this description are merely representative of an example of an implementation of a device embodying aspects of the disclosure and are not intended to be limiting.

To the extent used herein, the terms “about” or “approximately” apply to all numeric values and terms indicating specific physical orientations or relationships such as horizontal, vertical, parallel, perpendicular, concentric, or similar terms, specified herein, whether or not explicitly indicated. This term generally refers to a range of numbers, orientations, and relationships that one of ordinary skill in the art would consider as a reasonable amount of deviation to the recited numeric values, orientations, and relationships (i.e., having the equivalent function or result) in the context of the present disclosure. For example, and not intended to be limiting, this term can be construed as including a deviation of 10 percent of the given numeric value, orientation, or relationship, provided such a deviation does not alter the end function or result of the stated value, orientation, or relationship. Therefore, under some circumstances as would be appreciated by one of ordinary skill in the art a value of about or approximately 1% can be construed to be a range from 0.9% to 1.1%.

To the extent used herein, the term “adjacent” refers to being near (spatial proximity) or adjoining. Adjacent objects or portions thereof can be spaced apart from one another or can be in actual or direct contact with one another. In some instances, adjacent objects or portions thereof can be coupled to one another or can be formed integrally with one another.

To the extent used herein, the terms “substantially” and “substantial” refer to a considerable degree or extent. When used in conjunction with, for example, an event, circumstance, characteristic, or property, the terms can refer to instances in which the event, circumstance, characteristic, or property occurs precisely as stated as well as instances in which the event, circumstance, characteristic, or property occurs to a close approximation, such as accounting for typical tolerance levels or variability of the embodiments described herein.

To the extent used herein, the terms “optional” and “optionally” or the term “may” (e.g., as in the phrase “may include,” “may comprise,” “may produce,” “may provide,” or similar phrases) mean that the subsequently described component, structure, element, event, circumstance, characteristic, property, etc. may or may not be included or occur and that the description includes instances where the component, structure, element, event, circumstance, characteristic, property, etc. is included or occurs and instances in which it is not or does not.

To the extent used herein, the terms “first,” “second,” and similar terms preceding the name of an element (e.g., a component, apparatus, location, feature, or a portion thereof or a direction of movement, force, or other dynamic action) are used for identification purposes to distinguish between similar elements, and are not intended to necessarily imply order or rank, nor are the terms “first” and “second” intended to preclude the inclusion of additional similar elements. Furthermore, unless the context indicates otherwise, use of the term “first” preceding the name of an element (e.g., a component, apparatus, location, feature, or a portion thereof or a direction of movement, force, or other dynamic action) does not necessarily imply or require that there be additional, e.g., “second,” “third,” etc., such element(s).

To the extent used herein, the terms or phrases “configured to,” “adapted to,” “operable to,” “constructed and arranged to,” and similar terms mean that the subject of the term or phrase includes, constitutes, or otherwise encompasses the requisite structure(s), mechanism(s), arrangement(s), component(s), material(s), algorithm(s), circuit(s), programming, etc. to perform a specified task or tasks or achieve a specified output or characteristic, either automatically or perpetually or selectively when called upon to do so.

To the extent used herein, the term “amplification reaction” means a procedure used to produce multiple copies of a specific segment of nucleic acid. Amplification reactions may be isothermal or require repetitive cycling between different temperatures, such as is required with a Polymerase Chain Reaction (PCR).

To the extent used herein, the term “analyte” refers to a molecule or substance that is detected or subjected to analysis in an assay. Examples of analytes include nucleic acids, proteins (e.g., antibodies, polypeptides, and prions), and antigens.

To the extent used herein, the term “assay” refers to a procedure for detecting and/or quantifying an analyte in a sample. A sample containing or suspected of containing the analyte is contacted with one or more reagents and subjected to conditions permissive for generating a detectable signal informative of whether the analyte is present or an amount (e.g., mass or concentration) of the analyte in the sample.

To the extent used herein, the term “analyzer” refers to an automated instrument that is capable of performing one or more steps of an assay, including the step of determining the presence or absence of one or more analytes suspected of being present in a fluid sample.

To the extent used herein, the term “molecular assay” refers to a procedure for specifically detecting and/or quantifying a target molecule, such as a particular nucleic acid. A sample comprising or suspected of comprising the target molecule is contacted with one or more reagents, including at least one reagent specific for the target molecule, and subjected to conditions permissive for generating a detectable signal informative of whether the target molecule is present. For example, where the molecular assay includes an amplification reaction, such as a polymerase chain reaction (PCR), the reagents include primers that may be specific for a target nucleic acid, and the generation of a detectable signal can be accomplished, at least in part, by providing a labeled probe (e.g., fluorescently labeled probe) that hybridizes in a target-specific manner to the amplicon produced by the primers in the presence of the target. Alternatively, the reagents can include an intercalating dye (e.g., SYBR® Green) for detecting the formation of double-stranded nucleic acids.

To the extent used herein, the term “point-of-care testing” (POCT), sometimes referred to as near-patient testing, is testing conducted close to the site of patient care or treatment. This may be in the context of a hospital, doctor's office, or field testing. Unlike high-throughput systems, POCT systems are generally small and may be easily portable. Most POCT systems are capable of running an assay on a single or limited number of samples simultaneously.

To the extent used herein, the term “reagent” refers to any substance or mixture that participates in an assay, other than sample material and products of the assay. Examples of reagents for use in a molecular assay include nucleotides, enzymes, primers, probes, and salts.

To the extent used herein, the term “receptacle” or “fluid receptacle” refers to any type of fluid container, including, for example, a tube, a vial, a cuvette, a well or cartridge or other article having one or more wells or chambers formed therein or attached thereto, a microtiter plate, etc., that is configured to contain a sample or another fluid (collectively referred to herein as fluid). Tubes may be cylindrical (i.e., circular in cross-section) or non-cylindrical and may have flat or rounded closed ends. Non-limiting examples of receptacles include, for example, Novodiag® sample buffer and collection tubes (Mobidiag Oy; Espoo, Finland) and the Aptima® Multitest Swab Collection Kit (Hologic, Inc.; Marlborough, MA).

To the extent used herein, the term “sample” refers to any substance suspected of containing at least one analyte of interest. The analyte of interest may be, for example, a nucleic acid, a protein, a chemical, or the like. The substance may be derived from any source, including an animal, an industrial process, the environment, a water source, a food product, or a solid surface (e.g., surface in a medical facility). Substances obtained from animals may include, for example, blood or blood products, urine, mucus, sputum, saliva, semen, tears, pus, stool, nasopharyngeal or genitourinary specimen obtained with a swab or other collection device, and other bodily fluids or materials. The term “sample” will be understood to mean a specimen in its native form or any stage of processing.

To the extent used herein, the term “thermal contact” or “thermal communication” means the ability to allow thermal energy transfer between two systems or bodies at different temperatures. The two systems or bodies may be in direct physical contact such that the thermal energy transfer occurs directly from one system or body to the other system or body, or an intervening material, including air, may be disposed between the two systems or bodies such that thermal energy transfer occurs from one system or body to the other system or body through the intervening material.

To the extent used herein, the term “unit dose form” means an amount that is sufficient for performing a single assay. That is, as opposed to a bulk reagent, which is provided in amount that can be used to perform multiple assays, a “unit dose” or “unitized” reagent is an amount of a reagent that can be used for a single assay (the single assay may be designed to determine the presence of one or more analytes).

A “fluidic cartridge” is a device including a fluidic network of two or more chambers for containing fluid which are fluidly interconnected, or interconnectable, by one or more fluid channels. The device is configured to interface with a processing instrument or analyzer for effecting one or more processes on fluids contained in the cartridge, including, for example, one or more of applying positive or negative pressure to the cartridge, applying physical pressure to at least one chamber to at least partially collapse the chamber, or actuating a pump mechanism operatively coupled to the cartridge to effect fluid movement between chambers within the fluidic network, actuating or otherwise altering flow control mechanisms, such as valves, to alter the flow control mechanism between an open state permitting fluid flow past the flow control mechanism and a closed state blocking fluid flow past the flow control mechanism, heating and/or cooling the fluid in one or more chambers of the cartridge, and detecting and recording signals based on optical emissions from fluids contained in one or more chambers of the cartridge.

### DETAILED DESCRIPTION OF DRAWINGS

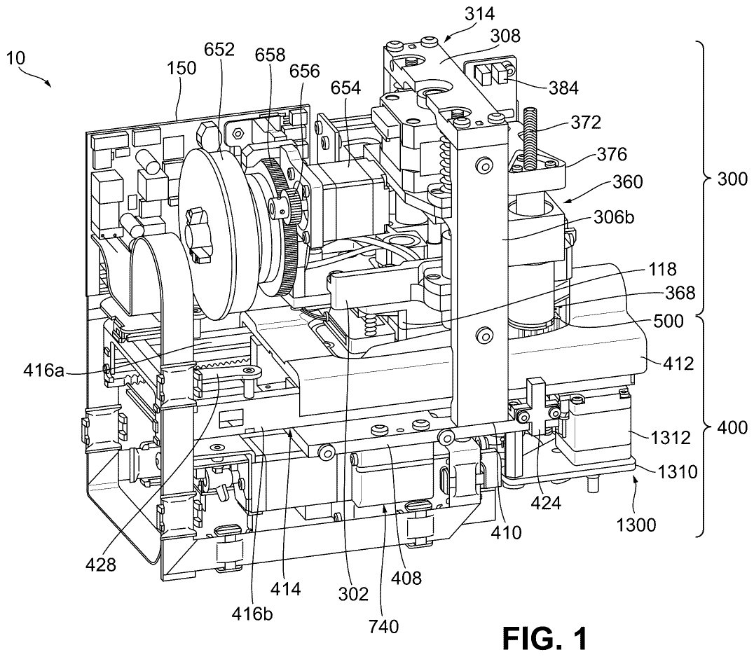

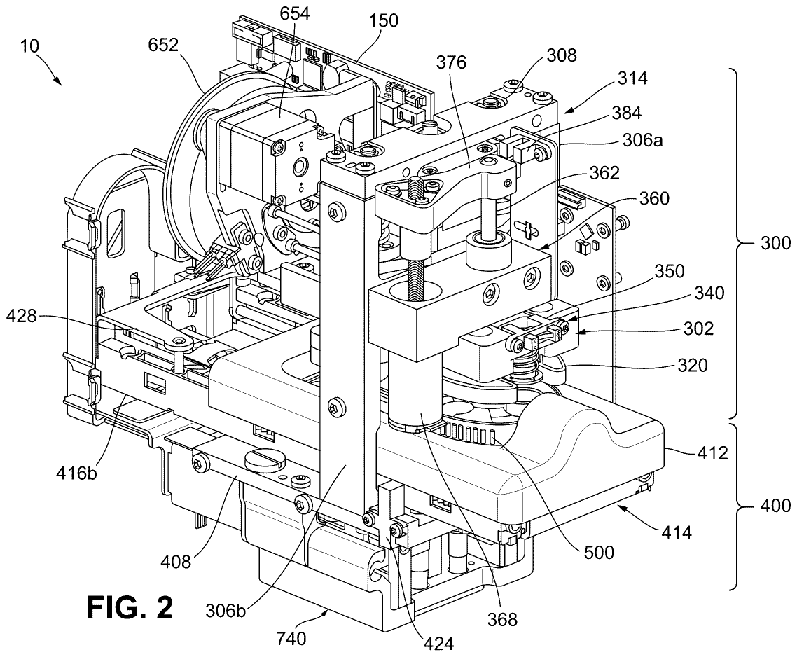

FIGS. 1 and 2 show the internal components of an instrument 10 as described herein for receiving and operating on a test platform, such as a fluidic cartridge (i.e., a device configured to be placed into and interface with a processing instrument and which includes reagent and sample storage and fluid handling components, such as fluid flow channels and flow control valves), to process a sample (e.g., perform an assay, such as a molecular assay, and collect data regarding the results of the assay) on or within the test platform. Instrument 10 includes components for applying thermal energy to one or more detection regions of the test platform, components for transmitting optical signals to and/or from the detection region(s), and a component for actuating a syringe pump within the test platform. FIG. 1 is a rear perspective view of the instrument 10, and FIG. 2 is a front perspective view of the instrument 10. Instrument 10 may be a point-of-care testing system for providing sample-to-result testing employing disposable fluidic cartridges comprising interconnected chambers (or wells) and reaction chambers that can be prepackaged in unit dose form with all of the reagents needed to perform the desired testing. The fluidic cartridges may be closed systems that minimize opportunities for contamination.

Typically, such an instrument would include a housing within which the internal components would be enclosed, but such a housing is omitted from FIG. 1 so that the internal components can be seen.

As shown in FIGS. 1 and 2, a test platform, e.g., a fluidic cartridge 500, is situated within the instrument 10, and the internal components of the instrument can be generally grouped into a first chassis, or upper chassis, 300, referring to those internal components situated above the cartridge 500, and a second chassis, or lower chassis, 400, referring to those internal components situated below the cartridge 500. Cartridge 500 may be a microfluidic cartridge, meaning that at least a portion of any fluid passages, channels, chambers, wells, reaction chambers, etc. within which fluid flows and/or is retained is geometrically constrained to a small scale (for example, sub-millimeter) at which surface forces acting on the fluids meet or exceed volumetric forces. Upper chassis 300 may include a syringe driver 360 configured to actuate a syringe plunger coupled to a syringe stopper within the cartridge 500, as will be described below.

### Fluidic Cartridge

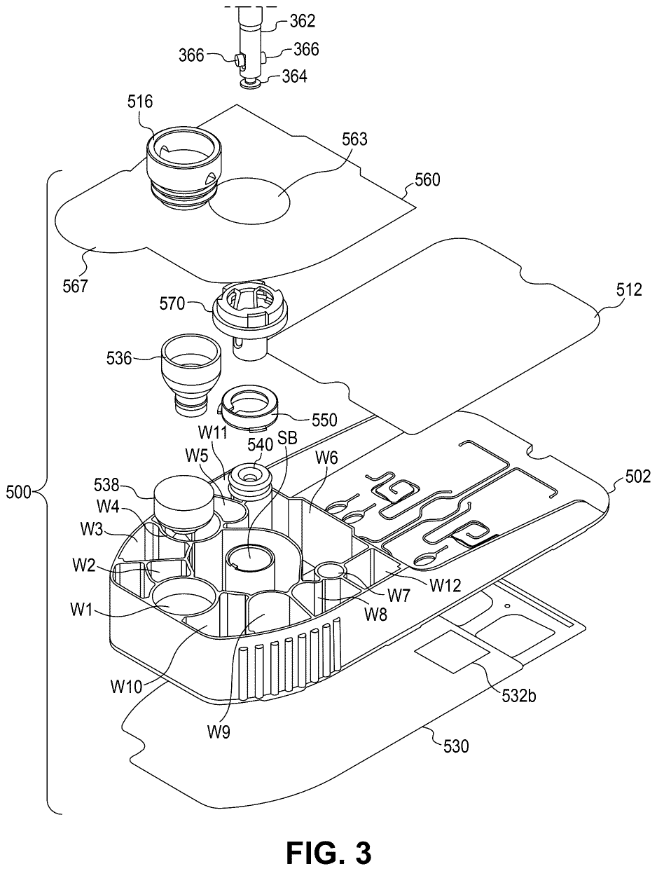

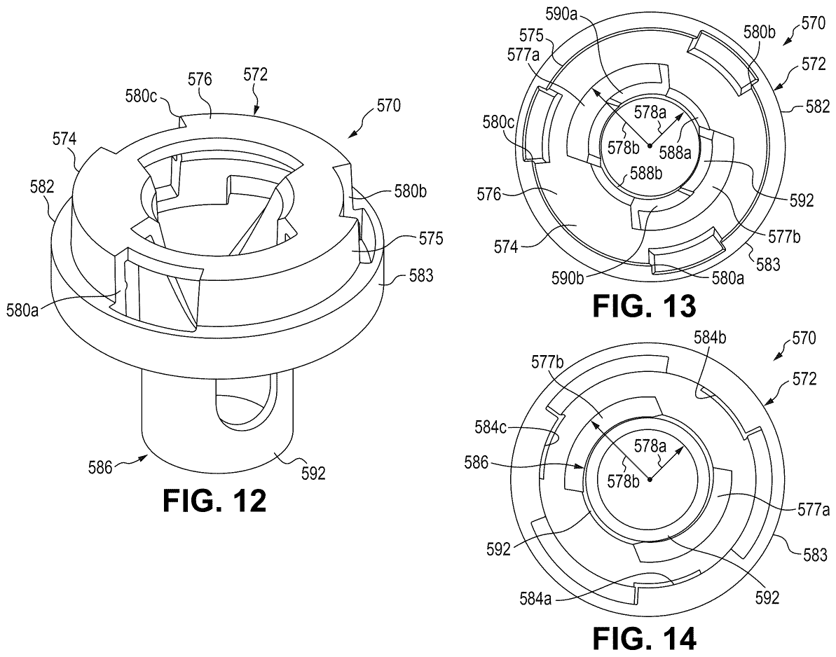

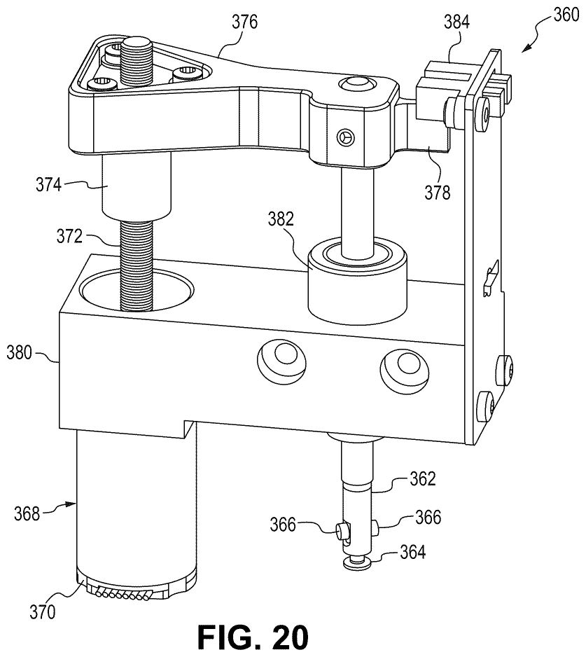

An embodiment of a fluidic cartridge 500 and components thereof are shown in FIGS. 3 to 19. FIG. 3 shows an exploded, top perspective view of fluidic cartridge 500. Cartridge 500 includes a cartridge body 502, a first (e.g., top) film 512, a second (e.g., bottom) film 530, an elastomeric stopper 540, a blocker ring 550, a blocker 570, a sample filter 538, a purification column insert 536 that positions and holds a purification column (e.g., a silica column), which may be in the form of a disc, a cap 516, and a protective venting cover 560. For convenience and consistent with the examples shown in the drawings, film 512 will be referred to herein as the top film and film 530 will be referred to herein as the bottom film. A plunger 362 coupled to syringe driver 360 of the instrument 10 (see FIG. 20, described below) includes a plunger head 364 that is received within a recess formed in the stopper 540 and plunger ribs 366 that engage the blocker 570 as described below. Cartridge body 502 of the fluidic cartridge 500 includes (i) a plurality of chambers, or functional wells, W1 to W12 and SB, containing or configured to receive materials (e.g., sample material, reagents, buffers, etc.) used in performing an assay (e.g., a molecular assay), within the cartridge, (ii) chambers, or functional wells, within which two or more materials may be combined and mixed, (iii) chambers, or functional wells, for receiving and holding waste material, and (iv) reaction/detection chambers 510a1, 510a2, 510b1, 510b2 (i.e., detection regions) within which reactions may take place and/or from which detectable signals emitted by a reaction within the chamber are detected. In the context of the present disclosure, although the terms “well” and “chamber” may be used interchangeably in some descriptions, in general, the term “well” refers, but is not limited, to an open-ended reservoir or depression formed in the cartridge body 502, such as wells W1 to W12 and SB, and the term “chamber” refers, but is not limited, to a well of the cartridge body 502 that is at least partially enclosed, e.g., by first film 512, second film 530, and/or cover 560, to form an at least partially enclosed compartment or space. More than one of the functions of containing, combining, reacting, and detecting may occur within one or more functional chambers of the cartridge 500. As described below, functional chambers within the cartridge may be fluidly interconnected by fluid channels, or conduits, and the cartridge includes one or more fluid flow control valves, which may be selectively acted upon, e.g., by valve actuators of instrument 10, to controllably permit or prevent fluid flow within a fluid channel with which the valve is operatively associated. The illustrated example has four reaction/detection chambers 510a1, 510a2, 510b1, 510b2, arranged in two pairs (or sets or groups) 510a1, 510a2 and 510b1, 510b2. In other examples, the cartridge has fewer than or more than four reaction/detection chambers. For example, a cartridge may have one or more groups or sets of three clustered reaction/detection chambers.

Cartridge body 502 has a first (e.g., top) face 501 and a second (e.g., bottom) face 503. For convenience and consistent with the examples shown in the drawings, face 501 will be referred to herein as the top face and face 503 will be referred to herein as the bottom face. Cartridge body 502 may be made by injection molding of a thermoplastic polymer material, such as, the cyclic olefin copolymers (COC) or the cyclic olefin polymers (COP), including polycarbonate, polyacrylamide, polyethylene, polymethyl-methacrylate (PMMA), polydimethylsiloxane (PDMS), and polyvinyl chloride (PVC) and is preferably made of polypropylene (PP). In some embodiments, the cartridge body 502 is made by stereolithography or by sintering. Cartridge body 502 may be made from an opaque material.

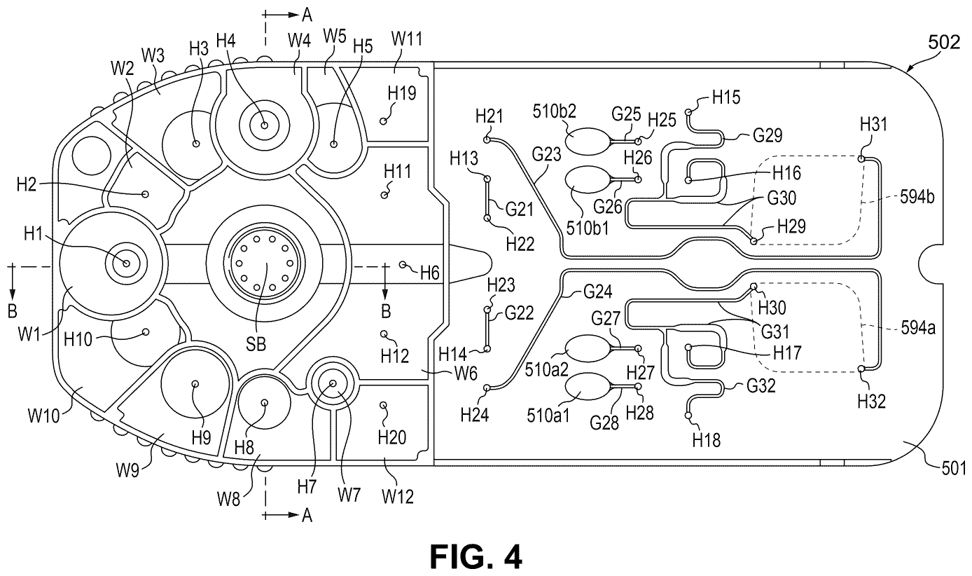

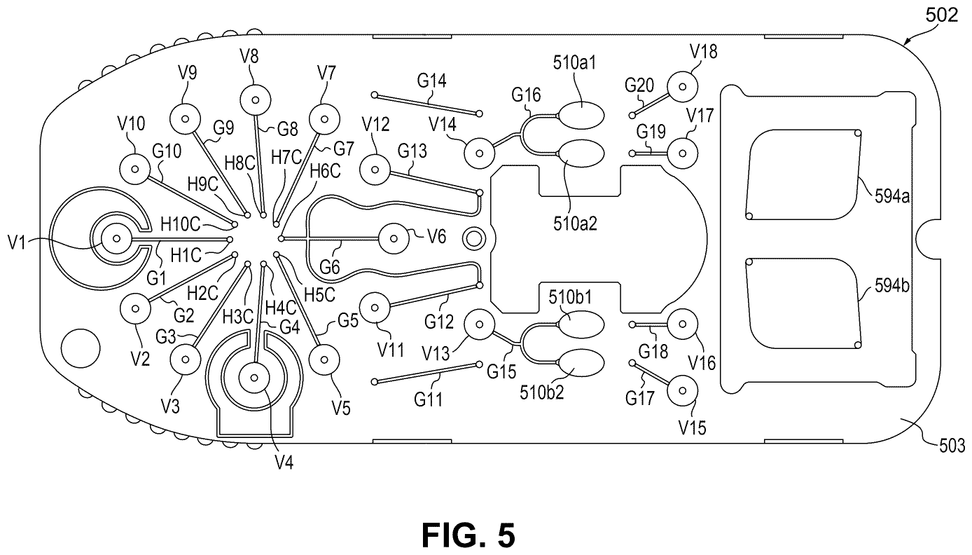

As shown in FIG. 4—a top plan view of cartridge body 502—and FIG. 5—a bottom plan view of cartridge body 502 —, cartridge body 502 includes a plurality of through-holes H1 to H32 extending between the top face 501 and the bottom face 503 to fluidically connect elements from either face to the other. Cartridge body 502 includes a plurality of bottom grooves G1 to G20 formed in the bottom face 503 and a plurality of top grooves G21 to G32 formed in the top face 501. Each of grooves G1 to G32 may have a depth of between 0.01 mm and 0.5 mm, preferably between 0.2 mm and 0.4 mm, most preferably about 0.3 mm, and may have a width of about 0.5 mm. Each of through-holes H1 to H18 is associated with a corresponding valve V1 to V18, comprising a cylindrical recess formed in the bottom face 503 of the cartridge body 502 and which is generally coaxially arranged with respect to the associated through-hole and has a diameter that is larger than the associated through-hole. In one example, the recess associated with each of valves V1 to V18 may have a diameter of between 1 mm and 10 mm, preferably between 2 mm and 8 mm, preferably about 4 mm, and a depth of between 0.02 mm and 0.4 mm, preferably between 0.05 mm and 0.15 mm, and most preferably about 0.1 mm. One or two of the grooves G1 to G32 terminates at an associated valve V1 to V18. Through-holes H1 to H10 are also associated with chambers W1 to W10, through-holes H11 and H12 are associated with chamber W6, through-hole H19 is associated with chamber W11, and through-hole H20 is associated with chamber W12. Through-holes H21 to H32 are not directly associated with either a valve or a chamber and provide connections between a groove or other feature on the top face 501 and a groove or other feature on the bottom face 503. Cartridge body 502 also includes central through-holes H1c to H10c arranged in a circle within well SB (syringe barrel).

The through-holes H1 to H32 and H1c to H10c, valves V1 to V18 and associated recesses, and the bottom grooves G1 to G21 and top grooves G22 to G32 formed in the cartridge body 502 form a fluidic network of channels and the fluid control valves in these channels. For that purpose, it is necessary to close the through-holes, recesses, and grooves that are open to the top face 501 or the bottom face 503 of the cartridge body 502. Bottom film 530 is secured to the bottom face 503 of the cartridge body 502 to cover bottom grooves G1 to G20 to form corresponding channels (which may be microfluidic channels), the recesses of valves V1 to V18 to form the corresponding valves, central through-holes H1c to H10c, and through-holes H19 to H32 flush with the bottom face 503. Bottom film 530 may comprise a material similar to the cartridge body 502 including, for example, polypropylene (PP). Bottom film 530 may comprise a thermoplastic film with a thickness between 0.1 mm and 0.2 mm (100 μm-200 μm), which is bonded or welded to the surface of the bottom face 503 by a thermal welding technique (e.g., by laser welding), bonding, adhesive, or chemical linking methods.

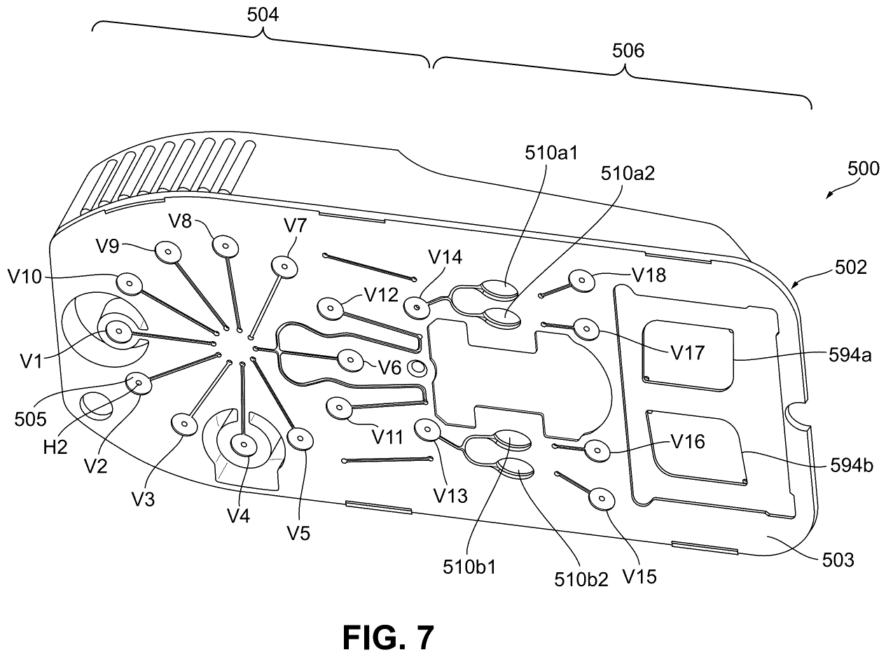

Valves V1 to V18 are formed by the bottom film 530, which may be deformable, extending across each recess opposite an annular valve seat defined between the recess of each valve V1 to V18, and the associated through-hole H1 to H18, respectively, of the valve. A single valve seat 505 between the recess of valve V2 and associated through hole H2 is labeled in FIG. 7. In one example, the surface of the deformable bottom film 530, positioned opposite the recesses of valves V1 to V18 is, when un-deformed, approximately planar and parallel to the bottom face 503 of the cartridge body 502 and spaced apart from the valve seat between the recess and the through-hole and is capable of being deformed by an external actuator locally pushing the film into the recess. The deformation of the bottom film 530 into contact with each valve seat of valves V1 to V18 blocks the associated through-holes H1 to H18, whose diameter is smaller than that of each associated recess so that the film contacts the valve seat and seals the associated through-hole.

Top film 512 may be secured to top face 501 of the cartridge body 502, e.g., by thermo-welding, adhesive, or chemical linking methods, to close the top grooves G21 to G32 flush with the top face 501 to form corresponding channels (which may be microfluidic channels) in the same way bottom film 530 closes bottom grooves G1 to G20 to form corresponding channels. Top film 512 may be made of a material similar to the cartridge body 502, e.g., polypropylene, and may have a thickness of about 0.1 mm.

Cartridge 500 may include processing regions 594a, 594b (see FIGS. 4, 5, 7). In one example, each of processing regions 594a, 594b comprises a micro-array slide (or biochip) bonded on the bottom face 503 of the cartridge body 502 within a recessed cavity that, when covered, e.g., by bottom film 530, forms a detection chamber for nucleic acid analysis. Instrument 10 may include means for optical excitation of the micro-array slide (not shown) and means for optical detection of a micro-array image (not shown) that is representative of an analyte of interest (e.g., a nucleic acid) of the sample being analyzed in the cartridge. See, e.g., U.S. Pat. No. 10,654,039 for further descriptions of a micro-array slide.

Referring to FIGS. 4 and 5, bottom grooves G1 to G10 extend between central through-holes H1c to H10c, respectively, and a recess associated with each of valves V1 to V10, respectively, each of the valves V1 to V10 being associated with a through-hole H1 to H10, respectively. Each of through-holes H1 to H10, associated with valves V1 to V10, respectively, connects chambers W1 to W10, respectively, to bottom grooves G1 to G10, respectively. In this context, reference to connections to or by the top or bottom grooves means connections to or by the corresponding channels formed by each groove when covered, such as by top film 512 or bottom film 530. Through-hole H11, associated with valve V11, connects chamber W6 to bottom groove G12. Through-hole H12, associated with valve V12, connects chamber W6 to bottom groove G13. Through-hole H13, associated with valve 13, connects bottom groove G15, which is connected to chambers 510b1 and 510b2, to top groove G21. Through-hole H14, associated with valve V14, connects bottom groove G16, which is connected to chambers 510a1 and 510a2, to top groove G22. Through-hole H15, associated with valve V15, connects bottom groove G17 to top groove G29, which merges with top groove G30. Through-hole H16, associated with valve V16, connects bottom groove G18 to top groove G30. Through-hole H17, associated with valve V17, connects bottom groove G19 to top groove G31. Through-hole H18, associated with valve V18, connects bottom groove G20 to top groove G32, which merges with top groove G31. Through-hole H19 connects bottom groove G11 to chamber W11. Through-hole H20 connects bottom groove G14 to chamber W12. Through-hole H21 connects bottom groove G11 to top groove G23. Through-hole H22 connects bottom groove G12 to top groove G21. Through-hole H23 connects bottom groove G13 to top groove G22. Through-hole H24 connects bottom groove G14 to top groove G24. Through-hole H25 connects bottom groove G17 to top groove G25, which is connected to chamber 510b2. Through-hole H26 connects bottom groove G18 to top groove G26, which is connected to chamber 510b1. Through-hole H27 connects bottom groove G19 to top groove G27, which is connected to chamber 510a2. Through-hole H28 connects bottom groove G20 to top groove G28, which is connected to chamber 510a1. Through-hole H29 connects top groove G30 to processing region 594b of the cartridge. Through-hole H31 connects processing region 594b to top groove G23, which is connected, via through-hole H21, to bottom groove G11, which is connected, via through-hole H19, to chamber W11 (e.g., a waste chamber). Through-hole H30 connects top groove G31 to processing region 594a of the cartridge. Through-hole H32 connects processing region 594a to top groove G24, which is connected, via through-hole H24, to bottom groove G14, which is connected, via through-hole H20, to chamber W12 (e.g., a waste chamber). Thus, when valve V8 is open, reaction chamber 510a1 is connected, via grooves G28, G20, G32, and G 31, to processing region 594a. When valve V17 is open reaction chamber 510a2 is connected, via grooves G27, G19, and G31, to processing region 594a. When valve V15 is open, reaction chamber 510b2 is connected, via channels G25, G17, G29, and G30, to processing region 594b. When valve V16 is open, reaction chamber 510b1 is connected, via channels G26, G18, and G30, to processing region 594b.

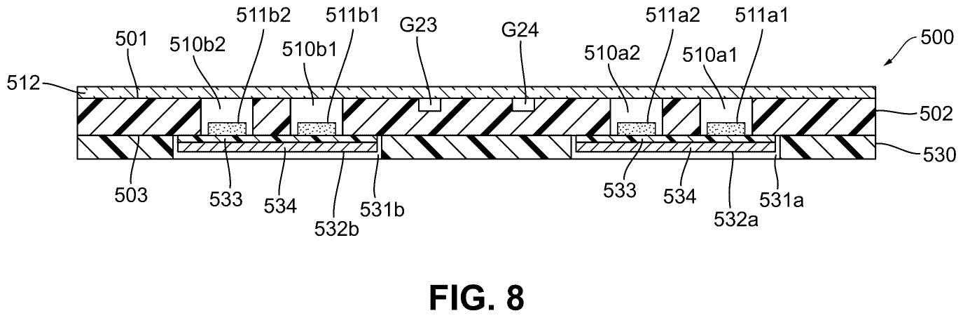

As shown in FIG. 8, which is a schematic, transverse cross-section of the cartridge 500, chambers 510a1, 510a2, 510b1, and 510b2 are defined by openings formed in the cartridge body 502 which extend between the top face 501 and bottom face 503 and which are enclosed by the bottom film 530 and the top film 512. Reaction/detection chambers 510a1, 510a2, 510b1, 510b2 receive reaction mixtures prepared from the contents of one or more of chambers W1 to W10, the reaction mixtures are exposed to heat (e.g., isothermal or thermocyclic profiles) within the chambers 510a1, 510a2, 510b1, 510b2 by contacting a top portion of the cartridge 500 in the vicinity of chambers 510a1, 510a2, 510b1, 510b2 with a top heater and contacting a bottom portion of the cartridge 500 in the vicinity of chambers 510a1, 510a2, 510b1, 510b2 with a bottom heater, and a reaction (e.g., an amplification reaction) occurs within the chambers 510a1, 510a2, 510b1, 510b2. The reaction mixtures within chambers 510a1, 510a2, 510b1, 510b2 may include detectable probes that, upon hybridization to a molecule of interest, emit detectable optical signals during a reaction, e.g., a fluorescent signal of a certain emission wavelength when exited by light of a certain excitation wavelength, for which purpose at least one wall of the chambers 510a1, 510a2, 510b1, 510b2 may be transparent or translucent. For example, where the cartridge body 502 is made from an opaque material, top film 512 may be transparent or translucent, or at least a portion of top film 512 covering chambers 510a1, 510a2, 510b1, 510b2 may be transparent or translucent, to permit an excitation signal to be delivered to the chambers from above the chambers and to permit an emission signal to be detected from above the chambers.

To promote even heat distribution over the chambers 510a1, 510a2, 510b1, 510b2, bottom film 530 may comprise a layer of thermally-conductive material, such as metallic foil (e.g., aluminum), disposed over the bottom face 503 of the cartridge body 502, at least in the vicinity of the chambers 510a1, 510a2 and in the vicinity of chambers 510b1, 510b2. As shown in FIG. 8, lower film 530 may have cutouts 531a, 531b over chambers 510a1, 510a2 and chambers 510b1, 510b2, respectively. A thermally-conductive laminate seal 532a is disposed within cutout 531a and affixed to cartridge body 502 over chambers 510a1, 510a2, and a thermally-conductive laminate seal 532b is disposed within cutout 531b and affixed to cartridge body 502 over chambers 510b1, 510b2. The cutout 531a, 531b and associated thermally-conductive laminate seal 532a, 532b may be rectangular, as shown in FIG. 3, circular, oval-shaped, or any desired shape. Where the reaction/detection chambers are arranged as spatially separated groups of chambers (wherein a “group” may include one or more chambers), a discrete thermally-conductive laminate seal may be provided to cover each group. For example, as the chambers 510a1, 510a2 and 510b1, 510b2 of fluidic cartridge 500 are arranged as spatially-separated groups (e.g., pairs), two separate thermally-conductive laminate seals are provided: laminate seal 532a for covering the group 510a1, 510a2 and laminate seal 532b for covering group 510b1, 510b2.

In one example, each thermally-conductive laminate seal 532a, 532b comprises a plastic layer 533 (e.g., polypropylene) to which a conductive foil layer 534 is laminated. Suitable, commercially-available products include Thermo-Fisher AB 3599, available from Thermo-Fisher Scientific of Waltham, Massachusetts. Conductive foil layer 534 may also be optically reflective (e.g., aluminum or metallized PET film). The plastic layer 533 and conductive foil layer 534 may be secured together by a suitable adhesive or other means suitable for securing plastic to foil. In one example, the conductive foil layer 534 has a thickness of 60 μm to 80 μm, and the plastic layer 533 has a thickness of 10 μm to 20 μm for a total thickness of each thermally-conductive laminate seal 532a, 532b of 70 μm to 100 μm. As noted herein, the bottom film 530 may have a thickness of about 0.1-0.2 mm (100 μm-200 μm). In another example, each thermally-conductive laminate seal 532a, 532b includes a second plastic layer (now shown) affixed to an opposite side of the conductive foil layer 534.

Each thermally-conductive laminate seal 532a, 532b is affixed to the cartridge body 502 by heat sealing, ultrasonic welding, adhesive, or other suitable method for bonding the plastic layer 533 of each thermally-conductive laminate seal 532a, 532b to the cartridge body 502 to prevent fluid leakage from the chambers 510a1, 510a2, 510b1, 510b2. In this regard, for heat sealing or ultrasonic welding, cartridge body 502 may include energy directors to facilitate the heat sealing or ultrasonic welding process. Energy directors are components or features in heat sealing applications that help focus and control the flow of energy (heat or vibrations) to the area where the seal is being created. Examples of energy directors include raised features (e.g., a rib) adjacent to or surrounding each of the chambers 510a1, 510a2, 510b1, 510b2 to form a narrow edge (e.g., a dome-shaped cross-section or a knife-edge (triangular) cross-section) that will focus energy at the edge and facilitate localized material melting at the edge to promote sealing to the laminate seals 532a, 532b. The conductive laminate seals 532a, 532b are heat sealed by melting and fusing the energy directors around the chambers 510a1, 510a2, 510b1, 510b2 with the plastic layer 533 of each of the laminate seals 532a, 532b.

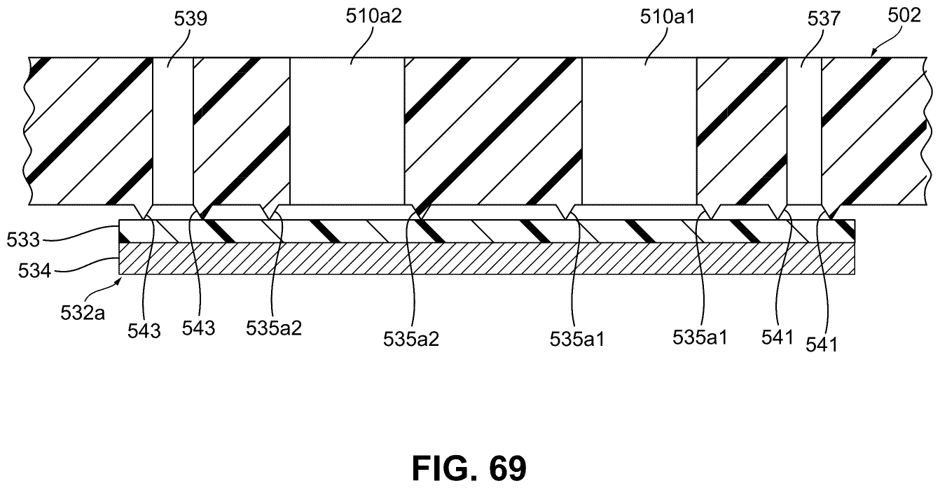

FIG. 69 is a partial transverse cross-section across the cartridge body 502 through the reaction chambers 510a1, 510a2 and thermally-conductive laminate seal 532a with top film 512 and bottom film 530 omitted from the figure. FIG. 69 shows an example of energy directors in the form of a knife-edge (triangular) rib 535a1 surrounding reaction chamber 510a1 and a knife-edge (triangular) rib 535a2 surrounding reaction chamber 510a2. In one example, energy directors 535a1 and 535a2 have a base width of about 0.3 mm and a peak height of about 0.26 mm. Similar energy directors (not shown) may surround reaction chambers 510b1 and 510b2. Energy directors 535a1 and 535a2 are not necessarily shown to scale in FIG. 69 and are shown in their pointed state before being melted and fused with plastic layer 533 of thermally-conductive laminate seal 532a during the heat sealing process.

In one example, the heat sealing temperature is about 165° C.-180° C. The lower end of this temperature range is fixed by the melting temperature of the plastic layer 533 (e.g., the melting temperature of polypropylene), but the higher end of this temperature range may be higher than 180° C. In an example, the sealing pressure is about 30-50 psi or greater. The sealing time is about 1.0-1.2 seconds, but may be as long as 5.0-10.0 seconds.

The cartridge body 502 may include quality control features for ensuring that the laminate seals 532a, 532b have been properly heat sealed to the body 502—e.g., for ensuring that the energy directors 535a1 and 535a2 have melted and fused with plastic layer 533 of thermally-conductive laminate seal 532a during the heat sealing process. As shown in FIG. 69, such quality control features may include one or more inspection holes 537, 539 extending through the cartridge body 502 adjacent to the chambers 510a1, 510a2 and within the surface areas that will be covered by the laminate seal 532a. In one example, inspection holes 537, 539 have a diameter of about 0.6 mm. Similar inspection holes (not shown) extending through the cartridge body 502 may be provided adjacent to the chambers 510b1, 510b2 and within the surface areas that will be covered by the laminate seal 532b. Each inspection hole is at least partially surrounded by energy directors that will melt when the laminate seals 532a, 532b are heat sealed to the cartridge body 502. Inspection hole 537 is surrounded by energy director 541, and inspection hole 539 is surrounded by energy director 543. Energy directors 541 and 543 are not necessarily shown to scale in FIG. 69 and are shown in their pointed state before being melted and fused with plastic layer 533 of thermally-conductive laminate seal 532a and before the energy directors melt into the inspection holes 537, 539 during the heat sealing process.

If the heat sealing is done properly, the energy director surrounding the inspection hole will melt and flow into the inspection hole, thereby closing the inspection hole (in whole or in part). If the heat sealing is done incorrectly so that the energy director surrounding the inspection hole does not fully melt and flow into the inspection hole, the inspection hole will remain open or substantially open, i.e., not closed, substantially closed, or at least partially closed. If the energy directors 541 and 543 surrounding inspection holes 537 and 539, respectively, fill, substantially fill, or at least partially fill the holes after the heat sealing process, it can be inferred that the energy directors 535a1, 535a2 surrounding reaction chambers 510a1, 510a2 have also properly melted and fused with plastic layer 533. The extent of closure of the inspection hole required to be deemed a successful fusion can vary according to application requirements. Conversely, if the energy directors 541 and 543 surrounding inspection holes 537 and 539, respectively, do not fill, substantially fill, or at least partially fill one or more of the holes after the heat sealing process, it can be inferred that the energy directors 535a1, 535a2 surrounding reaction chambers 510a1, 510a2 may not have properly melted and fused with plastic layer 533. Thus, whether the heat sealing was done properly can be determined by examining—e.g., with a machine vision device—whether each inspection hole is open or closed after heat sealing process. If the inspection hole is covered by the melted energy directors, it will appear black during the visual inspection, and if the inspection hole is not fully covered, it will appear grey or silver (i.e., the color of the conductive foil layer 534, which may be aluminum).

Energy directors 541 and 543 surrounding inspection holes 537 and 539, respectively, may be the same size and shape as the energy directors 535a1, 535a2 surrounding reaction chambers 510a1, 510a2, respectively, or may have a different size and/or shape. If the inspection hole energy directors have the same dimensions as the reaction chamber energy directors, both energy directors can be presumed to react similarly to the heat sealing conditions. The preferred size of the energy directors may be related to the size of the inspection hole—i.e., the larger the inspection hole, the larger the energy directors to ensure that the melted and fused energy directors cover the inspection hole (in whole or in part). Such energy director features can be molded into the cartridge body 502 as shown in FIG. 69.

The methods and techniques described above for affixing the laminate seals 532a, 532b to cartridge body 502 are not limited in their applications to seals having a thermally conductive layer, but may be used for affixing any type of plastic film or laminate having a plastic layer to a plastic body, such as cartridge body 502.

The conductive foil layer 534 of each thermally-conductive laminate seal 532a, 532b, being an effective thermal conductor, combined with a relatively thin plastic layer such as polypropylene, which acts as an insulator, facilitates rapid conductive thermal transfer from a heater disposed beneath the chambers 510a1, 510a2, 510b1, 510b2, thereby rapidly heating the chambers by the heater disposed beneath the chambers, and promotes even heat distribution to minimize thermal gradients across the chambers 510a1, 510a2, 510b1, 510b2.

In some examples, conductive foil layer 534 may improve the strength and accuracy of optical emission signal detection from the chambers 510a1, 510a2, 510b1, 510b2. The conductive foil layer 534 of each thermally-conductive laminate seal 532a, 532b may provide a reflective surface that increases optical emission signal strength. An optical excitation signal introduced from above each of the chambers 510a1, 510a2, 510b1, 510b2 passes through reaction mixtures within the chambers and excites probe-associated labels. Then, as the optical excitation signal is reflected off the conductive foil layer 534 at the bottom of each chamber, the reflected excitation signal again passes through reaction mixtures within the chambers, once again exciting probe-associated labels. Moreover, optical emission signal collected from above the chambers 510a1, 510a2, 510b1, 510b2 will be strengthened as both optical signal emitted directly toward the top of each chamber as chamber as optical signal emitted toward the bottom of each chamber and reflected toward the top of the chamber by the conductive foil layer 534 at the bottom of the chamber can be collected.

Furthermore, the laminate seals may increase the accuracy of emission signals collected from the chambers 510a1, 510a2, 510b1, 510b2. A relatively thick layer of transparent or translucent film (e.g., such as the thickness 100 μm to 200 μm of the bottom film 530) directly covering the chambers 510a1, 510a2, 510b1, 510b2 may act as an optical transmitter (i.e., a light pipe) that can transmit optical signals laterally from one chamber to an adjacent chamber (e.g., between chamber 510a1 and chamber 510a2 and between chamber 510b1 and chamber 510b2). Such inter-chamber optical transmissions are reduced or eliminated by thermally-conductive laminate seal 532a, 532b having a plastic layer 533 that may be as thin as 10 μm to 20 μm directly covering the chambers 510a1, 510a2, 510b1, 510b2. In addition, a metallic foil such as aluminum foil is impermeable to water, thereby preventing vapor transmissions to or from the chambers 510a1, 510a2, 510b1, 510b2 to enhance the stability of dry (dehydrated or lyophilized) reagents stored in the chambers.

Reagent(s) required for performing specified reactions within the reaction chambers 510a1, 510a2, 510b1, 510b2 may be pre-applied in a wet form and then dried to a surface of the laminate seal 532a, 532b facing the interior of the chambers, i.e., on an outer surface of the plastic layer 533 of the laminate seal 532a, 532b. Such reagent(s), which may comprise dehydrated or lyophilized components for performing PCR (e.g., Taq DNA polymerase, dNTPs, buffer, MgCl2, and, optionally, primers and/or probes) are applied in a wet form to the plastic layer 533 and then dried in place before or after the laminate seal 532a, 532b is sealed to the cartridge body 502 over the chambers 510a1, 510a2, 510b1, 510b2 to form a dried reagent “spot.” FIG. 8 shows reagent spots 511a1, 511a2, 511b1, 511b2 within reaction chambers 510a1, 510a2, 510b1, 510b2, respectively. Reagent spots 511a1, 511a2, 511b1, 511b2 are not necessarily drawn to scale in FIG. 8 and are shown with their thicknesses exaggerated for visibility. Each of reagent spots 511a1, 511a2, 511b1, 511b2 may be the same reagent or combination of reagents, or one or more of the reagent spots may be different reagents or combinations of reagents than the other reagent spots.

To facilitate the process of applying, and then drying, the reagent spot onto the surface of the plastic layer 533, referred to as “spotting,” the surface of plastic layer 533 may be treated to increase the hydrophilicity, or wettability, of the surface. To avoid wasting reagents and to ensure that the reagents are exposed to the reaction mixtures introduced to the reaction chambers 510a1, 510a2, 510b1, 510b2, it is preferred that reagent be spotted onto only portions of the plastic layer 533 that will be aligned with the chambers 510a1, 510a2, 510b1, 510b2. Accordingly, treatment of the surface that increases the hydrophilicity of the surface may be limited to one or more portions of the surface at which reagent spotting is desired, i.e., in alignment with the positions of chambers 510a1, 510a2, 510b1, 510b2, rather than to the entire surface.

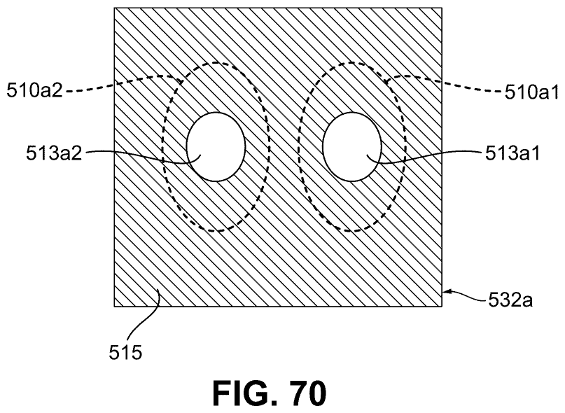

In one example, the outer surface of the plastic layer 533 is masked with a plastic tape having openings corresponding to the desired reagent spot locations in the chambers 510a1, 510a2, 510b1, 510b2. This is illustrated in FIG. 70, showing laminate seal 532a with a mask 515 (shown as cross-hatched) on the plastic layer having openings 513a1, 513a2. In the example shown in FIG. 70, openings 513a1, 513a2 are smaller than chambers 510a1, 510a2, the outlines of which are superimposed in dashed lines over the mask 515. In one example, suitable mask material is a polyester film having a typical thickness of 50±2 μm (measured according to the ASTM D-3652 test method) with an acrylic adhesive having a typical thickness of 7±2 μm (measured according to the ASTM D-3652 test method) with an adhesion to stainless steel value of 6-12 g/inch (measured according to the ASTM D-3330-1800 peel test method). Suitable materials are available from M&C Specialties, Southampton, Pennsylvania.

Alternative mask materials include materials that act as an electrical insulator, including various types of plastic, rubber, ceramic, or glass. Suitable adhesives have low adhesion so that they can be easily peeled from the surface of the plastic layer 533 and should not leave a residue on the surface after the mask is removed. A preferred characteristic of the mask is that it adhere to the surface with minimal air gap. The inventors have employed masks having a thickness of about 50 μm, although it is expected that thicker masks may work as well or better.

Next, the surface is subjected to a corona treatment whereby only the exposed areas of the outer surface of plastic layer 533 exposed by openings 513a1, 513a2 in the mask 515 are treated with the corona discharge, altering the exposed surface to increase hydrophilicity of the surface, while the masked areas of the outer surface 533 covered by mask 515 are left untreated by the corona discharge and remain relatively hydrophobic.

An example of a corona discharge device the inventors have used is the BD-20AC Laboratory Corona Treater, available from Electro-Technic Products of Chicago, Illinois. Another example of a corona discharge treatment device for integrating into a production, in-line converter is the Labeltec available from Tantec A/S of Denmark. An example of a corona treatment device setup is to position the corona treatment head of the treatment device at a specific height above the surface to be treated with the head set at its maximum power setting (e.g., 30 W). The height ranges from 3 mm to 30 mm and is related to the shape of the corona treatment head. In general, the higher the position of the corona treatment head, the longer the treatment time required to reach a certain level of hydrophilicity. A preferred distance between the corona treatment head and the surface to be treated with the device set at maximum power is 5˜20 mm.

The corona discharge treatment creates hydrophilic zones roughly corresponding in size and shape to the openings 513a1, 513a2 of mask 515, where each zone has an invisible hydrophobic boundary, thereby enhancing the precision of spotting the reagent. After the corona discharge treatment, the mask 515 is removed, and wet reagent, typically in microliter (μl) volumes, is applied to the plastic layer 533 and preferentially adheres to the hydrophilic zones corresponding to the openings 513a1, 513a2, thus enhancing the precision of reagent placement. The wet reagent spreads over a larger area on the hydrophilic surface as compared to a non-treated, relatively hydrophobic surface, resulting in faster drying during manufacturing and better adhesion of the dried reagent spots 511a1, 511a2, 511b1, 511b2 to the plastic layer 533. The drying time is highly dependent on spot volume, surface area, spot formulation, and drying techniques. Lower volume, larger surface area, less sugar in the spot, high temperature, and low humidity would reduce the drying time. Drying time may be as short as 1 to 2 minutes, preferably at temperatures below 40° C. Because the reagent is spread evenly across the hydrophilic zone, the resulting dried reagent will rehydrate more rapidly when exposed to liquid, such as an analyte containing eluate. The reagent spot for each of the reaction chambers 510a1, 510a2, 510b2, 510b2 is preferably a single spot roughly corresponding in size and shape to the openings 513a1, 513a2 of mask 515, but in some applications, it is possible the reagent spots may occupy multiple locations within one or more reaction chambers.

Dispensing volumes depend on the concentrations of reagents, and may range from 0.5 μl to 2.0 μl or more.

Wet reagent may be applied to the hydrophilic zones of the plastic layer 533 before or after each laminate seal 532a is affixed to the cartridge body 502.

Spotting reagent onto the plastic layer 533 after affixing the laminate seal 532a to the cartridge body 502 has the advantage of spotting directly into the region of interest without requiring other processes to ensure spotting accuracy beforehand that could compromise reagent performance or efficacy. A disadvantage of spotting reagent after affixing the laminate seal 532a to the cartridge body 502 is that if the reagent dispense is faulty, the entire cartridge must be discarded, which can be expensive and wasteful. Also, fitting dispense nozzles in the openings in the cartridge body 502 corresponding to reaction chambers 510a1, 510a2, 510b1, 510b2 can be difficult due to limited space within the cartridge.

Spotting reagent onto the plastic layer 533 before affixing the laminate seal 532a to the cartridge body 502 may allow spotting at a higher rate with fewer restrictions of fitting dispense nozzles in tight spaces. Faulty dispenses are less expensive since the individual laminate seals 532a can be discarded without having to discard the entire cartridge. A disadvantage of spotting reagent onto the plastic layer before affixing the laminate seal 532a to the cartridge body 502 is that the spotted laminate seal 532a may need to be held and stored in controlled conditions that do not degrade or compromise the performance of the reagent spots before it is affixed to the cartridge. Additionally, the laminate seals need to be physically handled, applied, and affixed to the cartridge, which could damage or degrade performance of the spotted reagent.

Suitable devices for applying reagents during the spotting process include the iONE microdispensing instrument available from M2-Automation GmbH of Berlin, Germany, or the iZERO production in-line microdispensing instrument available from M2-Automation GmbH of Berlin, Germany.

As previously explained and shown in FIG. 70, the openings 513a1, 513a2 may be made smaller than the reaction/detection chambers 510a1, 510a2, 510b1, 510b2 so that, as shown in FIG. 8, there may be a separation between sides of the reagent spots 511a1, 511a2, 511b1, 511b2 and the sides of the respective reaction chambers 510a1, 510a2, 510b1, 510b2. This will help ensure that reagent does not wick into the area between the bottom face 503 of the cartridge body 502 and the laminate seal 532a or 532b-either during the initial process of forming the spot, if the wet reagent is applied to the treated portion of plastic layer 533 after the laminate seal is bonded to the cartridge body 502, or during the reaction process when the dried reagent spot 511a1, 511a2, 511b1, 511b2 dissolves—so that all reagent is available for the reaction within the reaction chamber.

In another example, the surface of the plastic layer 533 may be treated with plasma to increase the hydrophilicity. Other treatments that may be effective to increase the hydrophilicity of the surface of the plastic layer are encompassed by this disclosure. Such treatments may include thermo-oxidative chemical treatment (treatment with a mixture of chromic, sulphuric, and phosphoric acids in a short time at elevated temperature), graft polymerization (surface activation followed by chemical grafting of hydrophilic chain), UV-ozone treatment causing the formation of oxidized material on the surface and which changes the surface morphology and wettability, deposition of SiOx on a polypropylene, and coating with surfactants. See, for example, Danu Ariono and Anita Kusuma Wardani, Modification and Applications of Hydrophilic Polypropylene Membrane, IOP Conference Series: Materials Science and Engineering; IOP Conf Series: Materials Science and Engineering 214 (2017) 012014 (https://iopscience.iop.org/article/10.1088/1757-899X/214/1/012014/pdf).

In another example in which the laminate seals 532a, 532b covering the reaction chambers 510a1, 510a2, 510b1, 510b2 are omitted, and the reaction chambers 510a1, 510a2, 510b1, 510b2 are covered by the bottom film 530, reagent spots 511a1, 511a2, 511b1, 511b2 (see FIG. 8) may be adhered to the surface of the bottom film 530 facing the bottom face 503 of the cartridge body 502 and the reaction chambers 510a1, 510a2, 510b1, 510b2 (for convenience, referred to as the top surface of the bottom film 530). In such an example, the top surface of the bottom film 530 may be treated to increase the relative hydrophilicity of the portion of the top surface to which reagents spots will be adhered. Such treatments may include any of the treatments described herein, including corona discharge and plasma treatment. For treatment by corona discharge or plasma treatment, the top surface of the bottom film 530 may be covered by a mask, such as mask 515 with openings 513a1, 513a2 shown in FIG. 70. When the masked film is treated by corona discharge or plasma, only the surface portions of the film exposed by the openings 513a1, 513a2 are contacted by the corona discharge or plasma so that the hydrophilicity of only those portions is increased.

All other descriptions herein regarding the composition, formation, size, etc. of the reagent spots 511a1, 511a2, 511b1, 511b2 on the surface of the plastic layer 533 of the conductive laminates 532a, 532b, materials used for forming masks, and corona discharge parameters are applicable to reagents spots adhered to the top surface of the bottom film 530.

In an alternative arrangement, if the surface of the laminate seal, bottom film, or other type of material enclosing the reaction chambers is already hydrophilic, it may be desirable to treat the surface to render portions of the surface hydrophobic so that spotted reagents will be attracted to only the hydrophilic portions of the surface. In this case, the surface may be covered with a mask that is the opposite of mask 515 described herein and shown in FIG. 70, i.e., a mask that covers only the portion(s) of the surface at which the reagent is to be spotted so that the covered portion(s) of the surface is not treated and remains hydrophilic, while the remainder of the surface is treated to change its surface structure from hydrophilic to hydrophobic. Processes for creating hydrophobic polymer surfaces are described by Fabio Palumbo, Chiara Lo Porto, and Pietro Favia; Plasma Nano-Texturing of Polymers for Wettability Control: Why, What and How; Coatings, 9, 640; 3 Oct. 2019; (https://www.mdpi.com/2079-6412/9/10/640).

When the laminate seals 532a, 532b are affixed to the cartridge body 502, a fixture may be used to ensure that the spotted reagents on the plastic layer 533 align with the reaction chambers 510a1, 510a2, 510b1, 510b2. The laminate seals 532a, 532b may be supported in the fixture, which may include alignment pins to align the cartridge body 502 with the laminate seals 532a, 532b. The laminate seals 532a, 532b may be carried on a backing liner including precise alignment features, such as alignment pins and mating alignment holes, which accurately holds laminate seals 532a, 532b in a known and controlled location on the fixture. With the laminate seals 532a, 532b and the cartridge body properly aligned, a heat sealing head is contacted with the laminate seals 532a, 532b to heat seal the laminate seals to the cartridge body as described herein.

The laminate seals 532a, 532b are separate from the bottom film 530—i.e., the laminate seals 532a, 532b are structurally and functionally isolated from the bottom film 530. Accordingly, different formulations and configurations of the bottom film 530 can be adopted, depending on specific operational, functional, and/or structural requirements for the bottom film, such as defining channels, without requiring a change in the laminate seals. In other examples, the bottom film covers a portion of a face of the cartridge that is spatially separated, or isolated, from the one or more reaction/detection chambers covered by one or more laminate seals, in which case cutouts formed in the bottom film are not necessary.

Functional chambers W1 to W12 and SB of the cartridge body 502 contain, or are configured to receive, during the use of the fluidic cartridge 500, at least one of a sample material, different reagent products, and a purification column, as well as fluids or solids intended for the preparation, amplification, and analysis of the sample. Other wells may serve as mixing chambers to temporarily hold two or more different materials combined therein or serve as waste chambers. Examples of the contents contained within and/or the functions of wells W1 to W12 and CW are set forth in Table 1 below:

TABLE 1

| Chamber | |
|---|---|
| (Functional | |
| Well) | Content/Function |
| W1 | Sample Chamber |
| W2 | Wash Buffer |
| W3 | Wash Buffer |
| W4 | Purification Column |
| W5 | PCR Mix 1 |
| W6 | Metering |
| W7 | PCR Mix 2 |
| W8 | Hybridization Buffer |
| W9 | Binding Buffer |
| W10 | Elution Buffer |
| W11 | Waste 1 |
| W12 | Waste 2 |
| SB | Syringe Barrel |

As explained above, chambers W1 to W5 and W7 to W10 include through-holes H1 to H5 and H7 to H10, respectively, formed through a bottom wall of the respective chamber, and functional chamber W6 includes three through-holes H6, H11, H12 formed through a bottom wall of the chamber. Syringe barrel SB includes central through-holes Hic, H2c, H3c, H4c, H5c, H6c, H7c, H8c, H9c, and H10c formed through a bottom wall of the barrel. Each of chambers W1-W10 is independently in fluidic communication with the central well SB via channels formed by grooves G1, G2, G3, G4, G5, G6, G7, G8, G9, and G10, respectively, controlled by the valves V1, V2, V3, V4, V5, V6, V7, V8, V9, and V10, respectively, and fluids can flow, in one direction or the other between these different functional chambers (i.e., from the chamber W1 to W10 to the syringe barrel SB or vice versa).

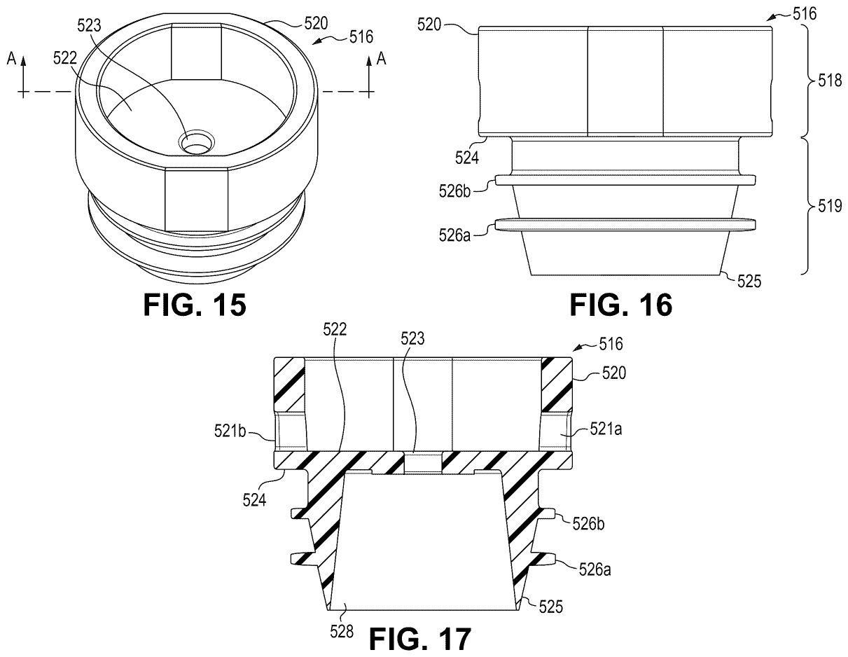

Details of an example of cap 516 are shown in FIGS. 15-17. Cap 516 includes an upper portion having a radial wall 522 with a peripheral wall 520 surrounding the radial wall 522 and extending in an axial direction. Cap 516 also includes a lower portion 519 defined by a peripheral wall 525 extending below the radial wall 522. The upper portion 518 of the cap 516 is wider than the lower portion 519, thereby defining a radial annular shoulder 524. Peripheral wall 525 is inserted into the sample chamber W1, for which purpose the wall 525 may be tapered, and the radial shoulder 524 contacts a top edge of the wall of the well W1. Lower portion 519 may also include radially-extending annular ribs 526a, 526b projecting from the outer surface of the peripheral wall 525. A vent hole 523 is formed in the radial wall 522, and side vent holes 521a, 521b are formed in the peripheral wall 520.

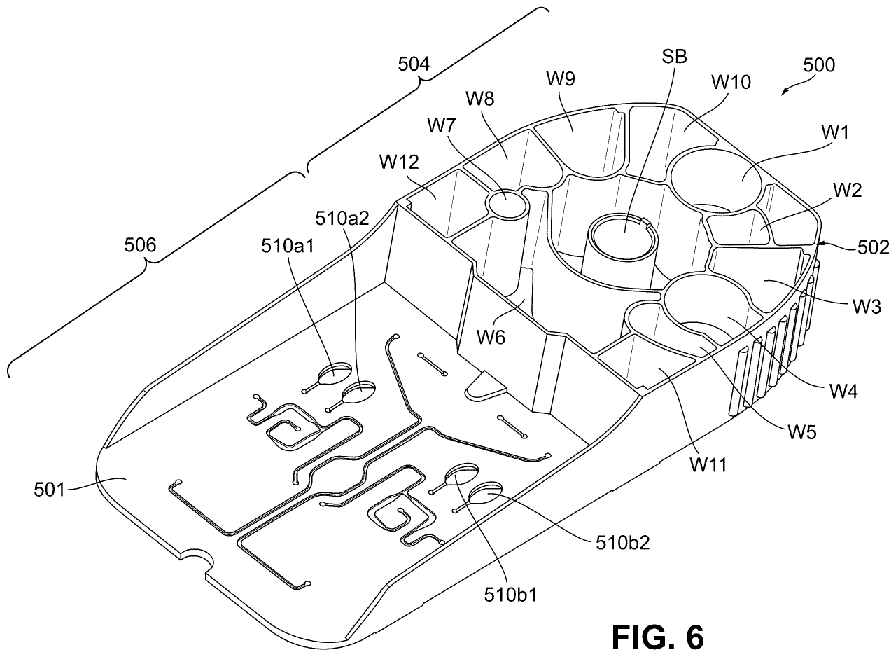

Cartridge 500 may comprise two functional sections. As shown in FIGS. 6 and 7, sample preparation section 504 of the cartridge 500 includes a number of chambers (e.g., chambers W1 to W12) that contain, or may receive during operations on the cartridge by instrument 10, various materials (which may include liquids or other fluids) used in preparing a sample for the performance of an assay or other procedure on the sample within the cartridge. Sample preparation section 504 is configured to receive a sample specimen in a sample chamber (e.g., chamber W1) (which may comprise or be connected to a fluid inlet port at which fluid sample is introduced to the sample chamber) and to process the sample using materials contained in one or more other chambers within the sample preparation section 504, for example, to isolate target molecules (e.g., lysis and purification of nucleic acids using silica based purification) from other components of the sample specimen and to combine the isolated molecules with materials used in the performance of an assay, such as amplification reagents and/or detection probes, to form a reaction mixture. Amplification reagents and/or detection probes may be provided in one or more of the chambers W2 to W10 of the sample preparation section 504 in a dry (e.g., lyophilized) form and reconstitution fluids for combining with and reconstituting the reagent or probe may be contained within one or more of chambers W2 to W10 of the sample preparation section 504. Valves V1-V10, controlling fluid flow to and from chambers W1—W10, respectively, and valves V11 and V12 controlling fluid flow to and from chamber W6, may be referred to as sample preparation (or process) valves, as they are located within and control fluid flow for chambers W1—W10 within the sample preparation section 504 of cartridge 500.

Referring to FIGS. 6 and 7, a reaction/detection section 506 of the cartridge 500 is configured to receive the processed sample (reaction mixture) from the sample preparation section 504 and to provide a platform at which one or more reactions take place, for example to amplify and detect target molecules (e.g., real-time PCR). Reaction/detection section 506 includes one or more reaction chamber(s) (e.g., reaction/detection chambers 510a1, 510a2, 510b1, 510b2), each of which defines an enclosure capable of containing a fluid substance and within which reactions may take place and from which detectable signals emitted during a reaction may be detected. The detectable signal may be an optical signal, such as fluorescence, and detection of the detectable signal may indicate the presence and/or amount of target molecules in a sample. Valves V13-V18, controlling fluid flow to and from reaction chambers 510a1, 510a2, 510b1, 510b2, may be referred to as reaction valves, as they are located within and control fluid flow for reaction chambers 510a1, 510a2, 510b1, 510b2 within the reaction/detection section 506 of cartridge 500.

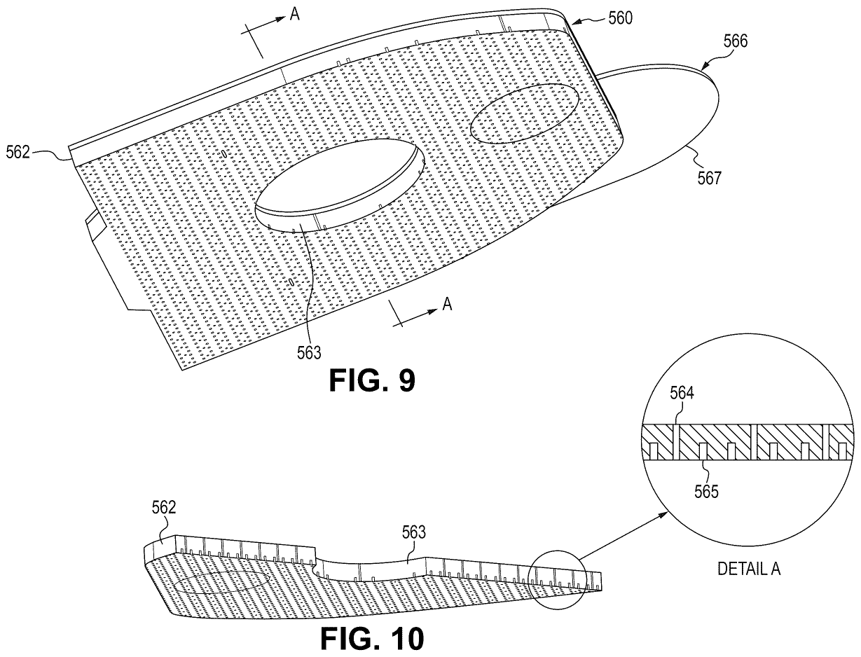

Referring to FIGS. 9 and 10, including Detail A, protective venting cover 560 includes two components: a venting membrane 562 that is hermetically sealed to the top of the cartridge body 502 to cover the chambers W1 to W12 of the sample preparation section 504 and a protective cover 566 heat laminated to a top surface of the venting membrane 562 and peelable from the venting membrane by a user prior to use of the cartridge. A plunger hole 563 formed in at least the venting membrane 562 (and optionally provided in the protective cover 566 as well) provides access to the syringe barrel SB by a syringe plunger.

As shown in FIG. 10 and detail A, venting membrane 562 is a porous plastic membrane with two sets of pores: through pores 564 and blind pores 565. The through pores 564 extend completely through the thickness of the venting membrane, and the blind pores 565 extend from a bottom surface of the venting membrane (the surface in contact with the cartridge body 502) partially through the thickness of the membrane. The venting membrane allows gas/vapor circulation via the through pores and contains liquid within the chambers W1 to W12 when the protective cover 566 is removed. The blind pores 565 enhance adhesion of the membrane 562 to the cartridge body 502 as the plastic of the cartridge body melts into the blind pores 565 when the membrane 562 is attached to the cartridge body 565.

In one example, protective cover 566 comprises a three-layer aluminum laminate: polyester (PET)/aluminum/polyethylene (PE), and is heat laminated to the top (exposed) surface of the venting membrane 562. The protective cover 566 may include a pull tab 567 extending beyond the venting membrane to allow the user to grasp and peel the cover from the membrane. The PE layer of the protective cover 566 melts during a heat lamination process and partly flows into the venting membrane through pores 564 to limit or prevent evaporation of the liquids stored in one or more of the chambers W1 to W12 of the cartridge 500 while the protective cover 566 is in place during manufacturing, storage, and transportation of the cartridge. When the protective cover 566 is peeled from the venting membrane 562 prior to use of the cartridge 500, the through pores 564 of the venting membrane 562 are freed from that PE, and all PE “hairs” which were clogging the through pores 564 are removed and remain attached to the aluminum laminate of the protective cover 566. In one embodiment, protective venting cover 560 does not cover chamber W1 (the sample chamber) and may have an opening formed at the location of chamber W1 so as to permit access to the sample chamber when the protective venting cover is attached to the cartridge.

Cartridge 500 includes a pump mechanism for moving fluids between the wells and chambers and through the grooves/channels and through-holes. In embodiment illustrated in FIG. 3, the pump mechanism comprises a syringe defined by the elastomeric stopper 540 disposed within the syringe barrel SB and actuated by the syringe plunger 362 of the instrument 10, as described below. Raising the stopper 540 within the syringe barrel SB creates a vacuum within the syringe barrel SB that pulls fluid through the channels G1 to G10 and the holes H1c to H10c and into the syringe barrel SB. Valves V1 to V10 can be actuated to control which of channel(s) G1 to G10 is(are) open to the syringe barrel SB. Typically, all but one valve V1 to V10 would be closed so that fluid is drawn into the syringe barrel SB through one of the channels G1 to G10 and holes H1c to H10c.

Lowering the stopper 540 within the syringe barrel SB creates pressure within the syringe barrel that pushes fluid from the syringe barrel SB through the holes H1c to H10c and channels G1 to G10. Again, valves V1 to V10 can be actuated to control which channel(s) is(are) open to the syringe barrel SB. Typically, all but one valve V1 to V10 would be closed so that fluid is pushed from the syringe barrel SB through one of the holes H1c to H10c and associated channels G1 to G10.

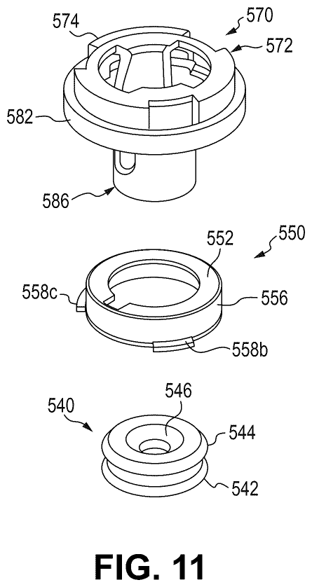

As seen in FIG. 11, stopper 540 is generally cylindrical and has a diameter that forms a sliding fit with a cylindrical wall 508 of the syringe barrel SB. Stopper 540 may include one or more peripheral rings (e.g., rings 542, 544) to promote a sealing contact between the stopper 540 and an inner surface of the cylindrical wall 508.

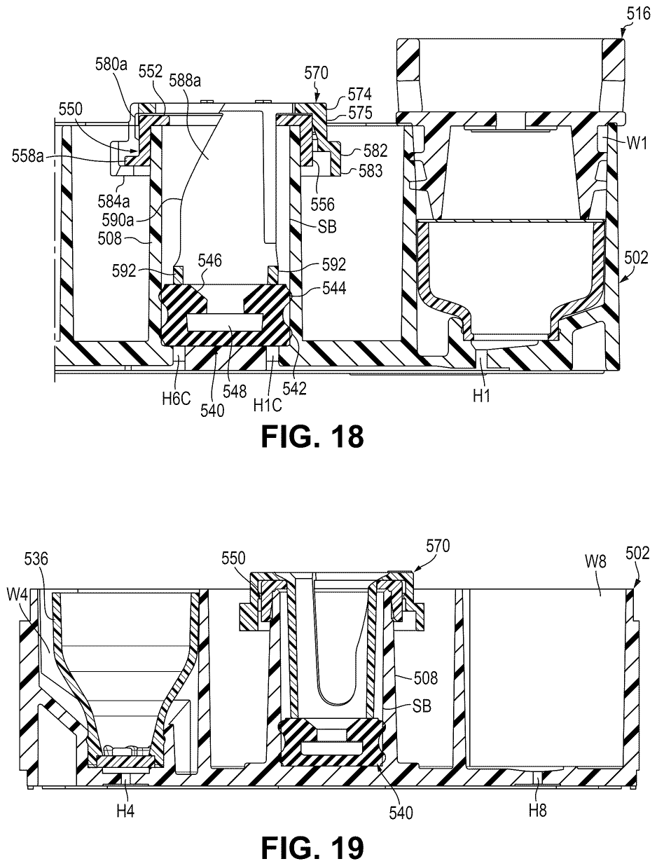

As shown in FIGS. 18 and 19, stopper 540 includes a plunger recess 546, for receiving plunger head 364 at the end of the syringe plunger 362, and a plunger pocket 548 for releasably retaining the plunger head 364 of the syringe plunger 362, as will be described below. Plunger recess 546 may include a conical (chamfered) portion to help guide the plunger head 364 of the syringe plunger into the plunger pocket 548.

During shipping and storage of the cartridge 500, and before the stopper 540 is engaged by a plunger 362, the stopper 540 is retained within the syringe barrel SB and pressed against a bottom wall of the syringe barrel SB—thereby blocking the holes H1c to H10c—by a blocker mechanism. As shown in FIG. 11, a blocker mechanism may comprise the blocker ring 550, secured to a top edge of the cylindrical wall 508 of the syringe barrel SB, and the blocker 570 is configured to be coupled to the blocker ring 550 and to be uncoupled from the blocker ring 550 when engaged by the plunger 362 moving down through the blocker 570 and into engagement with the stopper 540, as will be described below.

Blocker ring 550 includes an annular rim 552 and an axial ring 556 circumscribing the outer periphery of the annular rim 552. A bottom side of the annular rim 552 contacts the top circular edge of the cylindrical wall 508 of the syringe barrel SB. An inner diameter of the axial ring 556 is preferably only slightly larger than an outer diameter of the cylindrical wall 508 so that there is little lateral play between the blocker ring 550 and the cylindrical wall 508. An inner diameter of the annular rim 552 is preferably smaller than an inner diameter of the cylindrical wall 508 (and smaller than the diameter of the stopper 540) so that the blocker ring 550 prevents the stopper 540 from being removed from the syringe barrel SB. A radial notch 554 is formed across the top of the annular wall 552. Blocker ring 550 includes three angularly-spaced, radially extending flanges, or tabs, 558a, 558b, 558c projecting outwardly from a bottom edge of the axial ring 556.

The blocker ring 550 is fixed to the top of the cylindrical wall 508, e.g., by an adhesive or thermal or ultrasonic welding, or the blocker ring and the cylindrical wall can be integrally formed as a single piece.

As shown in FIGS. 11-14, blocker 570 includes a cap portion 572 and a center tube 586. Cap portion 572 includes a top, first cap portion 574 and a lower, second cap portion 582 that is coaxial with and has a larger outer diameter than the first cap portion 574. First cap portion 574 is defined by a top, radially-oriented wall 576 and a side, axially-oriented wall 575. Side wall 575 has an inner diameter that is slightly larger than an outer diameter of the axial ring 556 of the blocker ring 550 so that the first cap portion 574 of blocker 570 fits over the blocker ring 550 and there is little lateral play between the first cap portion 574 of blocker 570 and the blocker ring 550. Second portion 582 is defined by a side, axial wall 583 having an inner diameter that is larger than an outer diameter of a circle circumscribing the outer edges of the flanges 558a, 558b, 558c of the blocker ring 550 so that the second cap portion 582 of the blocker 570 fits over and past the flanges 558a, 558b, 558c of the blocker ring 550.

Blocker 570 includes three angularly-spaced flanges 584a, 584b, 584c, projecting inwardly from a lower edge of the axial wall 583 of the second cap portion 582 of the cap portion 572. A distance between a top surface of each radial flange 584a, 584b, 584c and a bottom surface of the radial wall 576 of the first cap portion 574 is at least as great as the distance between a bottom surface of each flange 558a, 558b, 558c of the blocker ring 550 and a top surface of the annular rim 552 of the blocker ring 550. Accordingly, when the blocker 570 is placed on the blocker ring 550 with the top surface of the annular rim 552 of the blocker ring 550 contacting the bottom surface of the radial wall 576 of the blocker 570, the blocker 570 can be rotated with respect to the blocker ring 550 to place each of the flanges 584a, 584b, 584c of the blocker 570 beneath a corresponding one of the flanges 558a, 558b, 558c of the blocker ring 550, thereby releasably interlocking the blocker 570 and the blocker ring 550.

Center tube 586 extends below the top wall 576 of the first cap portion 574 of cap portion 572. The length of the center tube 586 is greater than a distance from the top of the stopper 540 to the top wall of the annular rim 552 of the blocker ring 550 when the stopper is in contact with the bottom wall of the syringe barrel SB. Accordingly, the center tube 586 must be pushed down to partially compress the stopper 540 to enable the bottom surface of the top wall 576 of the first cap portion 574 to contact the top of the annular rim 552 of the blocker ring 550. This compression of the stopper provides a seal blocking the through-holes H1c to H10c in the syringe barrel SB. Also, the resilience of the stopper 540 pushes up on the center tube 586, thereby causing the flanges 584a, 584b, 584c of the blocker 570 to push up on the flanges 558a, 558b, 558c of the blocker ring 550, thereby enhancing frictional force between the flanges 584a, 584b, 584c and the flanges 558a, 558b, 558c to retain the blocker 570 in a fixed position with respect to the blocker ring 550. The retained blocker 570 holds the stopper 540 in a compressed state against the bottom wall of the syringe barrel SB.

Top wall 576 of the first cap portion 574 includes a center opening. Center tube 586 extends down from the top wall 576 from a perimeter of the center opening. Center tube 586 comprises opposed cam walls 588a, 588b extending down from opposed sides of the center opening formed in the top wall 576. Each cam wall 588a, 588b includes an associated cam edge 590a, 590b with a helical curve extending along one side of each cam wall 588a, 588b, respectively, from the top wall 576 to a terminal ring 592 extending continuously around the circumference of a lower end of the center tube 586.

Radial clearances 577a, 577b are formed on opposite sides of the center opening of the top wall 576 and are disposed between the cam walls 588a, 588b. Thus, a radius 578a from the center of the opening to each cam wall 588a, 588b (i.e., the diameter between the opposed walls 588a, 588b) is smaller than a radius 578b from the center of the opening to an outer edge of each clearance 577a, 577b (i.e., the diameter between the opposed clearances 577a, 577b.).

First cap portion 574 of the cap portion 572 of blocker 570 includes angularly-spaced cut outs 580a, 580b, 580c formed in the axially-oriented sidewall 575 to facilitate molding of internal features, such as the flanges 584a, 584b, 584c.

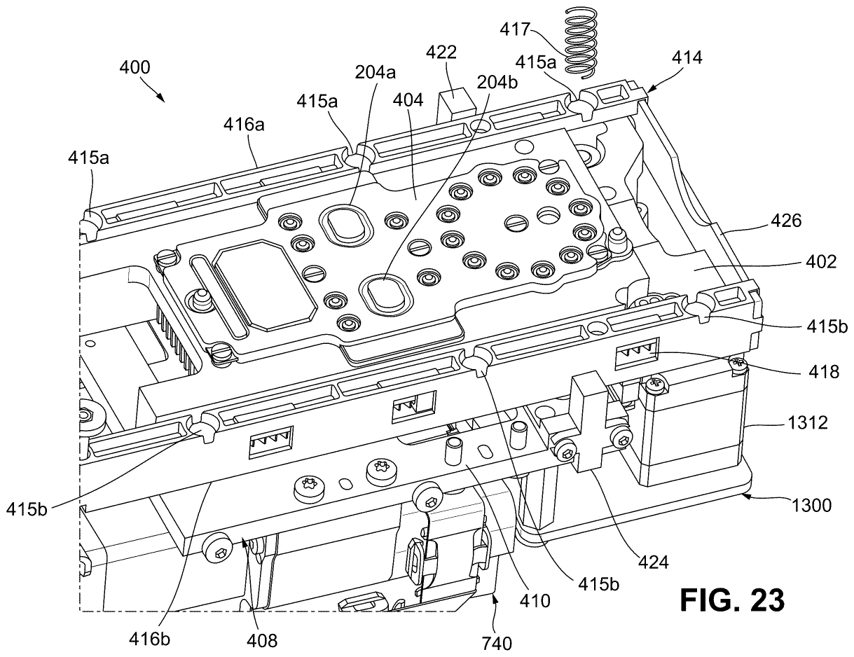

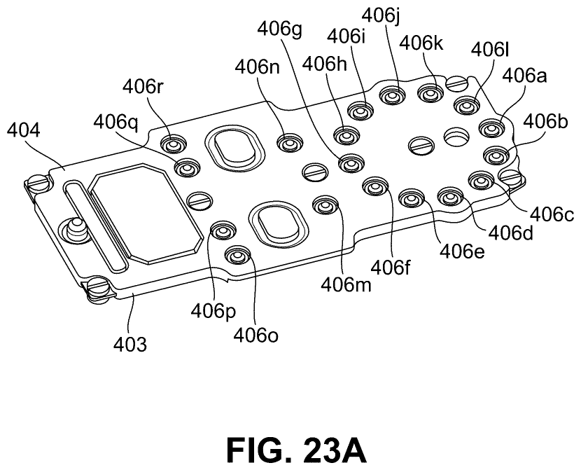

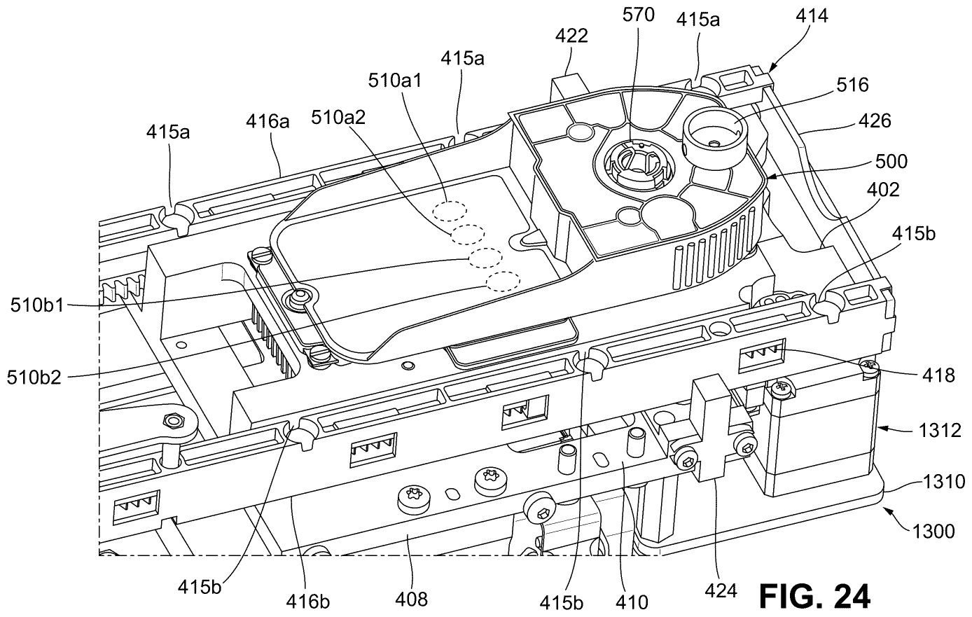

Instrument 10 includes a thermal/detector mechanism that may comprise a component or subsystem of instrument 10 and which operates to heat or cool the reaction/detection chambers 510a1, 510a2, 510b1, 510b2 and to detect optical signals emitted by reactions occurring within reaction/detection chambers 510a1, 510a2, 510b1, 510b2 when the cartridge 500 is within the instrument 10. FIGS. 23 and 24 are partial, top perspective views of the lower chassis 400 showing a cartridge support frame 402 respectively with and without a cartridge 500. FIG. 23 shows the cartridge support frame 402 which includes a cartridge support cradle 404 on which a cartridge can be operatively supported, and FIG. 24 shows the cartridge support frame 402 supporting the cartridge 500. FIG. 23A is a perspective view of the cartridge support cradle 404 in isolation. Cartridge support cradle 404 may include a gasket 403 made of a resilient material, such as rubber, secured to a platform 405 of the cartridge support frame 402. As shown in FIG. 23A, instrument 10 may include a plurality of valve actuator heads 406a-406r formed in the gasket 403. There are eighteen actuator heads in the example shown in FIG. 23A, each of actuator heads 406a-406r being associated with one of the valves V1 to V18, respectively, of cartridge 500. Each actuator head 406a-406r comprises a recess (which may be circular as shown in FIG. 23A) with a protuberance centered within the recess and projecting above the bottom of the recess. An actuator piston, or rod, is associated with each actuator head 406a-406r. Each actuator piston is disposed beneath gasket 403 and is oriented generally normally to the surface of cartridge support cradle 404 with a tip of the piston extending into the underside of the protuberance of the actuator head. Each actuator piston is selectively actuated—as described herein—to move between a first position at which the top of the protuberance of the actuator head 406a-406r is flush or recessed with respect to a top surface of the gasket 403 and a second position pushing the top of the protuberance of the associated actuator head 406a-406r above the top surface of the gasket 403. When in the second, protruding position, a valve actuator head 406a-406r associated with each valve V1 to V18 of cartridge 500 (see FIG. 7) selectively closes the associated valve by pressing the protuberance up, which presses the deformable bottom film 530 of the cartridge (see FIG. 8) into contact with the valve seat of the valve.

The cartridge support cradle 404 is supported on, attached to, or an integral part of cartridge support frame 402 of the lower chassis 400, and cartridge support frame 402 is supported on, attached to, or an integral part of a base plate 408.

Instrument 10 includes a movable holder that supports a test platform, such as a cartridge 500, and which may be selectively moved laterally with respect to the rest of the instrument between a position at which the holder is extended from the instrument 10 so that a cartridge 500, or other test platform, may be placed into or removed from the holder and a position retracted into the instrument to move a cartridge 500 supported on the holder to an operative position within the instrument in which the test platform, or a portion thereof, is positioned between first and second heaters, as will be described below. As shown in FIG. 23, a movable frame 414 encompasses the cartridge support frame 402 and the cartridge support cradle 404. Frame 414 comprises rails 416a, 416b held together in a spaced-apart arrangement by a cross piece 426 extending between ends of the rails 416a, 416b. Opposite ends of the rails 416a, 416b, not visible in FIG. 23, are held together in a spaced-apart arrangement by another cross piece 428 (see FIGS. 1 and 2) so that the rails 416a, 416b are generally parallel to one another. The frame 414 is movable with respect to the cartridge support frame 402, cartridge support cradle 404, and the base plate 408 from the retracted position shown in FIG. 23 to an extended position to the right of the position shown in FIG. 23. Instrument 10 includes an actuator for effecting automated—e.g., motorized—movement of the frame 414 relative to the cartridge support frame 402 and cartridge support cradle 404. In one example, rail 416b includes a rack 418, and a motor (not shown) includes a drive shaft and gear (not shown) engaged with the rack 418 to effect powered movement of the frame 414 between the extended and retracted positions as the motor rotates the drive shaft and gear in one direction or the other.

Referring to FIGS. 1 and 2, a cartridge holder 412 is supported on the frame 414 and moves laterally with the frame 414 between the extended and retracted positions. Cartridge 500 is supported within cartridge holder 412 on short lateral side flanges that extend beneath the cartridge 500 along opposite sides of the cartridge and that will not overlap or otherwise interfere with the cartridge support cradle 404 when the cartridge holder 412 and the frame 414 are in the retracted position to hold the cartridge 500 above the cartridge support cradle 404. Cartridge holder 412 is supported with respect to the frame 414 by springs 417 (see FIG. 23, only one spring is shown) disposed within recesses 415a, 415b formed in the tops of rails 416a, 416b, respectively (see FIG. 23). The springs are positioned between the holder 412 and rails 416a, 416b to hold the holder 412 in a raised position above the rails 416a, 416b, so that a cartridge 500 carried on the cartridge holder 412 can move over the cartridge support cradle 404 without contacting the cartridge support cradle 404 when the frame 414 is moved between the extended and retracted positions. When the frame 414 and the cartridge support holder 412 are retracted to position a cartridge 500 carried on the holder 412 above the cartridge support cradle 404, and a downward force is applied to the top of the cartridge 500—as will be described below—the springs between the cartridge holder 412 and rails 416a, 416b will allow the cartridge 500 and holder 412 to deflect downwardly and place the cartridge 500 supported by the holder 412 in contact with the cartridge support cradle 404. When the downward force is removed, the spring will again lift the holder 412 and cartridge 500 above the frame 414 and the cartridge support cradle 404 so that the frame 414, holder 412, and cartridge 500 are free to move relative cartridge support cradle 404 without contacting the cartridge support cradle 404.

Instrument 10 may further include sensors 422, 424 for detecting when the holder 412 and frame 414 are in the extended or retracted position. In one example, each sensor comprises an optical sensor with an optical emitter and an optical receiver. The emitter emits a light beam that is blocked from reaching the receiver by the rail 416a or 416b until the rail 416a or 416b is at a position at which a notch or opening formed in the corresponding rail allows the beam from the sensor emitter to be received by the sensor receiver. For example, as illustrated in FIG. 23, sensor 424 may be a holder extension sensor for which a beam from the sensor emitter is blocked by rail 416b until frame 414 is in the extended position and a notch formed in the rail 416b is aligned with the emitter and receiver of sensor 424 so that the beam from the emitter is received by the receiver. The resulting signal generated by the sensor 424 will then indicate that frame 414 and holder 412 are in the extended position. Similarly, sensor 422 may be a holder retraction sensor for which a beam from the sensor emitter is blocked by rail 416a until frame 414 and holder 412 are in the retracted position and a notch formed in the rail 416a is aligned with the emitter and receiver of sensor 422 so that the beam from the emitter is received by the receiver. The resulting signal generated by the sensor 422 will then indicate that frame 414 and holder 412 are in the retracted position.

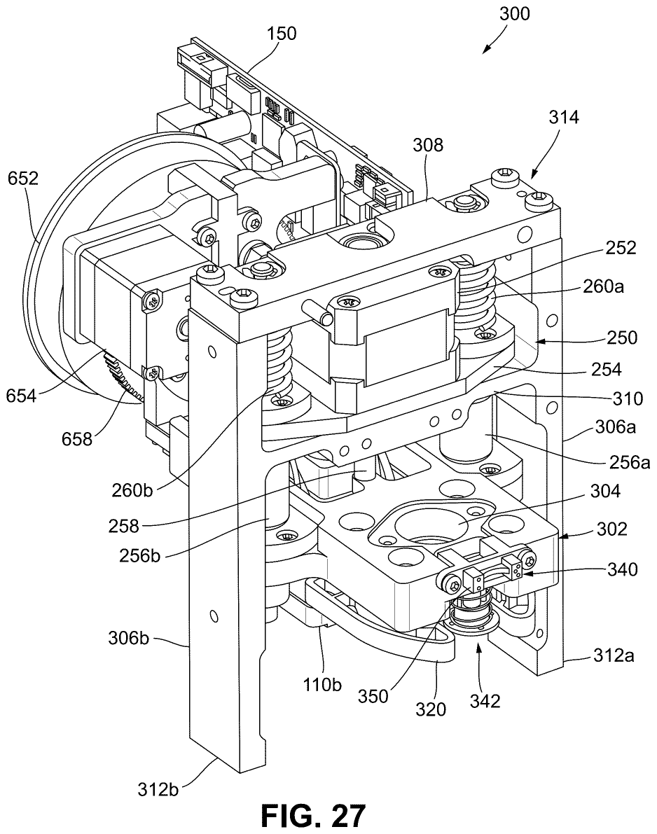

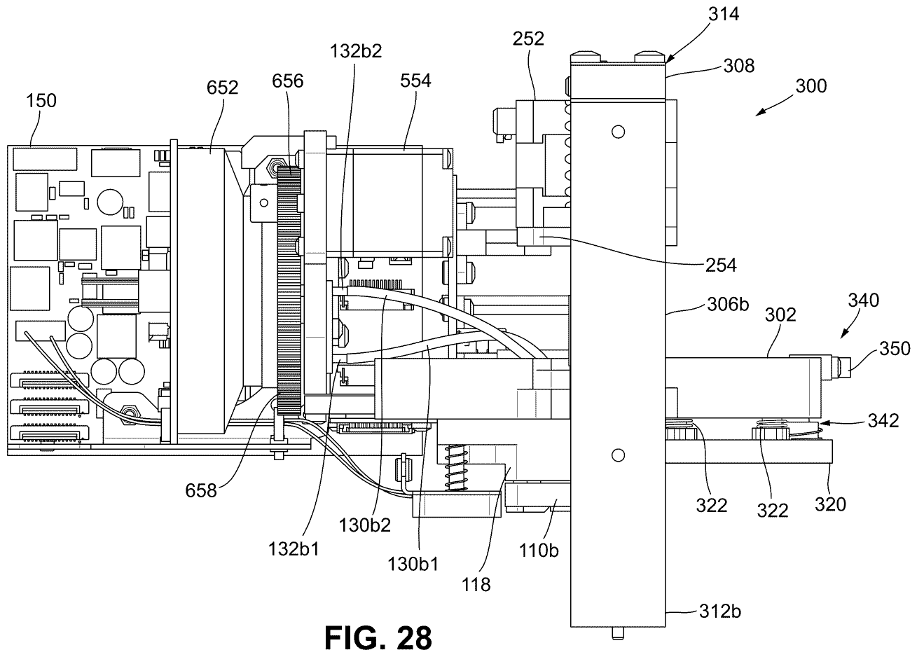

Referring to FIGS. 27-29, upper chassis 300 includes an upper block 302 and a motor mount 314 comprising side supports 306a, 306b, a top crossbar 308 extending between side supports 306a, 306b (but not necessarily between the top ends of the side supports 306a, 306b), and an intermediate crossbar 310 extending between side supports 306a, 306b at a spaced-apart position below the top crossbar 308. Lower ends 312a, 312b of side supports 306a, 306b, respectively, are attached to base plate 408 of the lower chassis 400 at location 410 (see FIGS. 23 and 24). A pressure plate 320 made from, e.g., a molded plastic or similar material (e.g., Delrin), is attached to a bottom side of upper block 302 by means of spring mounts 322 (see FIG. 28). In one example, there are four spring mounts 322 between the pressure plate 320 and the upper block 302; two spring mounts 322 are visible in FIG. 28. A spring mount is a connection—e.g., a bolt or a rod—between pressure plate 320 and upper block 302 that creates a gap between pressure plate 320 and upper block 302, and a spring (e.g., a coil compression spring) is disposed within the gap so that the pressure plate 320 and upper block 302 are held apart. Upper block 302 is configured for automated (e.g., motorized) movement with respect to base plate 408 of lower chassis 400, as will be described below, until pressure plate 320 bears against a top portion of the cartridge 500 supported on the cartridge support cradle 404, e.g., the top portion of the sample preparation section 504 of the cartridge 500 placed within the instrument 10, and the pressure plate 320 is able to deflect with respect to upper block 302 upon application of sufficient force to overcome the force of the springs of spring mounts 322.

### Valve Actuators

Instrument 10 includes one or more valve actuators including valve actuator pistons, or simply actuator pistons, for selectively actuating one of the actuator heads 406a-406r to open one of valves V1—V18 associated with the actuator head and permit fluid flow within the cartridge past the associated valve. In one example, actuator heads 406a-406r are associated with valves V1—V18, respectively, and each actuator piston operably engageable with each actuator 406a-406r is biased in an extended (first) position so that, when the cartridge 500 is placed into the instrument 10, and the pressure plate 320 is lowered onto the cartridge, each actuator piston presses against the protuberance of its associated actuator head 406a-406r to operably engage an associated valve by pressing against the associated valve to close that valve. Thus, when the cartridge is placed in the cartridge support cradle 404, and frame 414 is moved from its extended position to its retracted position, all the valves V1-V18 are initially closed due to the associated actuator pistons of actuator heads 406a-406r being biased in extended positions to push the actuator heads into extended positions and move the valves into closed positions. To open any of the valves, the associated actuator piston and actuator head 406a-406r is retracted to its second position against a biasing force out of engagement with the associated valve, thereby opening the valve. The valve actuators of instrument 10 are configured and controlled to selectively retract at least one actuator piston to open the valve associated with the retracted piston. The biasing force extending the actuator piston into extended positions may be generated by a component of the valve actuator.

In one example, the valve actuator(s) includes one or more piston actuator mechanisms, wherein a piston actuator mechanisms is coupled to or otherwise selectively engages each valve actuator piston so that, as the piston actuator mechanism moves, the piston actuator mechanism applies a force to the valve actuator piston coupled to or engaged by the piston actuator mechanisms to move the actuator piston against the biasing force from its first position to its second position, thereby opening the valve associated with the actuator piston. Continued movement of the piston actuator mechanism removes the force applied to the actuator piston coupled to the piston actuator mechanisms or causes the piston actuator mechanism to disengage the actuator piston, thereby removing the force applied to the actuator piston to allow the actuator piston to move under the biasing force back to its first position to close the valve associated with the actuator piston.

In another example, the valves of the cartridge may be configured so that pushing on the valve by the associated valve actuator head and valve actuator piston opens the valve and releasing the pushing force applied by the associated valve actuator head and valve actuator piston closes the valve. In this case, in their first, biased positions, the valve actuator pistons engage the associated valves to position the valves into open positions, and selective retraction of each valve actuator piston from its first position, against the biasing force, to its second position, causes the associated piston to change from an open position to a closed position.

As shown in FIG. 1, instrument 10 includes a first valve actuator 1300 for selectively retracting an actuator piston associated with one of the actuator heads 406a-406l and one of the circularly-arranged sample preparation (or process) valves V1 to V12 within sample preparation section 504 of cartridge 500 surrounding syringe barrel SB and associated with one of chambers holes H1 to H12 of wells W1 to W10 (see FIGS. 4 and 5). As shown in FIGS. 1 and 2, instrument 10 further includes a second valve actuator 740 for selectively retracting one or more actuator pistons associated with actuator heads 406m-406r and any of reaction valves V13 to V18 within reaction/detection section 506 of cartridge 500 associated with the reaction chambers 510a1, 510a2, 510b1, 510b2 of the cartridge 500 (see FIGS. 4 and 5).

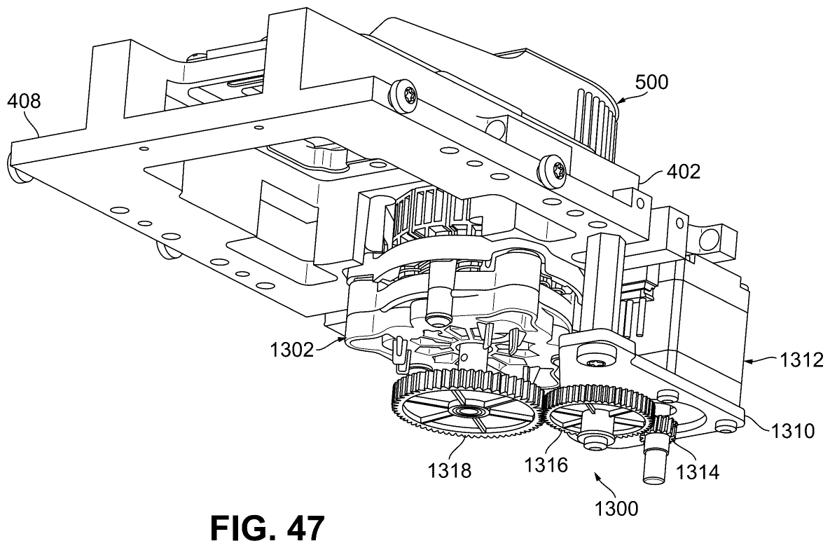

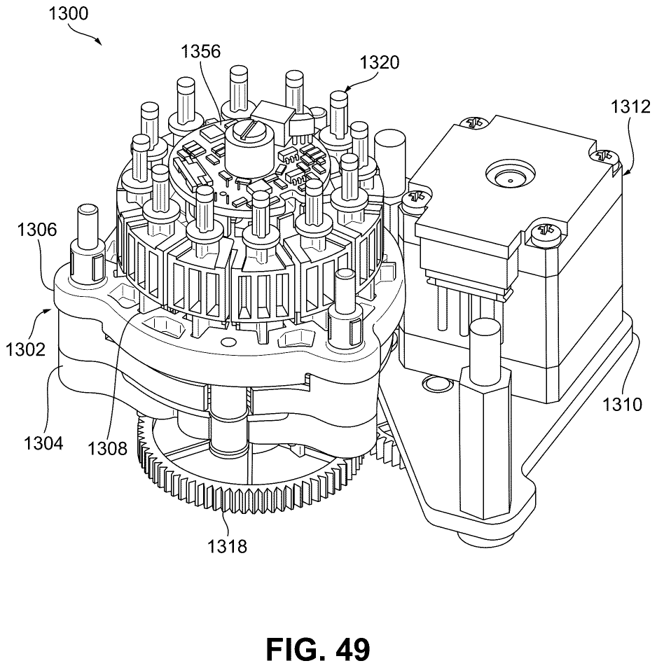

As shown FIGS. 47 and 49, first valve actuator 1300 comprises a rotary valve actuator having a housing 1302 defined by a lower housing 1304 and an upper housing 1306 connected to one another, e.g., by suitable fasteners, a plurality of valve actuator pistons 1320 extending upwardly through guide slots 1308 formed in a top surface of the upper housing 1306, and a rotary actuator motor 1312 supported on a motor mount 1310.

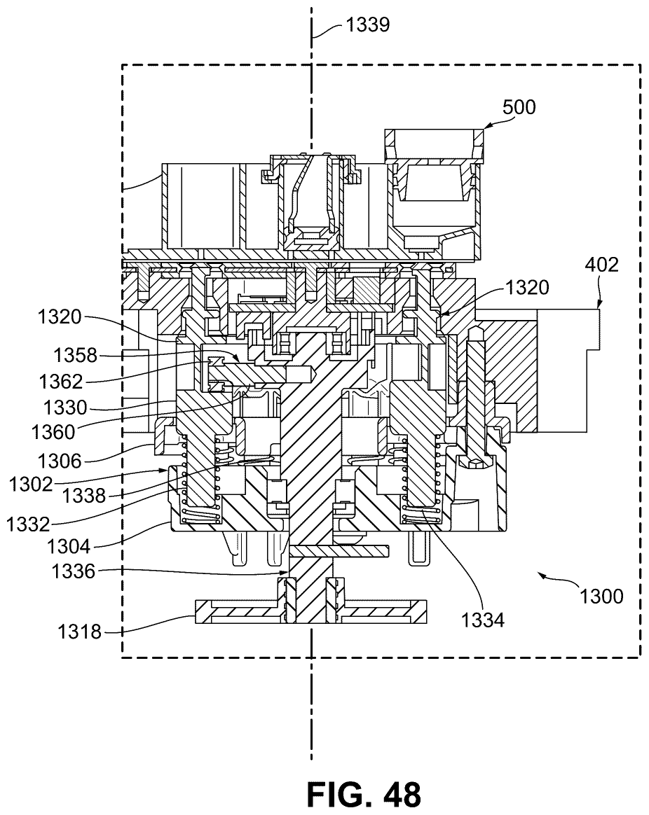

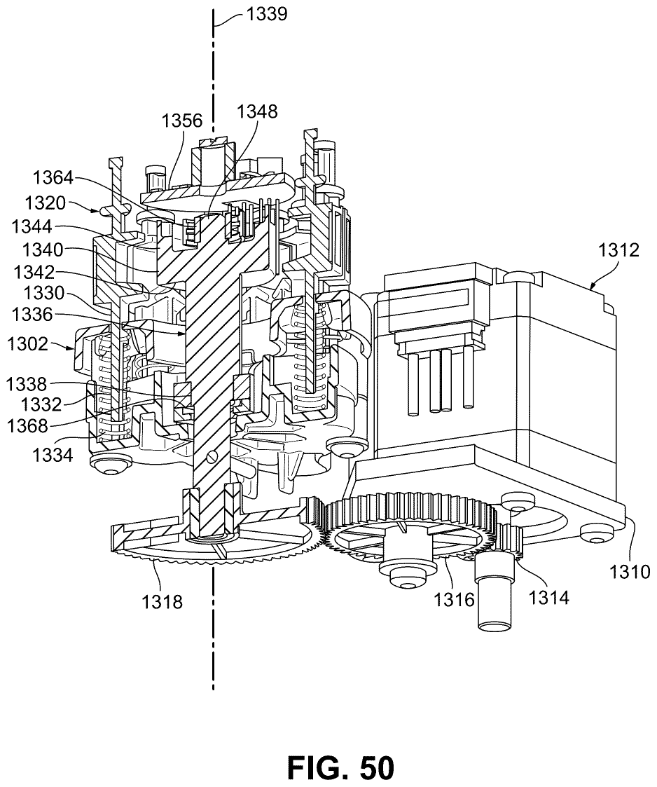

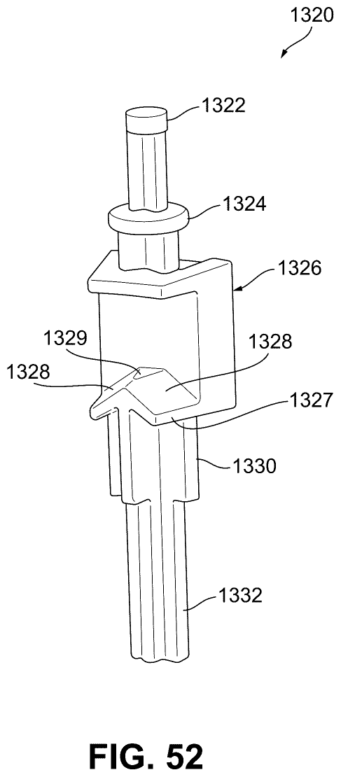

As shown in FIG. 52, each valve actuator piston 1320 includes a contact rod 1322. The contact rod 1322 of each valve actuator piston 1320 extends into an associated opening formed through platform 405 of the cartridge support frame 402 and engages the protuberance of one of the actuator heads 406a-406l formed in gasket 403 of cartridge support cradle 404. Each valve actuator piston 1320 may further include a stop flange 1324 to prevent over insertion of the valve actuator piston 1320 into platform 405, a cam block 1326 having a cam follower surface 1328, which, in the illustrated embodiment, has the shape of an inverted “V”, a lower rod 1330 projecting immediately below the cam block 1326, and a spring rod 1332 projecting below the lower rod 1330. As shown in FIGS. 48 and 50, the lower rod 1330 and spring rods 1332 of the valve actuator pistons 1320 extend into the housing 1302. As shown in FIG. 49, guide slots 1308 formed in the top surface of the upper housing 1306 have a shape conforming to the shape of the lower rod 1330. In the illustrated embodiment, lower rod 1330 has a “T” shaped cross-section, and each of the guide slots 1308 has a conforming shape which permits axial movement of each piston 1320 up and down within the associated guide slot 1308 while preventing rotation of each piston about its longitudinal axis. Each valve actuator piston 1320 includes an associated spring 1334 coaxially disposed over the spring rod 1332 and seated within the lower housing 1304 to exert an upward biasing force on the associated valve actuator piston 1320.

As shown in FIGS. 49 and 50, the valve actuator pistons 1320 are arranged in a circular configuration with the cam follower surfaces 1328 of the valve actuator pistons 1320 facing the center of the circular configuration. The cam block 1326 of each valve actuator piston 1320 may have a truncated pie shape to facilitate arranging the pistons 1320 in a circular shape. Each of valve actuator pistons 1320 is operatively associated with an associated one of valves V1-V12, respectively, via actuator heads 406a-406l and is movable between a first position corresponding to a closed configuration of the associated valve and a second position corresponding to an open position of the associated valve.

As shown in FIGS. 48 and 50, the rotary valve actuator 1300 includes a cam rotor 1336 rotatably supported by an upper bearing 1364 and a lower bearing 1368 for rotation about a cam rotor axis of rotation 1339. The cam rotor 1336 includes a vertically oriented center shaft 1338 having a longitudinal axis defining axis of rotation 1339 and a rotor head 1340 at a top end of the center shaft 1338. Rotor head 1340 has a cup-like structure including a radial extension flange 1342 and a circular axial wall 1344 that is coaxially-arranged with respect to the axis of rotation 1339. An end 1348 of the center shaft 1338 disposed inside the axial wall 1344 is supported in the upper bearing 1364.

The cam rotor 1336 is coupled to the rotary actuator motor 1312 to effect powered rotation of the cam rotor 1336. In one example, the cam rotor 1336 is coupled to the motor 1312 via a drive gear 1314 mounted on a driveshaft of the motor 1312, a transmission gear 1316, and a cam rotor gear 1318 secured to an end of the center shaft 1338 of the cam rotor 1336.

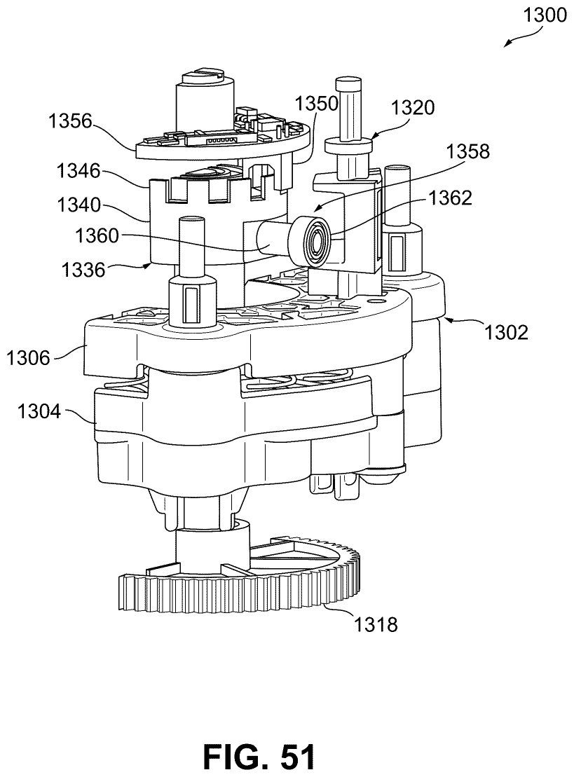

As shown in FIGS. 48 and 51, the rotary valve actuator 1300 further includes a rotary cam 1358 extending radially from the rotor head 1340 and including a cam rod 1360 that extends radially from the rotor head 1340 and a cam roller (e.g., a roller bearing) 1362 secured to the cam rod 1360 and rotatable about a longitude axis of the cam rod 1360 for engaging the cam follower surfaces 1328 of the valve actuator pistons 1320.

The rotary cam 1358 is configured so that the cam roller 1362 is disposed at the same radial distance from the axis of rotation 1339 of the cam rotor 1336 as the cam follower surfaces 1328 of the circularly arranged valve actuator pistons 1320. As the cam rotor 1336 rotates about its axis of rotation 1339, the cam roller 1362 of the rotary cam 1358 is configured to sequentially engage the cam follower surfaces 1328 of the valve actuator pistons 1320 one-by-one. The cam rod 1360 and the valve actuator pistons 1322 are positioned so that the longitudinal axis of the cam rod 1360 is at or near a bottom edge 1327 and below a peak 1329 of the cam follower surface 1328. As cam rotor 1336 and the rotary cam 1358 rotate about the axis of rotation 1339, the cam roller 1362 rolls along the cam follower surface 1328 from the bottom edge 1327 toward the peak 1329, and the angle of the cam follower surface 1328 causes the valve actuator piston 1320 to be pushed down by the action of the cam roller 1362 of the rotary cam 1358 to move the valve actuator piston 1320 from its spring-biased first (valve closed) position to its second (valve open) position to thereby release (open) the associated valve with which the contact rod 1322 of the valve actuator piston 1320 is engaged. As cam rotor 1336 and the rotary cam 1358 continue to rotate, cam roller 1362 rolls down from the peak 1329, and spring 1334 pushes the valve actuator piston 1320 upwardly to cause the contact rod 1322 to again close the associated valve.

The top peak 1329 of the cam follower surface 1328 may be flattened or otherwise shaped to provide a stable resting place for the cam roller 1362 while the cam roller 1362 is holding the valve actuator piston 1320 in the down position.

Rotary positioning and control of the cam rotor 1336 may be provided by a rotary position sensor, which, in the illustrated example, comprises an optical sensor 1350, including an optical emitter and an optical receptor, attached to a printed circuit board 1356 and positioned and configured to detect the passage of sensor flags 1346 disposed along a top edge of the axial wall 1344 of the rotor head 1340. Each sensor flag 1346—or gap between successive sensor flags 1346—may correspond to a position of one of the actuator pistons 1320 so that a signal generated by the sensor 1350 when a flag or gap is detected indicates a rotary position of one of the actuator pistons 1320. First valve actuator 1300 and/or instrument 10 may include other control features, such as a rotary encoder (not shown) coupled to rotary actuator motor 1312, to facilitate precise positioning of the rotary cam 1358 to thereby accurately control which of valves V1-V12 is opened, thereby enabling an orderly movement of fluids to and/or from the sample well W1 and functional chambers W21 and the syringe barrel SB to prepare a processed sample.

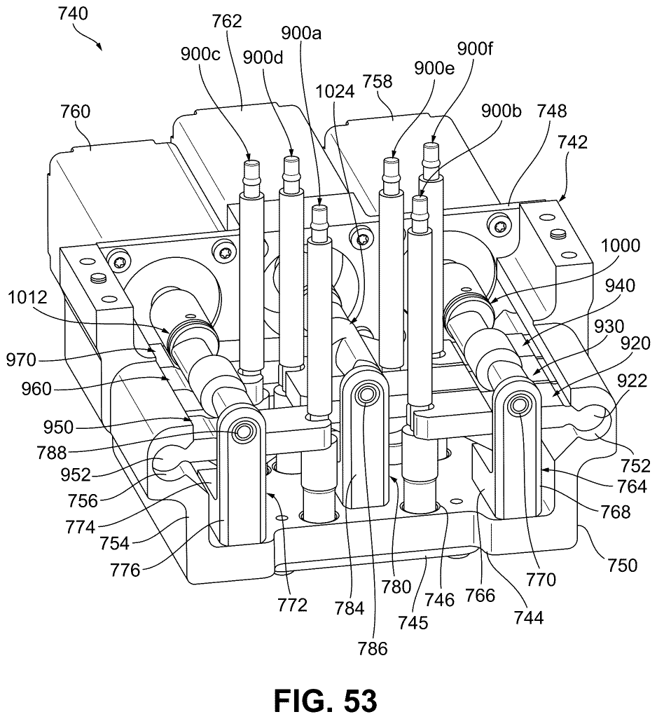

As shown in FIG. 53, second valve actuator 740 includes a frame 742 having a bottom wall 744, an end wall 748, a first side 750, and a second side 754. A plurality of valve actuator pistons 900a, 900b, 900c, 900d, 900e, 900f (six valve actuator pistons in the illustrated example) extend upwardly from associated piston openings formed in the bottom wall 744 of the frame 742. Each of valve actuator pistons 900a-900f is operatively associated with an associated one of valves V13, V14, V15, V16, V17, V18, respectively, via actuator heads 406m-406r and is movable between a first position corresponding to a closed configuration of the associated valve and a second position corresponding to an open position of the associated valve.

In an alternate example, the valve actuator may have less than or more than six valve actuator pistons. An example of a valve actuator with eight valve actuator pistons is described below.

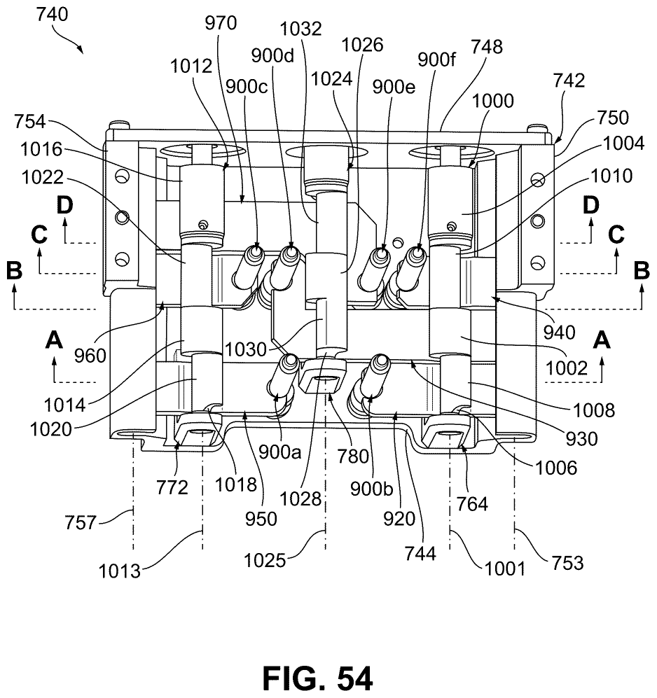

A first motor 758, a second motor 760, and a third motor 762 may be mounted to end wall 748 of the frame 742. Each of motors 758, 760, 762 may be a stepper motor. Second valve actuator 740 includes a first camshaft 1000, a second camshaft 1012, and a third camshaft 1024. First motor 758 is coupled to first camshaft 1000 for effecting powered rotation of the first camshaft 1000 about a first camshaft axis of rotation 1001 (see FIG. 54) corresponding to a longitudinal axis of first camshaft 1000, and second valve actuator 740 may include an encoder or other sensor mechanism coupled to or otherwise operable with first motor 758 and in communication with a controller for detecting and controlling a rotational position of the first camshaft 1000. Second motor 760 is coupled to second camshaft 1012 for effecting powered rotation of the second camshaft 1012 about a second camshaft axis of rotation 1013 (see FIG. 54) corresponding to a longitudinal axis of second camshaft 1012 and parallel to the first camshaft axis of rotation 1001, and second valve actuator 740 may include an encoder or other sensor mechanism coupled to or otherwise operable with second motor 760 and in communication with a controller for detecting and controlling a rotational position of the second camshaft 1012. Third motor 762 is coupled to third camshaft 1024 for effecting powered rotation of the third camshaft 1024 about a third camshaft axis of rotation 1025 (see FIG. 54) corresponding to a longitudinal axis of third camshaft 1024 and parallel to the first camshaft axis of rotation 1001 and the second camshaft axis of rotation 1013, and second valve actuator 740 may include an encoder or other sensor mechanism coupled to or otherwise operable with third motor 762 and in communication with a controller for detecting and controlling a rotational position of the third camshaft 1024.

As shown in FIG. 54, a journal end 1006 of first camshaft 1000 opposite the first motor 758 is rotatably supported by a first bearing mount 764. As shown in FIG. 53, first bearing mount 764 includes a mounting block 766 secured to the bottom wall 744 of the frame 742, an upright stanchion 768 extending upwardly from and end of the mounting block 766, and a bearing 770 disposed in an upper end of stanchion 768 that receives the journal end 1006 of the first camshaft 1000. As shown in FIG. 54, a journal end 1018 of second camshaft 1012 opposite the second motor 760 is rotatably supported by a second bearing mount 772. As shown in FIG. 53, second bearing mount 772 includes a mounting block 774 secured to the bottom wall 744 of the frame 742, an upright stanchion 776 extending upwardly from an end of the mounting block 774, and a bearing 778 disposed in an upper end of stanchion 776 that receives the journal end 1018 of the second camshaft 1012. As shown in FIG. 54, journal end 1028 of third camshaft 1024 opposite the third motor 762 is rotatably supported by a third bearing mount 780. Although not fully shown in the drawings (see FIG. 53), third bearing mount 780 has a similar form factor as first bearing mount 764 and second bearing mount 772, including a mounting block (not visible in FIG. 53) secured to the bottom wall 744 of the frame 742, an upright stanchion 784 extending upwardly from the mounting block, and a bearing 786 disposed in an upper end of stanchion that receives the journal end 1028 of the third camshaft 1024.

Referring to FIG. 54, first camshaft 1000 includes a first unlobed portion 1002 that is radially symmetric with respect to first camshaft axis of rotation 1001, a first cam lobe 1008 that is radially asymmetric with respect to first camshaft axis of rotation 1001, a second unlobed portion 1004 that is radially symmetric with respect to first camshaft axis of rotation 1001, a second cam lobe 1010 that is radially asymmetric with respect to first camshaft axis of rotation 1001, and the journal end 1006. Second camshaft 1012 includes a first unlobed portion 1014 that is radially symmetric with respect to second camshaft axis of rotation 1013, a first cam lobe 1020 that is radially asymmetric with respect to second camshaft axis of rotation 1013, a second unlobed portion 1016 that is radially symmetric with respect to second camshaft axis of rotation 1013, a second cam lobe 1022 that is radially asymmetric with respect to second camshaft axis of rotation 1013, and the journal end 1018. The third camshaft 1024 includes an unlobed portion 1026 that is radially symmetric with respect to third camshaft axis of rotation 1025, a first cam lobe 1030 that is radially asymmetric with respect to third camshaft axis of rotation 1025, a second cam lobe 1032 that is radially asymmetric with respect to third camshaft axis of rotation 1025, and the journal end 1028.

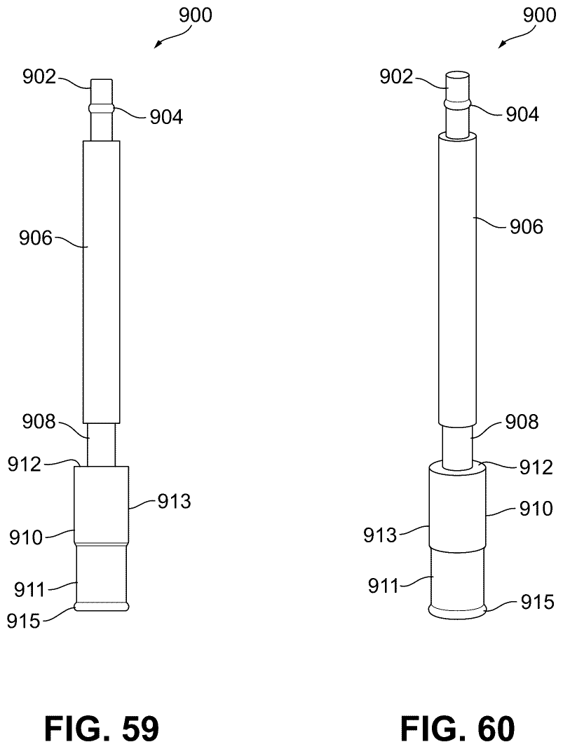

Referring to FIGS. 59 and 60, showing a single valve actuator piston 900 (valve actuator pistons 900a-900f being identical or substantially identical in form factor), each of the valve actuator piston 900a-900f includes a contact rod 902, a peripheral rib 904 (optional) surrounding contact rod 902, an extension 906, which may be of greater width (diameter if extension 906 is cylindrical) than contact rod 902, a lever collar 908 disposed at a bottom end of the extension 906 and having a width (e.g., diameter) that is smaller than the width (e.g., diameter) of the extension 906, and a spring housing 910. The contact rod 902 of each valve actuator piston 900a-900f extends into an associated opening formed through platform 405 of the cartridge support frame 402 and engages the protuberance of one of the actuator heads 406m-406r formed in gasket 403 of cartridge support cradle 404. Peripheral rib 904 may have a width (e.g., diameter if contact rod 902 is cylindrical) that is somewhat smaller than a width of an opening formed in platform 405 so as to permit the contact rod 902 to move back and forth within the opening. Moreover, the rib 904 provides a minimal edge contact between the contact rod 902 and inner side walls of the opening in platform 405 so as to reduce the likelihood of the contact rod 902 binding within the opening.

The length of extension 906—which may be elongated as shown—provides necessary clearance between the second valve actuator 740 and the cartridge support frame 402, and the increased width of extension 906 provides increased rigidity to reduce or avoid bending or buckling of the valve actuator piston 900.

Valve actuator piston 900 includes a lateral ledge defining a lever seat 912 engaged by an associated actuator lever to lower the valve actuator piston 900, as will be described herein. In one example, the lever collar 908 and a top end of the spring housing 910 (having a width, e.g., diameter, that is greater than a width of the lever collar 908) defines the lever seat 912.

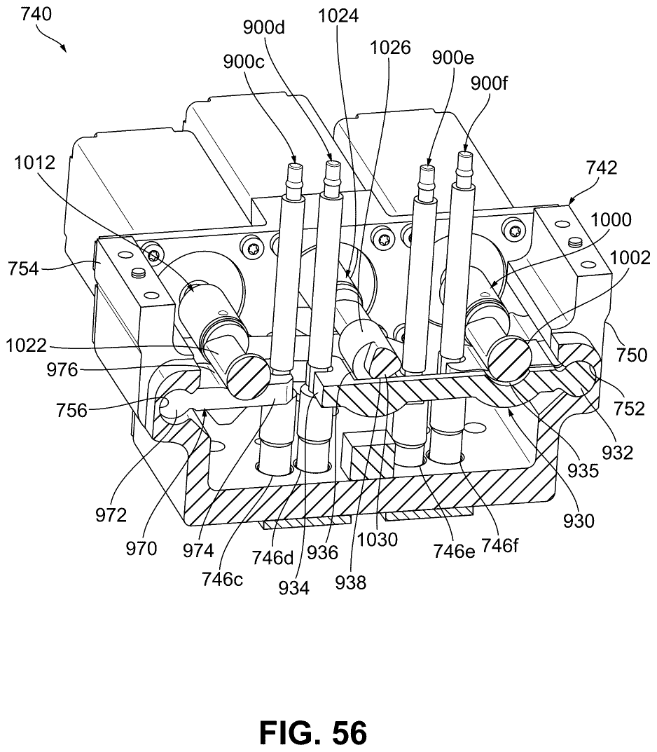

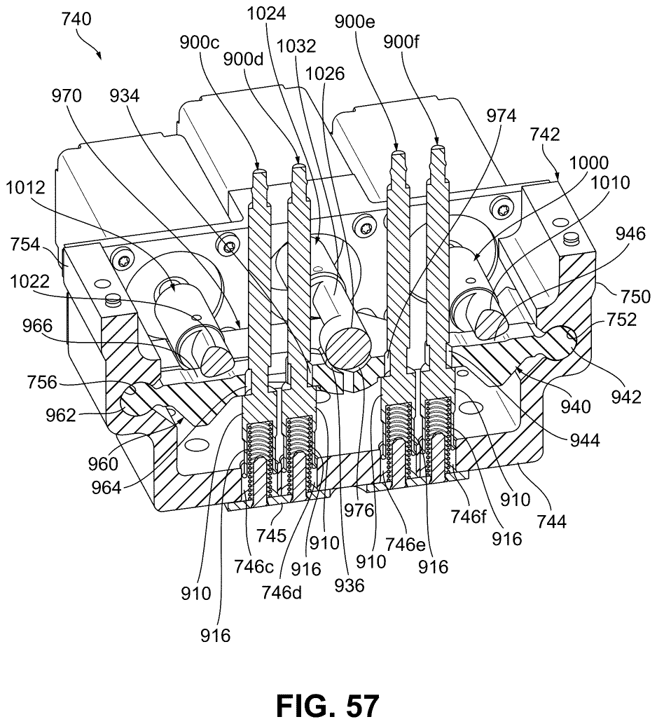

FIG. 56 shows actuator pistons 900a and 900b disposed within piston openings 746a and 746b, respectively, formed in bottom wall 744, and FIG. 57 shows actuator pistons 900c, 900d, 900e, and 900f disposed within piston openings 746c, 746d, 746e and 746f, respectively, formed in bottom wall 744. As shown in FIGS. 56 and 57, spring housing 910 includes a hollow, cylindrical chamber 914 that receives a spring 916 that bears against a bottom plate 745 covering a bottom end of piston openings 746a-746f formed in the bottom wall 744 to bias the valve actuator piston 900 axially upwardly along its longitudinal direction into the first position of the valve actuator piston 900. Referring again to FIGS. 59 and 60, lower portion 911 of spring housing 910 may have a width (e.g., diameter) that is smaller than a width (e.g., diameter of an upper portion 913 of spring housing 910, and a lower end of the spring housing 910 may have a radial rib 915 having a width (e.g., diameter) that is somewhat smaller than a width of piston opening 746 so as to permit the lower end of spring housing 910 to move back and forth within the piston opening 746. Moreover, the rib 915 provides a minimal edge contact between the spring housing 910 and inner side walls of the piston opening 746 so as to reduce the likelihood of the spring housing 910 binding within the piston opening 746.

In the configuration of second valve actuator 740 shown, valve actuator piston 900a is associated with actuator head 406m that is associated with (i.e., opens and closes) valve V13, valve actuator piston 900b is associated with actuator head 406n that is associated with (i.e., opens and closes) valve V14, valve actuator piston 900c is associated with actuator head 406o that is associated with (i.e., opens and closes) valve V15, valve actuator piston 900d is associated with actuator head 406p that is associated with (i.e., opens and closes) valve V16, valve actuator piston 900e is associated with actuator head 406q that is associated with (i.e., opens and closes) valve V17, and valve actuator piston 900f is associated with actuator head 406r that is associated with (i.e., opens and closes) valve V18.

Referring to FIG. 54, second valve actuator 740 further includes a first pivoting actuator lever 920 operatively engaged by first camshaft 1000, a second pivoting actuator lever 930 operatively engaged by third camshaft 1024, a third pivoting actuator lever 940 operatively engaged by first camshaft 1000, a fourth pivoting actuator lever 950 operatively engaged by second camshaft 1012, a fifth pivoting actuator lever 960 operatively engaged by second camshaft 1012, and a sixth pivoting actuator lever 970 operatively engaged by third camshaft 1024.

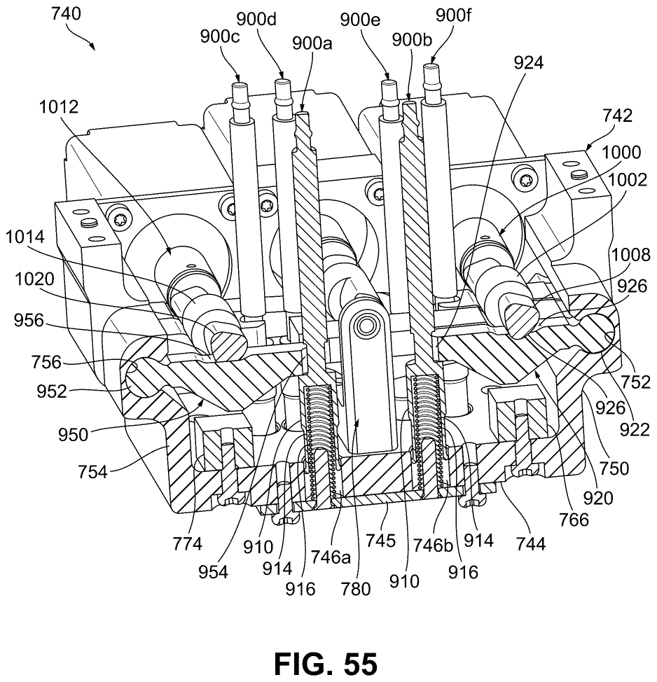

Each valve actuator piston 900a-900f is associated with one of actuator levers 920, 930, 940, 950, 960, 970 to couple the valve actuator piston to one of the camshafts 1000, 1012, or 1024. As shown in FIGS. 53, 54, and 55 valve actuator piston 900a is coupled to second camshaft 1012 by fourth actuator lever 950, and valve actuator piston 900b is coupled to first camshaft 1000 by first actuator lever 920. As shown in FIGS. 53, 54, 56, and 57, valve actuator piston 900c is coupled to second camshaft 1012 by fifth actuator lever 960, valve actuator piston 900d is coupled to third camshaft 1024 by second actuator lever 930, valve actuator piston 900e is coupled to third camshaft 1024 by a sixth actuator lever 970, and valve actuator piston 900c is coupled to first camshaft 1000 by a third actuator lever 940.

As shown in FIGS. 53, 54, and 55, first actuator lever 920 includes a pivot anchor 922—comprising a partial cylinder—rotatably retained within a conforming pivot socket 752 on the first side 750 of frame 742 to enable first actuator lever 920 to pivot about a first pivot axis 753 corresponding to a longitudinal axis of partially cylindrical pivot anchor 922 and which is parallel to first, second, and third camshaft axes 1001, 1013, 1025, respectively. First actuator lever 920 includes a valve actuator piston engagement end 924 opposite the pivot anchor 922—e.g., a yoke having a semicircular notch—that receives lever collar 908 and is seated on lever seat 912 of first valve actuator piston 900b disposed in piston opening 746b formed in bottom wall 744. In another example, the valve actuator piston does not have a lever collar of reduced width, and a lever seat is defined by a top end of spring housing 910, which has a width, e.g., diameter, that is greater than a width of extension 906. A cam follower surface 926 of first actuator lever 920 is engaged by first cam lobe 1008 of first camshaft 1000. As first camshaft 1000 rotates about first camshaft axis of rotation 1001, first cam lobe 1008 engages the cam follower surface 926 of first actuator lever 920 once per revolution of the first camshaft 1000 to cause the first actuator lever 920 to rotate (counter-clockwise in the illustrated example) about first pivot axis 753. As the first actuator lever 920 rotates due to engagement by the first cam lobe 1008 of first camshaft 1000, the piston engagement end 924 of first actuator lever 920 seated on the lever seat 912 of valve actuator piston 900b pushes down on the valve actuator piston 900b to move the valve actuator piston 900b from its spring-biased first (valve closed) position to its second (valve open) position to thereby release (open) the associated valve with which the contact rod 902 of valve actuator piston 900b is engaged (valve V14 in the illustrated example). As first camshaft 1000 continues to rotate and first cam lobe 1008 disengages from the cam follower surface 926 of first actuator lever 920, spring 916 disposed within spring chamber 914 of spring housing 910 pushes the valve actuator piston 900b upwardly to cause the contact rod 902 to again close the associated valve.

As shown in FIGS. 53, 54, and 56, second actuator lever 930 includes a pivot anchor 932—comprising a partial cylinder—rotatably retained within a conforming pivot socket 752 on the first side 750 of frame 742 to enable second actuator lever 930 to pivot about first pivot axis 753 corresponding to a longitudinal axis of partially cylindrical pivot anchor 932. Second actuator lever 930 has an “L” shape with a first leg extending from pivot anchor 932 and a second leg extending laterally from the first leg and including a piston engagement 934 on a side of the second leg—having, e.g., a semicircular notch—that receives lever collar 908 and is seated on lever seat 912 of valve actuator piston 900d disposed in piston opening 746d formed in bottom wall 744. A cam follower surface 938 on the first leg of second actuator lever 930 is engaged by first cam lobe 1030 of third camshaft 1024. A first relief curve 935 formed in the first leg of second actuator lever 930 receives the first unlobed portion 1002 of second camshaft 1012, and a second relief curve 936 formed in the second leg of second actuator lever 930 receives the unlobed portion 1026 of third camshaft 1024. First relief curve 935 allows first unlobed portion 1002 of first camshaft 1000 to rotate without affecting (imparting motion to) the second actuator lever 930, and second relief curve 936 allows unlobed portion 1026 of third camshaft 1024 to rotate without affecting (imparting motion to) the second actuator lever 930. As third camshaft 1024 rotates about third camshaft axis of rotation 1025, first cam lobe 1030 engages the cam follower surface 938 of second actuator lever 930 once per revolution of the third camshaft 1024 to cause the second actuator lever 930 to rotate (counter-clockwise in the illustrated example) about first pivot axis 753. As the second actuator lever 930 rotates due to engagement by the first cam lobe 1030 of third camshaft 1024, the piston engagement 934 seated on the lever seat 912 of valve actuator piston 900d pushes down on the valve actuator piston 900d to move the valve actuator piston 900d from its spring-biased first (valve closed) position to its second (valve open) position to thereby release (open) the associated valve with which the contact rod 902 of valve actuator piston 900d is engaged (valve V16 in the illustrated example). As third camshaft 1024 continues to rotate and first cam lobe 1030 disengages from the cam follower surface 938 of second actuator lever 930, spring 916 disposed within spring chamber 914 of spring housing 910 pushes the valve actuator piston 900d upwardly to cause the contact rod 902 to again close the associated valve.

As shown in FIGS. 53, 54, 56, and 57, third actuator lever 940 includes a pivot anchor 942—comprising a partial cylinder—rotatably retained within a conforming pivot socket 752 on the first side 750 of frame 742 to enable third actuator lever 940 to pivot about first pivot axis 753 which corresponds to a longitudinal axis of partially cylindrical pivot anchor 942. Third actuator lever 940 includes a piston engagement end 944 opposite the pivot anchor 942—e.g., a yoke having a semicircular notch—that receives lever collar 908 and is seated on lever seat 912 of valve actuator piston 900f disposed in piston opening 746f formed in bottom wall 744. A cam follower surface 946 of third actuator lever 940 is engaged by second cam lobe 1010 of first camshaft 1000. As first camshaft 1000 rotates about first camshaft axis of rotation 1001, second cam lobe 1010 engages the cam follower surface 946 of third actuator lever 940 once per revolution of the first camshaft 1000 to cause the third actuator lever 940 to rotate (counter-clockwise in the illustrated example) about first pivot axis 753. As the third actuator lever 940 rotates due to engagement by the second cam lobe 1010 of first camshaft 1000, the piston engagement end 944 seated on the lever seat 912 of valve actuator piston 900f pushes down on the valve actuator piston 900f to move the valve actuator piston 900f from its spring-biased first (valve closed) position to its second (valve open) position to thereby release (open) the associated valve with which the contact rod 902 of valve actuator piston 900f is engaged (valve V18 in the illustrated example). As first camshaft 1000 continues to rotate and second cam lobe 1010 disengages from the cam follower surface 946 of third actuator lever 940, spring 916 disposed within spring chamber 914 of spring housing 910 pushes the valve actuator piston 900f upwardly to cause the contact rod 902 to again close the associated valve.

As shown in FIGS. 53, 54, and 55, fourth actuator lever 950 includes a pivot anchor 952—comprising a partial cylinder—rotatably retained within a conforming pivot socket 756 on the second side 754 of frame 742 to enable fourth actuator lever 950 to pivot about a second pivot axis 757 which corresponds to a longitudinal axis of partially cylindrical pivot anchor 952 and which is parallel to first, second, and third camshaft axes 1001, 1013, 1025, respectively, and to first pivot axis 753. Fourth actuator lever 950 includes a piston engagement end 954 opposite the pivot anchor 952—e.g., a yoke having a semicircular notch—that receives lever collar 908 and is seated on lever seat 912 of valve actuator piston 900a disposed in piston opening 746a formed in bottom wall 744. A cam follower surface 956 of fourth actuator lever 950 is engaged by first cam lobe 1020 of second camshaft 1012. As second camshaft 1012 rotates about second camshaft axis of rotation 1013, first cam lobe 1020 engages the cam follower surface 956 of fourth actuator lever 950 once per revolution of the second camshaft 1012 to cause the fourth actuator lever 950 to rotate (clockwise in the illustrated example) about second pivot axis 757. As the fourth actuator lever 950 rotates due to engagement by the first cam lobe 1020 of second camshaft 1012, the piston engagement end 954 seated on the lever seat 912 of the valve actuator piston 900a pushes down on the valve actuator piston 900a to move the valve actuator piston 900a from its spring-biased first (valve closed) position to its second (valve open) position to thereby release (open) the associated valve with which the contact rod 902 of valve actuator piston 900a is engaged (valve V13 in the illustrated example). As second camshaft 1012 continues to rotate and first cam lobe 1020 disengages from the cam follower surface 956 of fourth actuator lever 950, spring 916 disposed within spring chamber 914 of spring housing 910 pushes the valve actuator piston 900a upwardly to cause the contact rod 902 to again close the associated valve.

As shown in FIGS. 53, 54, 56, and 57, fifth actuator lever 960 includes a pivot anchor 962—comprising a partial cylinder—rotatably retained within a conforming pivot socket 756 on the second side 754 of frame 742 to enable fifth actuator lever 960 to pivot about second pivot axis 757 which corresponds to a longitudinal axis of partially cylindrical pivot anchor 962. Fifth actuator lever 960 includes a piston engagement end 964 opposite the pivot anchor 962—e.g., a yoke having a semicircular notch—that receives lever collar 908 and is seated on lever seat 912 of valve actuator piston 900c disposed in piston opening 746c formed in bottom wall 744. A cam follower surface 966 of fifth actuator lever 960 is engaged by second cam lobe 1022 of second camshaft 1012. As second camshaft 1012 rotates about second camshaft axis of rotation 1013, second cam lobe 1022 engages the cam follower surface 966 of fifth actuator lever 960 once per revolution of the second camshaft 1012 to cause the fifth actuator lever 960 to rotate (clockwise in the illustrated example) about second pivot axis 757. As the fifth actuator lever 960 rotates due to engagement by the second cam lobe 1022 of second camshaft 1012, the piston engagement end 964 seated on the lever seat 912 of valve actuator piston 900c pushes down on the valve actuator piston 900c to move the valve actuator piston 900c from its spring-biased first (valve closed) position to its second (valve open) position to thereby release (open) the associated valve with which the contact rod 902 of valve actuator piston 900c is engaged (valve V15 in the illustrated example). As second camshaft 1012 continues to rotate and second cam lobe 1022 disengages from the cam follower surface 966 of fifth actuator lever 960, spring 916 disposed within spring chamber 914 of spring housing 910 pushes the valve actuator piston 900c upwardly to cause the contact rod 902 to again close the associated valve.

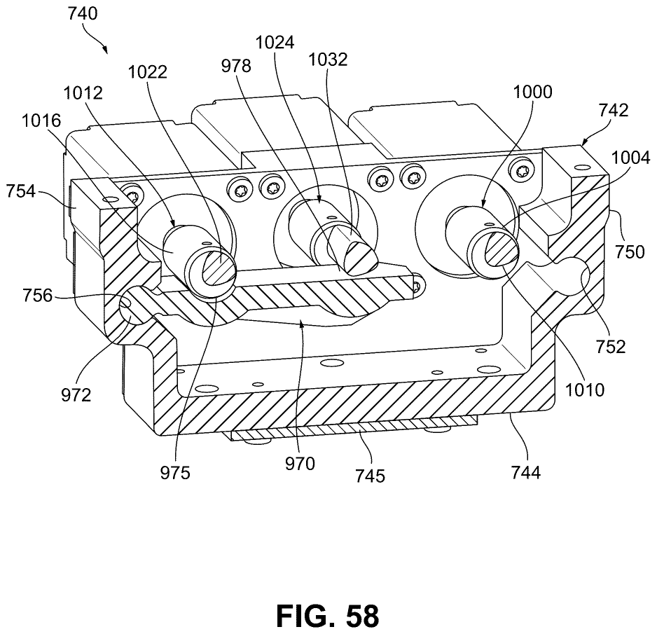

As shown in FIGS. 53, 54, 57, and 58, sixth actuator lever 970 includes a pivot anchor 972—comprising a partial cylinder—rotatably retained within a conforming pivot socket 756 on the second side 750 of frame 742 to enable sixth actuator lever 970 to pivot about second pivot axis 757 which corresponds to a longitudinal axis of partially cylindrical pivot anchor 972. Sixth actuator lever 970 has an “L” shape with a first leg extending from pivot anchor 972 and a second leg extending laterally from the first leg and including a piston engagement 974 on a side of the second leg—having, e.g., a semicircular notch—that receives lever collar 908 and is seated on lever seat 912 of valve actuator piston 900e disposed in piston opening 746e formed in bottom wall 744. A cam follower surface 978 on the first leg of sixth actuator lever 970 is engaged by second cam lobe 1032 of third camshaft 1024. A first relief curve 975 formed in the first leg of sixth actuator lever 970 receives the second unlobed portion 1016 of second camshaft 1012, and a second relief curve 976 formed in the second leg of sixth actuator lever 970 receives the unlobed portion 1026 of third camshaft 1024. First relief curve 975 allows second unlobed portion 1016 of second camshaft 1012 to rotate without affecting (imparting motion to) the sixth actuator lever 970, and second relief curve 976 allows unlobed portion 1026 of third camshaft 1024 to rotate without affecting (imparting motion to) the sixth actuator lever 970. As third camshaft 1024 rotates about third camshaft axis of rotation 1025, second cam lobe 1032 engages the cam follower surface 978 of sixth actuator lever 970 once per revolution of the third camshaft 1024 to cause the sixth actuator lever 970 to rotate (clockwise in the illustrated example) about second pivot axis 757. As the sixth actuator lever 970 rotates due to engagement by the second cam lobe 1032 of the third camshaft 1024, the piston engagement 974 seated on the lever seat 912 of the valve actuator piston 900e pushes down on the valve actuator piston 900e to move the valve actuator piston 900e from its spring-biased first (valve closed) position to its second (valve open) position to thereby release (open) the associated valve with which the contact rod 902 of valve actuator piston 900e is engaged (valve V17 in the illustrated example). As third camshaft 1024 continues to rotate and second cam lobe 1032 disengages from the cam follower surface 978 of the sixth actuator lever 970, spring 916 disposed within spring chamber 914 of spring housing 910 pushes the valve actuator piston 900e upwardly to cause the contact rod 902 to again close the associated valve.

The lobes of the camshafts 1000, 1012, 1024 can be configured, and the motors 758, 760, 762 can be programmed to operate, to actuate the actuator levers 920, 930, 940, 950, 960, 970 and associated valve actuator pistons 900b, 900d, 900f, 900a, 900c, 900e, respectively, in a desired synchronization during rotation of the camshafts to selectively open and close valves in the cartridge in accordance with desired fluid movement through the cartridge.

Thus, first valve actuator 1300 and second valve actuator 740 allow for an orderly opening and closing of valves to permit the introduction of processed samples into multiple reaction chambers.

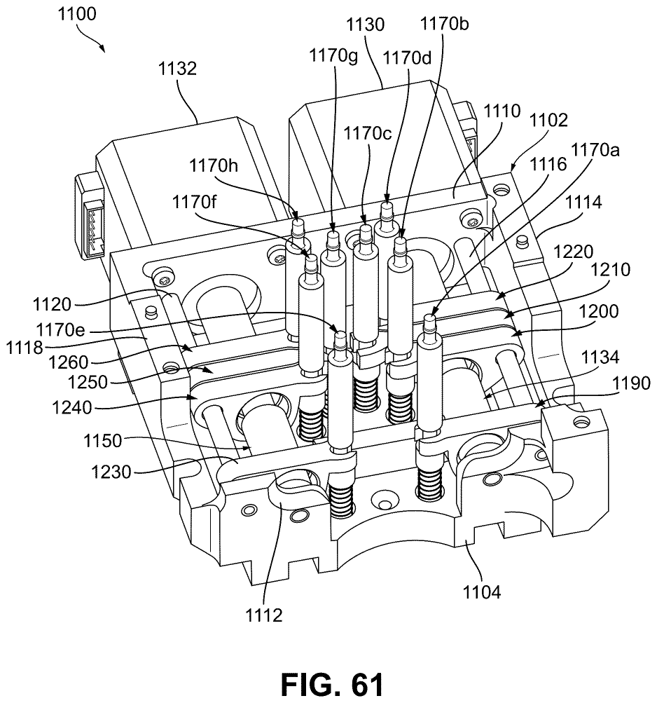

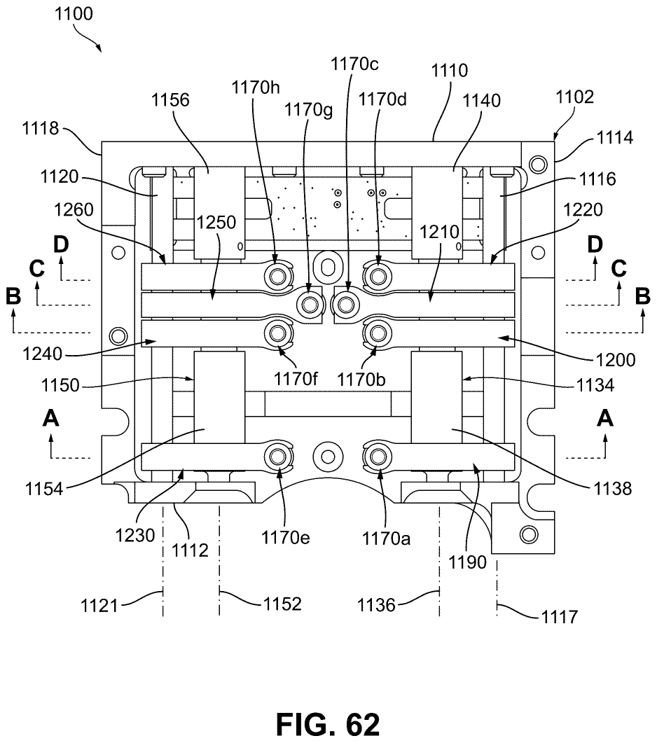

As shown in FIGS. 61 and 62, a second embodiment of second valve actuator is indicated by reference number 1100 and includes a frame 1102 having a bottom wall 1104, an end wall 1110, a front wall 1112, a first side 1114, and a second side 1118. A plurality of valve actuator pistons 1170a, 1170b, 1170c, 1170d, 1170e, 1170f, 1170g, 1170h (eight valve actuator pistons in the illustrated second embodiment) extend upwardly from associated piston openings 1108a-1108h formed in the bottom wall 1104 of the frame 1102. Each of valve actuator pistons 1170a-1170f is operatively engaged with an associated one of eight valves of a cartridge having at least eight valves (not shown) and is movable between a first position corresponding to a closed configuration of the associated valve and a second position corresponding to an open position of the associated valve.

A first motor 1130 and a second motor 1132 may be mounted to end wall 1110 of the frame 1102. Each of motors 1130, 1132 may be a stepper motor. Second valve actuator 1100 includes a first camshaft 1134 and a second camshaft 1150. First motor 1130 is coupled to first camshaft 1134 for effecting powered rotation of the first camshaft 1134 about a first camshaft axis of rotation 1136 corresponding to a longitudinal axis of first camshaft 1134, and second valve actuator 1100 may include an encoder or other sensor mechanism coupled to or otherwise operable with first motor 1130 and in communication with a controller for detecting and controlling a rotational position of the first camshaft 1134. Second motor 1132 is coupled to second camshaft 1150 for effecting powered rotation of the second camshaft 1150 about a second camshaft axis of rotation 1152 corresponding to a longitudinal axis of second camshaft 1150 and parallel to first camshaft axis of rotation 1136, and second valve actuator 1140 may include an encoder or other sensor mechanism coupled to or otherwise operable with second motor 1132 and in communication with a controller for detecting and controlling a rotational position of the second camshaft 1150.

An end of first camshaft 1134 opposite the first motor 758 is rotatably supported at front wall 1112, and an end of second camshaft 1150 opposite the second motor 1132 is rotatably supported at front wall 1112.

First camshaft 1134 includes a first unlobed portion 1138 that is symmetric with respect to the first camshaft axis of rotation 1136, a first cam lobe 1142 that is asymmetric with respect to the first camshaft axis of rotation 1136, a second unlobed portion 1140 that is symmetric with respect to the first camshaft axis of rotation 1136, a second cam lobe 1144 that is asymmetric with respect to the first camshaft axis of rotation 1136, a third cam lobe 1146 that is asymmetric with respect to the first camshaft axis of rotation 1136, and a fourth cam lobe 1148 that is asymmetric with respect to the first camshaft axis of rotation 1136. Second camshaft 1150 includes a first unlobed portion 1154 that is symmetric with respect to the second camshaft axis of rotation 1152, a first cam lobe 1158 that is asymmetric with respect to the second camshaft axis of rotation 1152, a second unlobed portion 1156 that is symmetric with respect to the second camshaft axis of rotation 1152, a second cam lobe 1160 that is asymmetric with respect to the second camshaft axis of rotation 1152, a third cam lobe 1162 that is asymmetric with respect to the second camshaft axis of rotation 1152, and a fourth cam lobe 1164 that is asymmetric with respect to the second camshaft axis of rotation 1152.

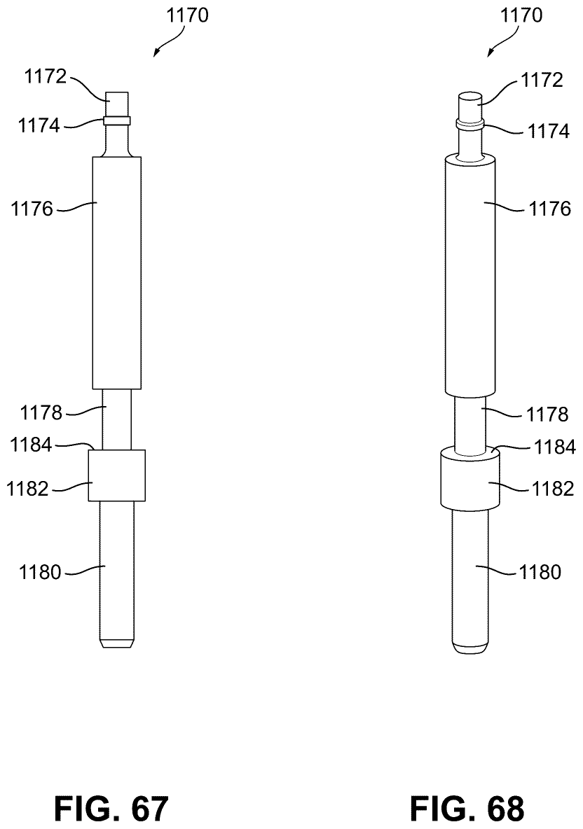

Referring to FIGS. 67 and 68 showing a single valve actuator piston 1170 (valve actuator pistons 1170a-1170h being identical or substantially identical in form factor), each of the valve actuator pistons 1170a-1170h includes a contact rod 1172, a peripheral rib 1174 (optional) surrounding contact rod 1172, an extension 1176, which may be of greater width (diameter if extension 1176 is cylindrical) than contact rod 1172, a lever collar 1178 disposed at a bottom end of the extension 1176 and having a width (e.g., diameter) that is smaller than the width (e.g., diameter) of the extension 1176, and a spring rod 1180. Each valve actuator piston 1170a-1170f extends into an associated opening formed through platform 405 of the cartridge support frame 402 and engages one of the valve actuator heads (such as actuator heads 406 of six-valve cartridge 500). Peripheral rib 1174 may have a width (e.g., diameter if contact rod 1172 is cylindrical) that is somewhat smaller than a width of an opening formed through platform 405 so as to permit the contact rod 1172 to move back and forth within the opening. Moreover, the rib 1174 provides a minimal edge contact between the contact rod 1172 and inner side walls of the opening in platform 405 so as to reduce the likelihood of the contact rod 1172 binding within the opening.

The length of extension 1176—which may be elongated as shown—provides necessary clearance between the second valve actuator 1100 and the cartridge support frame 402, and the increased width of extension 1176 provides increased rigidity to reduce or avoid bending or buckling of the valve actuator piston 1170.

Valve actuator piston 1170 includes a lateral ledge defining a lever seat 1184 engaged by an associated actuator lever to lower the valve actuator piston 1170 as will be described below. In one example, the lever collar 1178 and a top end of an enlargement 1182 between the lever collar 1178 and the spring rod 1180 having a width (e.g., diameter) that is greater than a width of the lever collar 1178 defines the lever seat 1184.

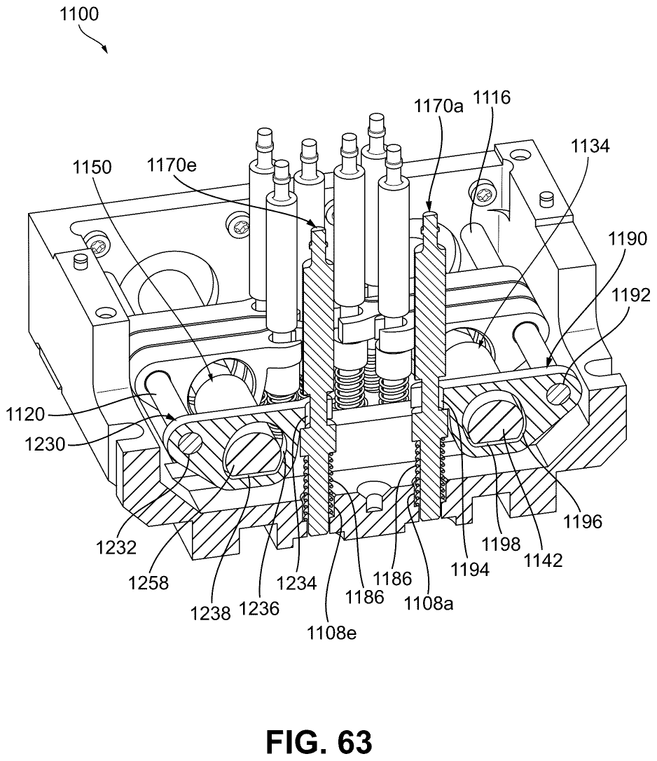

Spring rod 1180 extends through an associated piston opening 1108 and receives a spring 1186 that extends into and bears against an end of an oversized bore formed in a top end of the piston opening 1108 formed in the bottom wall 1104 (see, e.g., openings 1108a and 1108e in FIG. 63) to bias the valve actuator piston 1170 axially upwardly along its longitudinal direction into the first position of the valve actuator piston 1170 to close the associated piston. Spring rod 1180 may have a width (e.g., diameter) that is somewhat smaller than a width of piston opening 1108 so as to permit the rod 1180 to move back and forth within the piston opening 1108.

Valve actuator 1100 further includes an actuator lever associated with each valve actuator piston 1170a-1170h that couples the valve actuator piston to one of the camshafts 1134, 1150. As shown in FIG. 62, first valve actuator piston 1170a is coupled to first camshaft 1134 by a first actuator lever 1190, second valve actuator piston 1170b is coupled to first camshaft 1134 by a second actuator lever 1200, third valve actuator piston 1170c is coupled to first camshaft 1134 by a third actuator lever 1210, fourth valve actuator piston 1170d is coupled to first camshaft 1134 by a fourth actuator lever 1220, fifth valve actuator piston 1170e is coupled to second camshaft 1050 by a fifth actuator lever 1230, sixth valve actuator piston 1170f is coupled to second camshaft 1150 by a sixth actuator lever 1240, seventh valve actuator piston 1170g is coupled to second camshaft 1150 by a seventh actuator lever 1250, and eighth valve actuator piston 1170h is coupled to second camshaft 1150 by an eighth actuator lever 1260.

As shown in FIG. 63, first actuator lever 1190 includes a pivot hole 1192 which captures a pivot rod 1116 extending between back wall 1110 and front wall 1112 on the first side 1114 of frame 1102 to enable first actuator lever 1190 to pivot about a first pivot axis 1117 (see FIG. 62) corresponding to a longitudinal axis of the pivot rod 1116 and which is parallel to first and second camshaft axes 1136, 1152, respectively. First actuator lever 1190 includes a valve actuator piston engagement end 1194 opposite the pivot hole 1192—e.g., a yoke having a semicircular notch—that receives lever collar 1178 of first valve actuator piston 1170a disposed in piston opening 1108a in bottom wall 1104 and is seated on lever seat 1184. In another example, the valve actuator piston does not have a lever collar of reduced width, and a lever seat is defined by a top end of an enlargement, which has a width, e.g., diameter, that is greater than a width of extension 1176. A cam ring 1196 having a flat cam follower surface 1198 of first actuator lever 1190 is engaged by first cam lobe 1142 of first camshaft 1134. As first camshaft 1134 rotates about first camshaft axis of rotation 1136, first cam lobe 1142 engages the cam follower surface 1198 of first actuator lever 1190 once per revolution of the first camshaft 1134 to cause the first actuator lever 1190 to rotate (counter-clockwise in the illustrated example) about first pivot axis 1117. As the first actuator lever 1190 rotates due to engagement by the first cam lobe 1142 of first camshaft 1134, the piston engagement end 1194 of first actuator lever 1190 seated on the lever seat 1184 of first valve actuator piston 1170a pushes down on the first valve actuator piston 1170a to move the first valve actuator piston 1170a from its spring-biased first (valve closed) position to its second (valve open) position to thereby release (open) the associated valve with which the contact rod 1172 of first valve actuator piston 1170a is engaged. As first camshaft 1134 continues to rotate and first cam lobe 1142 disengages from the cam follower surface 1198 of first actuator lever 1190, spring 1186 seated in piston opening 1108a and disposed on spring rod 1180 pushes the first valve actuator piston 1170a upwardly to cause the contact rod 1172 to again close the associated valve.

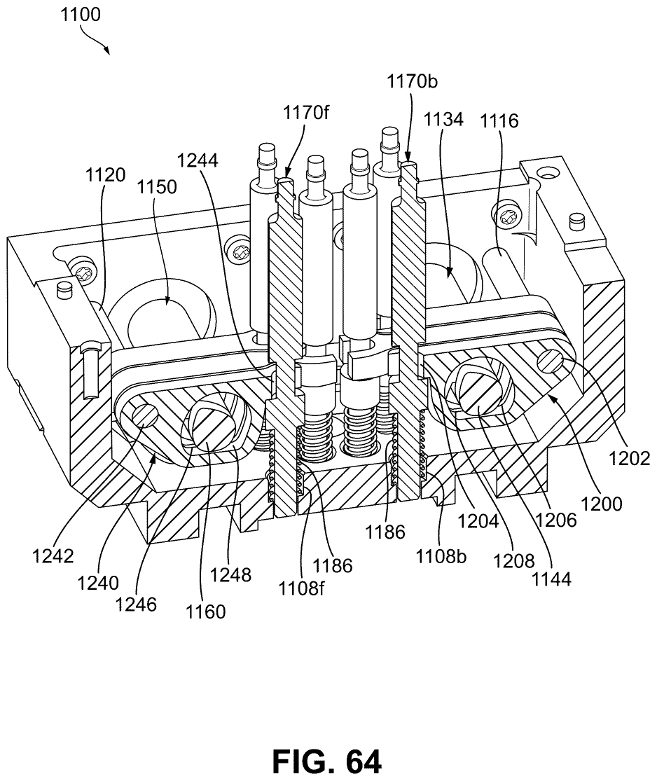

As shown in FIG. 64, second actuator lever 1200 includes a pivot hole 1202 which captures pivot rod 1116 on the first side 1114 of frame 1102 to enable second actuator lever 1200 to pivot about first pivot axis 1117. Second actuator lever 1200 includes a valve actuator piston engagement end 1204 opposite the pivot hole 1202—e.g., a yoke having a semicircular notch—that receives lever collar 1178 of second valve actuator piston 1170b disposed in piston opening 1108b in bottom wall 1104 and is seated on lever seat 1184. A cam ring 1206 having a flat cam follower surface 1208 of second actuator lever 1200 is engaged by second cam lobe 1144 of first camshaft 1134. As first camshaft 1134 rotates about first camshaft axis of rotation 1136, second cam lobe 1144 engages the cam follower surface 1208 of second actuator lever 1200 once per revolution of the first camshaft 1134 to cause the second actuator lever 1200 to rotate (counter-clockwise in the illustrated example) about first pivot axis 1117. As the second actuator lever 1200 rotates due to engagement by the second cam lobe 1144 of first camshaft 1134, the piston engagement end 1204 of second actuator lever 1200 seated on the lever seat 1184 of second valve actuator piston 1170b pushes down on the second valve actuator piston 1170b to move the second valve actuator piston 1170b from its spring-biased first (valve closed) position to its second (valve open) position to thereby release (open) the associated valve with which the contact rod 1172 of second valve actuator piston 1170b is engaged. As first camshaft 1134 continues to rotate and second cam lobe 1144 disengages from the cam follower surface 1208 of second actuator lever 1200, spring 1186 seated in piston opening 1108b and disposed on spring rod 1180 pushes the second valve actuator piston 1170b upwardly to cause the contact rod 1172 to again close the associated valve.

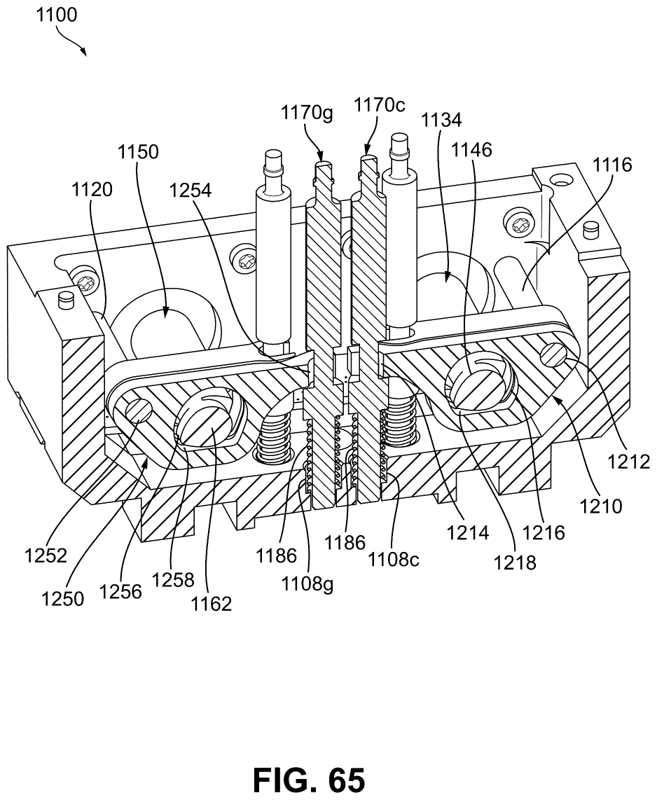

As shown in FIG. 65, third actuator lever 1210 includes a pivot hole 1212 which captures pivot rod 1116 on the first side 1114 of frame 1102 to enable third actuator lever 1210 to pivot about first pivot axis 1117. Third actuator lever 1210 includes a valve actuator piston engagement end 1214 opposite the pivot hole 1212—e.g., a yoke having a semicircular notch—that receives lever collar 1178 of third valve actuator piston 1170c disposed in piston opening 1108c in bottom wall 1104 and is seated on lever seat 1184. A cam ring 1216 having a flat cam follower surface 1218 of third actuator lever 1210 is engaged by third cam lobe 1146 of first camshaft 1134. As first camshaft 1134 rotates about first camshaft axis of rotation 1136, third cam lobe 1146 engages the cam follower surface 1218 of third actuator lever 1210 once per revolution of the first camshaft 1134 to cause the third actuator lever 1210 to rotate (counter-clockwise in the illustrated example) about first pivot axis 1117. As the third actuator lever 1210 rotates due to engagement by the third cam lobe 1146 of first camshaft 1134, the piston engagement end 1214 of third actuator lever 1210 seated on the lever seat 1184 of third valve actuator piston 1170c pushes down on the third valve actuator piston 1170c to move the third valve actuator piston 1170c from its spring-biased first (valve closed) position to its second (valve open) position to thereby release (open) the associated valve with which the contact rod 1172 of third valve actuator piston 1170c is engaged. As first camshaft 1134 continues to rotate and third cam lobe 1146 disengages from the cam follower surface 1218 of third actuator lever 1210, spring 1186 seated in piston opening 1108c and disposed on spring rod 1180 pushes the third valve actuator piston 1170c upwardly to cause the contact rod 1172 to again close the associated valve.

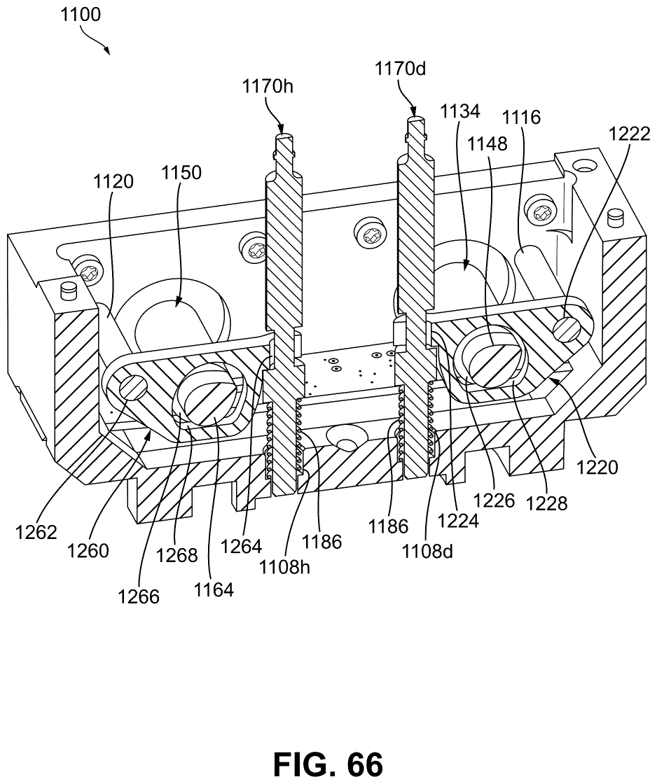

As shown in FIG. 66, fourth actuator lever 1220 includes a pivot hole 1222 which captures pivot rod 1116 on the first side 1114 of frame 1102 to enable fourth actuator lever 1220 to pivot about first pivot axis 1117. Fourth actuator lever 1220 includes a valve actuator piston engagement end 1224 opposite the pivot hole 1222—e.g., a yoke having a semicircular notch—that receives lever collar 1178 of fourth valve actuator piston 1170d disposed in piston opening 1108d in bottom wall 1104 and is seated on lever seat 1184. A cam ring 1226 having a flat cam follower surface 1228 of fourth actuator lever 1220 is engaged by fourth cam lobe 1148 of first camshaft 1134. As first camshaft 1134 rotates about first camshaft axis of rotation 1136, fourth cam lobe 1148 engages the cam follower surface 1228 of fourth actuator lever 1220 once per revolution of the first camshaft 1134 to cause the fourth actuator lever 1220 to rotate (counter-clockwise in the illustrated example) about first pivot axis 1117. As the fourth actuator lever 1220 rotates due to engagement by the fourth cam lobe 1148 of first camshaft 1134, the piston engagement end 1224 of fourth actuator lever 1220 seated on the lever seat 1184 of fourth valve actuator piston 1170d pushes down on the fourth valve actuator piston 1170d to move the fourth valve actuator piston 1170d from its spring-biased first (valve closed) position to its second (valve open) position to thereby release (open) the associated valve with which the contact rod 1172 of fourth valve actuator piston 1170d is engaged. As first camshaft 1134 continues to rotate and fourth cam lobe 1148 disengages from the cam follower surface 1228 of fourth actuator lever 1220, spring 1186 seated in piston opening 1108d and disposed on spring rod 1180 pushes the fourth valve actuator piston 1170d upwardly to cause the contact rod 1172 to again close the associated valve.

As shown in FIG. 63, fifth actuator lever 1230 includes a pivot hole 1232 which captures a second pivot rod 1120 extending between back wall 1110 and front wall 1112 on the second side 1118 of frame 1102 to enable fifth actuator lever 1230 to pivot about a second pivot axis 1121 (see FIG. 62) corresponding to a longitudinal axis of the pivot rod 1120 and which is parallel to first and second camshaft axes 1136, 1152, respectively, and to first pivot axis 1117. Fifth actuator lever 1230 includes a valve actuator piston engagement end 1234 opposite the pivot hole 1232—e.g., a yoke having a semicircular notch—that receives lever collar 1178 of fifth valve actuator piston 1170e disposed in piston opening 1108e in bottom wall 1104 and is seated on lever seat 1184. A cam ring 1236 having a flat cam follower surface 1238 of fifth actuator lever 1230 is engaged by first cam lobe 1158 of second camshaft 1150. As second camshaft 1150 rotates about second camshaft axis of rotation 1152, first cam lobe 1158 engages the cam follower surface 1238 of fifth actuator lever 1230 once per revolution of the second camshaft 1150 to cause the fifth actuator lever 1230 to rotate (clockwise in the illustrated example) about second pivot axis 1121. As the fifth actuator lever 1230 rotates due to engagement by the first cam lobe 1158 of second camshaft 1150, the piston engagement end 1234 of fifth actuator lever 1230 seated on the lever seat 1184 of fifth valve actuator piston 1170e pushes down on the fifth valve actuator piston 1170e to move the fifth valve actuator piston 1170e from its spring-biased first (valve closed) position to its second (valve open) position to thereby release (open) the associated valve with which the contact rod 1172 of fifth valve actuator piston 1170e is engaged. As second camshaft 1150 continues to rotate and first cam lobe 1158 disengages from the cam follower surface 1238 of fifth actuator lever 1230, spring 1186 seated in piston opening 1108e and disposed on spring rod 1180 pushes the fifth valve actuator piston 1170e upwardly to cause the contact rod 1172 to again close the associated valve.

As shown in FIG. 64, sixth actuator lever 1240 includes a pivot hole 1242 which captures second pivot rod 1120 on the second side 1118 of frame 1102 to enable sixth actuator lever 1240 to pivot about second pivot axis 1121. Sixth actuator lever 1240 includes a valve actuator piston engagement end 1244 opposite the pivot hole 1242—e.g., a yoke having a semicircular notch—that receives lever collar 1178 of sixth valve actuator piston 1170f disposed in piston opening 1108f in bottom wall 1104 and is seated on lever seat 1184. A cam ring 1246 having a flat cam follower surface 1248 of sixth actuator lever 1240 is engaged by second cam lobe 1160 of second camshaft 1150. As second camshaft 1150 rotates about second camshaft axis of rotation 1152, second cam lobe 1160 engages the cam follower surface 1248 of sixth actuator lever 1240 once per revolution of the second camshaft 1150 to cause the sixth actuator lever 1240 to rotate (clockwise in the illustrated example) about second pivot axis 1121. As the sixth actuator lever 1240 rotates due to engagement by the second cam lobe 1160 of second camshaft 1150, the piston engagement end 1244 of sixth actuator lever 1240 seated on the lever seat 1184 of sixth valve actuator piston 1170f pushes down on the sixth valve actuator piston 1170f to move the sixth valve actuator piston 1170f from its spring-biased first (valve closed) position to its second (valve open) position to thereby release (open) the associated valve with which the contact rod 1172 of sixth valve actuator piston 1170f is engaged. As second camshaft 1150 continues to rotate and second cam lobe 1160 disengages from the cam follower surface 1248 of sixth actuator lever 1240, spring 1186 seated in piston opening 1108f and disposed on spring rod 1180 pushes the sixth valve actuator piston 1170f upwardly to cause the contact rod 1172 to again close the associated valve.

As shown in FIG. 65, seventh actuator lever 1250 includes a pivot hole 1252 which captures second pivot rod 1120 on the second side 1118 of frame 1102 to enable seventh actuator lever 1250 to pivot about second pivot axis 1121. Seventh actuator lever 1250 includes a valve actuator piston engagement end 1254 opposite the pivot hole 1252—e.g., a yoke having a semicircular notch—that receives lever collar 1178 of seventh valve actuator piston 1170g disposed in piston opening 1108g in bottom wall 1104 and is seated on lever seat 1184. A cam ring 1256 having a flat cam follower surface 1258 of seventh actuator lever 1250 is engaged by third cam lobe 1162 of second camshaft 1150. As second camshaft 1150 rotates about second camshaft axis of rotation 1152, third cam lobe 1162 engages the cam follower surface 1258 of seventh actuator lever 1250 once per revolution of the second camshaft 1150 to cause the seventh actuator lever 1250 to rotate (clockwise in the illustrated example) about second pivot axis 1121. As the seventh actuator lever 1250 rotates due to engagement by the third cam lobe 1162 of second camshaft 1150, the piston engagement end 1254 of seventh actuator lever 1250 seated on the lever seat 1184 of seventh valve actuator piston 1170g pushes down on the seventh valve actuator piston 1170g to move the seventh valve actuator piston 1170g from its spring-biased first (valve closed) position to its second (valve open) position to thereby release (open) the associated valve with which the contact rod 1172 of seventh valve actuator piston 1170g is engaged. As second camshaft 1150 continues to rotate and third cam lobe 1162 disengages from the cam follower surface 1258 of seventh actuator lever 1250, spring 1186 seated in piston opening 1108g and disposed on spring rod 1180 pushes the seventh valve actuator piston 1170g upwardly to cause the contact rod 1172 to again close the associated valve.

As shown in FIG. 66, eighth actuator lever 1260 includes a pivot hole 1262 which captures second pivot rod 1120 on the second side 1118 of frame 1102 to enable eighth actuator lever 1260 to pivot about second pivot axis 1121. Eighth actuator lever 1260 includes a valve actuator piston engagement end 1264 opposite the pivot hole 1262—e.g., a yoke having a semicircular notch—that receives lever collar 1178 of eighth valve actuator piston 1170h disposed in piston opening 1108h in bottom wall 1104 and is seated on lever seat 1184. A cam ring 1266 having a flat cam follower surface 1268 of eighth actuator lever 1260 is engaged by fourth cam lobe 1164 of second camshaft 1150. As second camshaft 1150 rotates about second camshaft axis of rotation 1152, fourth cam lobe 1164 engages the cam follower surface 1268 of eighth actuator lever 1260 once per revolution of the second camshaft 1150 to cause the eighth actuator lever 1260 to rotate (clockwise in the illustrated example) about second pivot axis 1121. As the eighth actuator lever 1260 rotates due to engagement by the fourth cam lobe 1164 of second camshaft 1150, the piston engagement end 1264 of eighth actuator lever 1260 seated on the lever seat 1184 of eighth valve actuator piston 1170h pushes down on the eighth valve actuator piston 1170h to move the eighth valve actuator piston 1170h from its spring-biased first (valve closed) position to its second (valve open) position to thereby release (open) the associated valve with which the contact rod 1172 of eighth valve actuator piston 1170h is engaged. As second camshaft 1150 continues to rotate and fourth cam lobe 1164 disengages from the cam follower surface 1268 of eighth actuator lever 1260, spring 1186 seated in piston opening 1108h and disposed on spring rod 1180 pushes the eighth valve actuator piston 1170h upwardly to cause the contact rod 1172 to again close the associated valve.

The lobes of the camshafts 1134, 1150 can be configured, and the motors 1130, 1132 can be programmed to operate, to actuate the actuator levers 1190, 1200, 1210, 1220, 1230, 1240, 1250, 1260 and associated valve actuator pistons 1170a, 1170b, 1170c, 1170d, 1170e, 1170f, 1170g, 1170h, respectively, in a desired synchronization during rotation of the camshafts to selectively open and close valves in the cartridge in accordance with desired fluid movement through the cartridge.

In a variation of the second embodiment of second valve actuator 1100, the actuator levers could be pivotably coupled with the frame 1102 by pivot anchors and pivot sockets and/or each actuator lever could include a cam surface on top of the lever (as opposed to being within a cam ring)—as with the actuator levers of first embodiment of second valve actuator 740. Similarly, in a variation of the first embodiment of second valve actuator 740, the actuator levers could be pivotably coupled with the frame 742 by a pivot rod extending through a pivot hole formed through the lever and/or each actuator lever could include a cam surface within a cam ring—as with the actuator levers of second embodiment of second valve actuator 1100.

In a system for processing samples on a fluidic cartridge having only circularly-arranged valves, such as sample preparation (or process) valves V1 to V12, the system or instrument may include only the first valve actuator 1300, and in a system for processing samples on a fluidic cartridge having only non-circularly-arranged valves, such as reaction valves V13 to V18, the system or instrument may include only the second valve actuator 740 or 1100.

### Syringe Driver

Referring to FIGS. 1, 2, and 20, syringe driver 360 comprises a motor 368, which is preferably a servo motor, operatively coupled to a syringe plunger 362 for effecting axial, up-and-down movement of the syringe plunger 362. In this context, a servo motor is an electromechanical device that produces torque and velocity based on the supplied current and voltage and operated under feedback control and may be a brushless DC motor or any other motor capable of operation under feedback control. Plunger 362 includes the plunger head 364 defined by a groove circumscribing the syringe plunger 362 above an end of the syringe plunger and configured to engage the plunger recess 546 formed in the stopper 540, and the plunger head 364 seats in the plunger pocket 548. Syringe plunger 362 further includes laterally-extending plunger ribs, or posts, 366. Motor 368 is supported on a drive block 380, which may be attached to, or is otherwise fixed with respect to, side supports 306a, 306b and/or intermediate crossbar 310 of the motor mount 314. An encoder 370 (e.g., a rotary encoder) may be a coupled to the motor 368. Motor 368 turns a lead screw 372 coupled to a drive follower 374. Drive follower 374 is mounted to a drive bracket 376 in such a manner as to resist movement or rotation of the follower 374 with respect to the drive bracket 376. An end of the syringe plunger 362 is fixed to the drive bracket 376 (also so as to resist movement and or rotation of the syringe plunger 362 with respect to the drive bracket 376) at an end of the bracket 376 opposite the end at which the drive follower 374 is attached to the bracket 376. Plunger 362 extends through a bushing 382 disposed within the drive block 380. Rotation of the drive screw 372 by the motor 368 causes corresponding up or down movement of the drive follower 374, and the motion of the drive follower 374 is transmitted to the syringe plunger 362 by the drive bracket 376. The bushing 382 prevents binding of the syringe plunger 362 caused by the off-axis application of force to the syringe plunger 362 by the lead screw 372, follower 374, and drive bracket 376.

The syringe driver 360 may further include a sensor for detecting when, or confirming that, the syringe driver 360 has moved the syringe plunger 362 to a specified position (e.g., a “home” position). In the illustrated embodiment, drive bracket 376 includes a home tab 378 extending therefrom, and a home sensor 384 (e.g., a slotted optical detector) is positioned to detect the presence of the home tab 378 when the drive bracket 376 and the syringe plunger 362 are at a home position, which, in the illustrated example, is the top-most position of the syringe plunger 362.

To engage the stopper 540 of a cartridge 500 positioned below the syringe driver 360, the syringe plunger 362 is lowered by the motor 368 of the syringe driver 360 and passes through a syringe a drive hole 304 formed in the upper block 302. As the syringe plunger 362 descends, the lower end of the syringe plunger enters into the blocker 570. The outer diameter of the syringe plunger 362 is smaller than the inner diameter of the center tube 586 of the blocker 570, thereby enabling the syringe plunger 362 to do to descend into the center tube 586. The width of the syringe plunger 362 at the plunger ribs 366 is greater than the inner diameter of the center tube 586 of the blocker 570. Radial clearances 577a, 577b allow the plunger ribs 366 to pass into the stopper as the syringe plunger 362 continues to descend into the center tube 586, and the plunger ribs 366 engage the cam edges 590a, 590b of the cam walls 588a, 588b, respectively. Due to the helical curvature of the cam edges 590a, 590b, the descending plunger ribs 366 engaging the cam edges 590a, 590b causes the blocker 570 to rotate with respect to the blocker ring 550. Rotation of the blocker 570 moves the flanges 584a, 584b, 584c of the blocker 570 out of overlapping engagement with the flanges 558a, 558b, 558c of the blocker ring 550, thereby releasing the blocker 570 from the blocker ring 550. The plunger head 364 is received within the plunger pocket 548 of the stopper 540, and, with the blocker 570 released from the blocker ring 550, the syringe driver 360 is able to move the stopper 540 up and down within the syringe barrel SB via the syringe plunger 362. To ensure that the plunger head 364 is received within the plunger pocket 548 of the stopper 540, motor 368 may be operated to lower the syringe plunger 362 until motor stall. With the blocker 570 released from the blocker ring 550, and the stopper 540 attached to the plunger head 364 at the end of the syringe plunger 362, the blocker 570 is held onto the end of the plunger 362 by the stopper 540 and moves up and down with the plunger 362 and stopper 540. When the stopper 540 is first raised from the bottom of the syringe barrel SB after connecting stopper 540 to the syringe plunger 362, one of the valves V1 to V10 between one of the through holes H1c to H10c and an empty one of the chambers W1 to W10 may be opened to vent the system and avoid generating a vacuum within the syringe barrel SB as the stopper 540 is raised.

Syringe driver 360, via plunger 362 engaged with the elastomeric stopper 540, moves the stopper 540 up within the barrel SB to create a vacuum to draw fluids from other chambers of the cartridge into the barrel SB or moves the stopper 540 down within the barrel SB to create pressure to move fluids from the barrel SB to other chambers or reaction chambers of the cartridge. The volume of fluid that is drawn into the barrel SB when the stopper is raised corresponds to the volume of space between the bottom of the barrel SB and the bottom of the stopper, which in turn corresponds to the distance the stopper is raised above the bottom of the barrel. When the syringe plunger and stopper are moved down to the bottom of the barrel, the elastomeric stopper will compress to some extent, which is desired to ensure that most or all fluid is expelled from the barrel SB. Accordingly, when the syringe plunger is reversed to raise the stopper, some amount of that upward movement results in the uncompressing (rebound) of the stopper without actually raising the stopper above the bottom of the barrel. It is unknown how much compression the stopper has been subjected to when it is pressed against the bottom of the barrel. Some amount of rebound in the stopper is expected when the syringe plunger is retracted, but the exact amount may not be precisely known and may vary from instrument to instrument and cartridge to cartridge (e.g., from stopper to stopper). Accordingly, precise control of the amount the stopper is raised above the bottom of the barrel SB is a challenge. In addition, variations in the thicknesses of the cartridge and stopper, possible bowing in the cartridge, and other manufacturing and mechanical tolerances can affect the precision of the movement of the stopper, and thus the precision of the volume drawn into the barrel SB by the syringe.

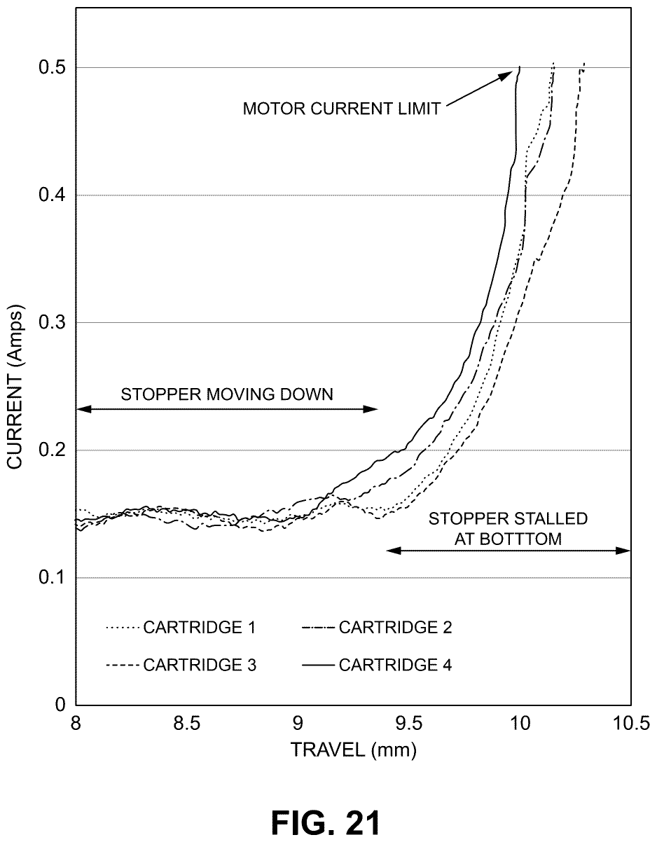

To address these challenges, motor 368 is a motor, such as a servo motor, for which electrical current (amps) drawn by the motor is proportional to resistance encountered (or force/torque generated) by the motor. FIG. 21 is a plot of motor current demand versus stopper travel for four different fluidic cartridges. Motor voltage (volts) and/or motor power demand (watts) and/or any motor operational parameter that is directly or indirectly proportional to motor output, such as resistance or torque, can be monitored instead of or in addition to motor current demand. As the stoppers move from 8.0 to 9.1 mm, current drawn by the motor is a relatively constant level between 0.14 and 0.16 amps. But after about 9.1 mm to 9.4 mm of stopper travel (depending on the cartridge), the motor current demand curve for each cartridge experiences a steep increase. The initiation of the steep rise (or inflection) of each curve represents the point of travel at which the stopper 540 contacts the bottom of the syringe barrel SB. Current to the motor will increase along this steep portion of the curve until the motor current demand limit (or motor current limit) is reached (0.5 amps in the illustration), indicating that the motor has stalled at a travel of 10.1 mm to 10.3 mm and there is no further downward movement or compression of the stopper. Motor stall can also be detected by the encoder 570 detecting no further movement (rotation) by the motor 368. The encoder 370 counts a number of steps before motor stall to track the amount of movement (e.g., rotation) of the motor 368 between the inflection point (i.e., initiation of the steep portion of the motor current curve) and motor stall (motor current limit reached). When the syringe plunger is withdrawn, the syringe plunger 362 is moved by motor 368 of syringe driver 360 by the same number of steps to uncompress the stopper and position that plunger at the position at which the motor current inflection occurred—i.e., the point at which the stopper first contacts the bottom of the syringe barrel SB. Next, the motor 368 can be operated for a specified number of encoder steps to move stopper to a specified position above the bottom of the syringe barrel.

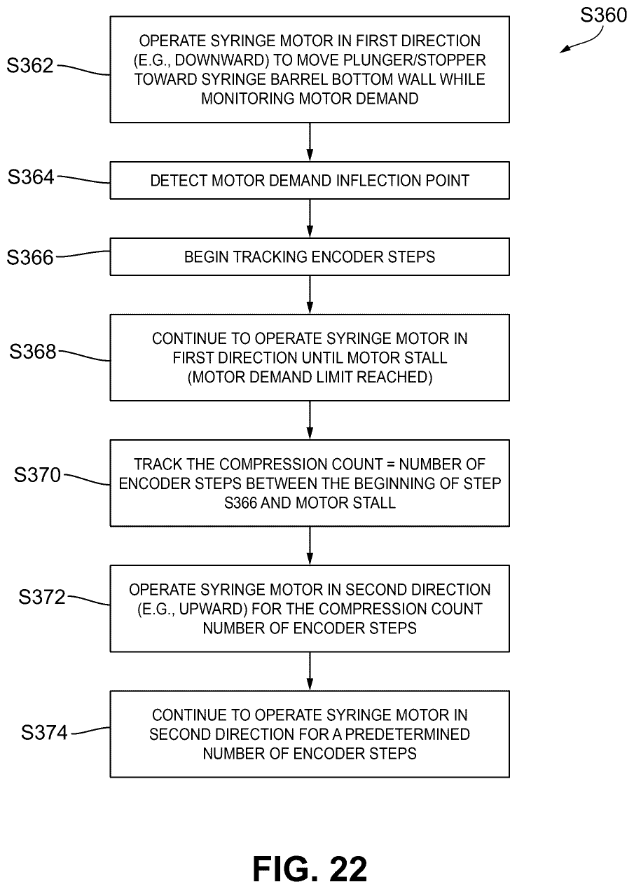

FIG. 22 shows a flow diagram illustrating a method S360 for using the demand (e.g., current drawn) of the motor 368 and the output of the encoder 370 to control the position of the stopper 540 and thus the volume of fluid drawn into the syringe barrel SB. Method S360 may be performed with or used in conjunction with a controller comprising any of the computer systems, devices, mechanisms, elements, or components disclosed herein, among other devices. Method S360 may be coded and stored as a computer-executable control algorithm for controlling the operation(s) of one or more of the computer systems, devices, mechanisms, elements, or components disclosed herein, among other devices. In various embodiments, some of the method steps shown may be performed concurrently, in a different order than shown, or may be omitted. Additional method steps may also be performed as desired. Flow begins at step S362.

To lower the stopper 540 to the bottom of the syringe barrel SB, in step S362, the controller operates syringe motor 368 in a first direction (e.g., downward) to move the syringe plunger 362 and the stopper 540 toward the bottom of the syringe barrel SB while monitoring motor demand (e.g., current drawn) by the motor 368.

In step S364, the controller detects an inflection point in the motor demand signal by any known means, such as, by detecting a change in signal magnitude that exceeds a predefined magnitude or by detecting a signal slope (first derivative of signal magnitude) or change in signal slope (second derivative of signal magnitude) that exceeds a predefined threshold. The stopper 540 has now contacted the bottom of the syringe barrel SB. The amount of change in the demand signal that is indicative of an inflection may vary, for example, with the hardness (durometer) of the stopper 540. In some instances, a change of about 10% may indicate an inflection. The amount of change that is defined as a threshold indicating an inflection point may be system-dependent. In addition, the manner of detecting a change in signal may be system dependent. For example, if inflection is detected by a change in magnitude of the motor demand signal by subtracting one motor demand value from an earlier value, the time span between comparisons—e.g., between consecutive demand signals, every other demand signal, every fifth demand signal, etc.—can be system dependent. If inflection is detected by a change in slope of the motor demand calculated by subtracting one motor demand value from an earlier value and dividing the difference by the time span between the first and second values, the time span between the first and second values—e.g., consecutive demand signals, every other demand signal, every fifth demand signal, etc.—can be system dependent.

In step S366, upon detecting a motor demand inflection point in step S364, the controller begins tracking steps of the encoder 370.

In step S368, the controller continues to operate motor 368 in the first direction until controller detects the motor demand limit reached indicating the motor is stalled.

In step S370, the controller records the number of encoder steps between the beginning of step S366 and motor stall. Since operation of the motor during step S368 primarily results in compression of the stopper 540, the number of encoder steps to motor stall will be referred to as the compression count.

To raise the stopper 540 from the bottom of the syringe barrel SB, in step S372, the controller operates motor 368 in a second direction (e.g., upward) for the compression count number of steps of the encoder 370. This raises the syringe plunger 362 back to the position at which the inflection point was detected in step S364 (i.e., the position at which the stopper 540 first contacted the bottom of the syringe barrel SB).

In step S374, the controller operates motor 368 in the second direction for a predetermined number of steps of the encoder 370. Operating the motor 368 for the predetermined number of steps of the encoder 370 moves the syringe plunger 362 and the stopper 540 to a desired position above the bottom of the syringe barrel SB.

To remove the stopper 540 and the blocker 570 from the end of the syringe plunger 362, the syringe plunger is raised within the syringe barrel SB until the stopper 540 contacts the blocker ring 550. As the diameter of the stopper 540 is larger than the inner diameter of the annular rim 552 of the blocker ring 550, the stopper 540 cannot move past the blocker ring 550 and continued upward movement of the syringe plunger 362 will withdraw the plunger head 364 of the syringe plunger 362 from the plunger pocket 548 of the stopper 540. To facilitate removal of the stopper 540 from the syringe plunger 362, valves V1 to V10 connected to center through holes H1c to H10c within the syringe barrel SB may be closed, thus creating a vacuum within the syringe barrel SB below the stopper 540 as the syringe plunger 362 and stopper 540 are raised within the syringe barrel SB, which may assist in pulling the stopper 540 off the end of the syringe plunger 362. With plunger head 364 withdrawn from the plunger pocket 548, the syringe plunger 362 is raised so that the end of the syringe plunger 362 is withdrawn from the plunger recess 546 of the stopper 540, but preferably without completely raising the syringe plunger 362 above the syringe barrel SB or the stopper ring 550. The syringe plunger 362 is then lowered into the syringe barrel SB where the end of the syringe plunger 362 contacts the stopper 540, and the syringe plunger 362 is further lowered to push the stopper 540 to the bottom of the syringe barrel SB, but without applying enough force to insert the plunger head 364 into the plunger pocket 548 of the stopper 540. The syringe plunger 362 is then withdrawn from the syringe barrel SB, and, with the stopper 540 no longer attached to the end of the syringe plunger 362, the blocker 570 will not be retained on the syringe plunger 362. The blocker 570 will slip off the end of the syringe plunger 362 with the cap portion 572 of the blocker 570 resting on the blocker ring 550 and the center tube 586 of the blocker 570 extending into the syringe barrel SB.

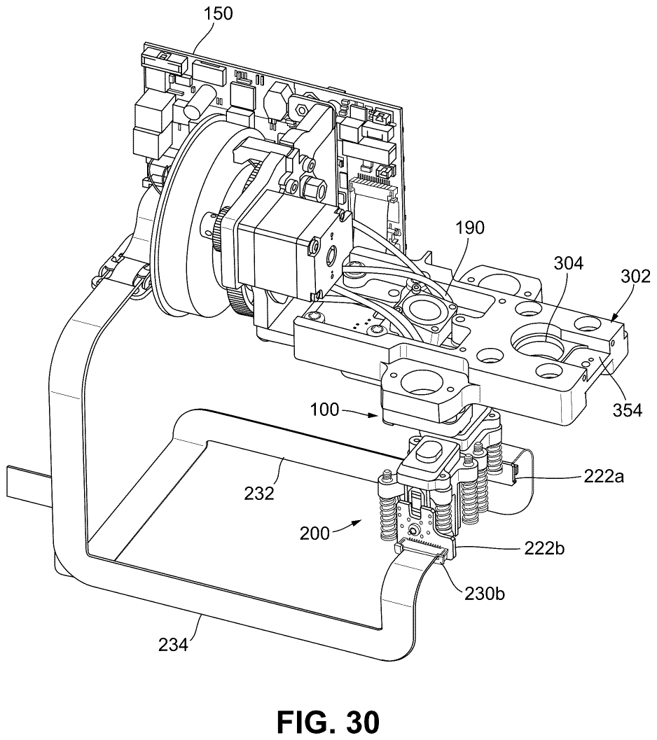

Referring to FIG. 30, which is a partial view of the instrument 10, instrument 10 includes a first thermal module (or first heater) 100 attached to the upper block 302 of the upper chassis and a second thermal module (or second heater) 200 that is part of the lower chassis for applying heat to the reaction/detection chambers 510a1, 510a2, 510b1, 510b2 of the cartridge 500 that is received between the first and second thermal modules/heaters. In the illustrated embodiment, when the cartridge 500 is placed in the instrument 10 (i.e., cartridge 500 is placed on holder 412, and holder 412 is moved to the retracted position), the second thermal module 200 engages the bottom side of the cartridge 500 at the reaction/detection chambers 510a1, 510a2, 510b1, 510b2, and the first thermal module 100 engages a top side of the cartridge 500 at the reaction/detection chambers 510a1, 510a2, 510b1, 510b2 when the upper block 302 is lowered with respect to the cartridge holder 412. In the illustrated embodiment, first thermal module 100 is disposed vertically above the second thermal module 200, so thermal modules 100, 200 may be referred to herein as the upper thermal module 100 and lower thermal module 200. Relative positions of the first and second thermal modules 100, 200 are not critical; second thermal module 200 may be located vertically above first thermal module 100, or first and second thermal modules 100, 200 may be located laterally side-by-side.

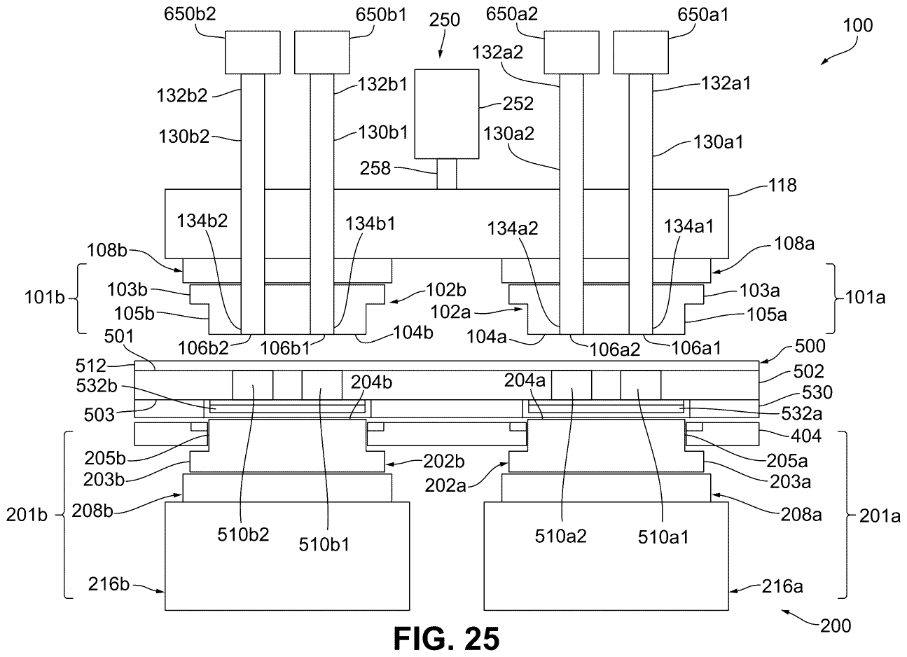

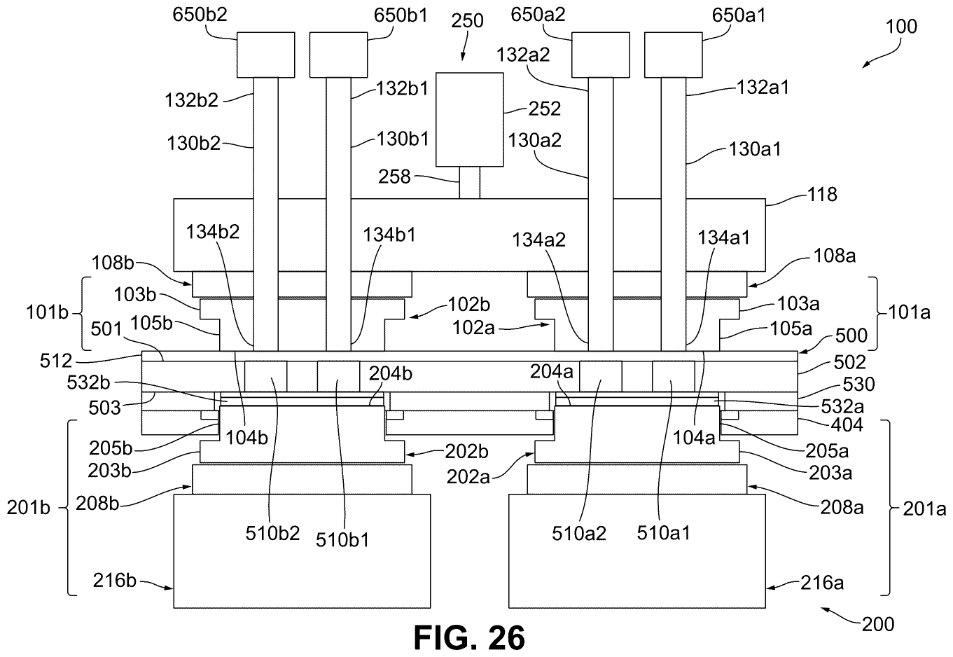

FIGS. 25 and 26 are schematic cross-sections through the first and second thermal modules 100, 200 and through the reaction/detection chambers 510a1, 510a2, 510b1, 510b2 of cartridge 500. To avoid over-cluttering the drawings, cross-sectional lines are omitted from FIGS. 25 and 26. In the illustrated embodiment, cartridge 500 comprises cartridge body 502 having grooves and/or cavities formed therein as described above with top film 512 affixed to the top face 501 and bottom film 530 affixed to the bottom face 503 of the cartridge body to form channels and reaction chambers of the cartridge 500. In FIGS. 25 and 26, top film 512 and bottom film 530 enclose cavities to the form reaction/detection chambers 510a1, 510a2, 510b1, 510b2. In FIG. 25 the first thermal module 100 is not in contact with the reaction/detection chambers 510a1, 510a2, 510b1, 510b2, and in FIG. 26 the first thermal module 100 is in contact with the reaction/detection chambers 510a1, 510a2, 510b1, 510b2. As will be described below, one or both of the first thermal module 100 and the second thermal module 200 is movable with respect to other so that the first and second thermal modules can be moved into and out of mutual engagement (contact) with the reaction/detection chambers 510a1, 510a2, 510b1, 510b2 of the cartridge 500.

In the illustrated embodiment, first thermal module 100 includes a first thermal assembly 101a and a second thermal assembly 101b that may be independent of the first thermal assembly. Similarly, second thermal module 200 includes a first thermal assembly 201a and a second thermal assembly 201b that may be independent of the first thermal assembly. First thermal assembly 101a of first thermal module 100 is associated with first thermal assembly 201a of second thermal module 200, and together the first thermal assemblies 101a and 201a are associated with reaction/detection chambers 510a1, 510a2 of the cartridge 500. Similarly, second thermal assembly 101b of first thermal module 100 is associated with second thermal assembly 201b of second thermal module 200, and together the second thermal assemblies 101b and 201b are associated with reaction/detection chambers 510b1, 510b2 of the cartridge 500. In the illustrated embodiment, first thermal module 100 includes two thermal assemblies 101a, 101b, and second thermal module 200 includes two thermal assemblies 201a, 201b. First and second thermal modules 100, 200 may include a number of thermal assemblies corresponding to the number of reaction/detection chambers of the cartridge 500, or each thermal assembly may be configured (i.e., sized and shaped) to engage more than one reaction/detection chamber, and thus, the first and second thermal modules 100, 200 may each have more or less than two thermal assemblies, depending on the number of reaction/detection chambers of the cartridge or the configuration of each thermal assembly.

### First Thermal Module

Referring to FIGS. 25 and 26, first thermal assembly 101a of first (upper) thermal module 100 includes a thermal element 108a (which may comprise a thermoelectric module, such as a Peltier device, or any other device, mechanism, or system, other than a light source, that heats, cools, or selectively heats or cools) and an associated thermal block 102a disposed in thermal contact with the thermal element 108a. Thermal block 102a may include a base portion 103a, which is in contact with thermal element 108a, and a projection 105a, which defines an exposed contact surface 104a that contacts the cartridge 500 at the reaction/detection chambers 510a1, 510a2.

Second thermal assembly 101b of first thermal module 100 includes a thermal element 108b (which may comprise a thermoelectric module, such as a Peltier device, or any other device, mechanism, or system, other than a light source, that heats, cools, or selectively heats or cools) and an associated thermal block 102b disposed in thermal contact with the thermal element 108b. Thermal block 102b may include a base portion 103b, which may be in contact with thermal element 108b, and a projection 105b which defines an exposed contact surface 104b that contacts the cartridge 500 at the reaction/detection chambers 510b1, 510b2. Thus, in the illustrated example, contact surface 104a contacts a group of chambers including 510a1, 510a2, and contact surface 104b contacts a group of chambers including 510b1, 510b2.

Thermal blocks 102a, 102b are preferably made (e.g., molded and/or machined) from a thermally conductive material, such as a thermally-conductive ceramic or a metal, such as aluminum.

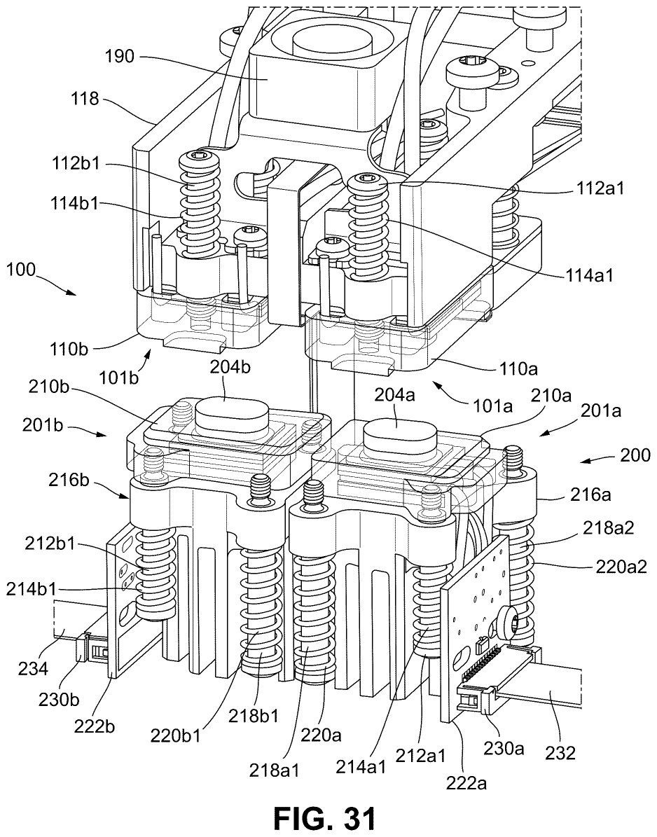

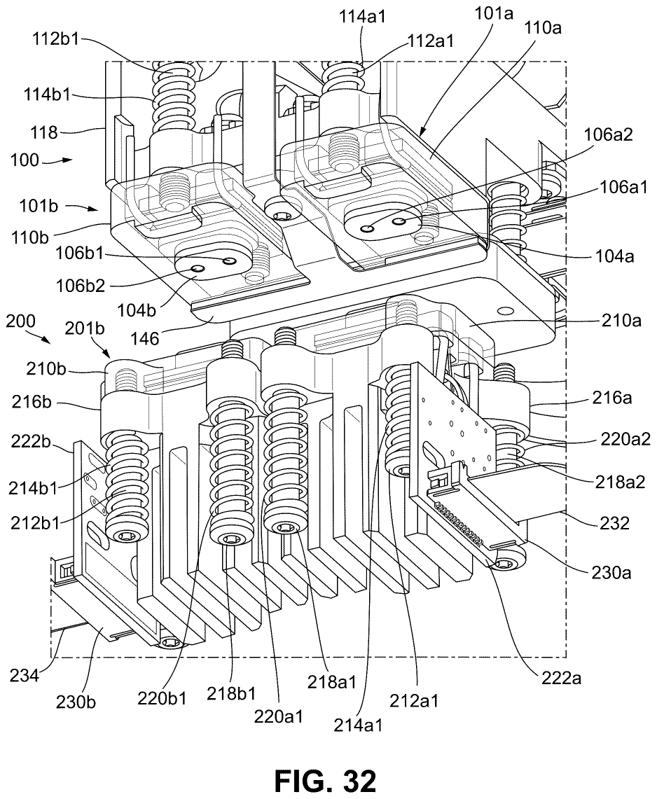

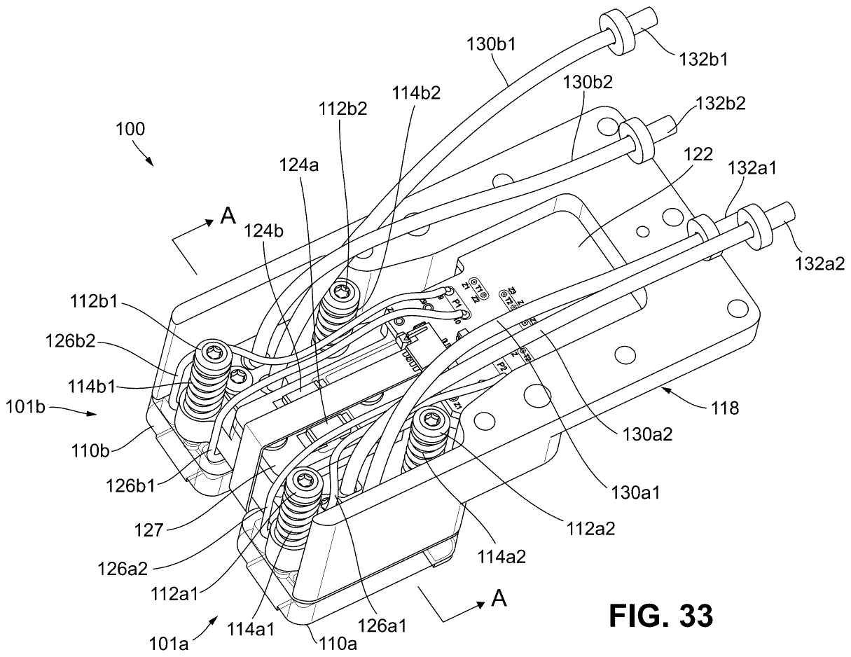

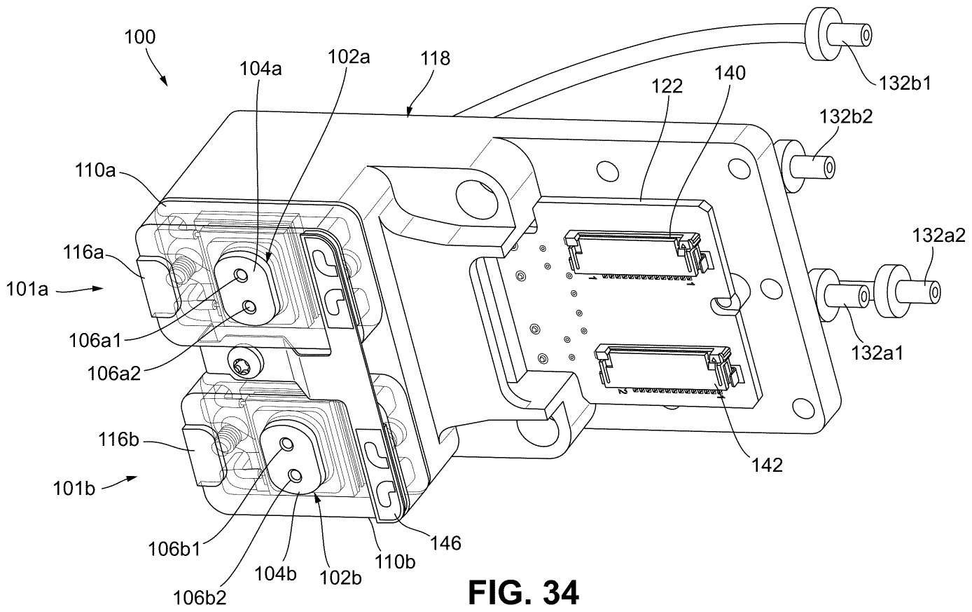

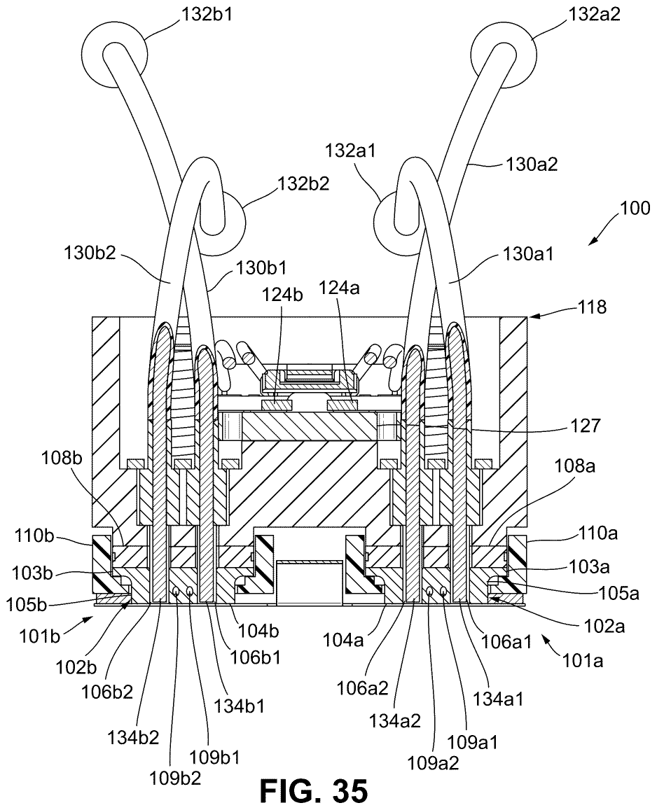

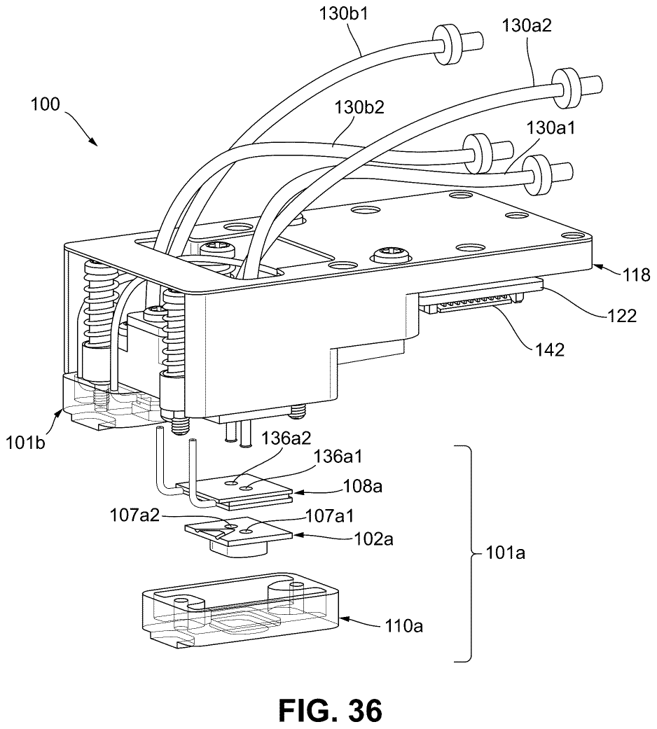

FIG. 31 is a top, partial perspective view of the first thermal module 100 and second thermal module 200, and FIG. 32 is a bottom, partial perspective view of the first thermal module 100 and the second thermal module 200. FIG. 33 is a top perspective view of the first thermal module 100, FIG. 34 is a bottom perspective view of the first thermal module 100, and FIG. 35 is a cross-sectional view of the first thermal module 100 through the line A-A in FIG. 33. FIG. 36 is a perspective view of the first thermal module 100 with first thermal assembly 101a shown in an exploded view.

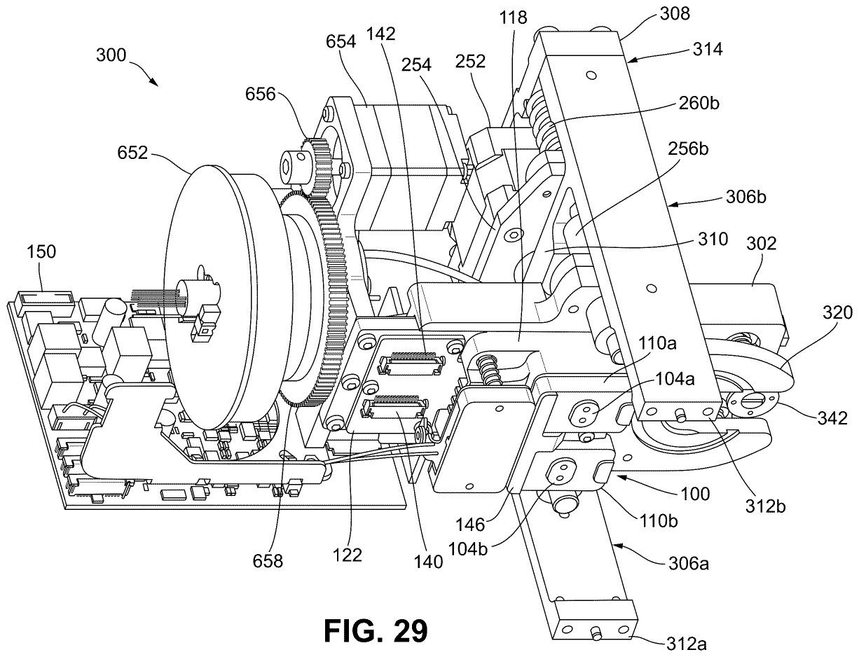

As shown in FIGS. 31, 32, 35, 36, a cover 110a may be positioned over thermal element 108a and associated thermal block 102a. Cover 110a is not shown in FIGS. 25 and 26. Projection 105a of thermal block 102a extends into or through an opening formed in the cover 110a to expose contact surface 104a. Thermal element 108a and associated thermal block 102a may be held in place with respect to mounting block 118 of the first thermal module 100, e.g., by means of fasteners such as cover bolts 112a1, 112a2, extending through-holes in the mounting block 118 and threaded into the cover 110a to secure the cover 110a to the mounting block 118. Mounting block 118 is attached to or part of upper block 302 (see, e.g., FIGS. 28 and 29) and is preferably made (e.g., molded and/or machined) from a thermally conductive material, such as a thermally-conductive ceramic or a metal, such as aluminum. As shown in FIGS. 31 and 33, a cover bolt spring 114a1 may be disposed coaxially over cover bolt 112a1 between a head of the bolt 112a1 and the mounting block 118. Similarly, a cover bolt spring 114a2 may be disposed coaxially over cover bolt 112a2 between a head of the bolt 112a2 and the mounting block 118. The purpose of the cover bolt springs 114a1 and 114a2 is to control the force that will be applied to the cover 110a when the cover bolts 112a1, 112a2 are tightened into the mating threads of cover 110a because the cover bolts 112a1, 112a2 are not tightened against the mounting block 118 but are tightened against the cover bolt springs 114a1, 114a2, respectively.

As also shown in FIGS. 31, 33, 35, a cover 110b may be positioned over thermal element 108b and associated thermal block 102b. Cover 110b is not shown in FIGS. 25 and 26. Projection 105b of thermal block 102b extends through an opening formed in the cover 110b to expose contact surface 104b. Thermal element 108b and associated thermal block 102b are held in place with respect to mounting block 118, e.g., by means of fasteners, such as cover bolts 112b1, 112b2 extending through-holes in mounting block 118 and threaded into the cover 110b to secure the cover 110b to mounting block 118. As shown in FIG. 33, cover bolt spring 114b1 may be disposed coaxially over cover bolt 112b1 between a head of the bolt 112b1 and mounting block 118. Similarly, a cover bolt spring 114b2 may be disposed coaxially over cover bolt 112b2 between a head of the bolt 112b2 and mounting block 118. The purpose of the cover bolt springs 114b1 and 114b2 is to control the force that will be applied to the cover 110b when the cover bolts 112b1, 112b2 are tightened into the mating threads of cover 110b because the cover bolts 112b1, 112b2 are not tightened against the mounting block 118 but are tightened against the cover bolt springs 114b1, 114b2, respectively.

As shown in FIG. 33, power lines 126a1, 126a2 connect a connector board 122 to thermal element 108a, and power lines 126b1, 126b2 connect connector board 122 to thermal element 108b. Power lines 126a1, 126a2, 126b1, 126b2 are not shown in FIGS. 25 and 26. Connector board 122 may include one or more connectors (see, e.g., connectors 140, 142 in FIGS. 29 and 34) for connecting connector board 122 to a control board (e.g., printed circuit board or “PCB”) 150 (see FIGS. 1 and 2), e.g., via one or more ribbon cables (not shown in FIGS. 11 and 16) or the like.

At least one of the first thermal module 100 and the second thermal module 200 is configured to permit detection of optical signals emitted by the contents of the reaction/detection chambers 510a1, 510a2, 510b1, 510b2 while the first thermal module 100 and second thermal module 200 are in contact with and applying heat to the reaction/detection chambers 510a1, 510a2, 510b1, 510b2. In one embodiment, as shown in FIGS. 25, 26, 32, 34, 35, 18 two through-holes are formed through the thermal block 102a forming openings 106a1, 106a2 in contact surface 104a of the first thermal assembly 101a of first thermal module 100, and two aligned holes are formed through the thermal element 108a of the first thermal assembly 101a. Optical fibers 130a1, 130a2 are aligned with or extend fully or partially into the through-holes and may terminate at the openings 106a1, 106a2 formed in the contact surface 104a. Optical fiber 130a1 has a proximal end 132a1 and a distal end 134a1, and optical fiber 130a2 has a proximal end 132a2 and a distal end 134a2 (see FIGS. 25 and 26). Distal ends 134a1 and 134a2 are positioned at or proximate to contact surface 104a at openings 106a1, 106a2, respectively (see FIGS. 25, 26, and 35). For example, distal ends 134a1 and 134a2 may be flush with contact surface 104a, may be recessed into the through-holes with respect to the contact surface 104a, or may extend beyond the contact surface 104a.

Similarly, as shown in FIGS. 25, 26, 32, 34, 35, two through-holes are formed through the thermal block 102b forming two openings 106b1, 106b2 in contact surface 104b of the second thermal assembly 101b of first thermal module 100, and two aligned holes are formed through the thermal element 108b of the second thermal assembly 101b. Optical fibers 130b1, 130b2 are aligned with or extend fully or partially into the through-holes and may terminate at the openings 106b1, 106b2 formed in the contact surface 104b. Optical fiber 130b1 has a proximal end 132b1 and a distal end 134b1, and optical fiber 130b2 has a proximal end 132b2 and a distal end 134b2 (see FIGS. 25 and 26). Distal ends 134b1 and 134b2 are positioned at or proximate to contact surface 104b at openings 106b1, 106b2, respectively (see FIGS. 25 and 26). For example, distal ends 134b1 and 134b2 may be flush with contact surface 104b, may be recessed into the through-holes with respect to the contact surface 104b, or may extend beyond the contact surface 104b.

In some instances, where the distal end of an optical fiber is recessed into a contact surface of a thermal assembly, during thermal cycling in which the heated contact surface is in contact with a wall of a reaction chamber, the material forming the wall of the reaction chamber may, due to the pressure applied by the contact surface, deform outwardly into the recess formed between the end of optical fiber and the contact surface. This may create a region at which bubbles within the reaction chamber can accumulate, and this accumulation of bubbles can degrade the ability to transmit optical signals from the optical fiber to the reaction chamber and/or from the reaction chamber to the optical fiber, thereby degrading signal detection via the fiber. On the other hand, if the end of the optical fiber protrudes from the contact surface, by even a small amount, the protruding fiber will deform the wall of the reaction chamber inwardly and create an indentation that will press bubbles away from the end of the optical fiber. Thus, in some embodiments, it is preferable that the distal ends 134a1 and 134a2 extend beyond the contact surface 104a, and that the distal ends 134b1 and 134b2 extend beyond the contact surface 104b. The amount by which the optical fibers protrude past the contact surfaces may be from 0.05 mm to 0.35 mm, with a nominal protrusion of 0.15 mm.

Through-holes are formed in the thermal elements 108a, 108b and in the thermal blocks 102a, 102b. (See FIG. 36 showing through-holes 136a1, 136a2 formed in thermal element 108a and through-holes 107a1, 107a2 formed in thermal block 102a). Optical fibers 130a1, 130a2, 130b1, 130b2 extend into or through or are aligned with the through-holes formed in the thermal elements 108a, 108b and in the thermal blocks 102a, 102b. In this embodiment, because holes are formed in the thermal elements 108a, 108b of the first thermal module, but are not formed in the thermal elements 208a, 208b of the second thermal module 200, thermal elements 108a, 108b of the first thermal module 100 may be larger than thermal elements 208a, 208b of the second thermal module 200.

In an alternate embodiment, a single through-hole and associated optical fiber or more than two through-holes and associated optical fibers are formed through the thermal elements 108a/b and through the thermal blocks 102a/b of first thermal module 100.

As shown in FIGS. 25 and 26, each of the proximal ends 132a1, 132a2, 132b1, 132b2 of optical fibers 130a1, 130a2, 130b1, 130b2, respectively, is or may be coupled to an optical device 650a1, 650a2, 650b1, 650b2 for emitting an optical signal to be transmitted by the corresponding optical fiber 130a1, 130a2, 130b1, 130b2 to a corresponding one of the reaction/detection chambers 510a1, 510a2, 510b1, 510b2 aligned with the corresponding fiber, for receiving and detecting an optical signal transmitted by the corresponding optical fiber 130a1, 130a2, 130b1, 130b2 from the corresponding reaction/detection chamber 510a1, 510a2, 510b1, 510b2, or for both emitting an optical signal to be transmitted by the corresponding optical fiber 130a1, 130a2, 130b1, 130b2 to the corresponding reaction/detection chamber 510a1, 510a2, 510b1, 510b2 and for receiving and detecting an optical signal transmitted by the corresponding optical fiber 130a1, 130a2, 130b1, 130b2 from the corresponding reaction/detection chambers 510a1, 510a2, 510b1, 510b2. FIGS. 25 and 26 show each optical device 650a1, 650a2, 650b1, 650b2 associated with a single corresponding optical fiber 130a1, 130a2, 130b1, 130b2. In other embodiments, two or more fibers may be associated with the same optical device.

An optical device 650a1, 650a2, 650b1, 650b2 may comprise a photodetector for detecting light (e.g., chemiluminescence) transmitted by the corresponding optical fiber that is spontaneously emitted from the reaction/detection chambers 510a1, 510a2, 510b1, 510b2 during or after a reaction within the reaction/detection chamber in which an analyte of interest (e.g., target molecule) is present, where the detected light—or absence thereof—is indicative of the presence or absence of the analyte of interest.

Alternatively, one or more optical devices 650a1, 650a2, 650b1, 650b2 may comprise a fluorometer, including both an excitation light source (e.g., an optical emitter, such as an LED) and an emission detector (e.g., an optical detector, such as a photodiode). Excitation light of a prescribed excitation wavelength from the excitation light source is transmitted by the corresponding fiber optical fiber 130a1, 130a2, 130b1 or 130b2 to the reaction/detection chambers 510a1, 510a2, 510b1, 510b2. Light (e.g., fluorescence) of a prescribed emission wavelength emitted by a fluorescent dye (or fluorophore molecule) during or after a reaction within the reaction/detection chamber in which an analyte of interest (e.g., target molecule) is present is transmitted by the corresponding fiber 130a1, 130a2, 130b1, or 130b2 from the reaction/detection chamber to the emission light detector.

A fluorometer may include additional optical components, such as one or more lenses, filters, collimators, reflectors, dichroic devices, etc., to focus and condition light emitted by the excitation light source so that excitation light transmitted by the fiber to the reaction/detection chamber substantially corresponds to the prescribed excitation wavelength and to focus and condition light transmitted by the fiber from the reaction/detection chamber so that light received by the emission detector substantially corresponds to the prescribed emission wavelength.

In applications involving both an excitation light signal transmitted from the excitation source to the reaction/detection chamber and a resulting emission light signal transmitted from the reaction/detection chamber to the emission light detector, one optical fiber may be employed for transmitting the excitation light signal to the reaction/detection chamber and another optical fiber may be employed for transmitting the resulting emission light signal from the reaction/detection chamber or one fiber may be used for both transmitting an excitation light signal and transmitting a resulting emission light signal. In applications involving excitation light signals of different prescribed excitation wavelengths and light signals of different prescribed emission wavelengths, fluorometers configured to emit excitation signals and detect emission signals of different prescribed wavelengths may be coupled to the different optical fibers 130a1, 130a2, 130b1, 130b2. Alternatively, fluorometers configured detect signals of different prescribed wavelengths may be supported on a moveable platform so that different fluorometers may be selectively coupled to each of the different optical fibers 130a, 130a2, 130b1, 130b2 to interrogate each of the reaction/detection chambers for each of the prescribed wavelengths corresponding to different dyes of different probes for detecting different analytes of interest.

Examples of optical devices and systems employing such optical devices are described in International Publication No. WO 2023/248185A1, “Compact detection system,” and U.S. Pat. No. 9,465,161, “Indexing signal detection module.”

As shown in FIGS. 25 and 26, each of the proximal ends 132a1, 132a2, 132b1, 132b2 of optical fibers 130a1, 130a2, 130b1, 130b2, respectively, is coupled to an associated optical device 650a1, 650a2, 650b1, 650b2, each of which may comprise an optical emitter and an associated optical detector. Each optical emitter is associated with one of the optical detectors. Each optical emitter may include a light emitting diode (LED), and each optical detector may include a photodiode.

Optical devices 650a1, 650a2, 650b1, 650b2 may be housed within a rotating detector housing 652. A detector housing motor 654 (e.g., a stepper motor) has a drive gear 656 engaged with a driven gear 658 that is connected to the housing 652. As motor 654 rotates the housing 652 via drive gear 656 and driven gear 658, different ones of the optical devices 650a1, a2, b1, b2 are rotated into alignment with different ones of the proximal ends 132a1, a2, b1, b2 of optical fibers 130a1, a2, b1, b2, respectively.

Where thermal elements 108a, 108b are thermoelectric modules, they may be mounted in contact with mounting block 118 (see, e.g., FIGS. 25, 26, and 35), which functions as a heat sink to draw heat away from the thermal elements 108a, 108b. In one example, a heat dissipation device, such as fan 190 (see FIGS. 30 and 31), may be provided to facilitate heat dissipation away from the mounting block 118.

As shown in FIGS. 33 and 35, heating elements 124a, 124b connected to a thermally conductive heater board 127 may be attached to mounting block 118 to maintain mounting block 118 at a desired temperature to facilitate efficient operation of thermoelectric modules 108a, 108b by minimizing temperature differentials between the thermoelectric modules 108a, 108b and the mounting block 118. Heating elements 124a, 124b, which may comprise resistors, may be connected for power and control to connector board 122. Thermistors (not shown) mounted to or within the heater board 127 may be provided for controlling power to the heating elements 124a, 124b to control the temperature of the heater board 127, and thus control temperature of the mounting block 118, and for which purpose an EPROM (erasable programmable read-only memory) may be provided on connector board 122 for storing thermal parameters for the thermistors.

As shown in FIGS. 29, 32, and 34, instrument 10 may include a capacitive flow sensor 146 that is movable with the first thermal module 100. Capacitive flow sensor 146 is configured to detect fluid flow in the cartridge 500 within flow channels located downstream of the reaction/detection chambers 510a1, 510a2, 510b1, 510b2.

### Second Thermal Module

Referring to FIGS. 25 and 26, first thermal assembly 201a of second (lower) thermal module 200 includes a thermal element 208a (which may comprise a thermoelectric module, such as a Peltier device, or any other device, mechanism, or system, other than a light source, that heats, cools, or selectively heats or cools) and an associated thermal block 202a disposed in thermal contact with thermal element 208a. Thermal block 202a includes a base portion 203a, which may be in contact with thermal element 208a, and a projection 205a which defines an exposed contact surface 204a which projects through the cartridge support cradle 404 (see FIGS. 23, 25, and 26) and contacts a bottom side of the cartridge 500 at the reaction/detection chambers 510a1 and 510a2.

Referring to FIGS. 25 and 26, second thermal assembly 201b of second thermal module 200 includes a thermal element 208b (which may comprise a thermoelectric module, such as a Peltier device, or any other device, mechanism, or system, other than a light source, that heats, cools, or selectively heats or cools) and an associated thermal block 202b disposed in thermal contact with thermal element 208b. Thermal block 202b includes a base portion 203b, which may be in contact with thermal element 208b, and a projection 205b which defines an exposed contact surface 204b which projects through the cartridge support cradle 404 (see FIGS. 23, 25, and 26) and contacts a bottom side of the cartridge 500 at the reaction/detection chambers 510b1 and 510b2. Thus, in the illustrated example, contact surface 204a contacts a group of chambers including 510a1, 510a2, and contact surface 204b contacts a group of chambers including 510b1, 510b2.

Thermal blocks 202a, 202b are preferably made (e.g., molded and/or machined) from a thermally conductive material, such as a thermally-conductive ceramic or a metal, such as aluminum.

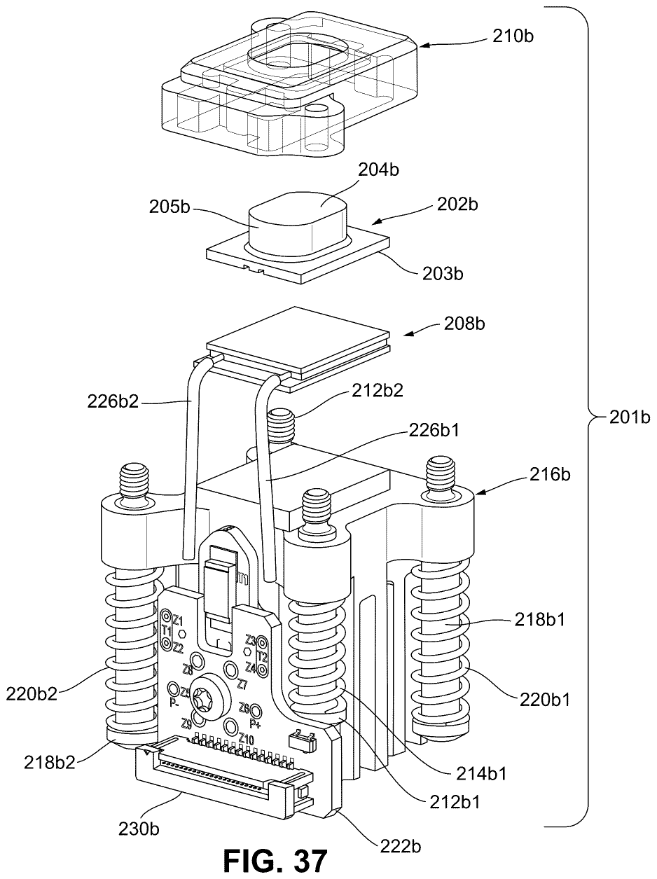

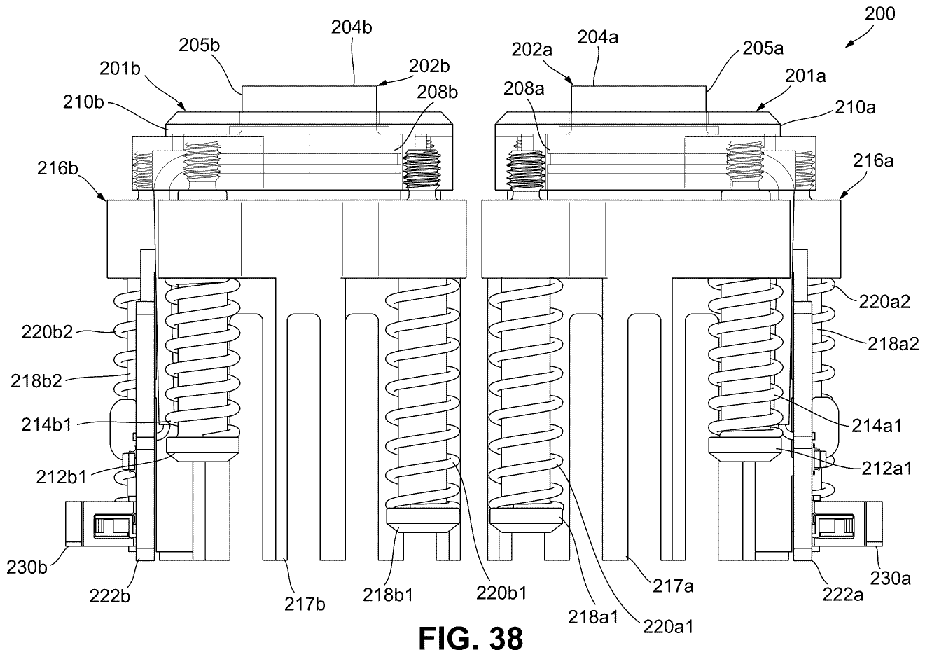

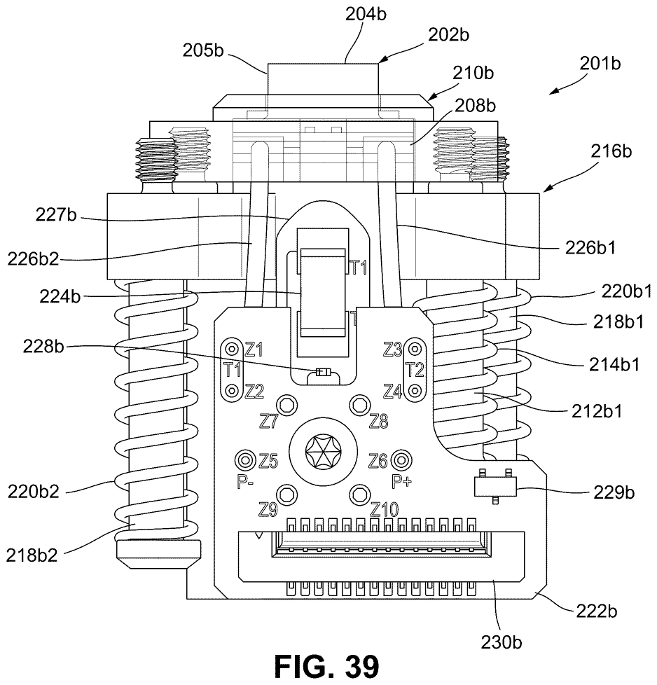

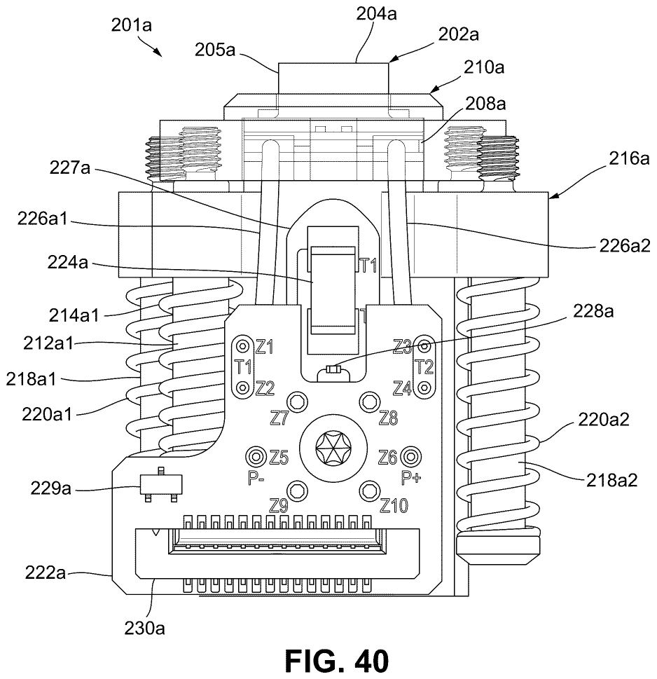

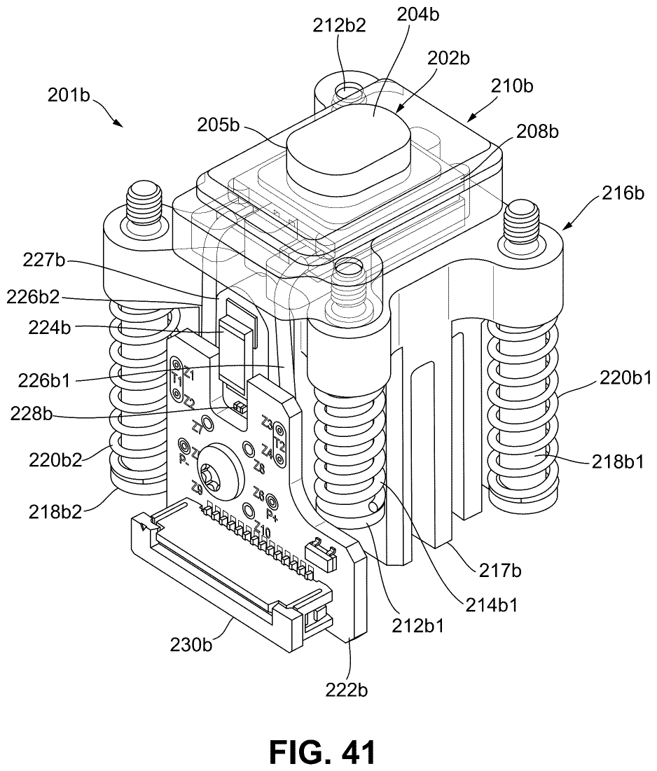

FIG. 37 is an exploded, perspective view of second thermal assembly 201b of second thermal module 200. FIG. 38 is a front view of the second thermal module 200, FIG. 39 is a left-side view of the second thermal assembly 201b of the second thermal module 200, and FIG. 40 is a right-side view of the first thermal assembly 201a of the second thermal module 200. FIG. 41 is a top perspective view of second thermal assembly 201b of second thermal module 200.

As shown in FIG. 37, a cover 210b may be positioned over thermal element 208b and associated thermal block 202b of second thermal assembly 201b. Cover 210b is not shown in FIGS. 25 and 26. As shown in FIGS. 38, 39 and 41, projection 205b of thermal block 202b projects through an opening formed in the cover 210b. Thermal element 208b and associated thermal block 202b of thermal assembly 201b may be held in place with respect to a heat sink 216b, e.g., by means of fasteners, such as cover bolts 212b1, 212b2 extending through-holes in the heat sink 216a and threaded into the cover 210b to secure the cover 210b to the heat sink 216b. As noted, thermal element 208b may be a thermoelectric module, e.g., a Peltier device, and heat sink 216b functions to draw heat away from the thermal element and dissipate the heat. Heat sink 216b is attached to or part of base plate 408 (see FIG. 23), and, in one example, includes a plurality of heat dissipation fins 217b. A cover bolt spring 214b1 may be disposed coaxially over cover bolt 212b1 between a head of the bolt 212b1 and the heat sink 216b. Similarly, and although not visible in the drawings, a cover bolt spring may be disposed coaxially over cover bolt 212b2 between a head of the bolt 212b2 and the heat sink 216b. The purpose of the cover bolt springs is to control the force that will be applied to the cover 210b when the cover bolts 212b1, 212b2 are tightened into the mating threads of cover 210b, because the cover bolts 212b1, 212b2 are not tightened against the heat sink 216b but are tightened against the cover bolt springs.

As shown in FIGS. 38 and 40, a cover 210a may be positioned over thermal element 208a and associated thermal block 202a. Cover 210a is not shown in FIGS. 25 and 26. Projection 205a of thermal block 202a projects through an opening formed in the cover 210a The thermal element 208a and associated thermal block 202a of thermal assembly 201a may be held in place with respect to a heat sink 216a, e.g., by means of fasteners, such as a cover bolt 212a1 extending through a hole in the heat sink 216a and threaded into the cover 210a. A second cover bolt—not shown in the drawings—extends through a hole in the heat sink 216a and into the cover 210a at a corner of the cover 210a diagonally across from cover bolt 212a1. As noted, thermal element 208a may be a thermoelectric module, e.g., a Peltier device, and heat sink 216a functions to draw heat away from the thermal element 208a and dissipate the heat. Heat sink 216a is attached to or part of base plate 408 (see FIG. 23), and, in one example, includes a plurality of heat dissipation fins 217a. A cover bolt spring 214b1 is disposed coaxially over cover bolt 212b1 between a head of the bolt 212b1 and the heat sink 216b. Similarly, a cover bolt spring is disposed coaxially over the second cover bolt between a head of the bolt and the heat sink. The purpose of the cover bolt springs is to control the force that will be applied to the cover 210a when the cover bolts 212a1 are tightened into the mating threads of cover 210a, because the cover bolts 212a1 are not tightened against the heat sink 216a but are tightened against the cover bolt springs 214a1.

Heat sinks 216a, 216b are preferably made (e.g., molded and/or machined) from a thermally conductive material, such as a thermally-conductive ceramic or a metal, such as aluminum.

Thermal assemblies 201a and 201b are mirror images of each other, and thus illustrations of thermal assembly 201a corresponding to the illustrations of thermal assembly 201b in FIGS. 37 and 41 are not provided.

In an embodiment, covers 110a, 110b, 210a, 210b are made from a plastic material, such as Ultem® (polyetherimide), which may be at least semi-transparent, or an acetal resin, such as Delrin® (polyoxymethylene (POM)). Desirable material properties of the cover material include machinability or moldability, good mechanical strength, and low thermal conductivity (e.g., 0.17 W/(m K) to 0.5 W/(m K)).

As shown in FIGS. 31 and 40, in one embodiment, first thermal assembly 201a of second thermal module 200 includes two heat sink bolts 218a1, 218a2 for securing heat sink 216a to an attaching structure within the lower chassis 400, for example, to the cartridge support frame 402 and/or the base plate 408. Similarly, as shown in FIGS. 31, 37-39, and 41, second thermal assembly 201b of second thermal module 200 includes two heat sink bolts 218b1, 218b2 for securing heat sink 216b to an attaching structure within the lower chassis 400, for example, to the cartridge support frame 402 and/or the base plate 408. A heat sink bolt spring 220a1 is disposed coaxially over heat sink bolt 218a1 between a head of the bolt 218a1 and the heat sink 216a, and a heat sink bolt spring 220a2 is disposed coaxially over heat sink bolt 218a2 between a head of the bolt 218a2 and the heat sink 216a. Similarly, a heat sink bolt spring 220b1 is disposed coaxially over heat sink bolt 218b1 between a head of the bolt 218b1 and the heat sink 216b, and a heat sink bolt spring 220b2 is disposed coaxially over heat sink bolt 218b2 between a head of the bolt 218b2 and the heat sink 216b. Each of the heat sink bolts 218a1, 218a2 extends through an associated opening formed through the heat sink 216a and is threaded into cartridge support frame 402 and/or the base plate 408, and each of the heat sink bolts 218b1, 218b2 extends through an associated opening formed through the heat sink 216b and is threaded into cartridge support frame 402 and/or the base plate 408. The purpose of the heat sink bolt springs 220a1, 220a2 is to allow the heat sink 216a, thermal module 208a, and thermal block 202a to deflect, or “float,” when a downward force of sufficient magnitude is applied to the contact surface 204a of the thermal block 202a. Similarly, the purpose of the heat sink bolt springs 220b1, 220b2 is to allow the heat sink 216b, thermal module 208b, and thermal block 202b to deflect, or “float,” when a downward force of sufficient magnitude is applied to the contact surface 204b of the thermal block 202b.

As shown in FIG. 40, power lines 226a1, 226a2 connect a connector board 222a to the thermal element 208a (not shown in FIG. 40) of thermal assembly 201a, and a connector 230a is provided for connecting the connector board 222a to control board 150 by a connector ribbon cable 232 (see FIG. 30). As shown in FIGS. 37, 39, and 41, power lines 226b1, 226b2 connect a connector board 222b to the thermal element 208b, and a connector 230b is provided for connecting the connector board 222b to control board 150 by a connector ribbon cable 234 (see FIG. 30).

In an alternate embodiment, rather than employing separate heat sinks 216a, 216b, the thermal elements 208a, 208b, associated thermal blocks 202a, 202b, and covers 210a, 210b of thermal assemblies 201a, 201b may be secured to a single heat sink that is large enough to accommodate more than one thermal element and associated thermal block and cover. On the other hand, having a separate heat sink for each thermal assembly may help the assembly and the thermal block contact surface take up differences in the positions of the mating surfaces due to system tolerances and cartridge warpage.

As shown in FIG. 40, at least one heating element 224a connected to a thermally conductive heater board 227a may be provided to maintain heat sink 216a at a desired temperature to facilitate efficient operation of thermoelectric module 208a of the thermal assembly 201a by minimizing temperature differentials between the thermoelectric module and the heat sink 216a. Heating element 224a, which may comprise a resistor, may be connected for power to connector board 222a. A thermistor 228a mounted to or embedded within the heater board 227a may be provided for controlling power to the heating element 224a to control the temperature of the heater board 227a, and thus control temperature of the heat sink 216a, and for which purpose an EPROM (erasable programmable read-only memory) 229a may be provided on connector board 222a for storing thermal parameters for the thermistor 228a.

Similarly, as shown in FIGS. 39 and 41, at least one heating element 224b connected to a thermally conductive heater board 227b may be provided to maintain heat sink 216b at a desired temperature to facilitate efficient operation of thermoelectric module 208b by minimizing temperature differentials between the thermoelectric module 208b and the heat sink 216b. Heating element 224b, which may comprise a resistor, may be connected for power to connector board 222b. A thermistor 228b mounted to or embedded within the heater board 227b may be provided for controlling power to the heating element 224b to control the temperature of the heater board 227b, and thus control temperature of the heat sink 216b, and for which purpose an EPROM (erasable programmable read-only memory) 229b may be provided on connector board 222b for storing thermal parameters for the thermistor 228b.

As shown in FIGS. 25 and 26, the contact surfaces 204a, 204b of the second thermal module 200 are situated in facing, or aligned, opposition with respect to associated contact surfaces 104a, 104b, respectively, of the first thermal module 100. When a test platform (e.g., fluidic cartridge 500) is placed on the cartridge support cradle 404 between the first thermal module 100 and the second thermal module 200, the contact surfaces 104a, 204a are aligned with each other and with opposed sides of the reaction/detection chambers 510a1, 510a2 disposed between them, and the contact surfaces 104b, 204b are aligned with each other and with opposed sides of the reaction/detection chambers 510b1, 510b2 disposed between them.

In an alternate embodiment, one or more through-holes are formed through one or more of the thermal elements 208a, 208b and one or more of the thermal blocks 202a, 208b of the second thermal module 200 forming one or more corresponding openings (not shown) in contact surface(s) 204a, 204b of the second thermal module 200, and an optical fiber (not shown) is associated with each through-hole of the second thermal module to transmit an optical signal through the thermal element and the thermal block. Optical fibers extending through the second thermal module 200 may be coupled to optical devices(s) for transmitting excitation optical signals to and/or receiving emission optical signals from the reaction/detection chambers through the second thermal module 200 in much the same way such optical devices are described above with respect to first thermal module 100.

The first and second thermal modules 100, 200 are constructed and arranged for relative movement toward and away from each other. Relative movement of the first thermal module 100 and the second thermal module 200 toward each other places the contact surfaces 104a, 204a in contact with opposite sides of the reaction/detection chambers 510a1, 510a2 to facilitate conductive thermal transfer between the contact surfaces 104a, 204a and the reaction/detection chambers 510a1, 510a2 and places the contact surfaces 104b, 204b in contact with opposite sides of the reaction/detection chambers 510b1, 510b2 to facilitate conductive thermal transfer between the contact surfaces 104b, 204b and the reaction/detection chambers 510b1, 510b2.

### Thermal Module Actuator

To effect relative movement between the first thermal module 100 and the second thermal module 200, either or both of the first thermal module 100 and the second thermal module 200 is configured to be movable toward and away from the other. The relative movement may be vertical when the first and second thermal modules 100, 200 are arranged one above the other. In another example, the relative movement may be lateral (horizontal, or non-vertical) when the first and second thermal modules 100, 200 are arranged side-by-side. In one example, second thermal module 200 is fixed within the instrument 10, and the first thermal module 100 is movable (e.g., vertically) with respect to the second thermal module 200. As illustrated schematically in FIGS. 25 and 26, a thermal module actuator 250 is configured to effect automated relative movement between the first thermal module (first heater) 100 and the second thermal module (second heater) 200. Thermal module actuator 250 may comprise an actuator motor 252 that is fixed within the upper chassis 300, e.g., to motor mount 314 (see FIGS. 1, 2, 27-29), and a lead screw 258 attached at one end to mounting block 118. Lead screw 258 may be attached directly or indirectly to mounting block 118. In the illustrated example, thermal module actuator 250 is configured to effect automated movement of the movable first thermal module 100 toward or away from the fixed second thermal module 200. In FIG. 25, first thermal module 100 is shown in a first, or raised, position above a top surface of the cartridge 500 so as to form gaps between the contact surfaces 104a, 104b and the cartridge 500. Cartridge 500 is supported on the contact surfaces 204a, 204b of the second thermal module 200 and on the cartridge support cradle 404. In FIG. 26, first thermal module 100 has been lowered by the thermal module actuator 250 to a second, or lowered or engaged, position at which detection regions of the test platform/cartridge are sandwiched between the first thermal module/heater 100 and the second thermal module/heater 200. In this context, the detection regions are “sandwiched” between the first thermal module/heater 100 and the second thermal module/heater 200 if the detection regions are disposed between the first thermal module/heater 100 and the second thermal module/heater 200 and in contact with or in sufficiently close proximity to the first thermal module/heater 100 and the second thermal module/heater 200 to enable effective thermal transfer between the first thermal module/heater 100 and the second thermal module/heater 200 and the detection regions (e.g., contact surfaces 104a, 104b are in thermal contact—which may include direct physical contact—with a top surface of reaction/detection chambers 510a1, 510a2, 510b1, 510b2, and contact surfaces 204a, 204b are in thermal contact—which may include direct physical contact—with a bottom surface of the reaction/detection chambers).

With reference to FIG. 27, thermal module actuator 250 comprises motor 252 (e.g., a stepper motor) mounted on a motor mounting plate 254 that is supported on, but not connected to, the intermediate crossbar 310 of the motor mount 314 at a position that is generally at a midpoint between the side supports 306a, 306b. Linear bearings/guide rods 256a, 256b are attached at one end to upper block 302 and at an opposite end to top crossbar 308 and extend through intermediate crossbar 310 and motor mounting plate 254 on opposite sides of motor 252. The lead screw (linear drive) 258 extends from motor 252, through the motor mounting plate 254 and intermediate crossbar 310, and to the upper block 302 to which the mounting block 118 of the thermal assemblies 101a, 101b of the first thermal module 100 are attached. Rotation of the lead screw 258 by the motor 252 raises or lowers the upper block 302, and the first thermal module 100 and mounting block 118 attached to the upper block 302, by moving the upper block 302 toward or away from the motor 252. During movement by motor 252 and lead screw 258, the upper block 302 is guided by the linear bearings 256a, 256b to avoid tilting and binding of the upper block 302.

When the pressure plate 320 contacts the top of the cartridge 500, further downward movement of the upper block 302 and mounting block 118 is arrested, and continued rotation of the lead screw 258 will then separate the motor 252 and motor mounting plate 254 from the intermediate crossbar 310. Springs 260a, 260b coaxially surrounding portions of linear bearings/guide rods 256a, 256b, respectively, between the motor mounting plate 254 and the top crossbar 308 on opposite sides of the motor 252 will compress as the motor mounting plate 254 separates from the intermediate crossbar 310, thereby increasing the spring force in each of the springs 260a, 260b, and thereby controlling the amount of downward force exerted by the lead screw 258 onto the upper block 302, depending on the spring constants of the springs 260a, 260b. In some embodiments, an optical sensor (not shown) comprising an emitter/receiver pair will detect a beam of light from the emitter to the receiver through a gap between the motor mounting plate 254 and the intermediate crossbar 310 to generate a signal to deactivate the motor 252 when the motor mounting plate 254 is lifted off the intermediate crossbar 310.

As shown, for example, in FIG. 34, cover 110a of first thermal assembly 101a may include a raised portion 116a, and cover 110b of second thermal assembly 101b may include a raised portion 116b. When first thermal module 100 is lowered by the thermal module actuator 250 so that the contact surfaces 104a, 104b contact reaction/detection chambers 510a1, 510a2, 510b1, 510b2, respectively, raised portions 116a, 116b bear against a portion of the reaction/detection section 506 of cartridge 500 at which valves are located, and the raised portions 116a, 116b provide a backing when valve actuator heads 406a-406r push up against a side of the cartridge opposite raised portions 116a, 116b to actuate the corresponding valves V1 to V18 in the cartridge 500.

### Contact Detector

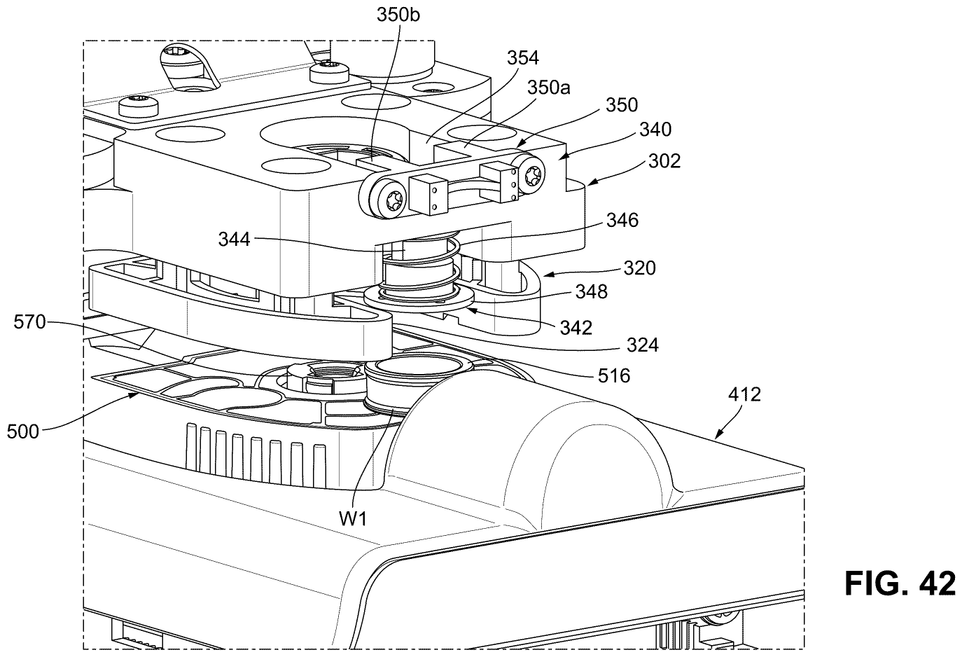

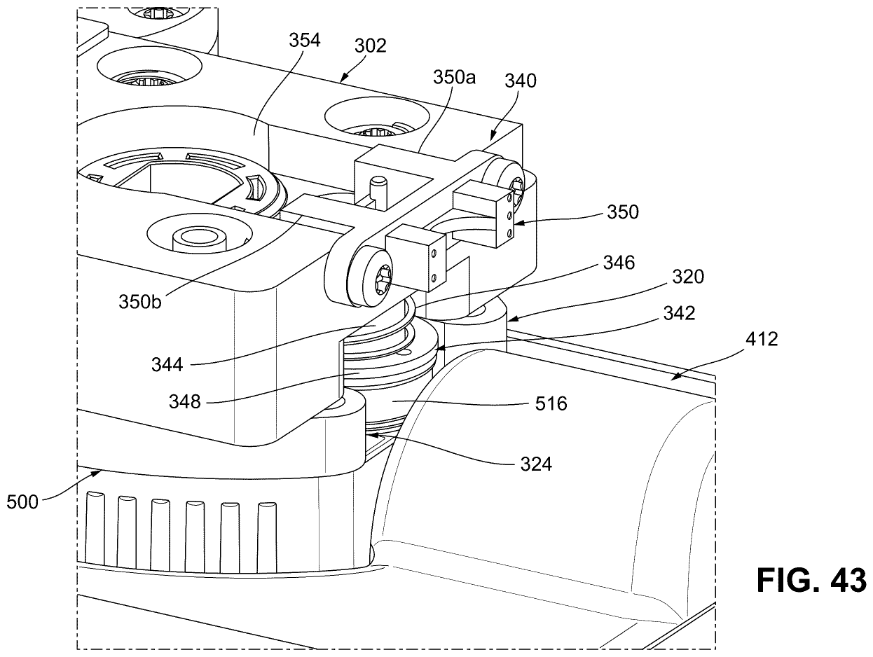

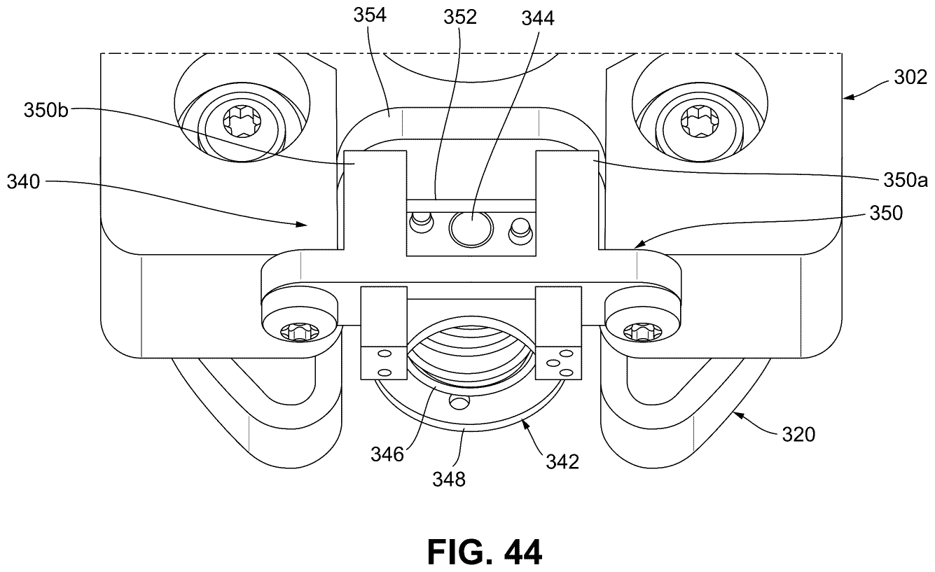

Instrument 10 may include a mechanism for holding a cap closed on sample chamber W1 of a cartridge 500 within the instrument 10 and for generating a signal to indicate that a cartridge 500, or other test platform if instrument 10 is operable with a platform other than a fluidic cartridge, is positioned on the cartridge support cradle 404. Referring to FIGS. 2 and 27, such a mechanism may comprise a contact detector 340 comprising, as shown in FIG. 27, a plunger 342 and an optical detector 350 attached to the upper block 302. FIG. 42 is a partial perspective view of the instrument showing block 302 in a raised position above cartridge 500 held in holder 412 so that pressure plate 320 and plunger 342 are not in contact with cartridge 500. FIG. 43 is a partial perspective view of the instrument showing block 302 in a lowered position with respect to cartridge 500 held in holder 412 so that pressure plate 320 and plunger 342 are in contact with cartridge 500. FIG. 44 is a partial, top perspective view showing the contact detector 340 without the cartridge 500 or holder 412.

As shown in FIGS. 42-44, an example of an optical sensor 350 included in the contact detector 340 includes an optical transmitter 350a and an optical receiver 350b disposed within a recess 354 (see also, FIG. 30 showing recess 354) formed in the top of the upper block 302. Plunger 342 includes a plunger rod 344 extending through the upper block 302, and a plunger pad 348 on a lower end of the plunger rod 344 and disposed within a cutout 324 formed in the pressure plate 320 (see also FIG. 29 showing cutout 324). A spring 346 is disposed around the plunger rod 344 between the upper block 302 and the plunger pad 348.

When the upper block 302 is in the first position (FIG. 42), no portion of the plunger 342 is disposed between the optical transmitter 350a and the optical receiver 350b, and an optical beam 352 from the transmitter 350a is received by the receiver 350b. As shown in FIG. 43, when a cartridge 500 is positioned on the cartridge support cradle 404 below the upper block 302, and the upper block 302 is lowered by the thermal module actuator 250 to its second position onto the cartridge 500, the pressure plate 320 contacts the top of the cartridge 500 and the plunger pad 348 of the plunger 342 contacts a top edge of the peripheral wall 520 of the cap 516 (see FIGS. 15-17) inserted into the sample chamber W1 of the cartridge 500. Vent hole 523 formed in the radial wall 522 of the cap 516 and side vent holes 521a, 521b (see FIG. 17) allow pressure equalization within the sample chamber W1 when the cap 516 is covered by the plunger pad 348 to permit sample fluid to be drawn from the sample chamber W1 by the syringe. As the upper block 302 is lowered, the plunger rod 344 of the plunger 342, which is biased in a downward position by spring 346, is pushed up through the upper block 302. An upper end of the rod 344 passes between the optical transmitter 350a and receiver 350b to alter (e.g., block) an optical beam 352 between them (see FIG. 43), thereby causing a signal or changing a signal (from unblocked to blocked) to indicate that a cartridge 500 is positioned on the cartridge support cradle 404. If no cartridge is positioned on the cradle 404 when the upper block 302 is lowered, the plunger 342 will not be pushed up and the plunger rod 344 will not break the optical beam 352, thereby indicating that a cartridge is absent.

In another embodiment, the rod 344 of plunger 342 is disposed between the optical transmitter 350a and the optical receiver 350b to block the beam 352 when the upper block 302 is in the first position. A hole is formed through the rod 344, and when the plunger 342 is moved upon contacting the cartridge when the upper block 302 is moved to the second position, the hole is aligned with the optical transmitter 350a and the optical receiver 350b, thereby allowing the optical beam 352 to pass from the optical transmitter 350a to the optical receiver 350b. Again, it is the change in signal caused by the beam 352 becoming unblocked as the upper block 302 moves from the first position to the second position and the plunger 342 contacts a cartridge disposed between the first thermal module 100 and the second thermal module 200 that indicates the presence of the cartridge.

Plunger 342, pushing down on the cap over the sample chamber W1 with the force of the spring 346, will help hold a cap in a closed position over the chamber W1 while the cartridge 500 is being operated on by the instrument 10.

### Operation

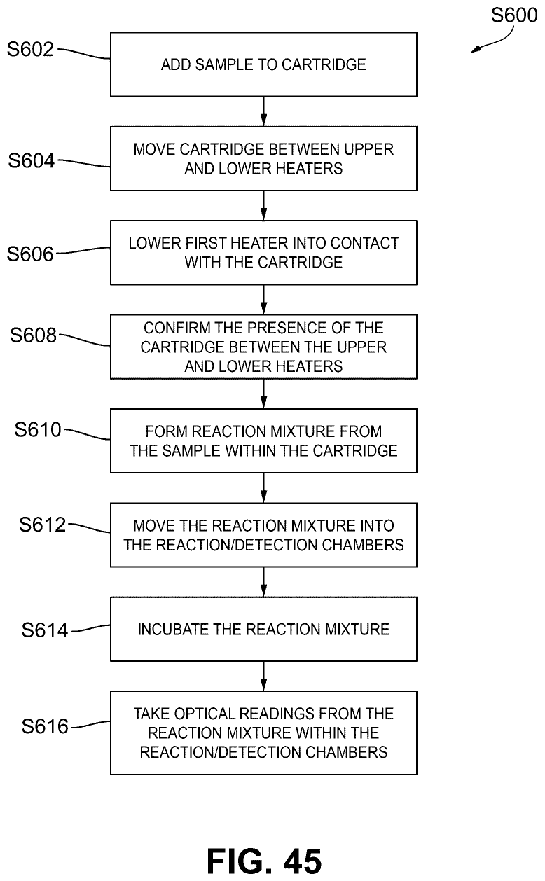

The following description presents an example of an operation for performing an assay using instrument 10 and a fluidic cartridge 500. FIG. 45 shows a flow diagram illustrating an embodiment of a method S600 for performing an assay using instrument 10 and fluidic cartridge 500. Method S600 may be performed with or used in conjunction with any of the computer systems, devices, mechanisms, elements, or components disclosed herein, among other devices. Method S600 may be coded and stored as a computer-executable control algorithm for controlling the operation(s) of one or more of the computer systems, devices, mechanisms, elements, or components disclosed herein, among other devices. In various embodiments, some of the method steps shown may be performed concurrently, in a different order than shown, or may be omitted. Additional method steps may also be performed as desired. Flow begins at step S602.

In step S602, sample is added to the cartridge 500 by dispensing sample material into the sample chamber W1 of the cartridge 500 and placing cap 516 over the sample chamber W1. Reagents and other materials necessary for performing the intended procedure—e.g., a molecular assay—are contained within one or more chambers W2-W5, W7-W10 of the sample preparation section 504 of the cartridge 500. Protective cover 566 is peeled off the venting membrane 562 of the protective venting cover 560.

Cartridge 500 is then placed on the cartridge holder 412, and, in step S604 the cartridge is placed between upper and lower heaters (e.g., between thermal assemblies 101a, 101b of first thermal module 100 and thermal assemblies 201a, 201b of the second thermal module 200) by retracting the cartridge holder 412 into the instrument 10 between the first and second thermal modules 100, 200. Due to springs 417 disposed between holder 412 and rails 416a, 416b, within recesses 415a, 415b, respectively, (see FIG. 23) which position the holder 412 above the frame 414, the cartridge 500 is supported slightly above the cartridge support cradle 404 with the reaction/detection chambers 510a1, 510a2 positioned above the contact surface 204a of the first thermal assembly 201a of the second thermal module 200 and the reaction/detection chambers 510b1, 510b2 positioned above the contact surface 204b of the second thermal assembly 201b of the second thermal module 200.

In step S606, the first heater is lowered into contact with the cartridge by lowering the first thermal module 100 by the thermal module actuator 250 to place pressure plate 320 in contact with the top of cartridge 500 and to place contact surface 104a of first thermal assembly 101a in contact with an outer surface of a portion of cartridge 500 forming an upper wall of reaction/detection chambers 510a1, 510a2 and to place contact surface 104b of second thermal assembly 101b in contact with an outer surface of a portion of cartridge 500 forming an upper wall of reaction/detection chambers 510b1, 510b2. Contact by the pressure plate 320 with atop surface of cartridge 500 (e.g., contact with the venting membrane 562 of cartridge 500) also compresses springs 417 between holder 412 and rails 416a, 416b and pushes cartridge 500 down into contact with the cartridge support cradle 404 to place contact surface 204a of first thermal assembly 201a in contact with an outer surface of a portion of cartridge 500 forming a lower wall of reaction/detection chambers 510a1, 510a2 and to place contact surface 204b of second thermal assembly 201b in contact with an outer surface of a portion of cartridge 500 forming a lower wall of reaction/detection chambers 510b1, 510b2.

In step S608, the presence of the cartridge 500 between the upper heater (first thermal module 100) and the lower heater (second thermal module 200) will be confirmed by the contact detector 340 as described above.

In step S610, a reaction mixture is formed with the sample in the cartridge 500. At least a portion of the sample contained in chamber W1 and one or more other materials contained within chambers of the sample preparation section 504 are combined by selectively actuating the plunger 362 and stopper 540 within the syringe barrel SB with syringe driver 360 while opening or closing selected ones of the valves V1 to V18 with associated valve actuator heads 406a-406r actuated by first valve actuator 1300 to move materials from one chamber to another. In one example, sample material added to the sample chamber W1 is lysed—either within the sample chamber W1 or prior to addition to the sample chamber W1—to release nucleic acids within the sample material. Lysed sample material is drawn by the syringe from the sample chamber W1 by closing all sample preparation valves V2 to V12, e.g., with the associated spring-biased valve actuator pistons 1320 of first valve actuator 1300, and opening valve V1—e.g., by positioning the rotary cam 1358 of the first valve actuator 1300 at a rotational position with respect to the axis of rotation 1339 corresponding to the valve actuator piston 1320 associated with valve V1 to engage the valve surface 1328 of the valve actuator piston to push the piston down—and raising the syringe plunger 362 and stopper 540 to draw sample into the syringe barrel SB. Lysed sample drawn from the sample chamber W1 passes through the sample filter 538 (if provided) to remove molecular material and other impurities. Sample is then moved from the syringe barrel to the purification column within insert 536 situated within chamber W4 by closing all valves except valve V4—e.g., closing all sample preparation valves V1 to V3 and V5 to V12 with the associated spring-biased valve actuator pistons 1320 of first valve actuator 1300 and opening valve V4 by positioning the rotary cam 1358 of the first valve actuator 1300 at a rotational position with respect to the axis of rotation 1339 corresponding to the valve actuator piston 1320 associated with valve V4 to engage the valve surface 1328 of the valve actuator piston to push the piston down—and lowering the syringe plunger 362 and stopper 540 to push sample from the syringe barrel SB to chamber W4. Within the purification column of chamber W4, target nucleic acid from the lysed sample material binds to and is immobilized on the purification column, which may be a silica-based purification column. Unbound material (e.g., cellular material that could interfere with amplification and/or detection of a targeted nucleic acid) is moved by the syringe from the chamber W4 to one of the waste chambers W11 or W12. The purification column within the chamber W4 may be washed one or more times with wash buffer from one or both of chambers W2 and W3, after which the used wash buffer is sent to waste chamber W11 or W12. Finally, the nucleic acid bound to the purification column in chamber W4 is eluted from the purification column using an elution buffer from chamber W10.

In one example, if the procedure to be performed on the sample is a PCR-based assay, a master-mix (i.e., a solution including all the components for a PCR reaction that are not analyte-specific) is formed and combined with a portion of the sample and an analyte-specific probe to form the reaction mixture. In step S612, the reaction mixture is drawn into the syringe barrel SB by the syringe plunger 362 and stopper 540 driven by the syringe driver 360—e.g., from chamber W4 by closing sample preparation valves V1 to V3 and V5 to V12 and opening sample preparation valve V4 with first valve actuator 1300—and then pushed (expelled from the syringe barrel SB) by the plunger 362 and stopper 540 into one or more of the reaction/detection chambers 510a1, 510a2, 510b1, 510b2. In one example employing the second valve actuator 740, flow of the reaction mixture from the syringe barrel SB to the chambers 510a1, 510a2, 510b1, 510b2 is controlled as follows. To move reaction mixture from the syringe barrel SB to the reaction chamber 510a1, second valve actuator 740 is operated to actuate (retract) valve actuator pistons 900b and 900f to open valves V14 and V18, respectively, and the syringe plunger 362 and stopper 540 are lowered by the syringe driver 360 to expel an amount of reaction mixture from the syringe barrel SB into the reaction chamber 510a1. To move reaction mixture from the syringe barrel SB to the reaction chamber 510a2, second valve actuator 740 is operated to actuate (retract) valve actuator pistons 900b and 900e to open valves V14 and V17, respectively, and the syringe plunger 362 and stopper 540 are lowered by the syringe driver 360 to expel an amount of reaction mixture from the syringe barrel SB into the reaction chamber 510a2. To move reaction mixture from the syringe barrel SB to the reaction chamber 510b1, second valve actuator 740 is operated to actuate (retract) valve actuator pistons 900a and 900d to open valves V13 and V16, respectively, and the syringe plunger 362 and stopper 540 are lowered to expel an amount of reaction mixture from the syringe barrel SB into the reaction chamber 510b1. To move reaction mixture from the syringe barrel SB to the reaction chamber 510b2, second valve actuator 740 is operated to actuate (retract) valve actuator pistons 900a and 900c to open valves V13 and V15, respectively, and the syringe plunger 362 and stopper 540 are lowered to expel an amount of reaction mixture from the syringe barrel SB into the reaction chamber 510b2.

In some examples, a reaction mixture having a different analyte-specific probe is produced for each of the reaction/detection chambers 510a1, 510a2, 510b1, 510b2 for detecting a different analyte of interest in each of the reaction/detection chambers.

Capacitive flow sensor 146 may be used to detect fluid flow within flow channels located downstream of the reaction/detection chambers 510a1, 510a2, 510b1, 510b2. Detection of fluid flow within the downstream channels may be employed as a feedback control signal to ensure proper filling of the reaction/detection chambers 510a1, 510a2, 510b1, 510b2—e.g., by causing reaction mixture to be pushed into the reaction/detection chambers 510a1, 510a2, 510b1, 510b2 until fluid flow is detected at the flow sensor 146. Alternatively, detection of fluid flow within the downstream channels may be employed as a process control signal to ensure proper filling of the reaction/detection chambers 510a1, 510a2, 510b1, 510b2—e.g., by causing a specified volume of reaction mixture to be pushed into the reaction/detection chambers 510a1, 510a2, 510b1, 510b2, whereby fluid flow detected at the flow sensor 146 will confirm that the reaction/detection chambers 510a1, 510a2, 510b1, 510b2 have been filled.

In step S614, the reaction mixture within each of the reaction/detection chambers 510a1, 510a2, 510b1, 510b2 is incubated.

To heat the reaction/detection chambers, power is applied to one or more of the thermal elements 108a, 108b, 208a, 208b to generate thermal energy that is applied, e.g., by thermal conduction via the corresponding thermal blocks 102a, 102b, 202a, 202b to the associated reaction/detection chambers 510a1, 510a2, 510b1, 510b2, respectively, to heat, cool, or alternately heat and cool the contents of the reaction/detection chambers. The thermal assemblies 101a, 101b of first thermal module 100 and the thermal assemblies 201a, 201b of the second thermal module 200 can be configured to apply a desired thermal profile to the contents of the chambers 510a1, 510a2, 510b1, 510b2. In some examples, the thermal profile may be an isothermal profile, an ascending or descending temperature ramp profile, or a thermal cycling profile. As previously noted, the contents of the chambers 510a1, 510a2, 510b1, 510b2 may include reaction mixtures that include a sample solution, amplification reagents for amplifying any analyte of interest (e.g., nucleic acid) that may be present in the sample solution when exposed to appropriate amplification conditions (including prescribed thermal conditions), and a detectable probe configured to emit a detectable optical signal when bound to any analyte of interest that may be present in the sample solution or an amplification product thereof. The detectable probe may emit a detectable optical signal spontaneously (e.g., a chemiluminescent signal) or when excited by an optical excitation signal of a prescribed wavelength (e.g., fluorescence emitted by a fluorescent dye or a fluorophore).

In one example, where the test to be performed is a real-time PCR nucleic acid amplification assay, a first step may be to heat the reaction mixture contained in the reaction/detection chambers at temperature within the range of 40° C. to 60° C. (e.g. 46° C.) for period of 1 to 20 minutes (e.g. 5 minutes) to activate a reverse transcriptase (RT) within the reaction mixture when the target is RNA. When the target nucleic acid is a DNA, RT is not used, and this step may be omitted. A next step is to heat the reaction mixture at temperature of about 95° C. for a period of 30 seconds to 2 minutes to activate a hot start Taq polymerase enzyme within the reaction mixture. After activating the RT (in the case of an RNA target) and Taq polymerase, thermal cycling may begin. The thermal cycle may comprise two temperatures per cycle—e.g., 60° C. (the annealing temperature) for a period of about 5 to 30 seconds (e.g., 22 seconds) and then 90° C. to 95° C. (the melt temperature) for a period of about 1 to 5 seconds. In one example, 40 to 50 thermal cycles may be performed, and fluorescence from the contents of the reaction/detection chambers may be measured once each cycle (e.g., at 60° C.) to obtain 40 to 50 data points and from which an emergence of a fluorescent signal is detected or no fluorescent signal is detected due to the absence of the signal.

Although each chamber 510a1, 510a2, 510b1, 510b2 is exposed to the same temperature profile by the first thermal module 100 and the second thermal module 200, the thermal elements 108a, 108b of the first and second thermal assemblies 101a, 101b, respectively, of the first thermal module 100, and the thermal elements 208a, 208b of the first and second thermal assemblies 201a, 201b, respectively, of the second thermal module 200 are independently controlled. The first thermal assemblies 101a, 201a of the first and second thermal modules 100, 200, respectively, apply the same temperature profile to chambers 510a1, 510a2, and the second thermal assemblies 101b, 201b of the first and second thermal modules 100, 200, respectively, apply the same temperature profile to chambers 510b1, 510b2. The temperature profile applied to chambers 510a1, 510a2 may be the same as or different from the temperature profile applied to chambers 510b1, 510b2.

As shown in FIGS. 29 and 34, first thermal assembly 101a of first thermal module 100 has a separate and independent connector 140 connecting connector board 122 to control board 150 (e.g., via a ribbon cable (not shown)), and second thermal assembly 101b of first thermal module 100 has a separate and independent connector 142 connecting connector board 122 to control board 150 (e.g., via a ribbon cable (not shown)). As shown in FIGS. 30-32 and 37-41, first thermal assembly 201a of second thermal module 200 has a separate and independent connector 230a connecting connector board 222a to control board 150 via connector ribbon cable 232, and second thermal assembly 201b of second thermal module 200 has a separate and independent connector 230b connecting connector board 222b to control board 150 via connector ribbon cable 234. One or more controllers are provided for controlling the temperature of each thermal element 108a, 108b, 208a, 208b, and the controller(s) may be incorporated on the control board 150 or may be remote from the control board 150.

As noted above and explained below, in one example, power to and thermal energy generated by each of thermal elements 108a, 108b, 208a, 208b are independently controlled. To facilitate independent control of the thermal elements 108a, 108b, 208a, 208b, the controller(s) controlling the thermal elements may receive independent control feedbacks. For example, as shown in FIG. 35, first thermal assembly 101a of the first thermal module 100 may include thermistors or other thermal/temperature sensors 109a1, 109a2 embedded in the thermal block 102a, and second thermal assembly 101b of the first thermal module 100 may include thermistors or other thermal/temperature sensors 109b1, 109b2 embedded in the thermal block 102b that are independent of the thermistors 109a1, 109a2. Although each thermal assembly is shown having two thermistors, each thermal assembly may include fewer than, or more than, two thermistors. Thermistors 109a1, 109a2 provide temperature feedback signals to the controller(s) controlling power to the thermal element 108a to control the temperature of thermal element 108a and the temperature of thermal block 102a, and, for this purpose, thermistors 109a1, 109a2 may be connected to the controller(s) via the control board 150. Similarly, thermistors 109b1, 109b2 provide temperature feedback signals to the controller(s) controlling power to the thermal element 108b to control the temperature of thermal element 108b and the temperature of thermal block 102b, and, for this purpose, thermistors 109b1, 109b2 may be connected to the controller(s) via the control board 150. Control signals provided by thermistors 109a1, 109a2 are independent of control signals provided by thermistors 109b1, 109b2, and vice versa.

Similarly, first thermal assembly 201a of the second thermal module 200 may include one or more thermistors or other thermal/temperature sensors (not shown) embedded in the thermal block 202a, and second thermal assembly 201b of the second thermal module 200 may include one or more thermistors or other thermal/temperature sensors (not shown) embedded in the thermal block 202b. The thermistor(s) of the first thermal assembly 201a of the second thermal module 200 provide temperature feedback signals to the controller(s) controlling power to the thermal element 208a to control the temperature of thermal element 208a and the temperature of thermal block 202a, and, for this purpose, the thermistor(s) of thermal block 202a may be connected to the controller(s) via the control board 150. Similarly, the thermistor(s) of the second thermal assembly 201b of the second thermal module 200 provide temperature feedback signals to the controller(s) controlling power to the thermal element 208b to control the temperature of thermal element 208b and the temperature of thermal block 202b, and, for this purpose, the thermistor(s) of thermal block 202b may be connected to the controller(s) via the control board 150. Control signals provided by thermistor(s) of the first thermal assembly 201a are independent of control signals provided by thermistor(s) of the second thermal assembly 201b, and vice versa.

While each thermal assembly 101a, 101b, 201a, 201b is independently controlled, in an embodiment, all thermal assemblies may be controlled to the same temperature profile, as explained below.

One control input option for controlling the temperature of a thermal cycler is to hold the heating element (e.g., thermal elements 108a, 108b, 208a, 208b) at a first, lower temperature (e.g., 60° C.) for the required time and then apply a nearly instantaneous pulse of maximum power to increase the temperature of the heating element to a second, higher temperature (e.g., 90° C.) as quickly as possible and then allow the system (i.e., the thermal assembly) to stabilize at the second temperature. But, due to differences in the thermal characteristics (thermal inertia) of the different systems with which each heating element is associated, as well as differences in the performance of different heating elements, the time required for the various system components to stabilize at the second temperature can vary so that the contact surfaces 104a, 104b of thermal assemblies 101a, 101b, respectively, of the first thermal module 100 and the contact surfaces 204a, 204b of the thermal assemblies 201a, 201b, respectively, of the second thermal module 200 may reach the desired second temperature at different times. Thus, the different thermal assemblies heating opposite sides of the reaction/detection chambers 510a1, 510a2, 510b1, 510b2 may not be thermally synchronized. Factors that can affect how fast the system reaches a temperature set point include the size of the thermal element, the age of the thermal element, ambient temperature, thickness of the films 512, 530 on the cartridge 500 and whether a thermally-conductive laminate seal 532a, 532b is placed over the reaction/detection chambers (see FIGS. 8, 25 and 26), the size and material (thermal mass) of thermal blocks 102a, 102b, 202a, 202b, the size and material (thermal mass) of the mounting block 118 and the heat sinks 216a, 216b, etc.

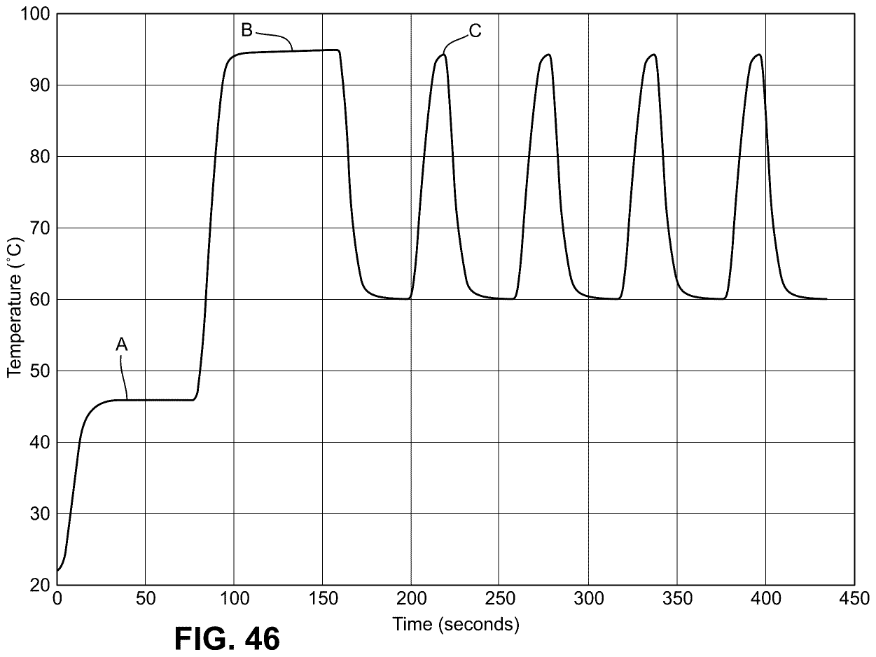

It has been discovered that, instead of applying a nearly instantaneous pulse of maximum power to increase the temperature of the heating element from the first temperature to the second temperature, applying a power input to the different thermal assemblies in the form of a power versus time profile (referred to as a power profile or power curve) in a smooth continuous fashion and controlled via thermal feedback allows each thermal assembly to “keep up” thermally, and thus, all thermal assemblies will follow the same temperature profile (i.e., temperature vs. time performance) and reach the desired temperature set points at the same time to remain thermally synchronized. An example of a temperature profile (or thermal waveform) for controlling the thermal assemblies 101a, 101b, 201a, 201b is shown in FIG. 46. The temperature profile includes a part “A” representing RT enzyme incubation at about 46° C. for a period of about 50 seconds, a part “B” representing enzyme hot start at about 95° C. for a period of about 67 seconds, and part “C” representing thermal cycles, wherein each cycle comprises incubation at about 60° C. for a period of about 22 seconds and incubation at about 95° C. for a period of about 5 seconds. Note also that within each cycle within part “C,” the transition from 60° C. to 95° C. is smooth and continuous over a period of about 22 seconds.

In one embodiment, the thermal elements 108a, 108b of the first and second thermal assemblies 101a, 101b, respectively, of the first thermal module 100, and thermal elements 208a, 208b of the first and second thermal assemblies 201a, 201b, respectively, of the second thermal module 200 are controlled independently to achieve a common temperature, or thermal, response profile, such as that shown in FIG. 46, for each of the thermal assemblies 101a, 101b, 201a, 201b. In one example, to achieve the same temperature profile of FIG. 46 in the thermal assemblies 101a, 101b, 201a, 201b, the power profiles (power vs. time) applied to each of the thermal elements 108a, 108b, 208a, 208b of the thermal assemblies may vary depending on the thermal inertia of the first and second thermal assemblies 101a, 101b, 201a, 201b of the first and second thermal modules 100, 200. Power is applied to each of the thermal elements 108a, 108b, 208a, 208b independently of the power applied to other thermal elements and the applied power to each thermal element may be in response to measurements of a thermal sensor (e.g., output of a thermistor) coupled to the thermal element (which is independent of the temperature sensor of the other thermal elements) as compared to the desired thermal profile. That is, each thermal assembly is driven to the same temperature profile (e.g., FIG. 46) by independently applying power to the thermal element of the thermal assembly in response to comparisons of measurements of the temperature sensor of the thermal assembly to the desired temperature profile.

In step S616, optical readings are taken from the reaction mixture within the reaction/detection chambers. As thermal energy is being applied to the reaction mixtures within the detection/reaction chambers 510a1, 510a2, 510b1, 510b2, each detection/reaction chamber can be interrogated for the emission of one or more detectable optical signals via optical fibers 130a1, 130a2, 130b1, 130b2 and signal detectors (optical devices 650a1, 650a2, 650b1, 650b2) constructed and arranged to detect optical signals transmitted by the fibers. As noted above, the signal detector(s) may comprise a photodetector for detecting light spontaneously emitted (e.g., chemiluminescence) from the reaction/detection chambers 510a1, 510a2, 510b1, 510b2 and which is indicative of the presence or absence of an analyte of interest (e.g., target molecule). In another example, the signal detector(s) may comprise a fluorometer including an excitation light source for emitting excitation of light of a prescribed excitation wavelength that is transmitted by the fiber to the reaction/detection chambers 510a1, 510a2, 510b1, 510b2 and an emission detector for detecting light of a prescribed emission wavelength that is emitted by the contents of the chamber (i.e., excitation light is absorbed by a fluorescent dye or a fluorophore, which then emits fluorescent light of a different wavelength) and transmitted by the fiber from the reaction/detection chamber to the emission detector.

### Hardware and Software

Aspects of the subject matter disclosed herein may be implemented via control and computing hardware components, software (which may include firmware), data input components, and data output components. Hardware components include computing and control modules (e.g., system controller(s)), such as processing circuitry, configured to effect computational and/or control steps by receiving one or more input values, executing one or more algorithms stored on non-transitory machine-readable media (e.g., software) that provide instruction for manipulating or otherwise acting on or in response to the input values, and output one or more output values. Such processing circuitry may include one or more processors (e.g., one or more general purpose microprocessors and/or one or more other processors, such as one or more computer(s), an application specific integrated circuit (ASIC), field-programmable gate arrays (FPGAs), and the like), which processors may be co-located in a single housing or in a single data center or may be geographically distributed (i.e., the processing circuitry may be encompassed by a distributed computing apparatus). Such outputs may be displayed or otherwise indicated to a user for providing information to the user, for example information as to the status of the instrument or of a process being performed thereby, or such outputs may comprise inputs to other processes and/or control algorithms. Data input components comprise elements by which data is input for use by the control and computing hardware components. Such data inputs may comprise signals generated by sensors or scanners, such as, position sensors, speed sensors, accelerometers, environmental (e.g., temperature) sensors, motor encoders, barcode scanners, or RFID scanners, as well as manual input elements, such as keyboards, stylus-based input devices, touch screens, microphones, switches, manually-operated scanners, etc. Data inputs may further include data retrieved from memory. Data output components may comprise hard drives or other storage media, monitors, printers, indicator lights, or audible signal elements (e.g., chime, buzzer, horn, bell, etc.).

The above-described techniques can be implemented in digital and/or analog electronic circuitry, or in computer hardware, firmware, software, or in combinations of them. The implementation can be as a computer program product, i.e., a computer program tangibly embodied in a machine-readable storage device, for execution by, or to control the operation of, a data processing apparatus, e.g., a programmable processor, a computer, and/or multiple computers. A computer program can be written in any form of computer or programming language, including source code, compiled code, interpreted code, and/or machine code, and the computer program can be deployed in any form, including as a stand-alone program or as a subroutine, element, or other unit suitable for use in a computing environment. A computer program can be deployed to be executed on one computer or on multiple computers at one or more sites.

Method steps can be performed by one or more processors executing a computer program to perform functions of the invention by operating on input data and/or generating output data. Method steps can also be performed by, and an apparatus can be implemented as, special purpose logic circuitry, e.g., a FPGA (field programmable gate array), a FPAA (field-programmable analog array), a CPLD (complex programmable logic device), a PSoC (Programmable System-on-Chip), ASIP (application-specific instruction-set processor), or an ASIC (application-specific integrated circuit). Subroutines can refer to portions of the computer program and/or the processor/special circuitry that implement one or more functions.

Processors suitable for the execution of a computer program include, by way of example, both general and special purpose microprocessors, and any one or more processors of any kind of digital or analog computer. Generally, a processor receives instructions and data from a read-only memory or a random-access memory or both. The essential elements of a computer are a processor for executing instructions and one or more memory devices for storing instructions and/or data. Memory devices, such as a cache, can be used to temporarily store data. Memory devices can also be used for long-term data storage. Generally, a computer also includes, or is operatively coupled to receive data from or transfer data to, or both, one or more mass storage devices for storing data, e.g., magnetic, magneto-optical disks, or optical disks. A computer can also be operatively coupled to a communications network in order to receive instructions and/or data from the network and/or to transfer instructions and/or data to the network. Computer-readable storage devices suitable for embodying computer program instructions and data include all forms of volatile and non-volatile memory, including by way of example semiconductor memory devices, e.g., DRAM, SRAM, EPROM, EEPROM, and flash memory devices; magnetic disks, e.g., internal hard disks or removable disks; magneto-optical disks; and optical disks, e.g., CD, DVD, HD-DVD, and Blu-ray disks. The processor and the memory can be supplemented by and/or incorporated in special purpose logic circuitry.

While the subject matter of this disclosure has been described and shown in considerable detail with reference to certain illustrative embodiments, including various combinations and sub-combinations of features, those skilled in the art will readily appreciate other embodiments and variations and modifications thereof as encompassed within the scope of the present disclosure. Moreover, the descriptions of such embodiments, combinations, and sub-combinations is not intended to convey that the claimed subject matter requires features or combinations of features other than those expressly recited in the claims. Accordingly, the scope of this disclosure is intended to include all modifications and variations encompassed within the scope of the following appended claims.

1. An assembly comprising:
a first thermal module comprising one or more thermal assemblies, wherein each thermal assembly of the first thermal module comprises:
a thermal element; and
a thermal block associated with the thermal element, wherein the thermal block has an exposed contact surface and at least one through hole extending through the thermal block, and wherein the thermal element and the associated thermal block of each thermal assembly are in thermal contact;
a second thermal module comprising one or more thermal assemblies, wherein each thermal assembly of the second thermal module comprises:
a thermal element; and
a thermal block associated with the thermal element, wherein the thermal block has an exposed contact surface, wherein the thermal element and the associated thermal block of each thermal assembly are in thermal contact, and wherein each contact surface of the second thermal module is situated in aligned opposition with respect to an associated contact surface of the first thermal module;
a thermal module actuator configured to effect automated relative movement between the first thermal module and the second thermal module to vary a distance between the contact surface of each thermal assembly of the second thermal module and the associated contact surface of each thermal assembly of the first thermal module; and
an optical fiber associated with each through hole extending through the thermal block of each thermal assembly of the first thermal module to transmit an optical signal through each thermal block of the first thermal module.

2. The assembly of claim 1, wherein each thermal block comprises at least one of a thermally conductive ceramic and a metal.

3. The assembly of claim 1, further comprising at least one of an optical emitter and an optical detector optically coupled to a proximal end of each optical fiber associated with the through hole extending through the thermal block of each thermal assembly of the first thermal module.

4. The assembly of claim 1, wherein the first thermal module comprises two thermal assemblies, and wherein the second thermal module comprises two thermal assemblies.

5. The assembly of claim 1, wherein the thermal block of each thermal assembly of the first thermal module includes at least two through holes extending through the thermal block.

6. The assembly claim 1, wherein the thermal element of each thermal assembly of the first thermal module includes a through hole that is associated with each through hole extending through the associated thermal block of the first thermal module, and wherein each optical fiber extends through one of the through holes extending through the thermal element of the first thermal module.

7. The assembly of claim 1, wherein the through hole extends through the thermal block of each thermal assembly of the first thermal module to the contact surface, and wherein the optical fiber associated with each through hole extends at least partially through the associated through hole or is aligned with the associated through hole.

8. The assembly of claim 7, wherein each optical fiber extends fully through the associated hole so that an end of the optical fiber is flush with the contact surface.

9. The assembly of claim 7, wherein each optical fiber extends through the associated hole so that an end of the optical fiber extends from 0.05 mm to 0.35 mm above the contact surface of the associated thermal block.

10. The assembly of claim 1, wherein the thermal block of each thermal assembly of the second thermal module has at least one through hole extending through the thermal block, and wherein the assembly comprises an optical fiber associated with each through hole extending through the thermal block of each thermal assembly of the second thermal module to transmit an optical signal through each thermal block of the second thermal module.

11. The assembly of claim 10, further comprising at least one of an optical emitter and an optical detector optically coupled to a proximal end of each optical fiber associated with the through hole extending through the thermal block of each thermal assembly of the second thermal module.

12. The assembly of claim 10, wherein the thermal block of each thermal assembly of the second thermal module includes at least two through holes extending through the thermal block.

13. The assembly of claim 10, wherein the thermal element of each thermal assembly of the second thermal module includes a through hole that is associated with each through hole extending through the associated thermal block of the second thermal module, and wherein each optical fiber extends through one of the through holes extending through the thermal element of the second thermal module.

14. The assembly of claim 1, wherein each thermal assembly of the first thermal module comprises a cover positioned over the thermal element and the associated thermal block of the thermal assembly, wherein the cover has an opening formed therein through which the contact surface of the thermal block is exposed, and wherein each thermal assembly of the second thermal module comprises a cover positioned over the thermal element and the associated thermal block of the thermal assembly, wherein the cover has an opening formed therein through which the contact surface of the thermal block is exposed, and wherein the cover comprises a plastic.

15. The assembly of claim 1, wherein the thermal element of each thermal assembly of the first thermal module comprises a thermoelectric module, and wherein the thermal element of each thermal assembly of the second thermal module comprises a thermoelectric module.

16. The assembly of claim 1, wherein each thermal assembly of the second thermal module comprises a heat sink including a plurality of heat dissipation fins, and wherein the thermal element of each thermal assembly of the second thermal module is in thermal contact with the heat sink.

17. The assembly of claim 16, further comprising a heat sink heater operatively associated with each heat sink.

18. The assembly of claim 1, further comprising a mounting block, wherein the thermal element of each thermal assembly of the first thermal module is in thermal contact with the mounting block.

19. The assembly of claim 18, further comprising a mounting block heater operatively associated with the mounting block.

20. The assembly of claim 18, further comprising a fan positioned adjacent the mounting block.

21. The assembly of claim 1, further comprising:
a heat sink associated with the second thermal module, wherein the heat sink comprises a plurality of heat dissipation fins, and wherein the thermal element of each thermal assembly of the second thermal module is in thermal contact with the heat sink;
a cover positioned over the thermal element and associated thermal block of each thermal assembly of the second thermal module, wherein the cover has an opening extending therein through which the contact surface of the associated thermal block is exposed, at least two fasteners securing the cover to the heat sink of each thermal assembly of the second thermal module, each fastener extending through a hole through a portion of the heat sink and into the cover of each thermal assembly of the second thermal module; and
a spring disposed over each of the at least two fasteners between a head of the fastener and a surface of the heat sink of the second thermal module.

22. The assembly of claim 21, wherein the heat sink comprises a separate heat sink for each thermal assembly of the second thermal module.

23. The assembly of claim 1, further comprising:
a mounting block associated with the first thermal module, wherein the thermal element of each thermal assembly of the first thermal module is in thermal contact with the mounting block;
a cover positioned over each thermal element and associated thermal block of each thermal assembly of the first thermal module, wherein the cover has an opening formed therein through which the contact surface of the thermal block is exposed, at least two fasteners securing the cover of each thermal assembly of the first thermal module to the mounting block, each fastener extending through a hole through a portion of the mounting block and into the cover; and
a spring disposed over each of the at least two fasteners securing the cover of each thermal assembly of the first thermal module to the mounting block between a head of the fastener and a surface of the mounting block.

24. The assembly of claim 1, wherein the second thermal module is fixed and the first thermal module is movable, and wherein the thermal module actuator is coupled to the first thermal module and is configured to move the first thermal module between a first position and a second position with respect to the second thermal module, wherein the contact surface of each thermal assembly of the first thermal module is closer to the associated contact surface of each thermal assembly of the second thermal module when the first thermal module is in the second position than when the first thermal module is in the first position.

25. The assembly of claim 24, further comprising a contact detector coupled to the first thermal module and configured generate a detectable signal when the contact detector contacts a test platform disposed between the first thermal module and the second thermal module when the first thermal module is moved from the first position to the second position.

26. The assembly of claim 24, wherein the thermal module actuator comprises: a motor secured to a motor mount; and a lead screw coupled to the motor and to the first thermal module so that rotation of the lead screw by the motor effects movement of the first thermal module with respect to the second thermal module from the first position to the second position or from the second position to the first position.

27. The assembly of claim 26, wherein the motor is mounted to a motor mounting plate that is supported by the motor mount, wherein, when the first thermal assembly is moved to the second position by the thermal module actuator, continued operation of the motor causes the motor mounting plate to separate from the motor mount, and wherein the assembly further comprises at least one spring disposed between the motor mounting plate and a portion of the motor mount, such that a spring force of each spring increases as the motor mounting plate separates from the motor mount.

28. The assembly of claim 27, wherein the motor mount comprises:
side supports;
a top crossbar extending between the side supports; and
an intermediate crossbar extending between the side supports at a spaced-apart position from the top crossbar, wherein the motor and motor mounting plate are supported on the intermediate cross bar such that when the first thermal assembly is moved to the second position by the thermal module actuator, continued operation of the motor causes the motor mounting plate to separate from the intermediate crossbar and move toward the top crossbar, and wherein the at least one spring comprises two springs disposed between the motor mounting plate and the top crossbar.

29. The assembly of claim 28, further comprising:
an upper block to which the first thermal module is attached, wherein the lead screw is coupled to the upper block; and
linear bearings positioned between the intermediate crossbar and the upper block.

30. The assembly of claim 1, further comprising a movable tray for supporting a test platform and configured for selective, motorized movement between an extended position not located between the first and second thermal modules and a retracted position located between the first and second thermal modules.
